(19) United States
(12) Patent Application Publication
(10) Pub. No.: US 2024/0343743 A1
(43) Pub. Date: Oct. 17, 2024

(54) LIGHT EMITTING ELEMENT, POLYCYCLIC COMPOUND FOR THE SAME, AND DISPLAY DEVICE INCLUDING THE LIGHT EMITTING ELEMENT

(71) Applicant: Samsung Display Co., Ltd., Yongin-si (KR)

(72) Inventor: Nobutaka AKASHI, Yokohama (JP)

(73) Assignee: Samsung Display Co., Ltd., Yongin-si (KR)

(21) Appl. No.: 18/439,153

(22) Filed: Feb. 12, 2024

(30) Foreign Application Priority Data
Apr. 5, 2023 (KR) 10-2023-0044630

(51) Int. Cl. C07F 5/02; C09K 11/06; H10K 50/12; H10K 50/15; H10K 50/16; H10K 85/30; H10K 85/60

(52) U.S. Cl. CPC C07F 5/02; C09K 11/06; H10K 50/12; H10K 50/15; H10K 50/16; H10K 85/342; H10K 85/658; C09K 2211/1022

(57) ABSTRACT

Embodiments provide a polycyclic compound and a light emitting element that includes the polycyclic compound. The light emitting element includes a first electrode, a second electrode facing to the first electrode, and at least one functional layer disposed between the first electrode and the second electrode, wherein the at least one functional layer includes the polycyclic compound. The polycyclic compound is represented by Formula 1, which is explained in the specification.

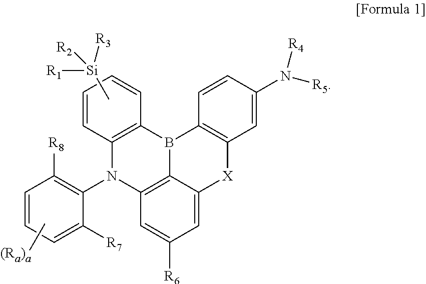

### CROSS-REFERENCE TO RELATED APPLICATION(S)

This application claims priority to and benefits of Korean Patent Application No. 10-2023-0044630 under 35 U.S.C. § 119, filed on Apr. 5, 2023, in the Korean Intellectual Property Office, the entire contents of which are incorporated herein by reference.

### BACKGROUND

### 1. Technical Field

The disclosure relates to a polycyclic compound, a light emitting element including the same, and a display device including the light emitting element.

### 2. Description of the Related Art

Active development continues for an organic electroluminescence display device as an image display device. An organic electroluminescence display device is so-called a display device of a self-luminescent type in which holes and electrons respectively injected from a first electrode and a second electrode recombine in an emission layer so that a light emitting material in the emission layer emits light to achieve display.

In the application of a light emitting element to a display device, there is a demand for an organic electroluminescence device having a low driving voltage, high emission efficiency, and a long lifetime, and continuous development is required on materials for a light emitting element that are capable of stably achieving such characteristics.

In order to implement an organic electroluminescence display device with high emission efficiency, technologies pertaining to phosphorescence emission, which uses triplet state energy, or to fluorescence emission, which uses triplet-triplet annihilation (TTA) in which singlet excitons are generated by the collision of triplet excitons, are being developed. Development is currently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved emission efficiency and lifetime.

The disclosure also provides a polycyclic compound which is capable of improving emission efficiency and lifetime of a light emitting element.

The disclosure provides a display device having excellent display quality by including a light emitting element having improved emission efficiency and lifetime.

An embodiment provides a light emitting element which may include a first electrode, a second electrode facing to the first electrode, and at least one functional layer disposed between the first electrode and the second electrode, wherein the at least one functional layer may include a first compound represented by Formula 1.

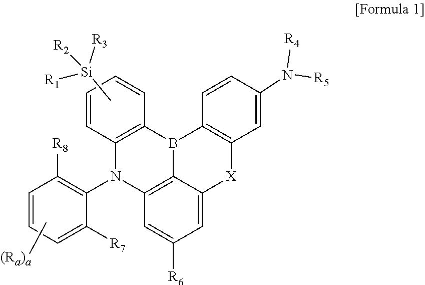

In Formula 1, X may be N(Ar), O, or S; Ar may be a substituted or unsubstituted aryl group of 6 to 30 ring-forming carbon atoms; R₁ to R₅ may each independently be a substituted or unsubstituted alkyl group of 1 to 30 carbon atoms, a substituted or unsubstituted aryl group of 6 to 30 ring-forming carbon atoms, or combined with an adjacent group to form a ring; R₆ and Rₐ may each independently be a hydrogen atom, a substituted or unsubstituted alkyl group of 3 to 30 carbon atoms, or a substituted or unsubstituted aryl group of 6 to 30 ring-forming carbon atoms; at least one of R₇ and R₈ may each independently be a substituted or unsubstituted alkyl group of 3 to 30 carbon atoms or a substituted or unsubstituted aryl group of 6 to 30 ring-forming carbon atoms, and the remainder of R₇ and R₈ may be a hydrogen atom; a may be an integer from 0 to 3; and at least one hydrogen atom may be optionally substituted with a deuterium atom.

In an embodiment, the first compound may be represented by Formula 1-1a or Formula 1-1b.

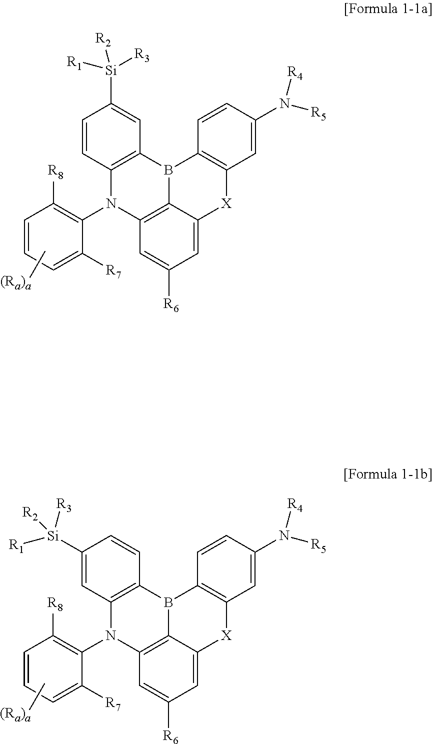

In Formula 1-1a and Formula 1-1b, X, R₁ to R₈, Rₐ, and a may be each as defined in Formula 1.

In an embodiment, the first compound may be represented by Formula 1-2a or Formula 1-2b.

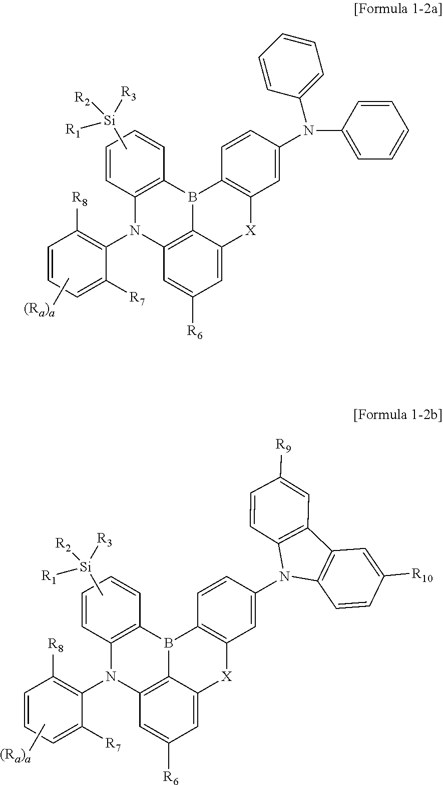

In Formula 1-2a and Formula 1-2b, R₉ and R₁₀ may each independently be a hydrogen atom, a substituted or unsubstituted alkyl group of 3 to 30 carbon atoms, or a substituted or unsubstituted aryl group of 6 to 30 ring-forming carbon atoms; and X, R₁ to R₃, R₆ to R₈, Rₐ, and a may be each as defined in Formula 1.

In an embodiment, the first compound may be represented by one of Formula 1-3a to Formula 1-3c.

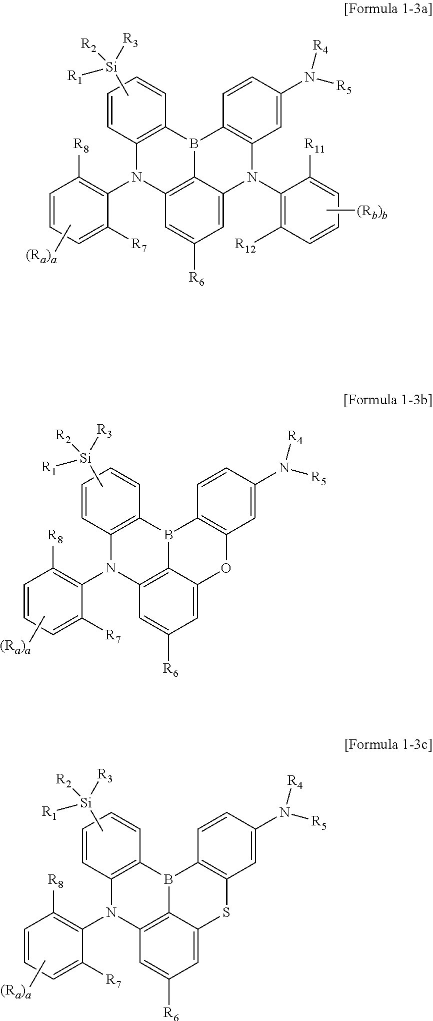

In Formula 1-3a to Formula 1-3c, at least one of R₁₁ and R₁₂ may each independently be a substituted or unsubstituted alkyl group of 3 to 30 carbon atoms, or a substituted or unsubstituted aryl group of 6 to 30 ring-forming carbon atoms, and the remainder of R₁ and R₁₂ may be a hydrogen atom; Re may be a hydrogen atom, a substituted or unsubstituted alkyl group of 3 to 30 carbon atoms, or a substituted or unsubstituted aryl group of 6 to 30 ring-forming carbon atoms; b may be an integer from 0 to 3; and R₁ to R₈, Rₐ, and a may be each as defined in Formula 1.

In an embodiment, the first compound may be represented by one of Formula 1-4a to Formula 1-4c.

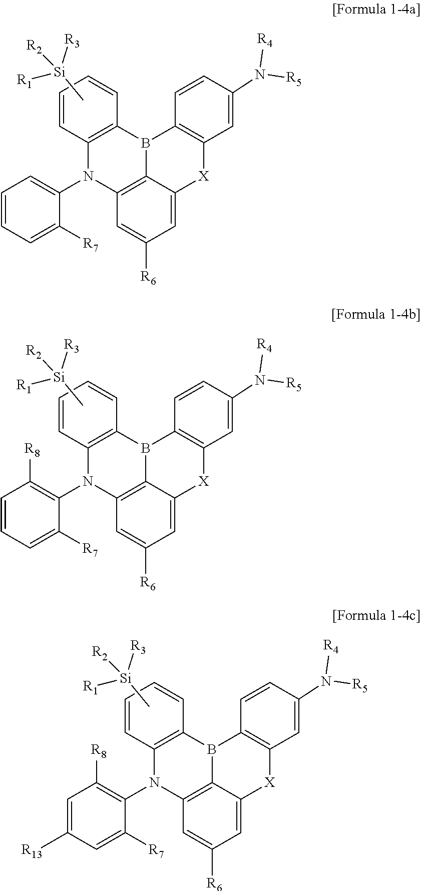

In Formula 1-4a to Formula 1-4c, R₇, R₈, and R₁₃ may each independently be an unsubstituted i-propyl group, an unsubstituted t-butyl group, or a substituted or unsubstituted phenyl group; and X and R₁ to R₆ may be each as defined in Formula 1.

In an embodiment, the first compound may be represented by one of Formula 1-5a to Formula 1-5e.

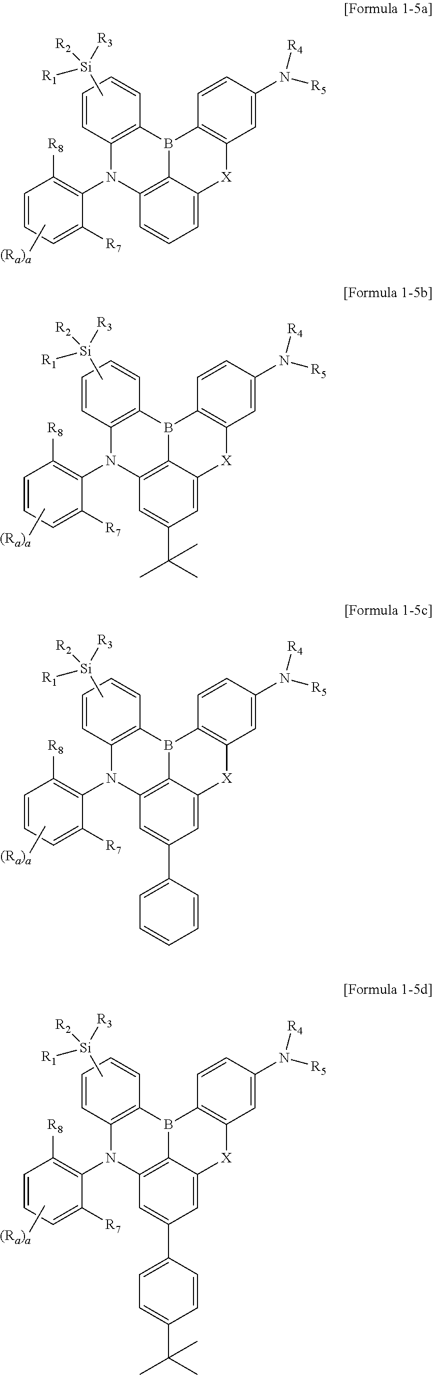

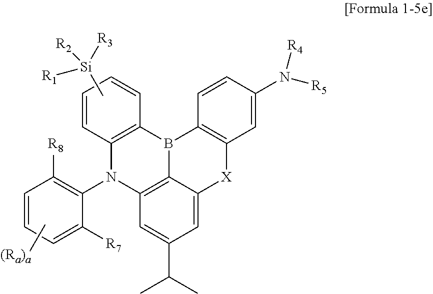

In Formula 1-5a to Formula 1-5e, X, R₁ to R₈, R₇, R₈, Rₐ, and a may be each as defined in Formula 1.

In an embodiment, R₁ to R₃ may each independently be an unsubstituted methyl group or an unsubstituted phenyl group.

In an embodiment, the first compound may include at least one compound selected from Compound Group 1, which is explained below.

In an embodiment, the at least one functional layer may further include at least one of a second compound represented by Formula HT and a third compound represented by Formula ET.

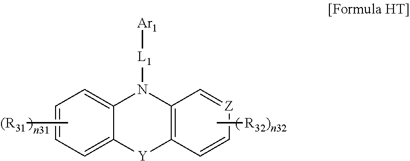

In Formula HT, L₁ may be a direct linkage, a substituted or unsubstituted arylene group of 6 to 30 ring-forming carbon atoms, or a substituted or unsubstituted heteroarylene group of 2 to 30 ring-forming carbon atoms; Ar may be a substituted or unsubstituted aryl group of 6 to 30 ring-forming carbon atoms or a substituted or unsubstituted heteroaryl group of 2 to 30 ring-forming carbon atoms; Y may be a direct linkage, C(R_{y1})(R_{y2}), or Si(R_{y3})(R_{y4}); Z may be C(R_{z}) or N; R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; n31 may be an integer from 0 to 4; and n32 may be an integer from 0 to 3.

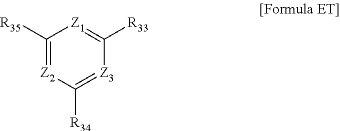

In Formula ET, Z₁ to Z₃ may each independently be N or C(R₃₆); at least one of Z₁ to Z₃ may each be N; and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring.

In an embodiment, the at least one functional layer may include the first compound, the second compound, and the third compound.

In an embodiment, the at least one functional layer may include an emission layer, a hole transport region disposed between the first electrode and the emission layer, and an electron transport region disposed between the emission layer and the second electrode; and the emission layer may include the first compound, and at least one of the second compound and the third compound.

In an embodiment, the emission layer may emit delayed fluorescence.

In an embodiment, the emission layer may emit blue light.

In an embodiment, the at least one functional layer may further include a fourth compound represented by Formula PS.

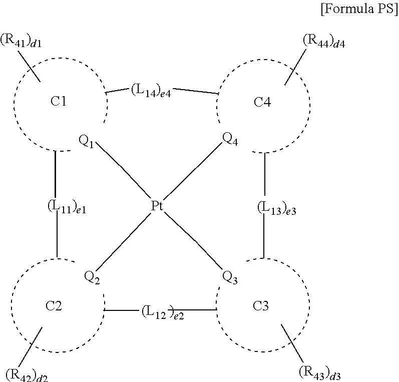

In Formula PS, Q₁ to Q₄ may each independently be C or N; C1 to C4 may each independently be a substituted or unsubstituted hydrocarbon ring of 5 to 30 ring-forming carbon atoms or a substituted or unsubstituted heterocycle of 2 to 30 ring-forming carbon atoms; L₁₁ to L₁₄ may each independently be a direct linkage,

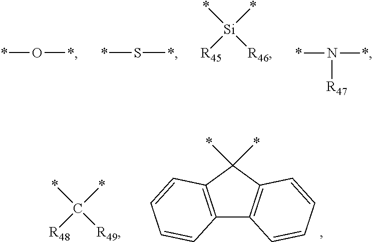

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, wherein in L₁₁ to L₁₄, ----* represents a bond to one of C1 to C4; e1 to e4 may each independently be 0 or 1; R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring; and d1 to d4 may each independently be an integer from 0 to 4.

In an embodiment, the at least one functional layer may include the first compound, the second compound, the third compound, and the fourth compound.

Another embodiment provides a polycyclic compound represented by Formula 1, which is explained herein.

In an embodiment, the polycyclic compound represented by Formula 1 may be represented by Formula 1-1a or Formula 1-1b, which are explained herein.

In an embodiment, the polycyclic compound represented by Formula 1 may be represented by Formula 1-2a or Formula 1-2b, which are explained herein.

In an embodiment, the polycyclic compound represented by Formula 1 may be represented by one of Formula 1-3a to Formula 1-3c, which are explained herein.

In an embodiment, the polycyclic compound represented by Formula 1 may be represented by one of Formula 1-4a to Formula 1-4c, which are explained herein.

In an embodiment, the polycyclic compound represented by Formula 1 may be represented by one of Formula 1-5a to Formula 1-5e, which are explained herein.

In an embodiment, R₁ to R₃ may each independently be an unsubstituted methyl group or an unsubstituted phenyl group.

In an embodiment, the polycyclic compound represented by Formula 1 may be selected from Compound Group 1, which is explained below.

Another embodiment provides a display device which may include a base layer, a circuit layer disposed on the base layer, and a display element layer disposed on the circuit layer and including a light emitting element. The light emitting element may include a first electrode, a second electrode facing the first electrode, and at least one functional layer disposed between the first electrode and the second electrode. The functional layer may include a first compound represented by Formula 1, and at least one of a second compound represented by Formula HT and a third compound represented by Formula ET. Formulas 1, HT, and ET are explained herein.

In an embodiment, the at least one functional layer may include an emission layer, a hole transport region disposed between the first electrode and the emission layer, and an electron transport region disposed between the emission layer and the second electrode; and the emission layer may include the first compound, and at least one of the second compound and the third compound.

In an embodiment, the light emitting element may include a first light emitting element emitting red light, a second light emitting element emitting green light, and a third light emitting element emitting blue light; and the third light emitting element may include the first compound.

In an embodiment, the light emitting element may emit blue light.

In an embodiment, the display device may further include a light controlling layer disposed on the display element layer and including a quantum dot.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic diagram of an interior of a vehicle including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may be monocyclic or polycyclic. A ring that is formed by adjacent groups being combined with each other may itself be connected to another ring to form a spiro structure.

In the specification, the term “adjacent group” may be interpreted as a substituent that is substituted for an atom which is directly combined with an atom substituted with a corresponding substituent, as another substituent that is substituted for an atom which is substituted with a corresponding substituent, or as a substituent that is sterically positioned at the nearest position to a corresponding substituent. For example, in 1,2-dimethylbenzene, two methyl groups may be interpreted as “adjacent groups” to each other, and two ethyl groups in 1,1-diethylcyclopentene may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group including one or more carbon-carbon double bonds in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., but embodiments are not limited thereto.

In the specification, an alkynyl group may be a hydrocarbon group including one or more carbon-carbon triple bonds in the middle or at a terminus of an alkyl group having 2 or more carbon number. An alkynyl group may be linear or branched. The number of carbon atoms in an alkynyl group is not particularly limited, but may be 2 to 30, 2 to 20, or 2 to 10. Examples of the alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group of 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be combined with each other to form a spiro structure. Examples of a substituted fluorenyl group may include the groups shown below. However, embodiments are not limited thereto.

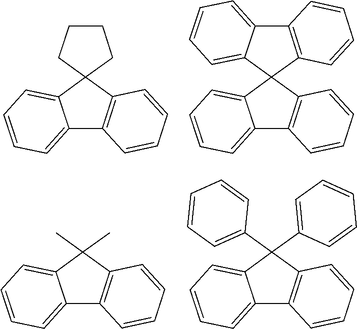

In the specification, a heterocyclic group may be any functional group or substituent derived from a ring including one or more of B, O, N, P, Si, S, and Se as heteroatoms. A heterocyclic group may be an aliphatic heterocyclic group or an aromatic heterocyclic group. An aromatic heterocyclic group may be a heteroaryl group. An aliphatic heterocyclic group and an aromatic heterocyclic group may each independently be monocyclic or polycyclic. If a heterocyclic group includes two or more heteroatoms, the two or more heteroatoms may be the same as or different from each other.

In the specification, an aliphatic heterocyclic group may include one or more of B, O, N, P, Si, S, and Se as heteroatoms. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include one or more of B, O, N, P, Si, S, and Se as heteroatoms. If a heteroaryl group includes two or more heteroatoms, the two or more heteroatoms may be the same as or different from each other. The heteroaryl group may be monocyclic or polycyclic. The number of ring-forming carbon in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not particularly limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamine group, etc., but embodiments are not limited thereto.

In the specification, the number of carbon atoms in a carbonyl group is not particularly limited, but the number of carbon atoms may be 1 to 40, 1 to 30, or 1 to 20. For example, a carbonyl group may have one of the following structures, but embodiments are not limited thereto.

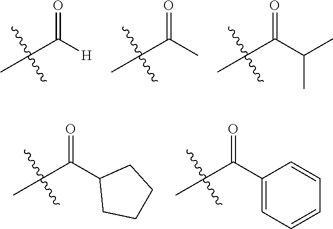

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. The oxy group may be an alkoxy group or an aryl oxy group. An alkoxy group may be linear, branched, or cyclic. The number of carbon atoms in an alkoxy group is not particularly limited but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group include a dimethylboron group, a diethylboron group, a t-butylmethylboron group, a diphenylboron group, a phenylboron group, etc., but embodiments are not limited thereto.

In the specification, the number of carbon atoms of an amine group is not limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, alkyl groups within an alkylthio group, alkylsulfoxy group, alkylaryl group, alkylamino group, alkylboron group, alkyl silyl group, or alkyl amine group may be the same as an example of an alkyl group as described above.

In the specification, aryl groups within an aryloxy group, arylthio group, arylsulfoxy group, aryl amino group, arylboron group, aryl silyl group, and aryl amine group may be the same as an example of an aryl group as described above.

In the specification, a direct linkage may be a single bond.

In the specification, the symbols

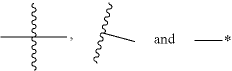

each represent a bond to a neighboring atom in a corresponding formula or moiety.

Hereinafter, embodiments will be described with reference to the accompanying drawings.

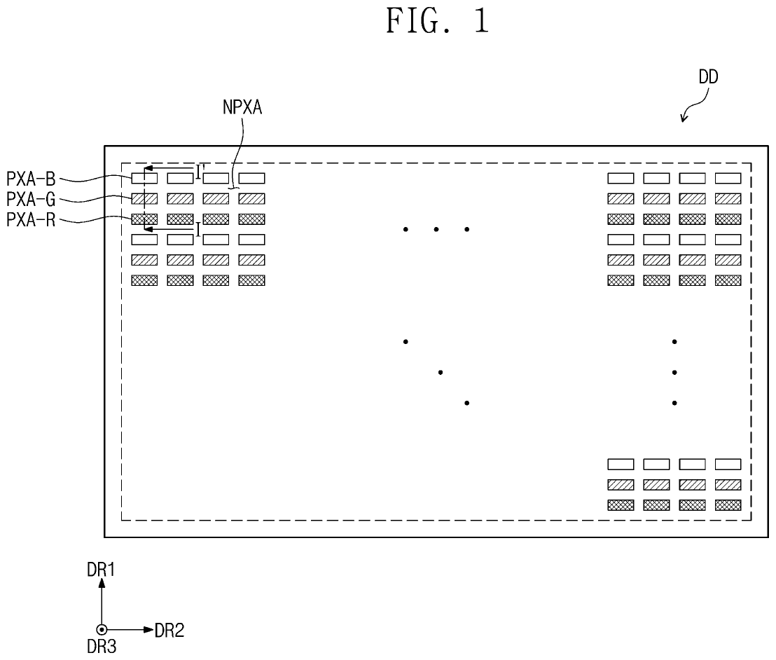

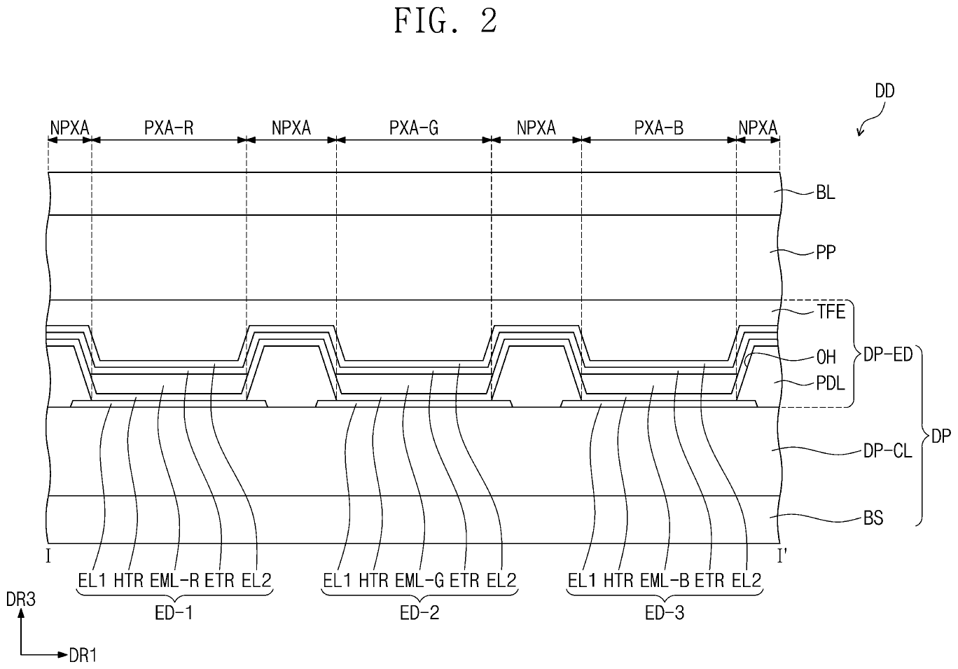

FIG. 1 is a schematic plan view of a display device DD according to an embodiment. FIG. 2 is a schematic cross-sectional view of a display device DD according to an embodiment. FIG. 2 is a schematic cross-sectional view showing a part taken along line I-I′ in FIG. 1.

The display device DD may include a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a plugging layer (not shown). The plugging layer (not shown) may be disposed between a display element layer DP-ED and a base substrate BL. The plugging layer (not shown) may be an organic layer. The plugging layer (not shown) may include at least one of an acrylic resin, a silicon-based resin, and an epoxy-based resin.

The display panel DP may include a base layer BS, a circuit layer DP-CL provided on the base layer BS, and a display element layer DP-ED. The display element layer DP-ED may include a pixel definition layer PDL, light emitting elements ED-1, ED-2, and ED-3 disposed in the pixel definition layer PDL, and an encapsulating layer TFE disposed on the light emitting elements ED-1, ED-2, and ED-3.

The base layer BS provides a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include switching transistors and driving transistors for driving the light emitting elements ED-1, ED-2, and ED-3 of the display element layer DP-ED.

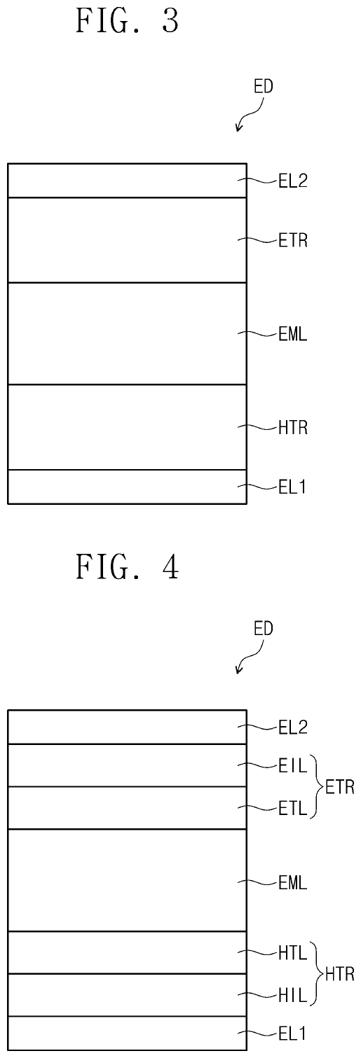

The light emitting elements ED-1, ED-2, and ED-3 may each have a structure of a light emitting element ED according to an embodiment according to any of FIG. 3 to FIG. 6, which are explained below. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment where the emission layers EML-R, EML-G, and EML-B of light emitting elements ED-1, ED-2, and ED-3 are disposed in openings OH defined in a pixel definition layer PDL, and a hole transport region HTR, an electron transport region ETR, and a second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel definition layer PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an ink jet printing method.

An encapsulating layer TFE may cover the light emitting elements ED-1, ED-2, and ED-3. The encapsulating layer TFE may encapsulate the display element layer DP-ED. The encapsulating layer TFE may be a thin film encapsulating layer. The encapsulating layer TFE may be a single layer or a stack of multiple layers. The encapsulating layer TFE may include at least one insulating layer. The encapsulating layer TFE according to an embodiment may include at least one inorganic layer (hereinafter, encapsulating inorganic layer). In an embodiment, the encapsulating layer TFE may include at least one organic layer (hereinafter, encapsulating organic layer) and at least one encapsulating inorganic layer.

The encapsulating inorganic layer protects the display element layer DP-ED from moisture and/or oxygen, and the encapsulating organic layer protects the display element layer DP-ED from foreign materials such as dust particles. The encapsulating inorganic layer may include silicon nitride, silicon oxy nitride, silicon oxide, titanium oxide, or aluminum oxide, but embodiments are not limited thereto. The encapsulating organic layer may include an acrylic compound, an epoxy-based compound, etc. The encapsulating organic layer may include a photopolymerizable organic material, but embodiments are not limited thereto.

The encapsulating layer TFE may be disposed on the second electrode EL2 and may be disposed to fill openings OH.

Referring to FIG. 1 and FIG. 2, the display device DD may include non-luminous areas NPXA and luminous areas PXA-R, PXA-G, and PXA-B. The luminous areas PXA-R, PXA-G, and PXA-B may each be an area that emits light respectively produced from the light emitting elements ED-1, ED-2, and ED-3. The luminous areas PXA-R, PXA-G, and PXA-B may be separated from each other in a plan view.

The luminous areas PXA-R, PXA-G, and PXA-B may each be an area separated by the pixel definition layer PDL. The non-luminous areas NPXA may be areas between neighboring luminous areas PXA-R, PXA-G, and PXA-B and which may correspond to the pixel definition layer PDL. In an embodiment, the luminous areas PXA-R, PXA-G, and PXA-B may each correspond to a pixel. The pixel definition layer PDL may separate the light emitting elements ED-1, ED-2, and ED-3. The emission layers EML-R, EML-G, and EML-B of the light emitting elements ED-1, ED-2, and ED-3 may be disposed in the openings OH defined in the pixel definition layer PDL and separated from each other.

The luminous areas PXA-R, PXA-G, and PXA-B may be arranged into groups according to the color of light produced from the light emitting elements ED-1, ED-2, and ED-3. In the display device DD according to an embodiment shown in FIG. 1 and FIG. 2, three luminous areas PXA-R, PXA-G, and PXA-B, which respectively emit red light, green light, and blue light are illustrated as an example. For example, the display device DD according to an embodiment may include a red luminous area PXA-R, a green luminous area PXA-G, and a blue luminous area PXA-B, which are distinct from one another.

In the display device DD according to an embodiment, light emitting elements ED-1, ED-2, and ED-3 may emit light having wavelengths that are different from each other. For example, in an embodiment, the display device DD may include a first light emitting element ED-1 emitting red light, a second light emitting element ED-2 emitting green light, and a third light emitting element ED-3 emitting blue light. For example, the red luminous area PXA-R, the green luminous area PXA-G, and the blue luminous area PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength region, or at least one light emitting element may emit light in a wavelength that is different from the remainder. For example, the first to third light emitting elements ED-1, ED-2, and ED-3 may each emit blue light.

The luminous areas PXA-R, PXA-G, and PXA-B in the display device DD according to an embodiment may be arranged in a stripe configuration. Referring to FIG. 1, the red luminous areas PXA-R, the green luminous areas PXA-G, and the blue luminous areas PXA-B may be respectively arranged along a second direction DR2. In another embodiment, the red luminous area PXA-R, the green luminous area PXA-G, and the blue luminous area PXA-B may be arranged in this repeating order along a first direction DR1.

FIG. 1 and FIG. 2 illustrate that the luminous areas PXA-R, PXA-G, and PXA-B all have a similar area, but embodiments are not limited thereto. In an embodiment, the areas of the luminous areas PXA-R, PXA-G, and PXA-B may be different in size or shape from each other, according to a wavelength region of emitted light. The areas of the luminous areas PXA-R, PXA-G, and PXA-B may be areas in a plan view that are defined by the first direction DR1 and the second direction DR2.

An arrangement of the luminous areas PXA-R, PXA-G, and PXA-B is not limited to the configuration shown in FIG. 1, and the order in which the red luminous areas PXA-R, the green luminous areas PXA-G, and the blue luminous areas PXA-B are arranged may be provided in various combinations, according to the display quality characteristics that are required for the display device DD. For example, the luminous areas PXA-R, PXA-G, and PXA-B may be arranged in a pentile configuration (such as PENTILE™), or in a diamond configuration (such as Diamond Pixel™).

The areas of the luminous areas PXA-R, PXA-G, and PXA-B may be different in size from each other. For example, in an embodiment, an area of a green luminous area PXA-G may be smaller than an area of a blue luminous area PXA-B, but embodiments are not limited thereto.

In the display device DD according to an embodiment shown in FIG. 2, at least one of the first to third light emitting elements ED-1, ED-2, and ED-3 may include the polycyclic compound according to an embodiment, which will be explained below.

Hereinafter, FIG. 3 to FIG. 6 are each a schematic cross-sectional view of a light emitting element according to an embodiment. The light emitting element ED according to an embodiment may include a first electrode EL1, a second electrode EL2 facing the first electrode EL1, and at least one functional layer disposed between the first electrode EL1 and the second electrode EL2. The light emitting element ED according to an embodiment may include a first compound according to an embodiment, which will be explained below, in the at least one functional layer. In the specification, the polycyclic compound according to an embodiment may be referred to as a first compound.

The light emitting element ED may include a hole transport region HTR, an emission layer EML, an electron transport region ETR, or the like, as the at least one functional layer. Referring to FIG. 3, the light emitting element ED according to an embodiment may include a first electrode EL1, a hole transport region HTR, an emission layer EML, an electron transport region ETR, and a second electrode EL2. In an embodiment, a light emitting element ED may include the polycyclic compound according to an embodiment, which will be explained below, in the emission layer EML.

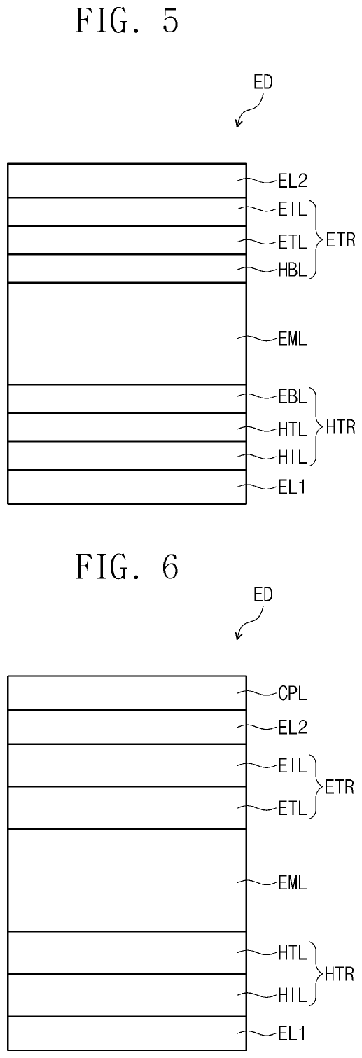

In comparison to FIG. 3, FIG. 4 shows a schematic cross-sectional view of a light emitting element ED according to an embodiment, wherein a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (for example, a mixture of Ag and Mg). In another embodiment, the first electrode EL1 may have a structure of multiple layers including a reflective layer or a transflective layer formed of the above materials, and a transmissive conductive layer formed of ITO, IZO, ZnO, or ITZO. For example, the first electrode EL1 may have a three-layer structure of ITO/Ag/ITO, but embodiments are not limited thereto. In an embodiment, the first electrode EL1 may include the above-described metal materials, combinations of two or more metal materials selected from the above-described metal materials, or oxides of the above-described metal materials. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission auxiliary layer (not shown), or an electron blocking layer EBL. A thickness of the hole transport region HTR may be in a range of about 50 Å to about 15,000 Å.

The hole transport region HTR may be a layer consisting of a single material, a layer including different materials, or a structure including multiple layers including different materials.

In embodiments, the hole transport region HTR may have a structure of a single layer of a hole injection layer HIL or a hole transport layer HTL, or may have a structure of a single layer formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

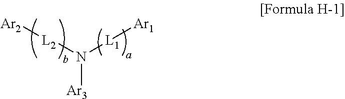

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formular H-1, a and b may each independently be an integer from 0 to 10. If a or b is 2 or more, multiple L₁ groups and multiple L₂ groups may each independently be a substituted or unsubstituted arylene group of 6 to 30 ring-forming carbon atoms or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. In Formula H-1, Ar₃ may be a substituted or unsubstituted aryl group of 6 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ may include an amine group as a substituent. In another embodiment, a compound represented by Formula H-1 may be a carbazole-based compound in which at least one of Ar₁ and Ar₂ may include a substituted or unsubstituted carbazole group, or may be a fluorene-based compound in which at least one of Ar₁ and Ar₂ may include a substituted or unsubstituted fluorene group.

The compound represented by Formula H-1 may be any compound selected from in Compound Group H-1. However, the compounds shown in Compound Group H-1 are only examples, and the compound represented by Formula H-1 is not limited to Compound Group H-1.

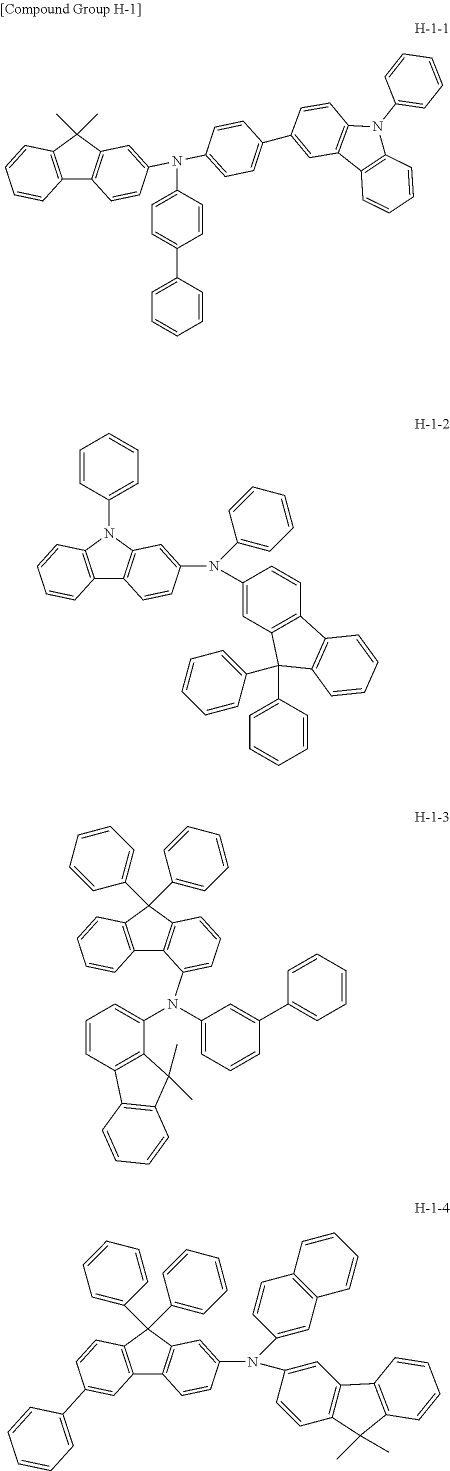 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

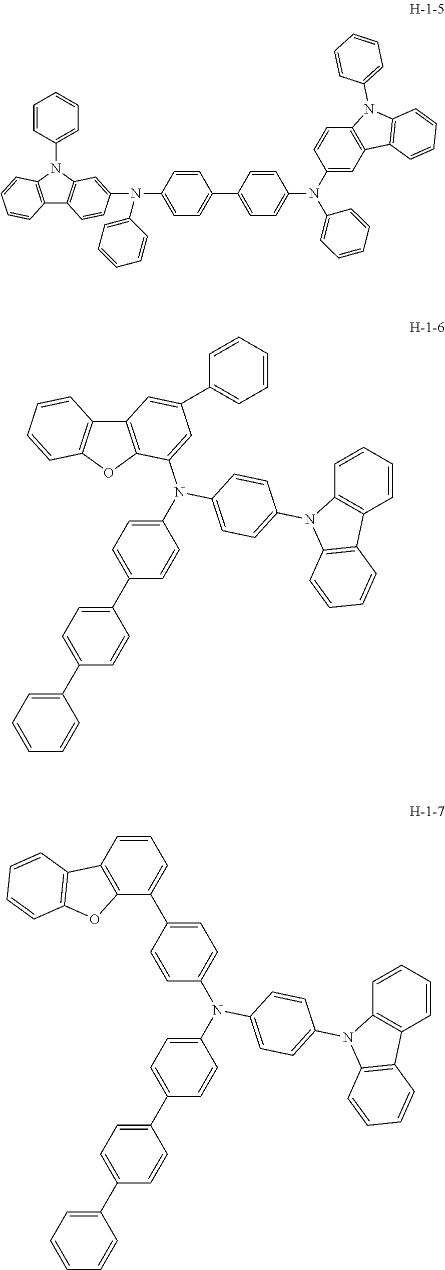 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

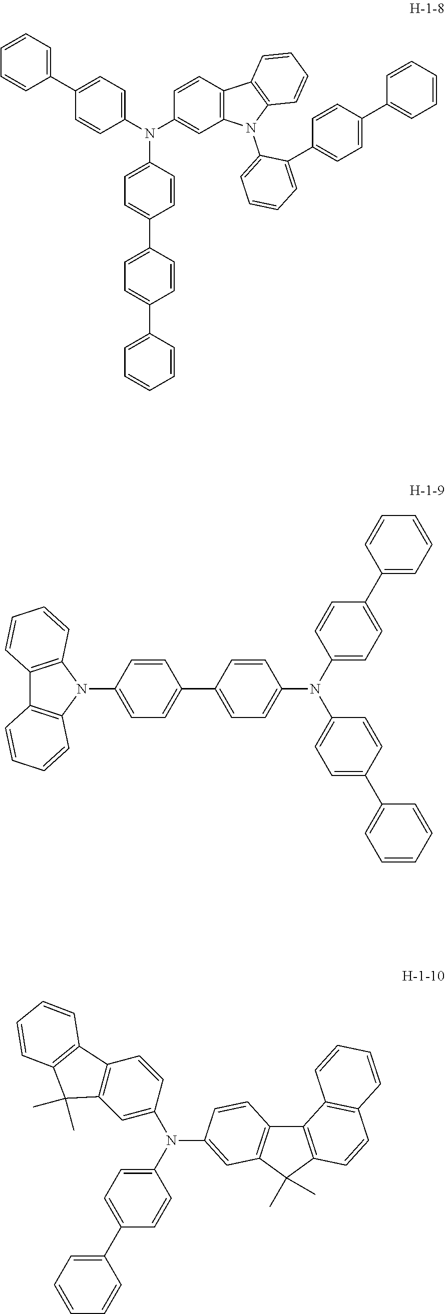 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

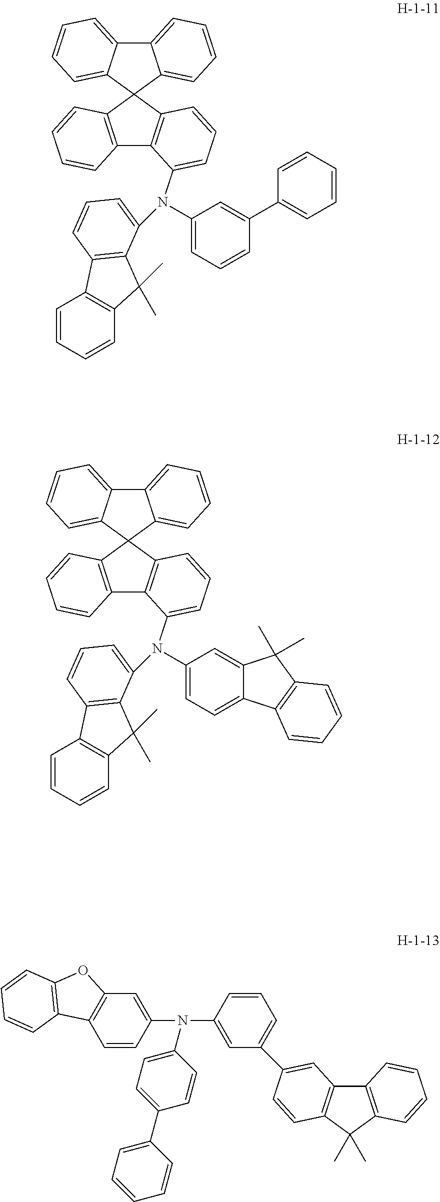 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

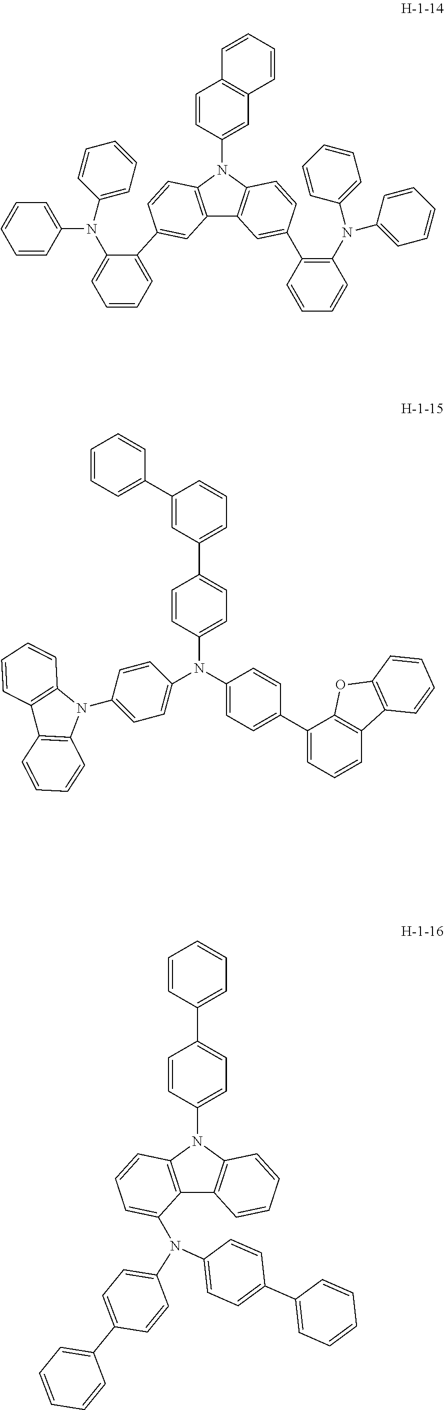 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

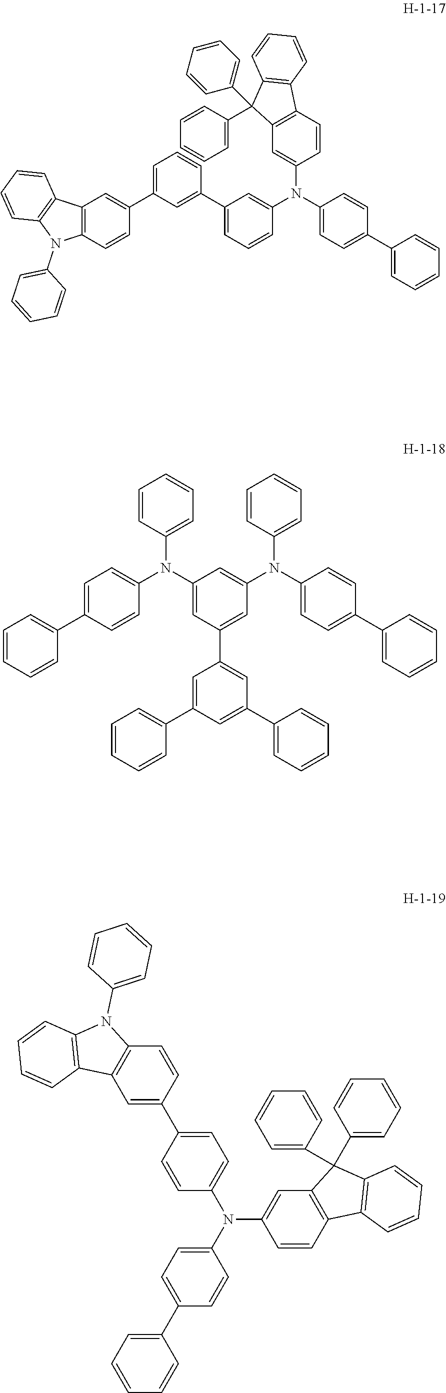 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f:2′,3′-h] quinoxaline-2,3,6,7,10,11-hexacarbonitrile (HATCN), etc.

The hole transport region HTR may include a carbazole derivative such as N-phenylcarbazole and polyvinylcarbazole, a fluorene-based derivative, a triphenylamine-based derivatives such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), or the like.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. In case where the hole transport region HTR includes a hole injection layer HIL, a thickness of the hole injection region HIL may be in a range of about 30 Å to about 1,000 Å. In case where the hole transport region HTR includes a hole transport layer HTL, a thickness of the hole transport layer HTL may be in a range of about 30 Å to about 1,000 Å. In case where the hole transport region HTR includes an electron blocking layer, a thickness of the electron blocking layer EBL may be in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without substantial increase of a driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide compound, a quinone derivative, a metal oxide, and a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL and a hole transport layer HTL. The buffer layer (not shown) may compensate for a resonance distance according to a wavelength of light emitted from an emission layer EML and may increase emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness of in a range of about 100 Å to about 300 Å. The emission layer EML may be a layer consisting of a single material, a layer including different materials, or a structure including multiple layers including different materials.

The light emitting element ED according to an embodiment may include a first electrode EL1, a second electrode EL2 facing the first electrode EL1, and at least one functional layer disposed between the first electrode EL1 and the second electrode EL2, and the at least one functional layer may include the polycyclic compound according to an embodiment. In an embodiment, the at least one functional layer may include an emission layer EML, and the emission layer EML may include the polycyclic compound according to an embodiment. In an embodiment, the emission layer EML may include the polycyclic compound according to an embodiment as a dopant.

The polycyclic compound according to an embodiment may have a structure that includes aromatic rings which are fused together via a boron atom, a nitrogen atom, and a heteroatom. The heteroatom may be a nitrogen atom, an oxygen atom, or a sulfur atom. For example, the polycyclic compound according to an embodiment may have a structure that includes first to third aromatic rings which are fused together via a boron atom, a nitrogen atom, and a heteroatom. The first to third aromatic rings may each be connected to the boron atom, the first and second aromatic rings may be connected via the boron atom, the first and third aromatic rings may be connected via the nitrogen atom, and the second and third aromatic rings may be connected via the heteroatom. The first to third aromatic rings may each independently be substituted or unsubstituted benzene rings. In the specification, a structure of the first to third aromatic rings that are fused via the boron atom, the nitrogen atom, and the heteroatom may be referred to as a “core structure”.

The polycyclic compound according to an embodiment may include a silyl group and may further include an amine group or a carbazole group. For example, a silyl group may be bonded to the first aromatic ring of the polycyclic group, and an amine group or a carbazole group may be bonded to the second aromatic ring. In an embodiment, a phenyl group may be bonded to the nitrogen atom of the core structure of the polycyclic compound, and at least one bulky substituent may be bonded to the phenyl group bonded to the nitrogen atom. For example, a bulky substituent may be bonded to the phenyl group bonded to the nitrogen atom, at an ortho position to the nitrogen atom of the core structure. The bulky substituent may be an alkyl group of 3 to 30 carbon atoms or an aryl group of 6 to 30 ring-forming carbon atoms. A hydrogen atom may be bonded to the third aromatic ring of the polycyclic compound according to an embodiment, or a bulky substituent may be bonded to the third aromatic ring of the polycyclic compound according to an embodiment, at a para position to the boron atom. The bulky substituent may be an alkyl group of 3 to 30 carbon atoms or an aryl group of 6 to 30 ring-forming carbon atoms.

In an embodiment, the emission layer EML may include a first compound represented by Formula 1. In the specification, the first compound corresponds to the above-described polycyclic compound according to an embodiment.

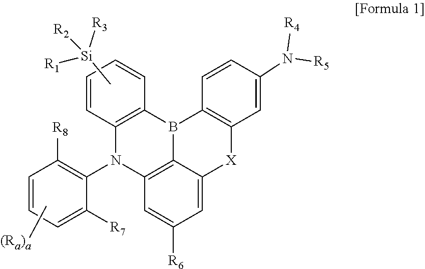

In Formula 1, X may be N(Ar), O, or S. For example, X may be N(Ar), X may be O, or X may be S.

In Formula 1, Ar may be a substituted or unsubstituted aryl group of 6 to 30 ring-forming carbon atoms. For example, Ar may be a substituted phenyl group. For example, if Ar is a substituted phenyl group, Ar may be a phenyl group substituted with an i-propyl group, a t-butyl group, or a phenyl group.

In Formula 1, R₁ to R₅ may each independently be a substituted or unsubstituted alkyl group of 1 to 30 carbon atoms, a substituted or unsubstituted aryl group of 6 to 30 ring-forming carbon atoms, or combined with an adjacent group to form a ring. For example, R₁ to R₅ may be the same as each other, or at least one of R₁ to R₅ may be different from the remainder.

In an embodiment, R₁ to R₃ may each independently be an unsubstituted methyl group or an unsubstituted phenyl group. For example, R₁ to R₃ may each be an unsubstituted methyl group, or R₁ to R₃ may each be an unsubstituted phenyl group.

For example, R₄ and R₅ may each independently be a substituted or unsubstituted phenyl group or combined with each other to form a ring. For example, if R₄ and R₅ are combined with each other to form a ring, R₄ and R₅ may form a substituted or unsubstituted carbazole group. If R₄ and R₅ are combined with each other to form a substituted carbazole group, the carbazole group may be substituted with a t-butyl group or a phenyl group.

In Formula 1, R₆ and Rₐ may each independently be a hydrogen atom, a substituted or unsubstituted alkyl group of 3 to 30 carbon atoms, or a substituted or unsubstituted aryl group of 6 to 30 ring-forming carbon atoms. For example, R₆ may be a hydrogen atom, an unsubstituted i-propyl group, an unsubstituted t-butyl group, or a substituted or unsubstituted phenyl group. For example, if R₆ is a substituted phenyl group, R₆ may be a phenyl group substituted with a t-butyl group. For example, Rₐ may be a hydrogen atom, an unsubstituted i-propyl group, an unsubstituted t-butyl group, or an unsubstituted phenyl group.

In Formula 1, at least one of R₇ and R₈ may each independently be a substituted or unsubstituted alkyl group of 3 to 30 carbon atoms or a substituted or unsubstituted aryl group of 6 to 30 ring-forming carbon atoms, and the remainder of R₇ and R₈ may be a hydrogen atom. In an embodiment, R₇ and R₈ may be the same as or different from each other. One of R₇ and R₈ may be a substituted or unsubstituted alkyl group of 3 to 30 carbon atoms or a substituted or unsubstituted aryl group of 6 to 30 ring-forming carbon atoms, and the remainder of R₇ and R₈ may be a hydrogen atom. In another embodiment, R₇ and R₈ may each independently be a substituted or unsubstituted alkyl group of 3 to 30 carbon atoms or a substituted or unsubstituted aryl group of 6 to 30 ring-forming carbon atoms. For example, at least one of R₇ and R₈ may be an unsubstituted i-propyl group, an unsubstituted t-butyl group, or a substituted or unsubstituted phenyl group. If R₇ and R₈ are each a substituted phenyl group, R₇ and R₈ may each be a phenyl group substituted with a t-butyl group.

In Formula 1, a may be an integer from 0 to 3. A case where a is 0 may be the same as a case where a is 3 and all Rₐ groups are hydrogen atoms. If a is 2 or more, two or more Rₐ groups may be the same as each other, or at least one thereof may be different from the remainder.

In Formula 1, at least one hydrogen atom may be optionally substituted with a deuterium atom. For example, Formula 1 may have a structure that does not include a deuterium atom, or may have a structure in which some or all hydrogen atoms are substituted with deuterium atoms.

In an embodiment, the polycyclic compound represented by Formula 1 may be represented by Formula 1-1a or Formula 1-1b.

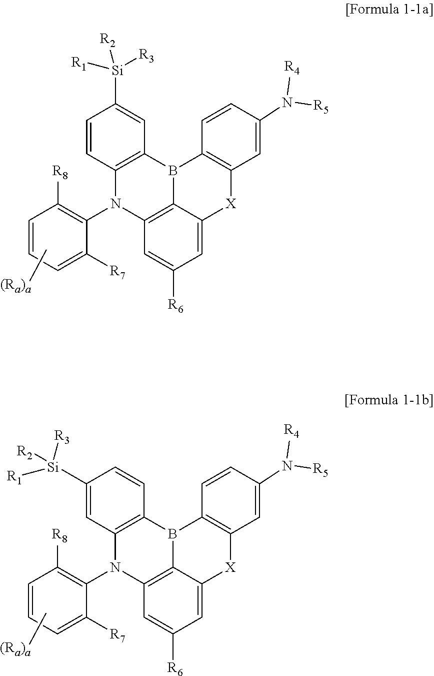

Formula 1-1a and Formula 1-1b each represent a case where the bonding position of the silyl group of Formula 1 is further defined. In Formula 1-1a, the silyl group is bonded at a para position to the nitrogen atom, and in Formula 1-1b, the silyl group is bonded at a para position to the boron atom.

In Formula 1-1a and Formula 1-1b, X, R₁ to R₈, Rₐ, and a are each as defined in Formula 1.

In Formula 1-1a and Formula 1-1b, at least one hydrogen atom may be optionally substituted with a deuterium atom.

In an embodiment, the polycyclic compound represented by Formula 1 may be represented by Formula 1-2a or Formula 1-2b.

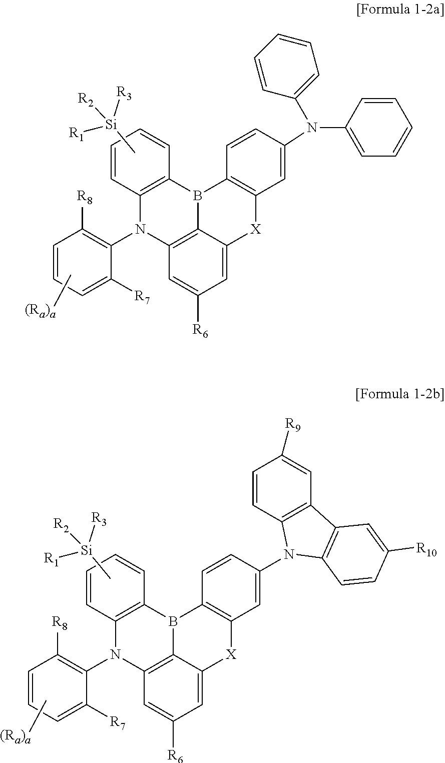

Formula 1-2a and Formula 1-2b each represent a case where R₄ and R₅ of Formula 1 are further defined. Formula 1-2a represents a case where R₄ and R₅ are each an unsubstituted phenyl group, and Formula 1-2b represents a case where R₄ and R₅ are combined with each other to form a substituted or unsubstituted carbazole group.

In Formula 1-2a and Formula 1-2b, R₉ and R₁₀ may each independently be a hydrogen atom, a substituted or unsubstituted alkyl group of 3 to 30 carbon atoms, or a substituted or unsubstituted aryl group of 6 to 30 ring-forming carbon atoms. R₉ and R₁₀ may be the same as or different from each other. For example, R₉ and R₁₀ may each independently be a hydrogen atom, an unsubstituted t-butyl group, or an unsubstituted phenyl group.

In Formula 1-2a and Formula 1-2b, X, R₁ to R₃, R₆ to R₈, Rₐ, and a are each as defined in Formula 1.

In Formula 1-2a and Formula 1-2b, at least one hydrogen atom may be optionally substituted with a deuterium atom. For example, in Formula 1-2b, R₉ and R₁₀ may each be a phenyl group substituted with a deuterium atom.

In an embodiment, the polycyclic compound represented by Formula 1 may be represented by one of Formula 1-3a to Formula 1-3c.

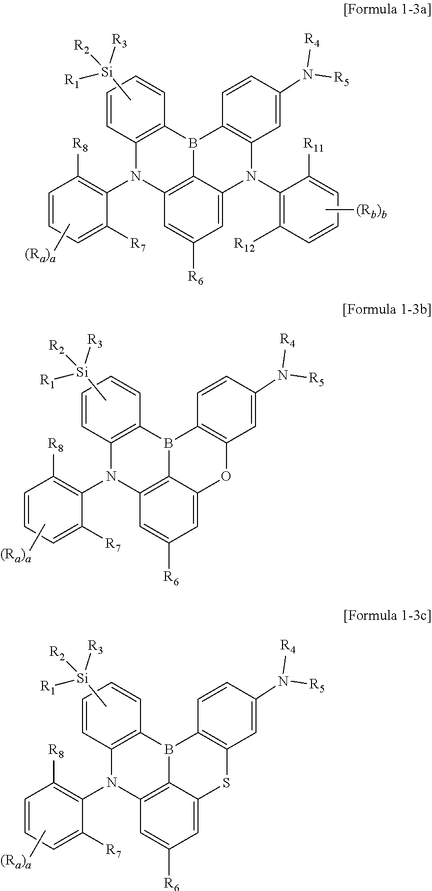

Formula 1-3a to Formula 1-3c each represent a case where the heteroatom of the core structure is further defined. Formula 1-3a represents a case where X is N(Ar), Formula 1-3b represents a case where X is 0, and Formula 1-3c represents a case where X is S.

In Formula 1-3a to Formula 1-3c, at least one of R₁ and R₁₂ may each independently be a substituted or unsubstituted alkyl group of 3 to 30 carbon atoms or a substituted or unsubstituted aryl group of 6 to 30 ring-forming carbon atoms, and the remainder of R₁₁ and R₁₂ may be a hydrogen atom. R₁₁ and R₁₂ may be the same as or different from each other. For example, one of R₁₁ and R₁₂ may be a substituted or unsubstituted alkyl group of 3 to 30 carbon atoms, or a substituted or unsubstituted aryl group of 6 to 30 ring-forming carbon atoms, and the remainder of R₁₁ and R₁₂ may be a hydrogen atom. For example, R₁₁ and R₁₂ may each independently be a substituted or unsubstituted alkyl group of 3 to 30 carbon atoms, or a substituted or unsubstituted aryl group of 6 to 30 ring-forming carbon atoms. For example, at least one of R₁₁ and R₁₂ may be an unsubstituted i-propyl group, an unsubstituted t-butyl group, or a substituted or unsubstituted phenyl group. If R₁₁ to R₁₂ are each a substituted phenyl group, R₁₁ and R₁₂ may each be a phenyl group substituted with a t-butyl group.

In Formula 1-3a to Formula 1-3c, R_{b} may be a hydrogen atom, a substituted or unsubstituted alkyl group of 3 to 30 carbon atoms, or a substituted or unsubstituted aryl group of 6 to 30 ring-forming carbon atoms. For example, R_{b} may be a hydrogen atom, an unsubstituted i-propyl group, an unsubstituted t-butyl group, or an unsubstituted phenyl group.

In Formula 1-3a to Formula 1-3c, b may be an integer from 0 to 3. A case where b is 0 may be the same as a case where b is 3 and all R_{b} groups are hydrogen atoms. If b is 2 or more, two or more R_{b} groups may be the same as each other, or at least one thereof may be different from the remainder.

In Formula 1-3a to Formula 1-3c, R₁ to R₈, Rₐ, and a are each as defined in Formula 1.

In Formula 1-3a to Formula 1-3c, at least one hydrogen atom may be optionally substituted with a deuterium atom.

In an embodiment, the polycyclic compound represented by Formula 1 may be represented by one of Formula 1-4a to Formula 1-4c.

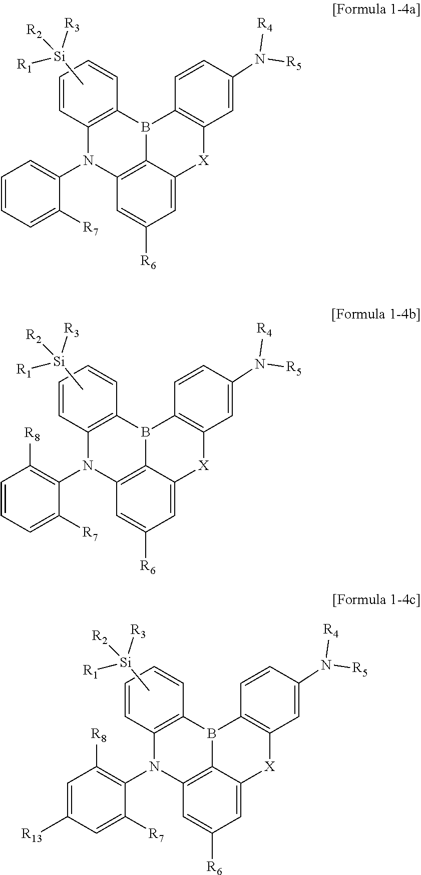

Formula 1-4a to Formula 1-4c each represents a case where the bonding position and types of substituents of the phenyl group bonded to the nitrogen atom is further defined. Formula 1-4a is a case where only one substituent is bonded at an ortho position to the nitrogen atom, Formula 1-4b is a case where two substituents are each bonded at an ortho position to the nitrogen atom, and Formula 1-4c is a case where substituents are bonded at both ortho positions to the nitrogen atom and a para position to the nitrogen atom.

In Formula 1-4a to Formula 1-4c, R₇, R₈, and R₁₃ may each independently be an unsubstituted i-propyl group, an unsubstituted t-butyl group, or a substituted or unsubstituted phenyl group. R₇, R₈, and R₁₃ may be all the same, or at least one of R₇, R₈, and R₁₃ may be different from the remainder. For example, R₇, R₈, and R₁₃ may each be an unsubstituted t-butyl group, or R₇, R₈, and R₁₃ may each be an unsubstituted phenyl group. For example, one of R₇, R₈, and R₁₃ may be an unsubstituted t-butyl group, and the remaining two may each be an unsubstituted phenyl group. For example, one of R₇, R₈, and R₁₃ may be an unsubstituted phenyl group, and the remaining two may each be an unsubstituted t-butyl group. For example, one of R₇, R₈, and R₁₃ may be an unsubstituted t-butyl group, and the remaining two may each be a phenyl group substituted with a t-butyl group. For example, R₇, R₈, and R₁₃ may each be an unsubstituted i-propyl group.

In Formula 1-4a to Formula 1-4c, X and R₁ to R₆ are each as defined in Formula 1.

In Formula 1-4a to Formula 1-4c, at least one hydrogen atom may be optionally substituted with a deuterium atom.

In an embodiment, the polycyclic compound represented by Formula 1 may be represented by one of Formula 1-5a to Formula 1-5e.

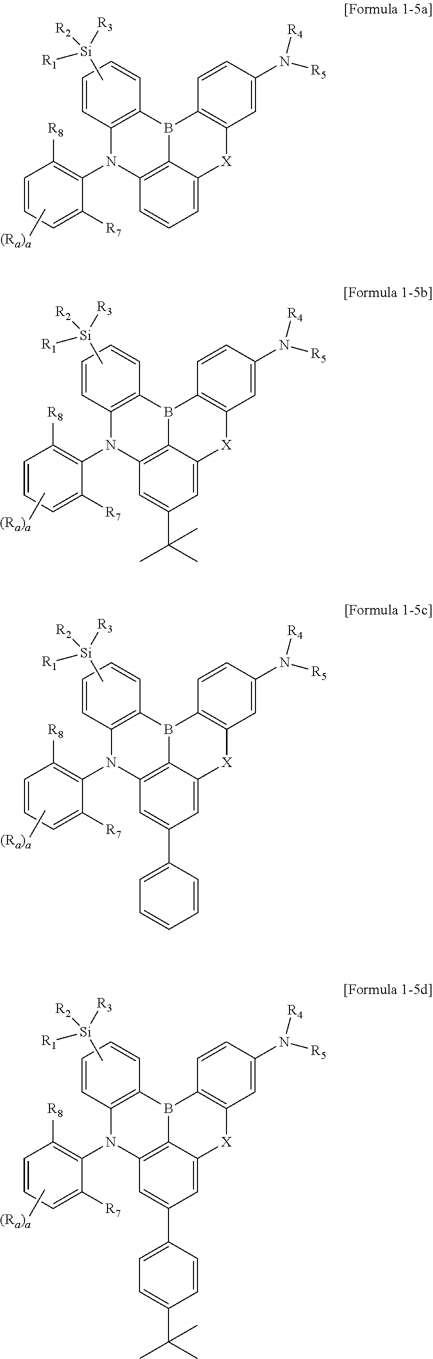

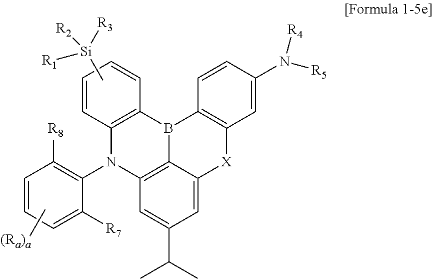

Formula 1-5a to Formula 1-5e each represents a case where R₆ of Formula 1 is further defined. Formula 1-5a represents a case where R₆ is a hydrogen atom, Formula 1-5b represents a case where R₆ is an unsubstituted t-butyl group, Formula 1-5c represents a case where R₆ is an unsubstituted phenyl group, Formula 1-5d represents a case where R₆ is a phenyl group substituted with a t-butyl group, and Formula 1-5e represents a case where R₆ is an unsubstituted i-propyl group.

In Formula 1-5a to Formula 1-5e, X, R₁ to R₅, R₇, R₈, Rₐ, and a are each as defined in Formula 1.

In Formula 1-5a to Formula 1-5e, at least one hydrogen atom may be optionally substituted with a deuterium atom.

In an embodiment, the polycyclic compound may be any compound selected from Compound Group 1. In an embodiment, in the light emitting element ED the at least one functional layer (for example, an emission layer EML) may include at least one polycyclic compound selected from Compound Group 1.

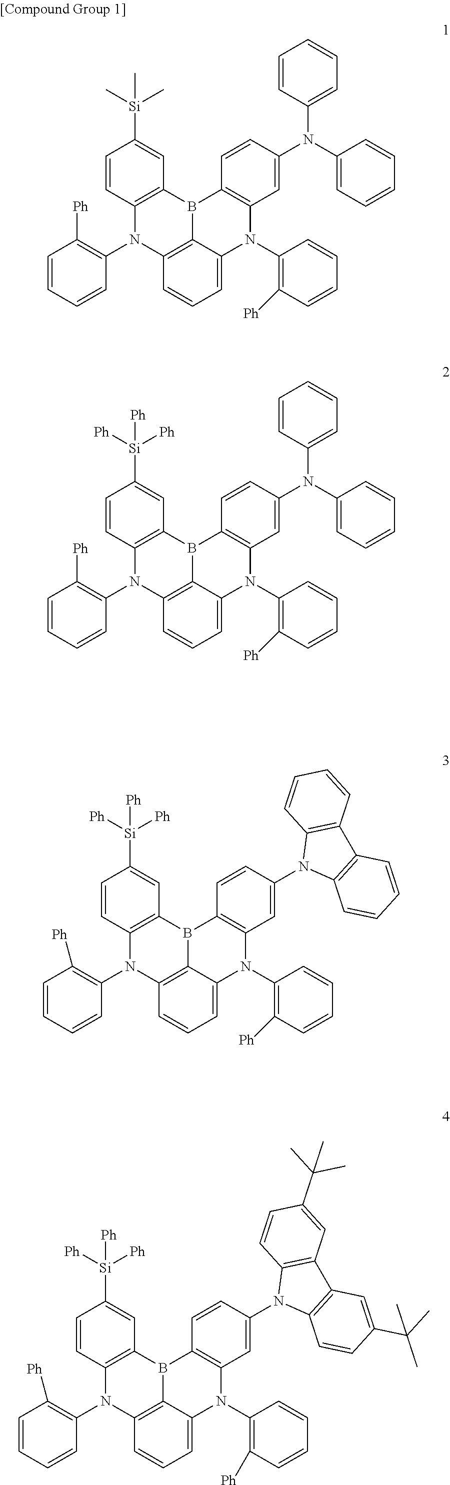

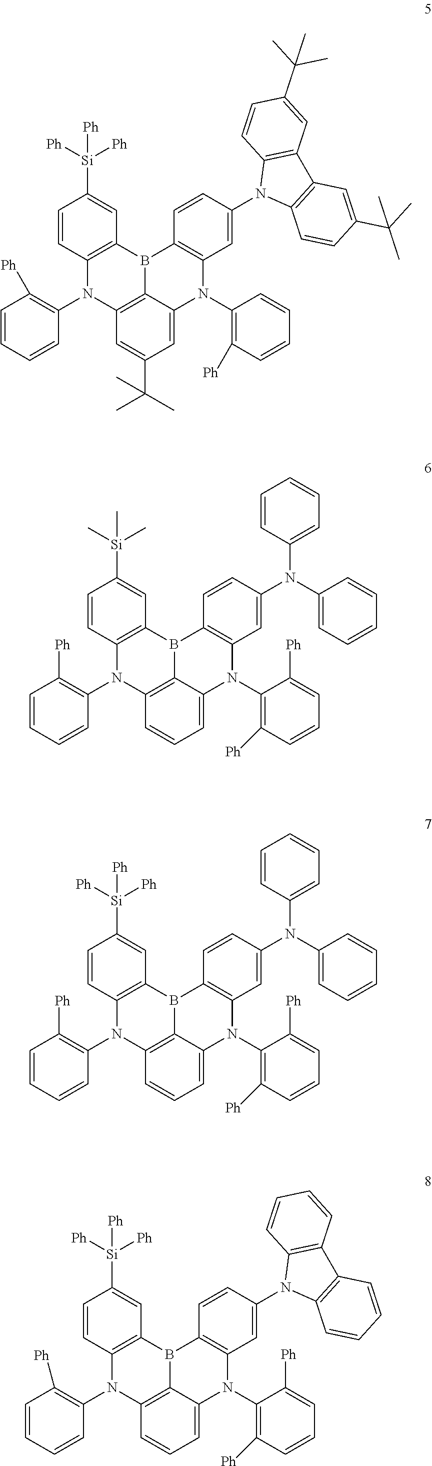

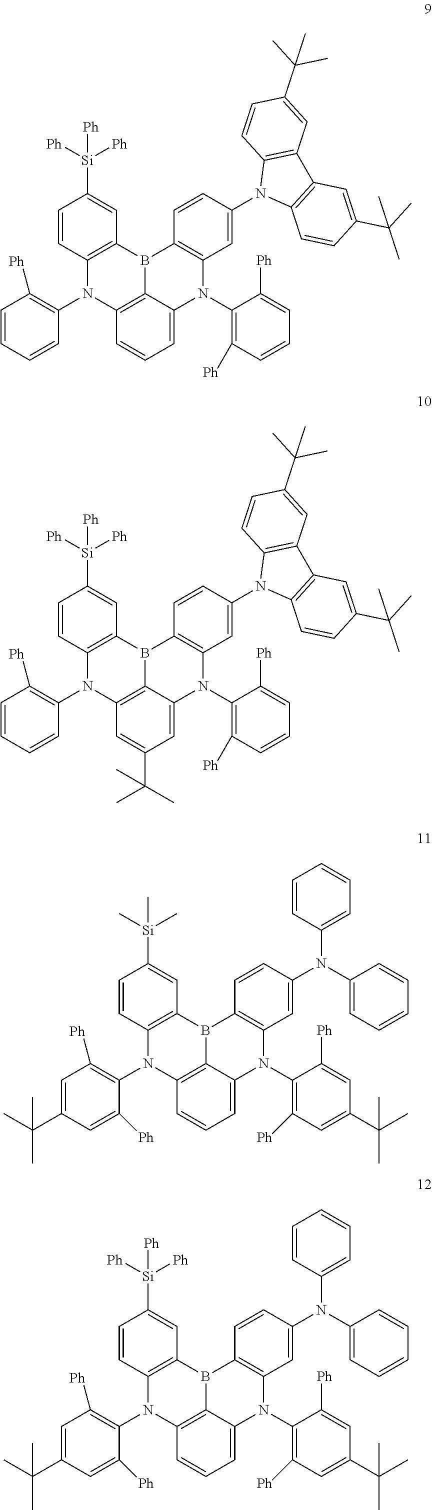

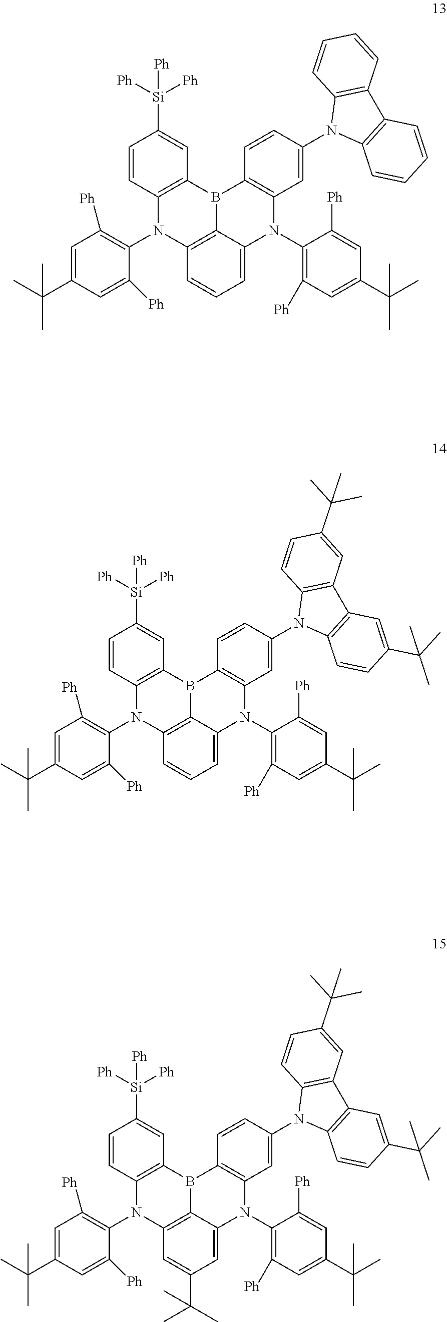

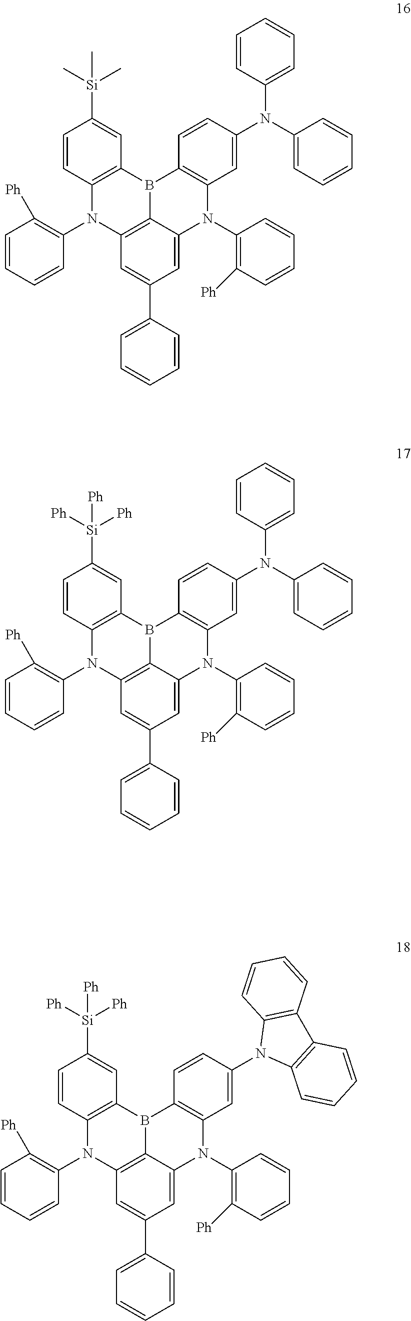 [SMILES: C[Si](C)(C)c1ccc2c(c1)B1c3ccc(N(c4ccccc4)c4ccccc4)cc3N(c3ccccc3-c3ccccc3)c3cc(-c4ccccc4)cc(c31)N2c1ccccc1-c1ccccc1 ; c1ccc(-c2cc3c4c(c2)N(c2ccccc2-c2ccccc2)c2cc(N(c5ccccc5)c5ccccc5)ccc2B4c2cc([Si](c4ccccc4)(c4ccccc4)c4ccccc4)ccc2N3c2ccccc2-c2ccccc2)cc1 ; c1ccc(-c2cc3c4c(c2)N(c2ccccc2-c2ccccc2)c2cc(-n5c6ccccc6c6ccccc65)ccc2B4c2cc([Si](c4ccccc4)(c4ccccc4)c4ccccc4)ccc2N3c2ccccc2-c2ccccc2)cc1]

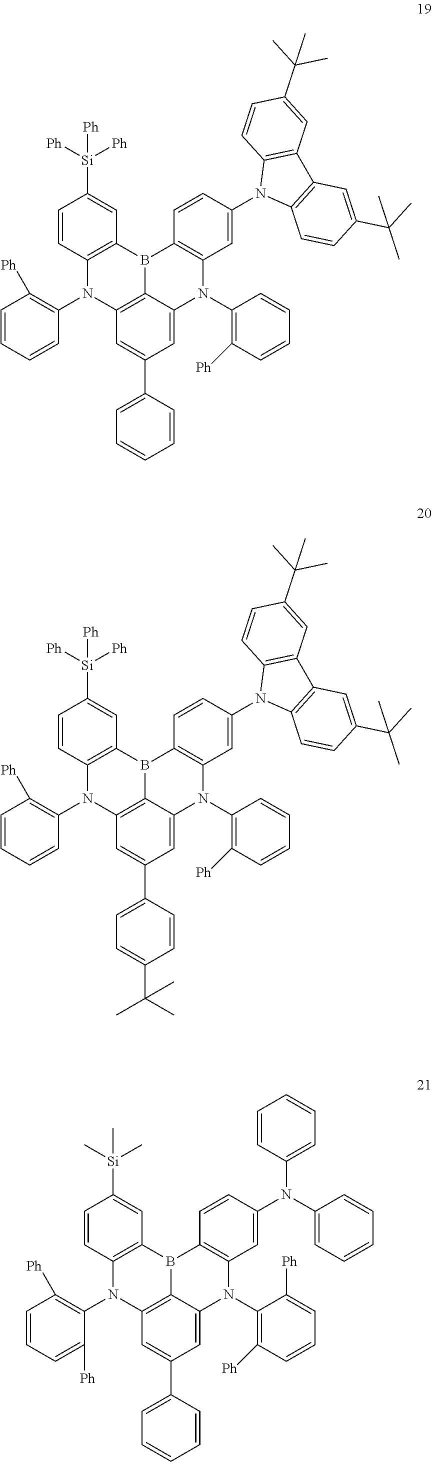 [SMILES: CC(C)(C)c1ccc2c(c1)c1cc(C(C)(C)C)ccc1n2-c1ccc2c(c1)N(c1ccccc1-c1ccccc1)c1cc(-c3ccccc3)cc3c1B2c1cc([Si](c2ccccc2)(c2ccccc2)c2ccccc2)ccc1N3c1ccccc1-c1ccccc1 ; CC(C)(C)c1ccc(-c2cc3c4c(c2)N(c2ccccc2-c2ccccc2)c2cc(-n5c6ccc(C(C)(C)C)cc6c6cc(C(C)(C)C)ccc65)ccc2B4c2cc([Si](c4ccccc4)(c4ccccc4)c4ccccc4)ccc2N3c2ccccc2-c2ccccc2)cc1 ; C[Si](C)(C)c1ccc2c(c1)B1c3ccc(N(c4ccccc4)c4ccccc4)cc3N(c3c(-c4ccccc4)cccc3-c3ccccc3)c3cc(-c4ccccc4)cc(c31)N2c1c(-c2ccccc2)cccc1-c1ccccc1]

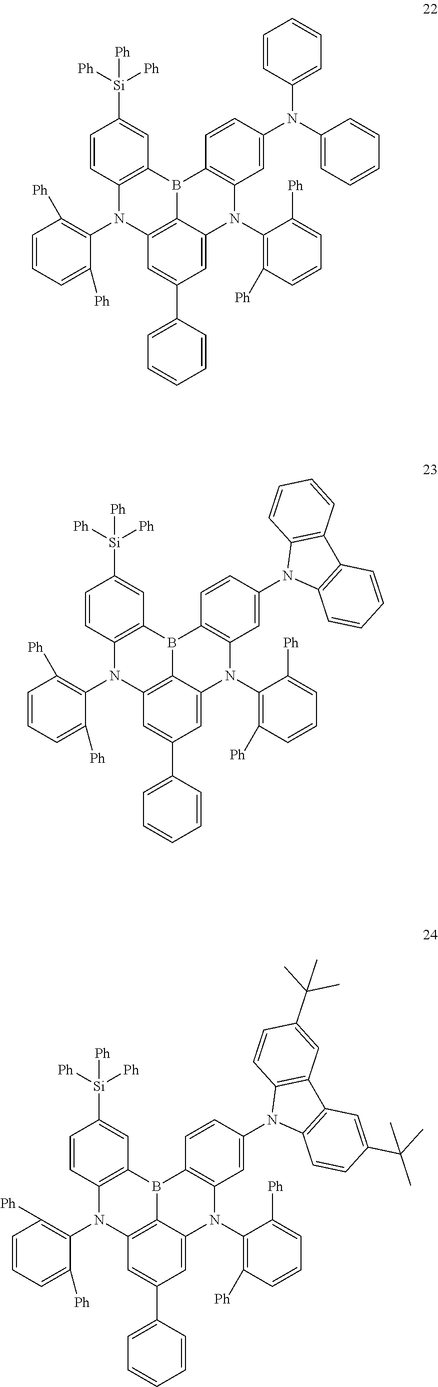 [SMILES: c1ccc(-c2cc3c4c(c2)N(c2c(-c5ccccc5)cccc2-c2ccccc2)c2cc(N(c5ccccc5)c5ccccc5)ccc2B4c2cc([Si](c4ccccc4)(c4ccccc4)c4ccccc4)ccc2N3c2c(-c3ccccc3)cccc2-c2ccccc2)cc1 ; c1ccc(-c2cc3c4c(c2)N(c2c(-c5ccccc5)cccc2-c2ccccc2)c2cc(-n5c6ccccc6c6ccccc65)ccc2B4c2cc([Si](c4ccccc4)(c4ccccc4)c4ccccc4)ccc2N3c2c(-c3ccccc3)cccc2-c2ccccc2)cc1 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1cc([Si](c2ccccc2)(c2ccccc2)c2ccccc2)ccc1N3c1c(-c2ccccc2)cccc1-c1ccccc1]

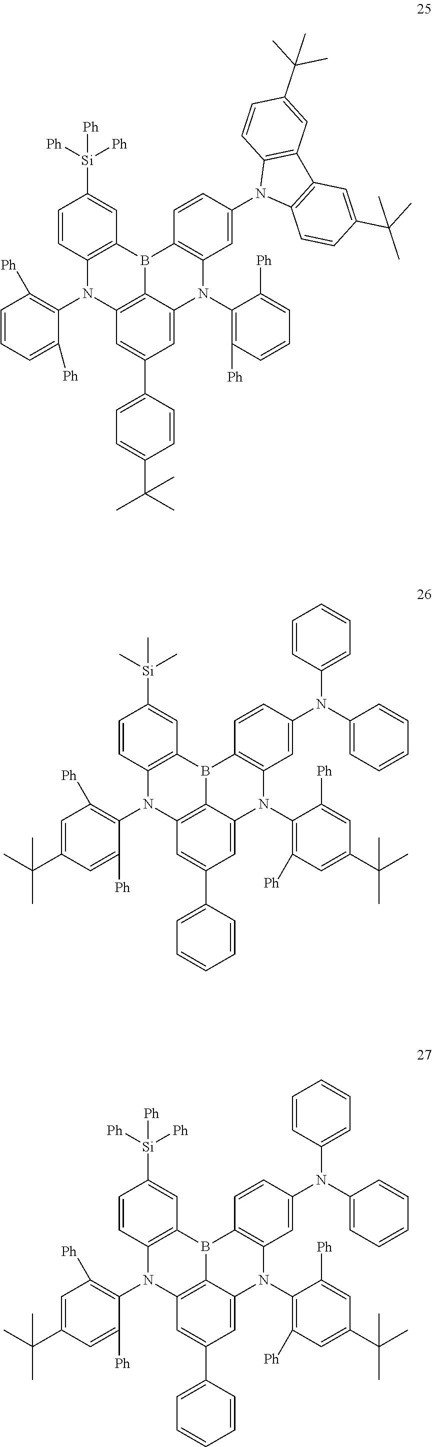

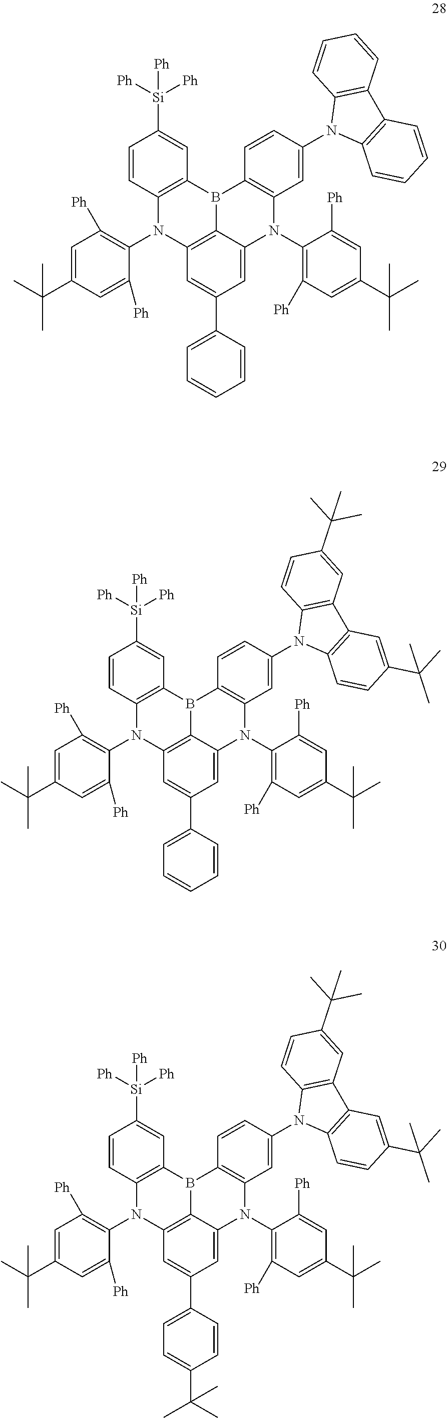

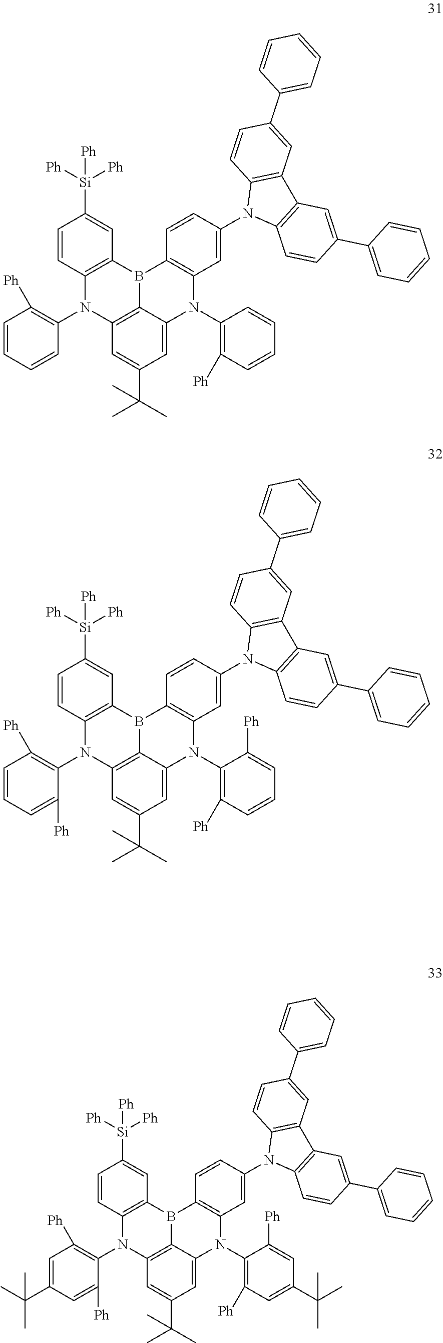

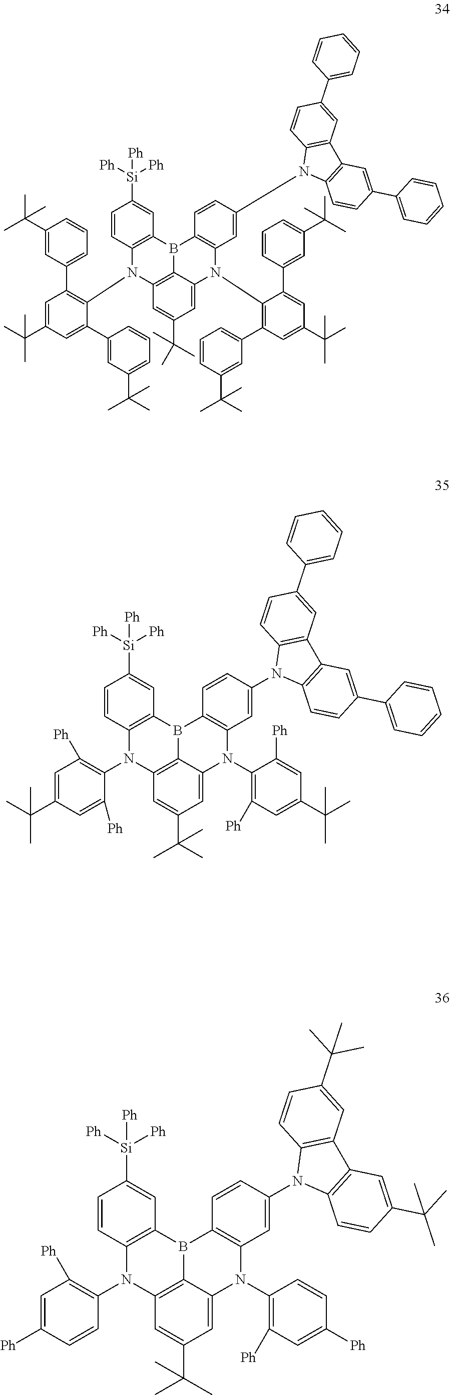

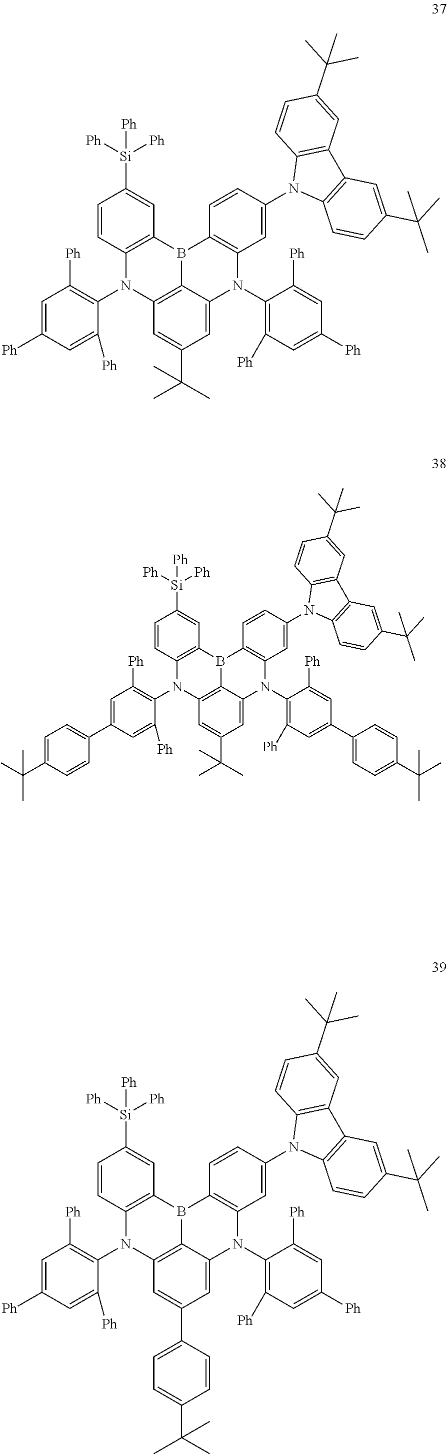

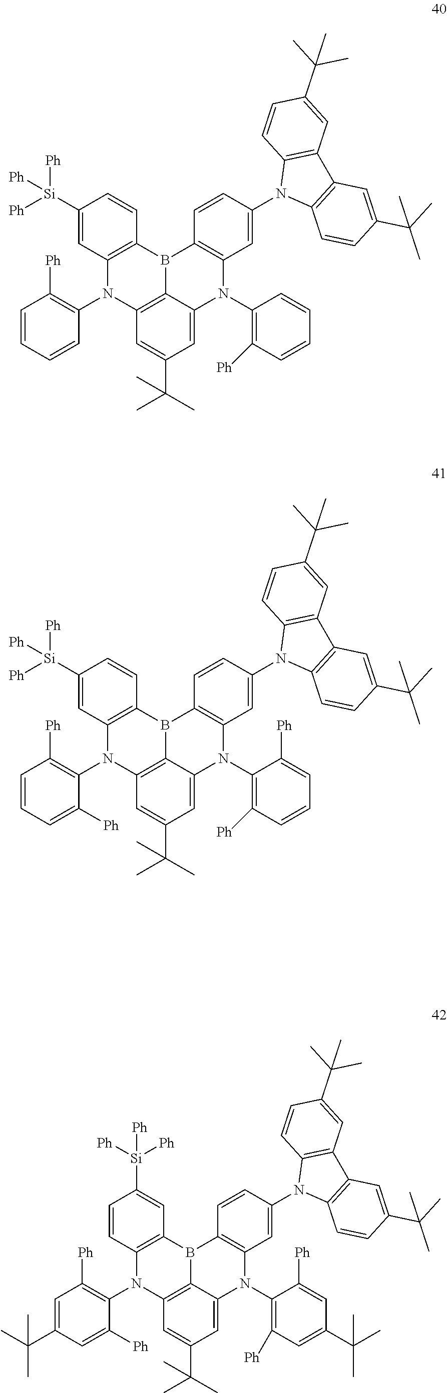

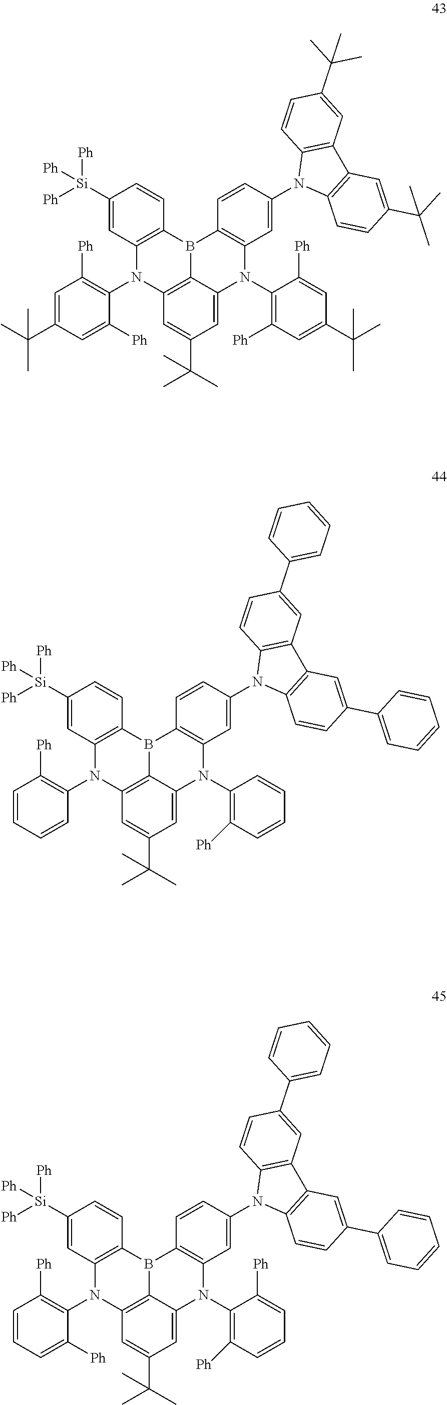

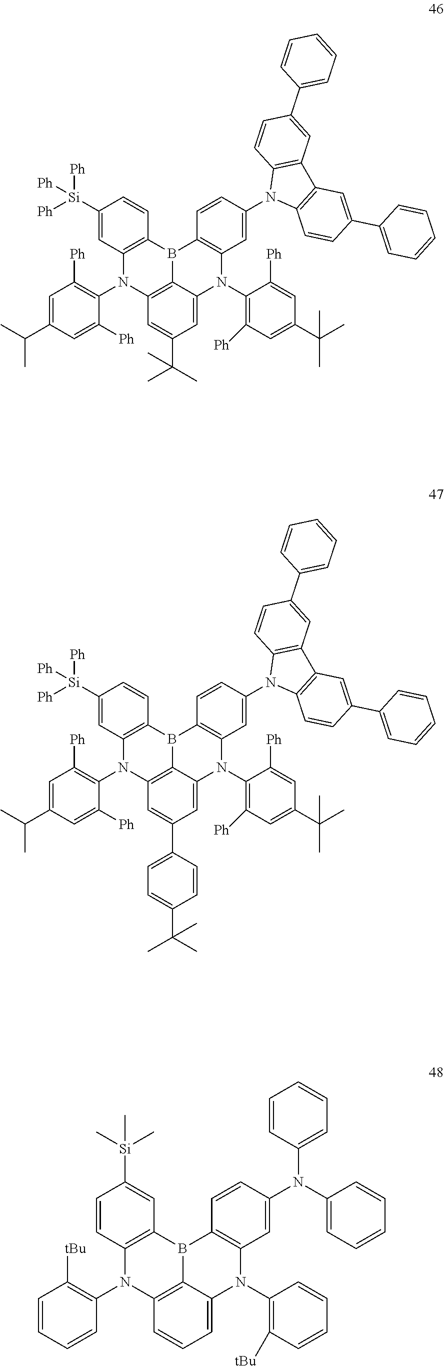

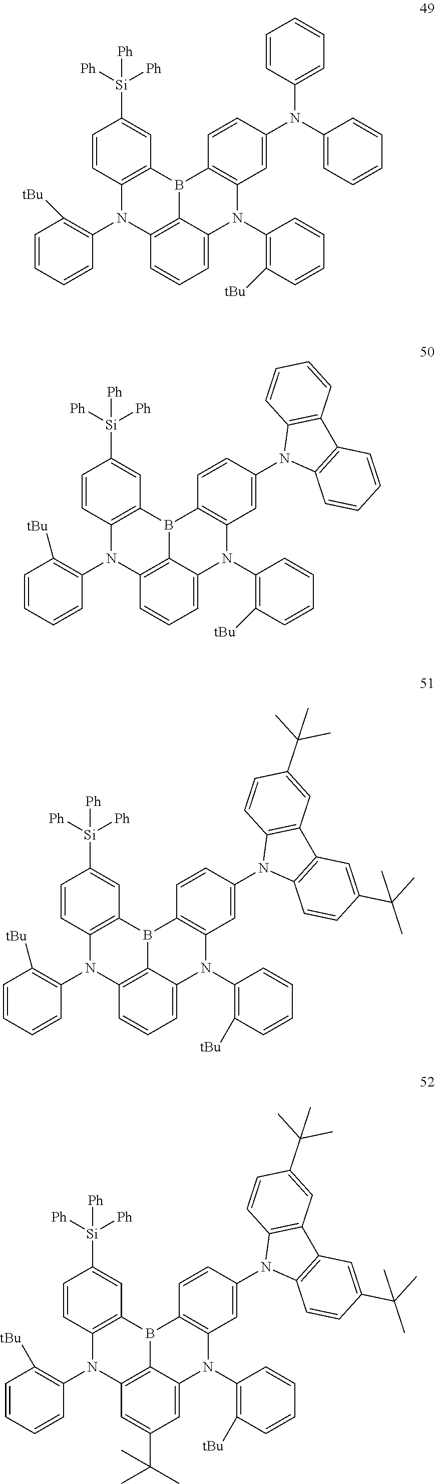

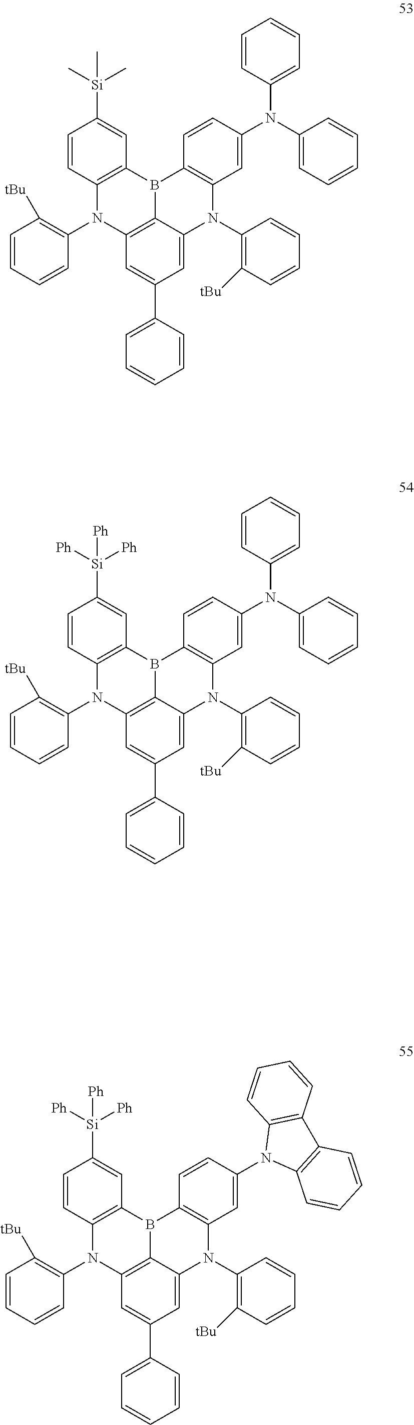 [SMILES: CC(C)(C)c1ccccc1N1c2ccc([Si](C)(C)C)cc2B2c3ccc(N(c4ccccc4)c4ccccc4)cc3N(c3ccccc3C(C)(C)C)c3cc(-c4ccccc4)cc1c32 ; CC(C)(C)c1ccccc1N1c2ccc([Si](c3ccccc3)(c3ccccc3)c3ccccc3)cc2B2c3ccc(N(c4ccccc4)c4ccccc4)cc3N(c3ccccc3C(C)(C)C)c3cc(-c4ccccc4)cc1c32 ; CC(C)(C)c1ccccc1N1c2ccc([Si](c3ccccc3)(c3ccccc3)c3ccccc3)cc2B2c3ccc(-n4c5ccccc5c5ccccc54)cc3N(c3ccccc3C(C)(C)C)c3cc(-c4ccccc4)cc1c32]

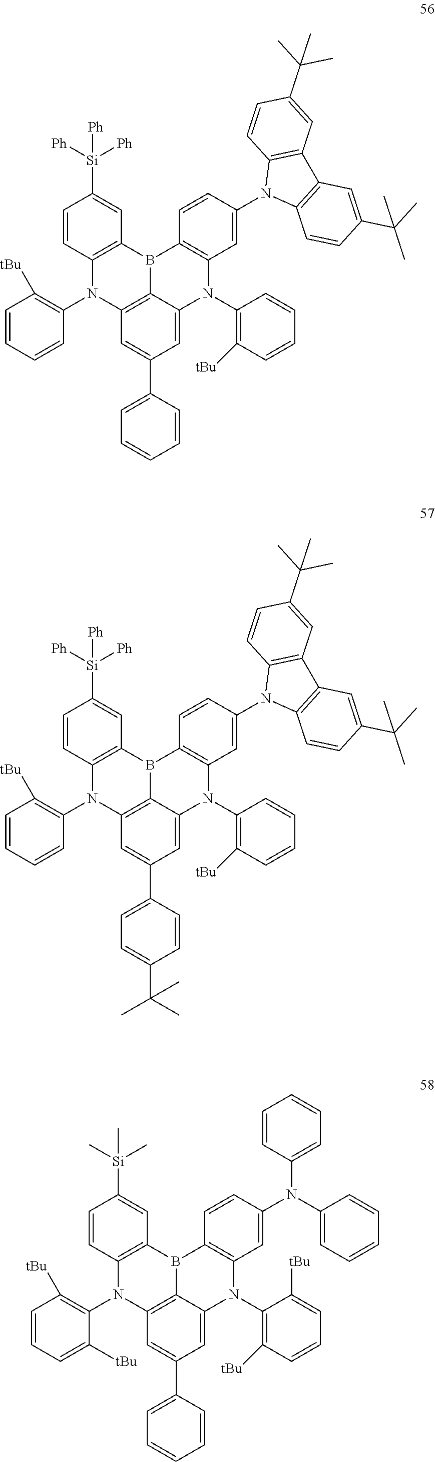 [SMILES: CC(C)(C)c1ccc2c(c1)c1cc(C(C)(C)C)ccc1n2-c1ccc2c(c1)N(c1ccccc1C(C)(C)C)c1cc(-c3ccccc3)cc3c1B2c1cc([Si](c2ccccc2)(c2ccccc2)c2ccccc2)ccc1N3c1ccccc1C(C)(C)C ; CC(C)(C)c1ccc(-c2cc3c4c(c2)N(c2ccccc2C(C)(C)C)c2cc(-n5c6ccc(C(C)(C)C)cc6c6cc(C(C)(C)C)ccc65)ccc2B4c2cc([Si](c4ccccc4)(c4ccccc4)c4ccccc4)ccc2N3c2ccccc2C(C)(C)C)cc1 ; CC(C)(C)c1cccc(C(C)(C)C)c1N1c2ccc([Si](C)(C)C)cc2B2c3ccc(N(c4ccccc4)c4ccccc4)cc3N(c3c(C(C)(C)C)cccc3C(C)(C)C)c3cc(-c4ccccc4)cc1c32]

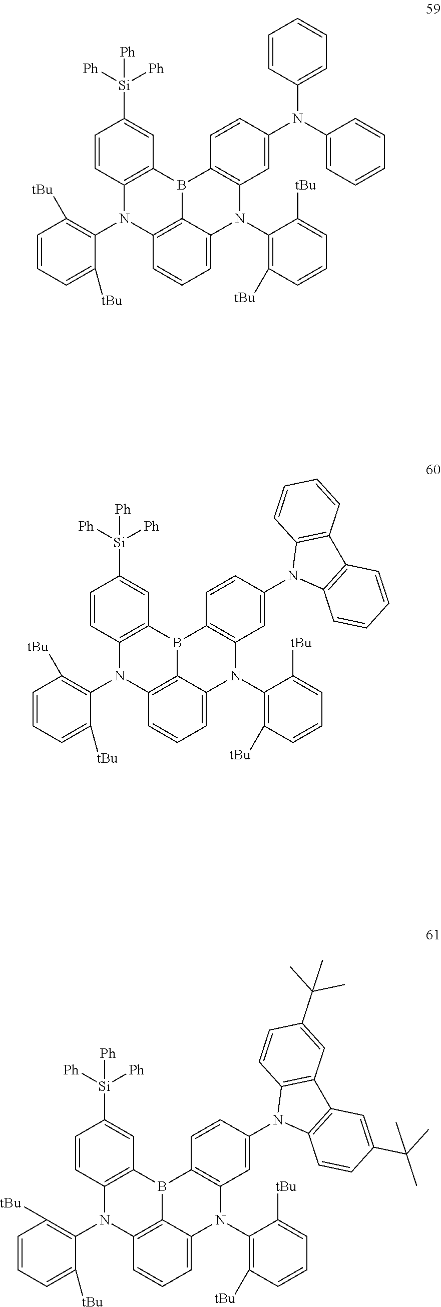 [SMILES: CC(C)(C)c1cccc(C(C)(C)C)c1N1c2ccc([Si](c3ccccc3)(c3ccccc3)c3ccccc3)cc2B2c3ccc(N(c4ccccc4)c4ccccc4)cc3N(c3c(C(C)(C)C)cccc3C(C)(C)C)c3cccc1c32 ; CC(C)(C)c1cccc(C(C)(C)C)c1N1c2ccc([Si](c3ccccc3)(c3ccccc3)c3ccccc3)cc2B2c3ccc(-n4c5ccccc5c5ccccc54)cc3N(c3c(C(C)(C)C)cccc3C(C)(C)C)c3cccc1c32 ; CC(C)(C)c1ccc2c(c1)c1cc(C(C)(C)C)ccc1n2-c1ccc2c(c1)N(c1c(C(C)(C)C)cccc1C(C)(C)C)c1cccc3c1B2c1cc([Si](c2ccccc2)(c2ccccc2)c2ccccc2)ccc1N3c1c(C(C)(C)C)cccc1C(C)(C)C]

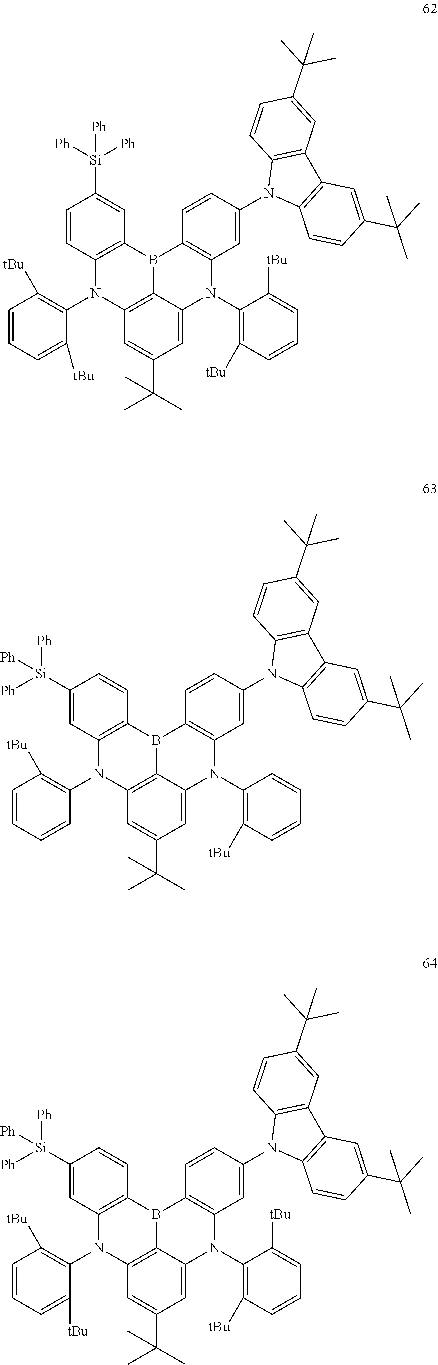 [SMILES: CC(C)(C)c1cc2c3c(c1)N(c1c(C(C)(C)C)cccc1C(C)(C)C)c1cc(-n4c5ccc(C(C)(C)C)cc5c5cc(C(C)(C)C)ccc54)ccc1B3c1cc([Si](c3ccccc3)(c3ccccc3)c3ccccc3)ccc1N2c1c(C(C)(C)C)cccc1C(C)(C)C ; CC(C)(C)c1cc2c3c(c1)N(c1ccccc1C(C)(C)C)c1cc([Si](c4ccccc4)(c4ccccc4)c4ccccc4)ccc1B3c1ccc(-n3c4ccc(C(C)(C)C)cc4c4cc(C(C)(C)C)ccc43)cc1N2c1ccccc1C(C)(C)C ; CC(C)(C)c1cc2c3c(c1)N(c1c(C(C)(C)C)cccc1C(C)(C)C)c1cc([Si](c4ccccc4)(c4ccccc4)c4ccccc4)ccc1B3c1ccc(-n3c4ccc(C(C)(C)C)cc4c4cc(C(C)(C)C)ccc43)cc1N2c1c(C(C)(C)C)cccc1C(C)(C)C]

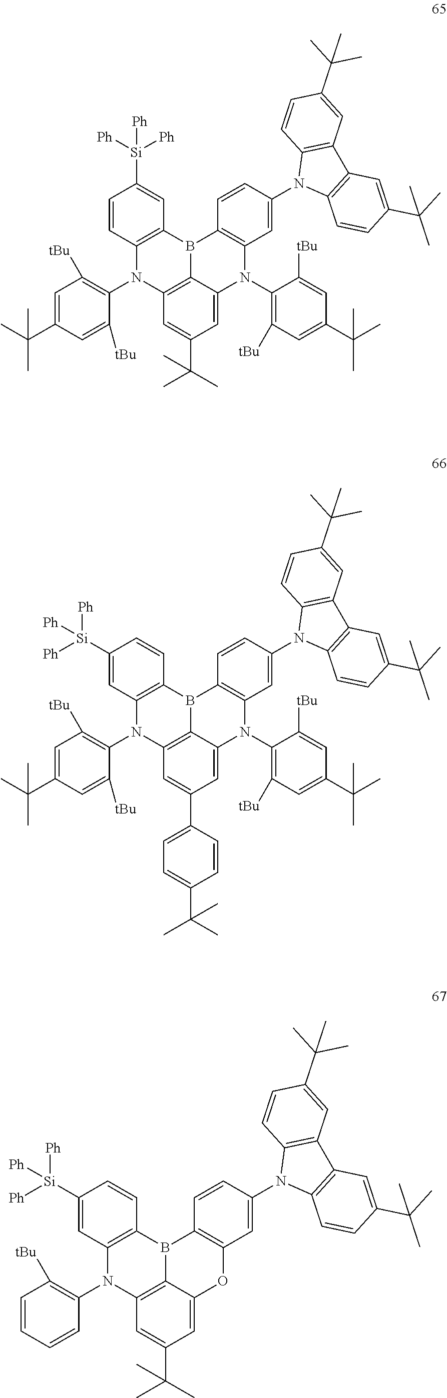

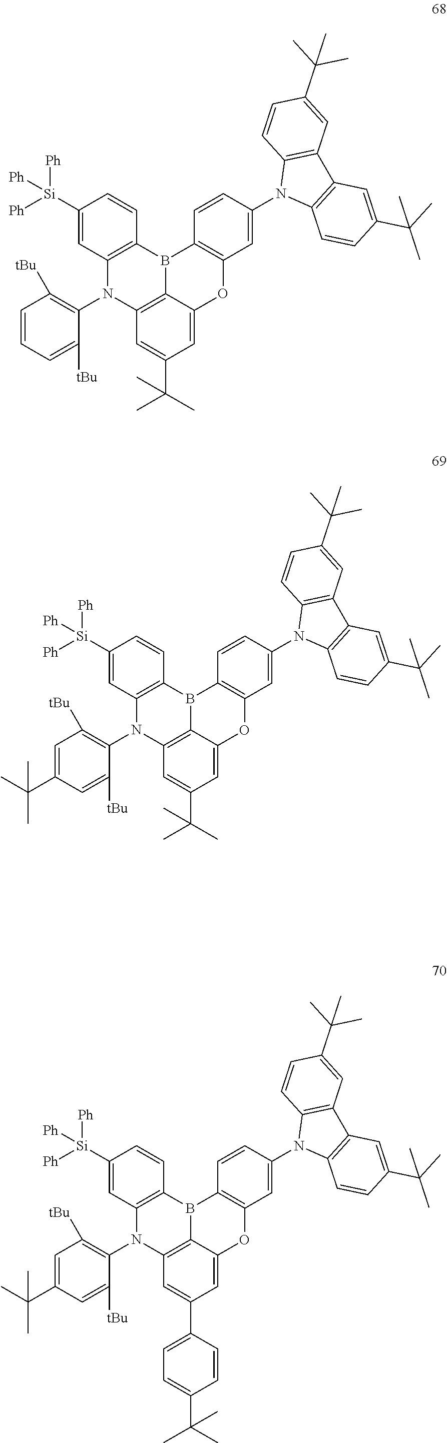

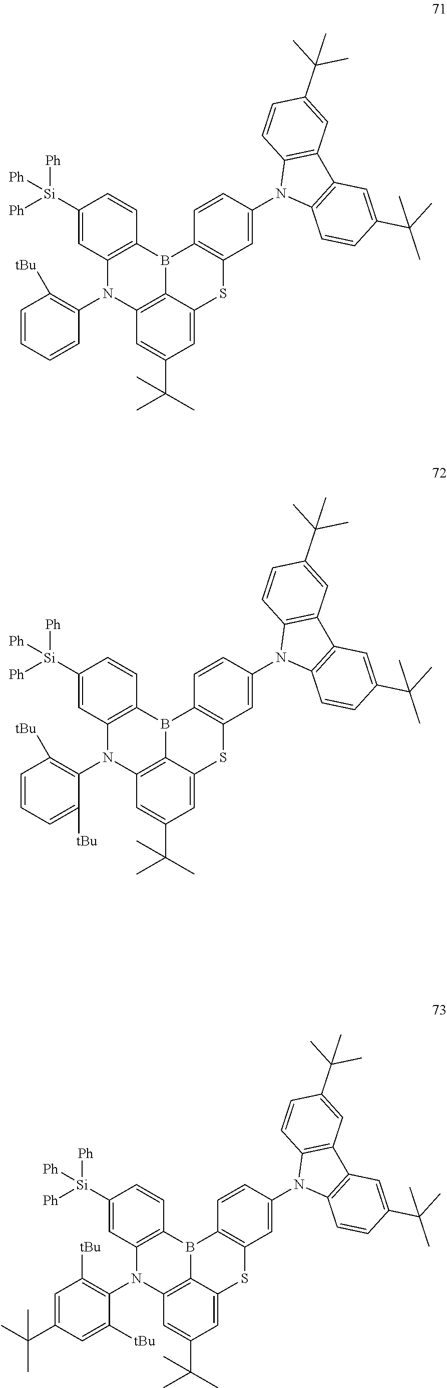

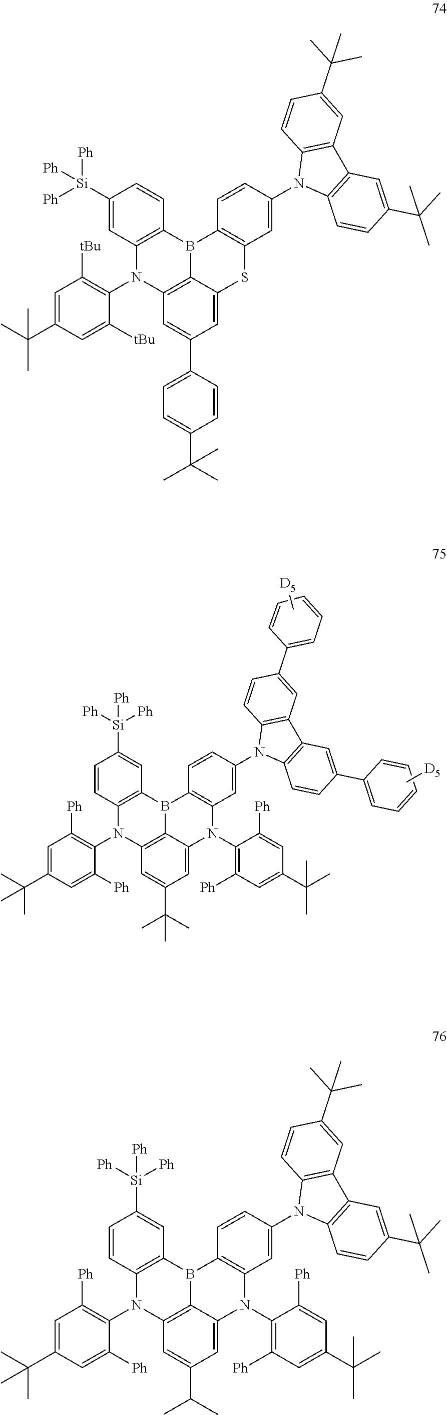

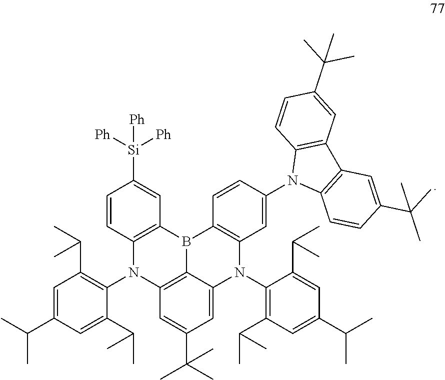 [SMILES: CC(C)c1cc(C(C)C)c(N2c3ccc([Si](c4ccccc4)(c4ccccc4)c4ccccc4)cc3B3c4ccc(-n5c6ccc(C(C)(C)C)cc6c6cc(C(C)(C)C)ccc65)cc4N(c4c(C(C)C)cc(C(C)C)cc4C(C)C)c4cc(C(C)(C)C)cc2c43)c(C(C)C)c1]

In Compound Group 1, D represents a deuterium atom, and Ph represents an unsubstituted phenyl group.

As described above, the polycyclic compound represented by Formula 1 may include a core structure of three benzene rings that are fused together via a boron atom, a nitrogen atom, and a heteroatom. The heteroatom may be a nitrogen atom, an oxygen atom, or a sulfur atom. The polycyclic compound according to an embodiment may include a silyl group and may further include an amine group or a carbazole group. In the polycyclic compound, a phenyl group may be bonded to the nitrogen atom of the core structure, and a bulky substituent may be bonded to the phenyl group at an ortho position to the nitrogen atom. In the polycyclic compound, a hydrogen atom, an alkyl group of 3 to 30 carbon atoms, or an aryl group of 6 to 30 ring-forming carbon atoms may be bonded to the benzene ring connected with the nitrogen atom and the heteroatom of the core structure, at a para position to the boron atom. When the polycyclic compound is applied to an emission layer EML of a light emitting element ED, the properties of the light emitting element ED including emission efficiency and lifetime may be improved.

The polycyclic compound according to an embodiment may be included in an emission layer EML. The polycyclic compound may be included in the emission layer EML as a dopant material. The polycyclic compound may be a thermally activated delayed fluorescence (TADF) material. The polycyclic compound may be used as a thermally activated delayed fluorescence (TADF) dopant. For example, the emission layer EML according to an embodiment may include at least one polycyclic compound selected from Compound Group 1 as a thermally activated delayed fluorescence dopant. However, the use of the polycyclic compound is not limited thereto.

In an embodiment, the polycyclic compound represented by Formula 1 may be a thermally activated delayed fluorescence dopant. In an embodiment, a difference between a lowest triplet excitation state energy level (T1 level) and a lowest singlet excitation state energy level (Si level) of the thermally activated delayed fluorescence dopant (ΔE_{ST}) may be equal to or less than about 0.6 eV. In another embodiment, a difference between a lowest triplet excitation state energy level (T1 level) and a lowest singlet excitation state energy level (S1 level) of the thermally activated delayed fluorescence dopant (ΔE_{ST}) may be equal to or less than about 0.2 eV.

In an embodiment, a full width at half maximum (FWHM) of an emission spectrum of the polycyclic compound represented by Formula 1 may be in a range of about 10 to about 35 nm. Since the FWHM of an emission spectrum of the polycyclic compound is within the above-described range, emission efficiency may be improved when the polycyclic compound is applied to a light emitting element. If used as a material for a blue light emitting element, lifetime may be improved.

In an embodiment, the polycyclic compound represented by Formula 1 may emit blue light. The polycyclic compound may have a maximum emission wavelength in a range of about 450 nm to about 480 nm. For example, the polycyclic compound may have a maximum emission wavelength in a range of about 455 nm to about 470 nm.

In an embodiment, the emission layer EML may include the first compound represented by Formula 1, and at least one of a second compound represented by Formula HT, and a third compound represented by Formula ET.

In an embodiment, the emission layer EML may further include a second compound represented by Formula HT-1. In an embodiment, the second compound represented by Formula HT may be used as a hole transport host material in the emission layer EML.

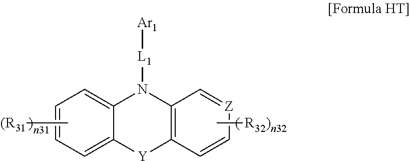

In Formula HT, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT, Ar₁ may be a substituted or unsubstituted aryl group of 6 to 30 ring-forming carbon atoms or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT, Y may be a direct linkage, C(R_{y1})(R_{y2}), or Si(R_{y3})(R_{y4}). For example, two benzene rings that are directly bonded to the nitrogen atom of Formula HT may be directly connected to each other via a direct linkage,

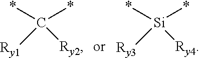

For example, if Y is a direct linkage, the second compound represented by Formula HT may include a carbazole moiety.

In Formula HT, Z may be C(R_{z}) or N.

In Formula HT, R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring. For example, R_{y1} to R_{y4} may each independently be a methyl group or a phenyl group. For example, R₃₁ and R₃₂ may each independently be a hydrogen atom or a deuterium atom.

In Formula HT, n31 may be an integer from 0 to 4. If n31 is 0, the compound represented by Formula HT may not be substituted with R₃₁. A case where n31 is 4 and all R₃₁ groups are each a hydrogen atom may be the same as a case where n31 is 0. If n31 is 2 or more, two or more R₃₁ groups may be the same as each other, or at least one R₃₁ group may be different from the remainder.

In Formula HT, n32 may be an integer from 0 to 3. If n32 is 0, the compound represented by Formula HT may not be substituted with R₃₂. A case where n32 is 3 and all R₃₂ groups are each a hydrogen atom may be the same as a case where n32 is 0. If n32 is 2 or more, two or more R₃₂ groups may be the same as each other, or at least one R₃₂ group may be different from the remainder.

In an embodiment, the emission layer EML may further include a third compound represented by Formula ET. In an embodiment, the third compound may be used as an electron transport host material in the emission layer EML.

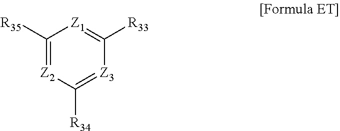

In Formula ET, Z₁ to Z₃ may each independently be N or C(R₃₆); and at least one of Z₁ to Z₃ may each be N. For example, Z₁ to Z₃ may each be N. For example, Z₁ and Z₂ may each be N, and Z₃ may be C(R₃₆); Z₁ may be C(R₃₆), and Z₂ and Z₃ may each be N; or Z₁ and Z₃ may each be N, and Z₂ may be C(R₃₆). For example, Z₁ may be N, and Z₂ and Z₃ may each independently be C(R₃₆); Z₂ may be N, and Z₁ and Z₃ may each independently be C(R₃₆); or Z₃ may be N, and Z₁ and Z₂ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring. For example, R₃₃ to R₃₆ may each independently be a substituted or unsubstituted phenyl group, a substituted or unsubstituted carbazole group, etc. However, embodiments are not limited thereto.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (Ti) of the exciplex formed by the hole transport host and the electron transport host may be in a range of about 2.4 eV to about 3.0 eV. The triplet energy level of the exciplex may have a value that is smaller than an energy gap of each host material. The exciplex may have a triplet energy level equal to or less than about 3.0 eV, which is the energy gap between the hole transport host and the electron transport host.

In an embodiment, the emission layer EML may further include a fourth compound, in addition to the first compound, the second compound, and the third compound. The fourth compound may be used as a phosphorescence sensitizer in an emission layer EML. Energy may transfer from the fourth compound to the first compound, thereby emitting light.

The emission layer EML may include, as a fourth compound, an organometallic complex that includes platinum (Pt) as a central metal atom and ligands connected to the central metal atom. In an embodiment, the emission layer EML may further include a fourth compound represented by Formula PS.

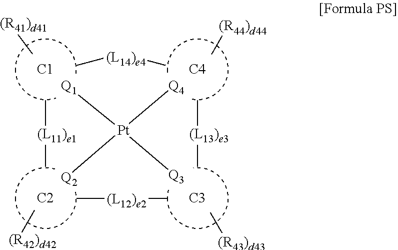

In Formula PS, Q₁ to Q₄ may each independently be C or N.

In Formula PS, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula PS, L₁₁ to L₁₄ may each independently be a direct linkage,

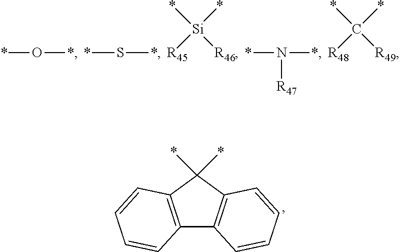

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, wherein in L₁₁ to L₁₄, ----* represents a bond to one of C1 to C4.

In Formula PS, e1 to e4 may each independently be 0 or 1. If e1 is 0, C1 and C2 may not be directly bonded to each other. If e2 is 0, C2 and C3 may not be directly bonded to each other. If e3 is 0, C3 and C4 may not be directly bonded to each other. If e4 is 0, C1 and C4 may not be directly bonded to each other.

In Formula PS, R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring. For example, R₄₁ to R₄₉ may each independently be a substituted or unsubstituted methyl group or a substituted or unsubstituted t-butyl group.

In Formula PS, d1 to d4 may each independently be an integer from 0 to 4. If d1 to d4 are 0, the fourth compound may not be substituted with R₄₁ to R₄₄. A case where d1 to d4 are each 4, and all groups of R₄₁ to R₄₄ are hydrogen atoms may be the same as a case where d1 to d4 are each 0. If d1 to d4 are each 2 or more, multiple groups of each of R₄₁ to R₄₄ may be the same as each other, or at least one thereof may be different from the remainder.

In an embodiment, in Formula PS, C1 to C4 may each independently be a substituted or unsubstituted hydrocarbon ring or a substituted or unsubstituted heterocycle that is represented by one of Formula C-1 to Formula C-4.

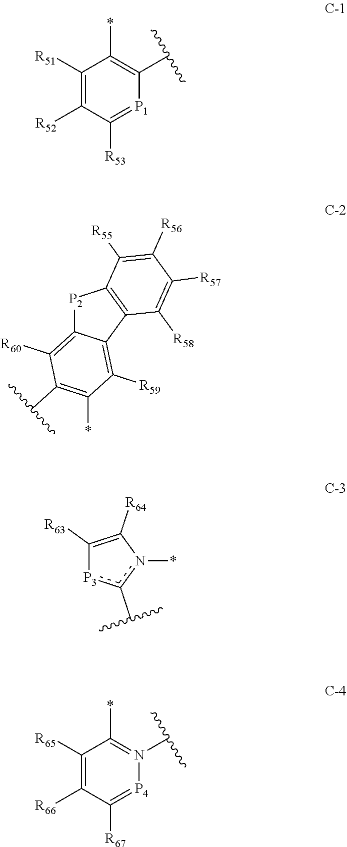

In Formula C-1 to Formula C-4, P₁ may be C----* or C(R₅₄), P₂ may be N----* or N(R₆₁), P₃ may be N----* or N(R₆₂), and P₄ may be C----* or C(R₆₈).

In Formula C-1 to Formula C-4, R₅₁ to R₆₈ may each independently be a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula C-1 to Formula C-4,

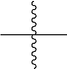

represents a bond to Pt, and ----* represents a bond to an adjacent cyclic group (C1 to C4) or to a linker (L₁₁ to L₁₄).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form exciplex, and energy may be transferred from the exciplex to the fourth compound and the first compound, thereby emitting light. In an embodiment, the fourth compound may be a sensitizer. The fourth compound included in the emission layer EML of the light emitting element ED may serve as a sensitizer to transfer energy from the host to the first compound, which is a light emitting dopant. For example, the fourth compound, which serves as an auxiliary dopant, accelerates energy transfer to the first compound, which serves as a light emitting dopant, thereby increasing an emission ratio of the first compound. Accordingly, the emission efficiency of the emission layer EML may be improved. When energy transfer to the first compound increases, excitons formed in the emission layer EML may not accumulate in the emission layer EML and may emit light rapidly, so that deterioration of a light emitting element ED may be reduced. Accordingly, the lifetime of the light emitting element ED may be increased.

The light emitting element ED may include the first compound, the second compound, the third compound, and the fourth compound, and the emission layer EML may include the combination of two host materials and two dopant materials. In the light emitting element ED, the emission layer EML may include different two hosts, the first compound that emits delayed fluorescence, and the fourth compound that includes an organometallic complex, and thus the light emitting element ED may show excellent emission efficiency.

In an embodiment, the second compound represented by Formula HT may be selected from Compound Group HT. In an embodiment, in the light emitting element ED, the second compound may include at least one compound selected from Compound Group HT. In Compound Group HT, D represents a deuterium atom, and Ph represents an unsubstituted phenyl group.

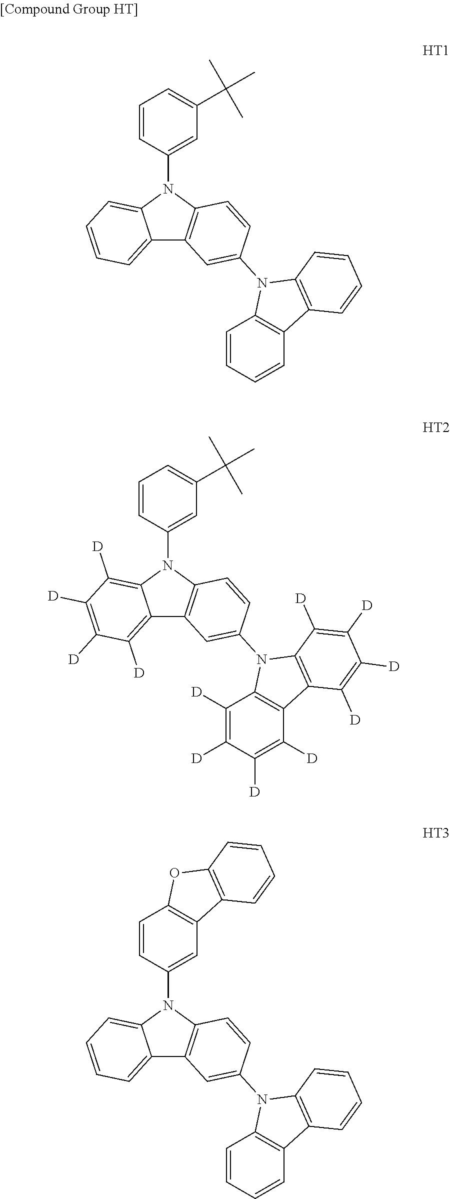 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

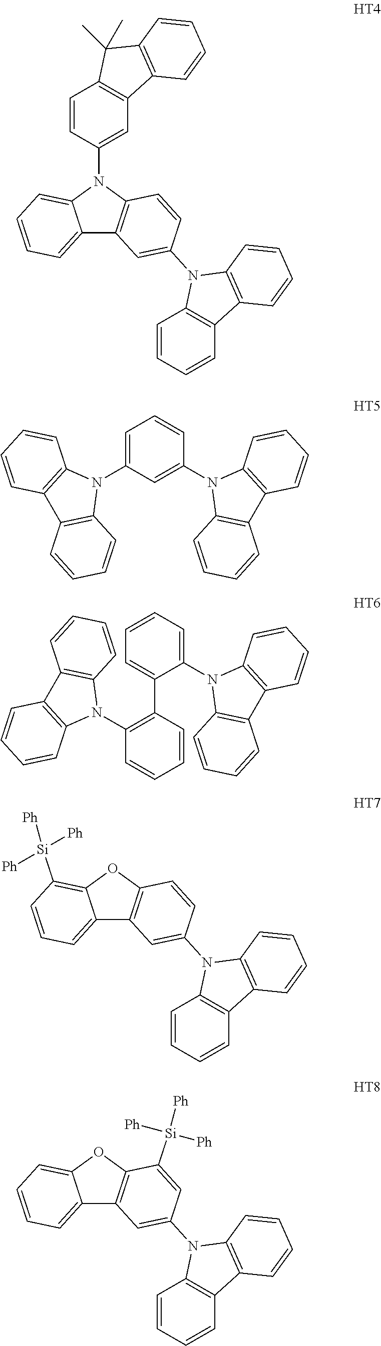

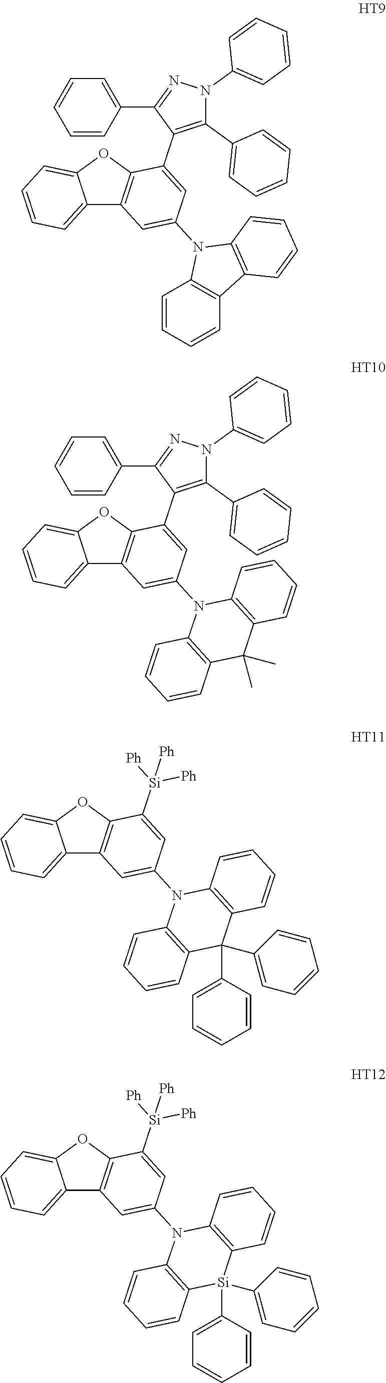 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

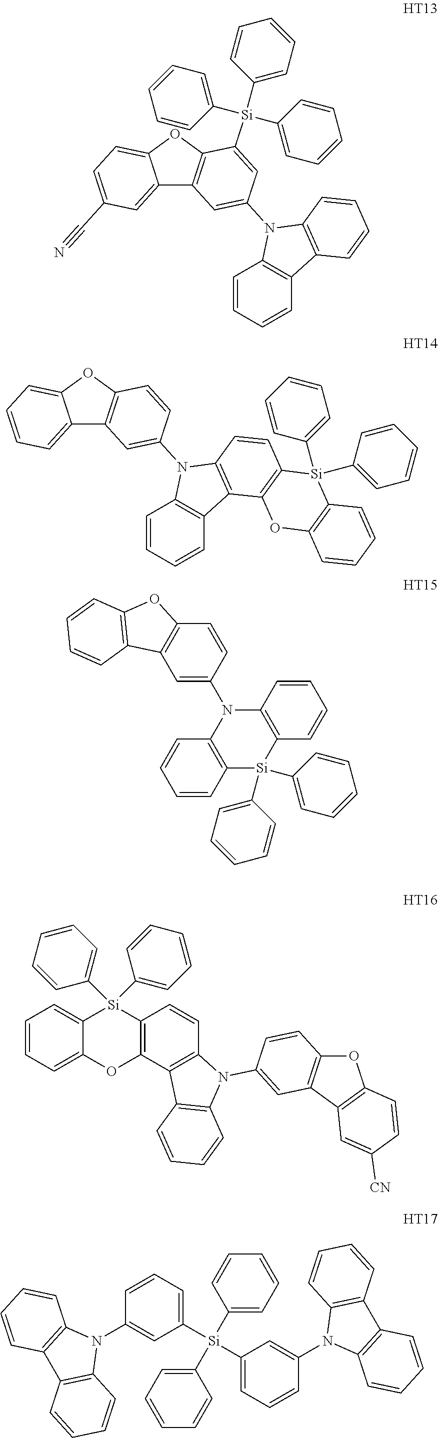

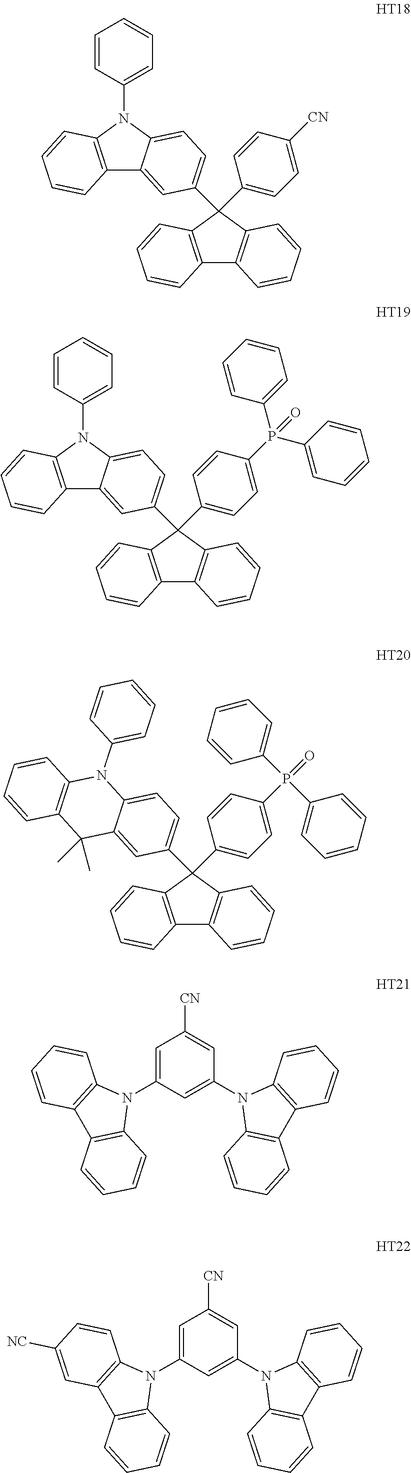 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

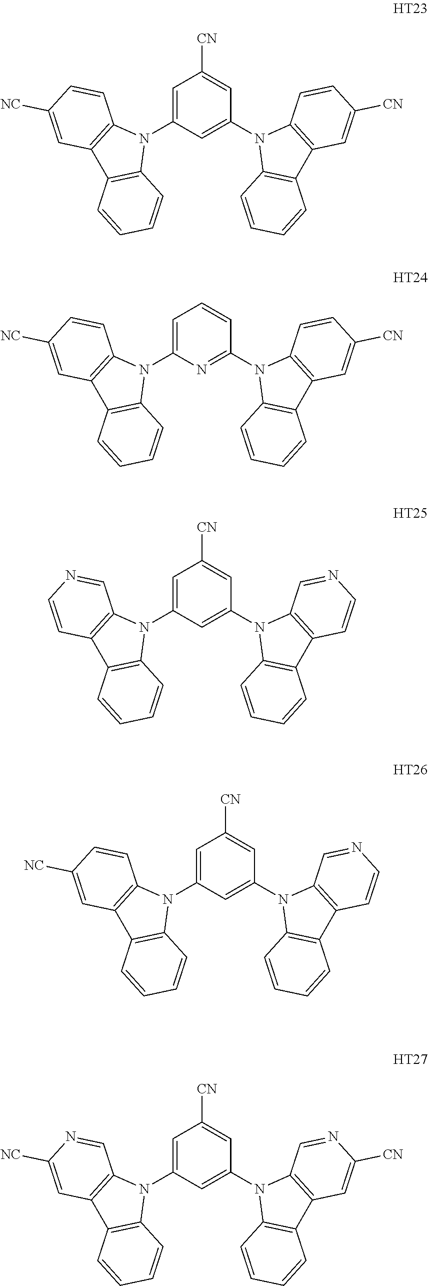 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

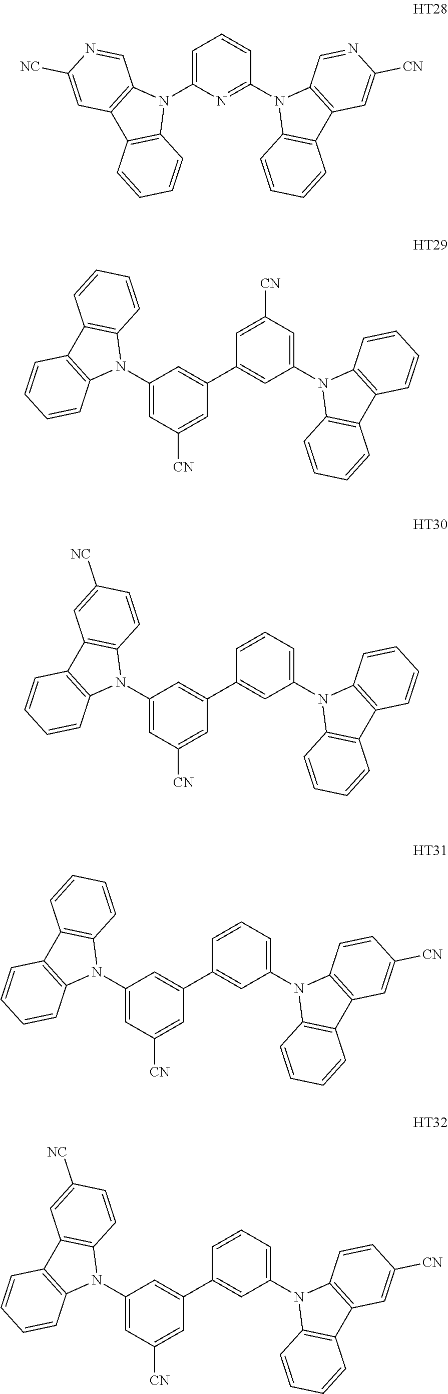 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

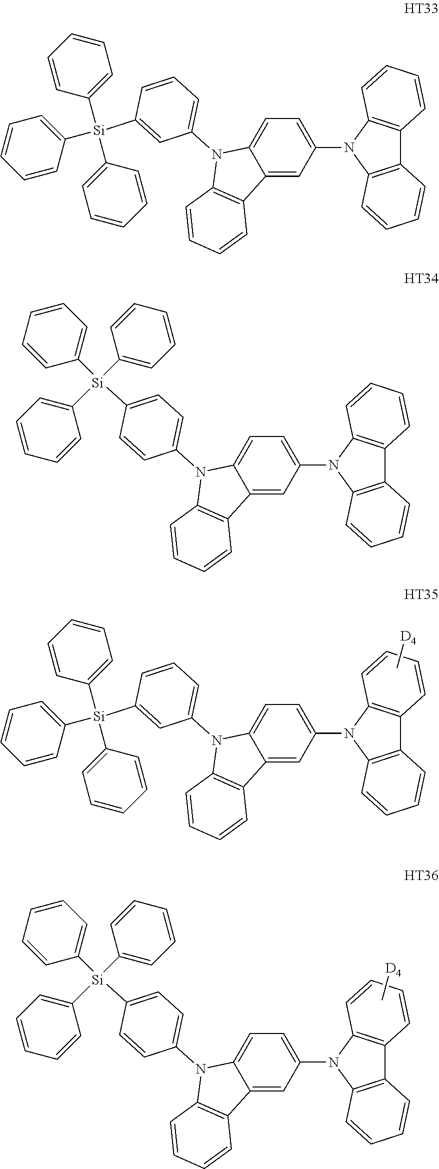

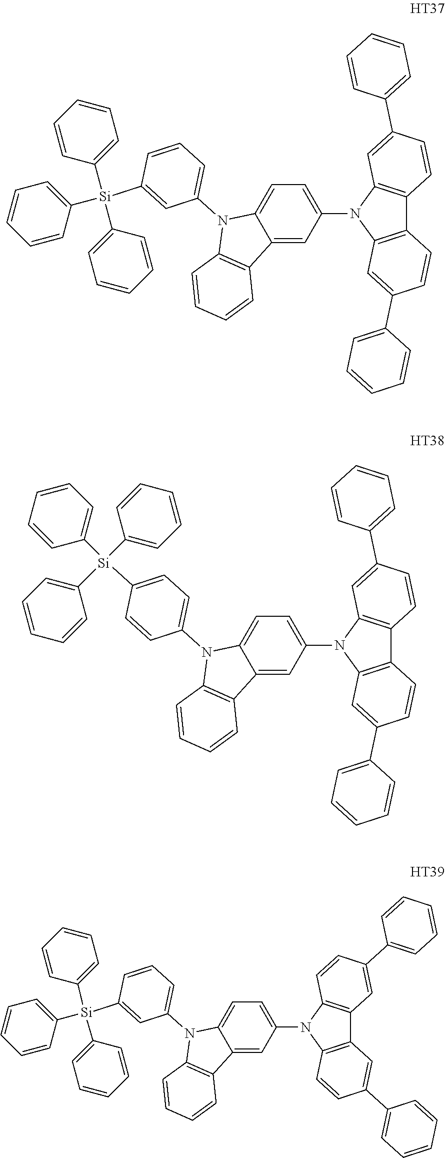 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

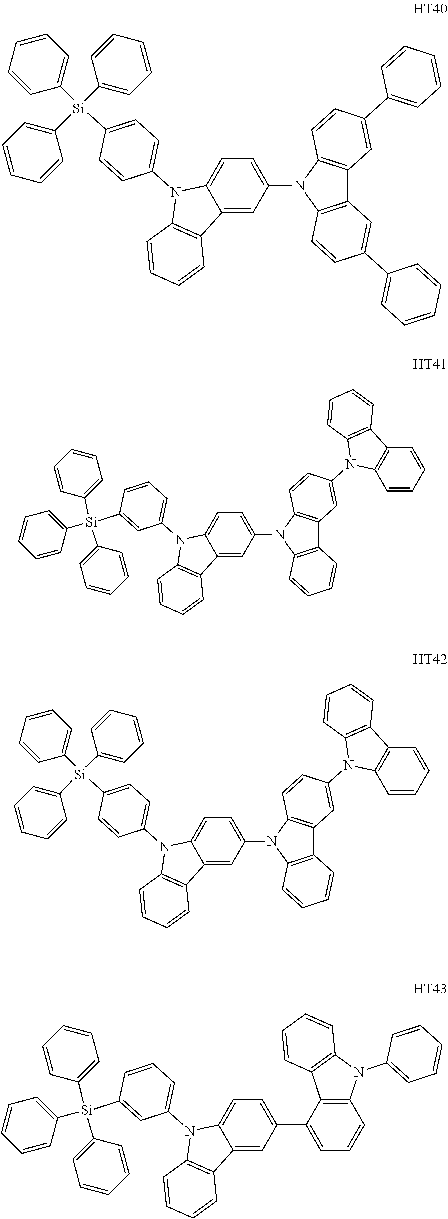 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

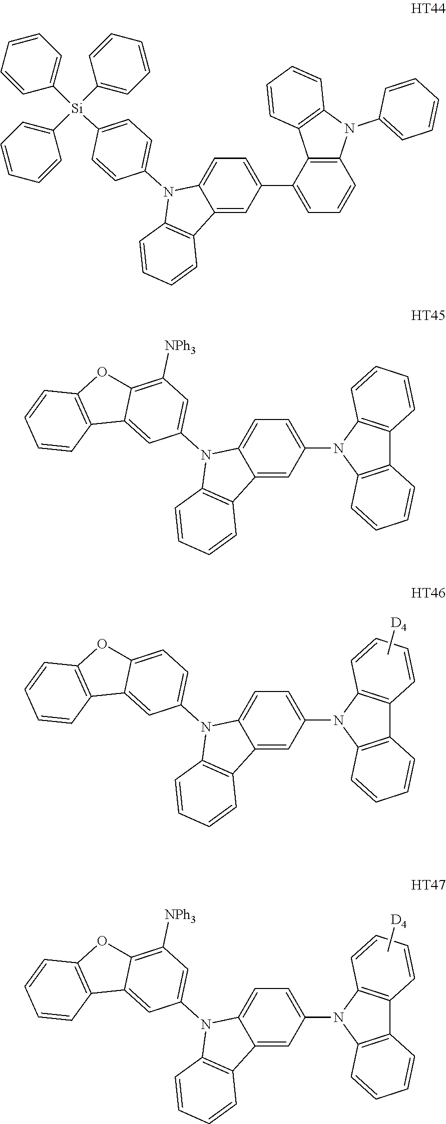

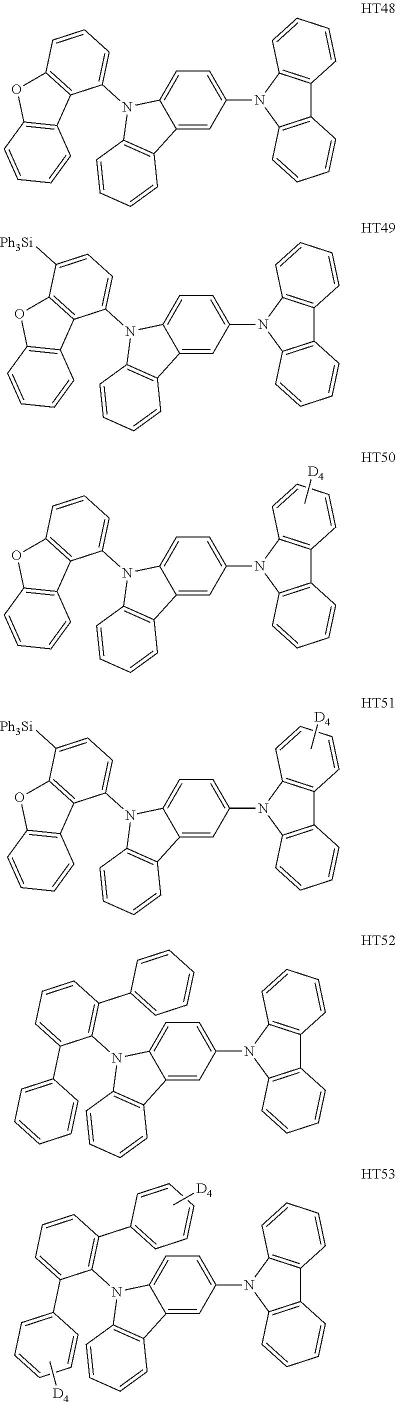

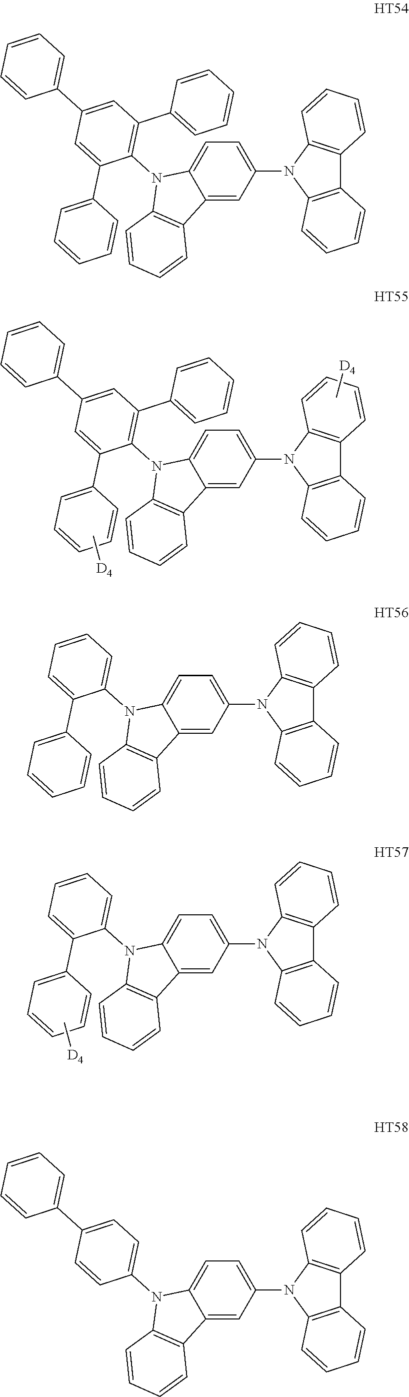

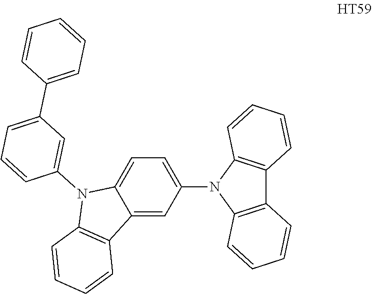 [SMILES: c1ccc(-c2cccc(-n3c4ccccc4c4cc(-n5c6ccccc6c6ccccc65)ccc43)c2)cc1]

In an embodiment, the third compound represented by Formula ET may be selected from Compound Group ET. In an embodiment, in the light emitting element ED, the third compound may include at least one compound selected from Compound Group ET. In Compound Group ET, D represents a deuterium atom.

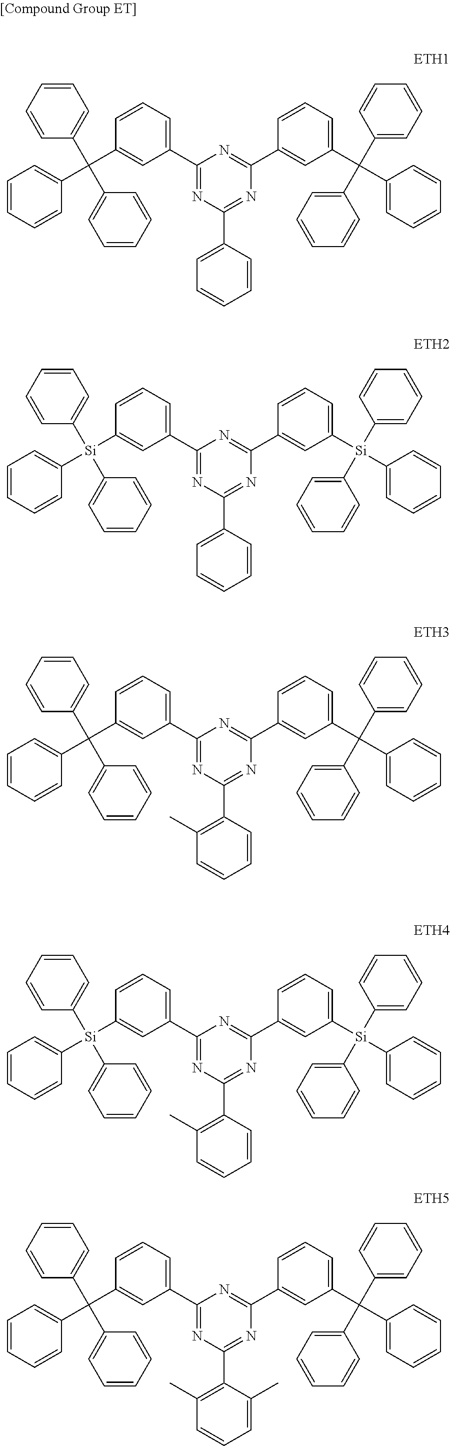

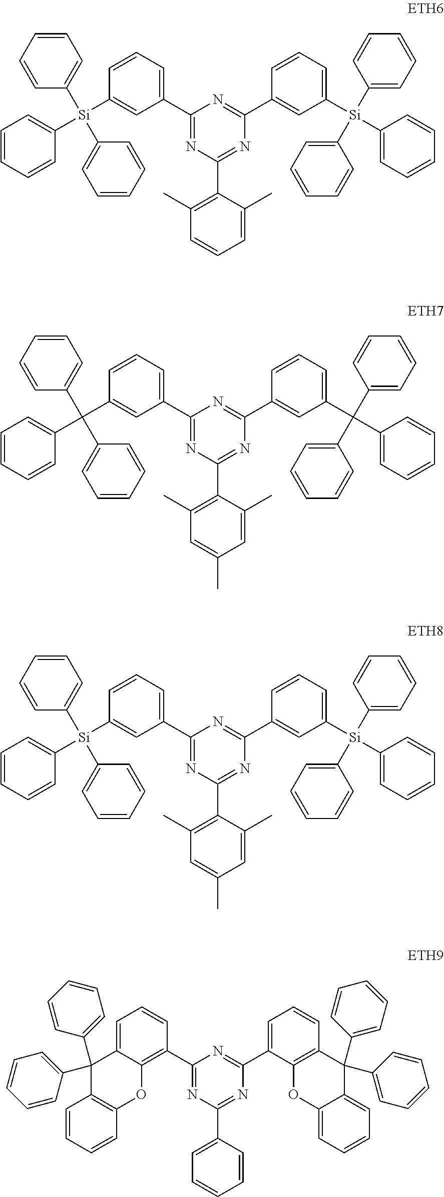 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

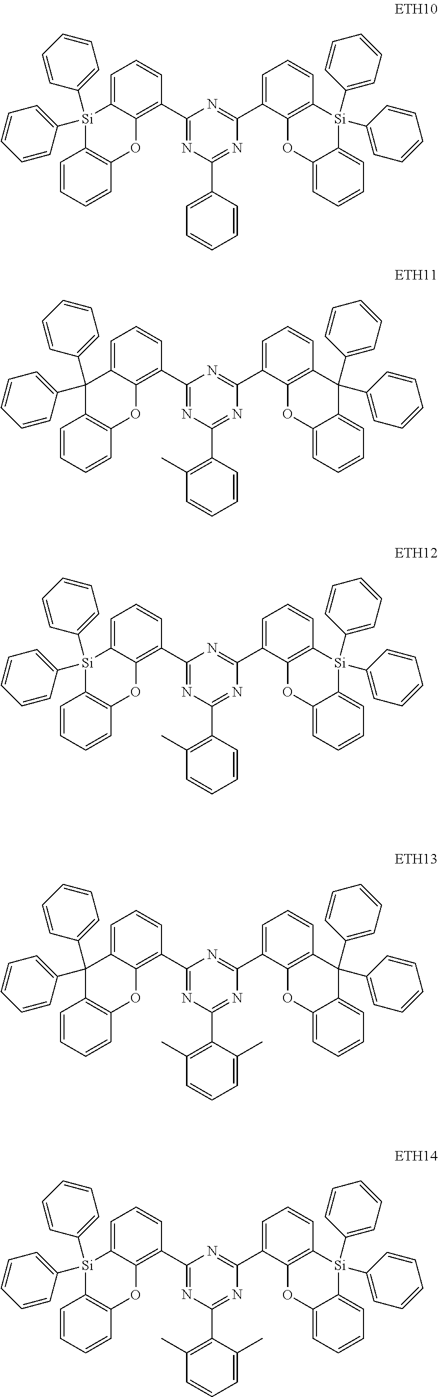

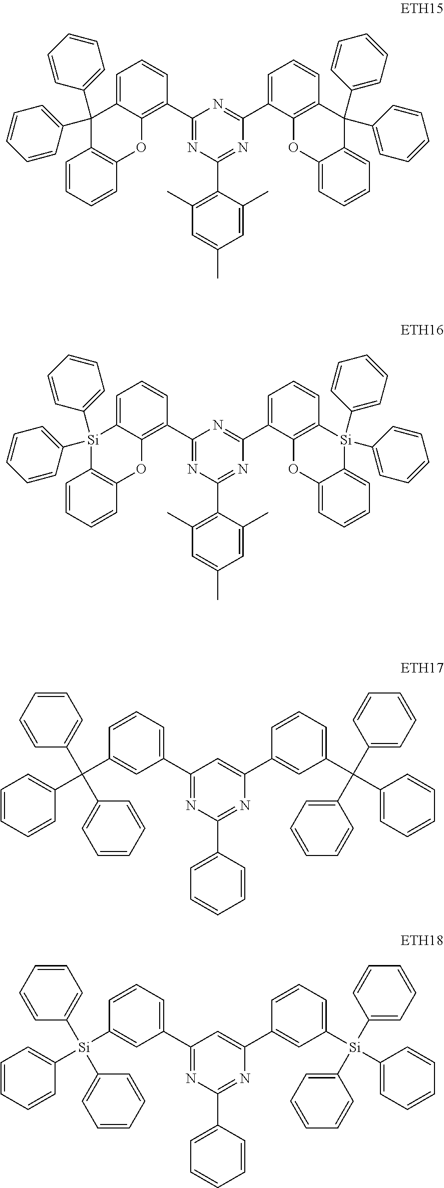 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1]

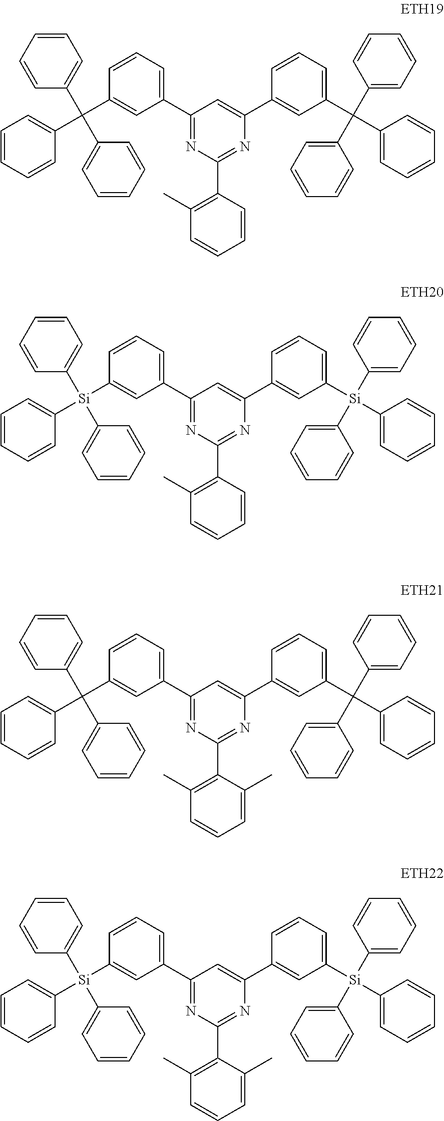 [SMILES: Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

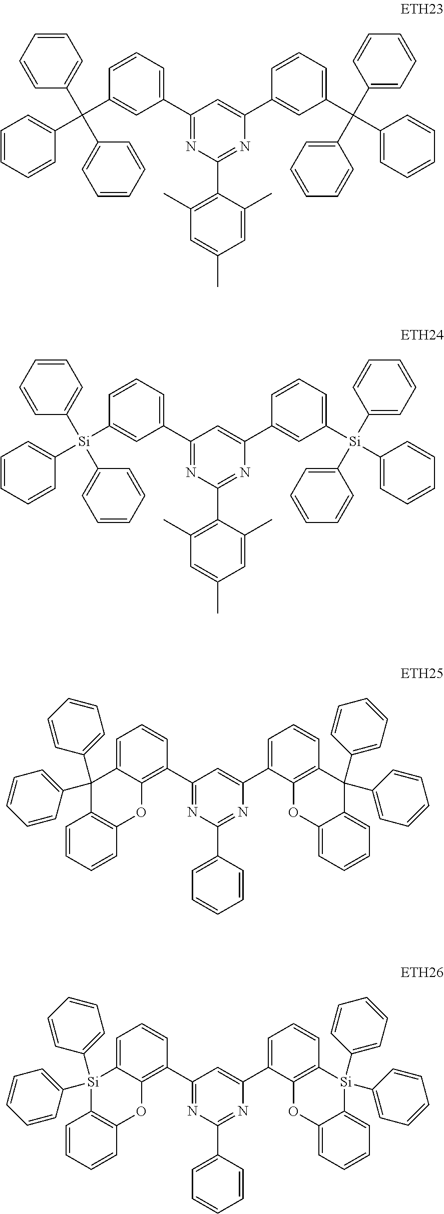 [SMILES: Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1]

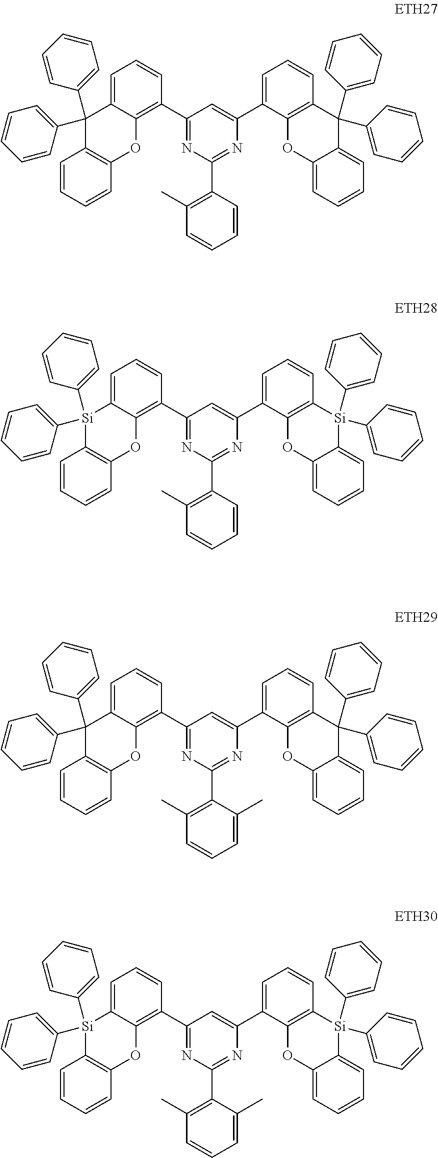 [SMILES: Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

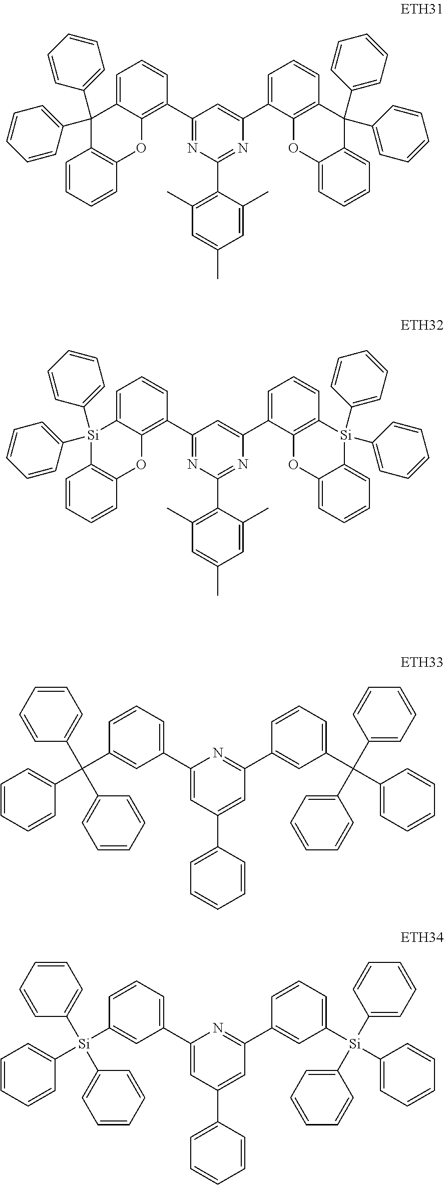 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1]

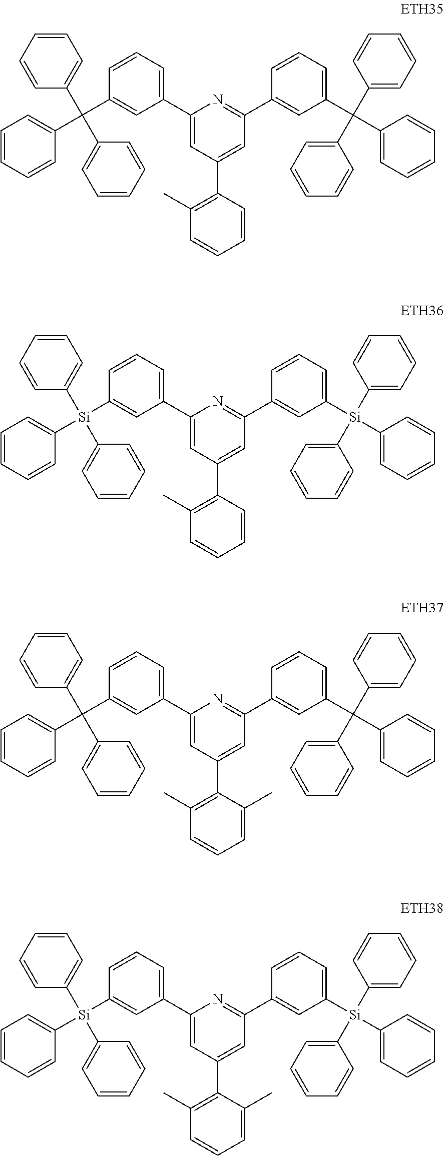 [SMILES: Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

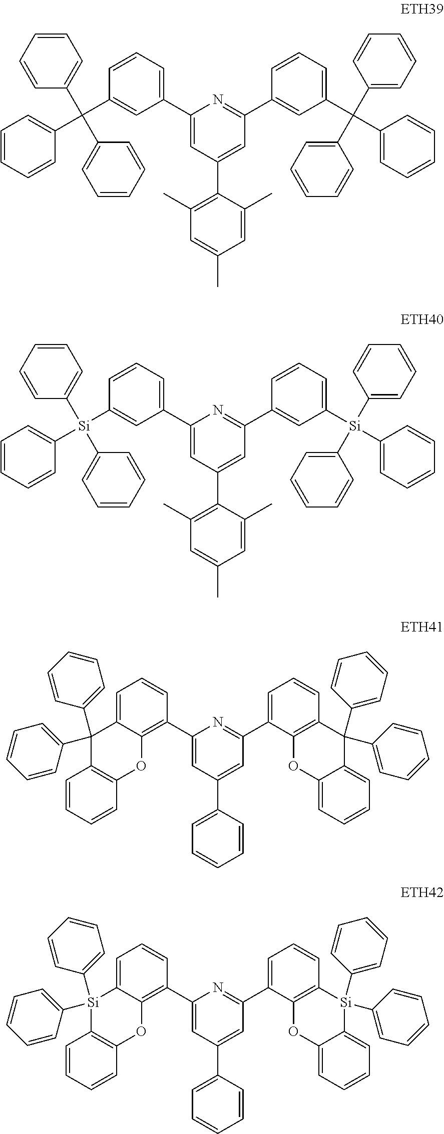 [SMILES: Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1]

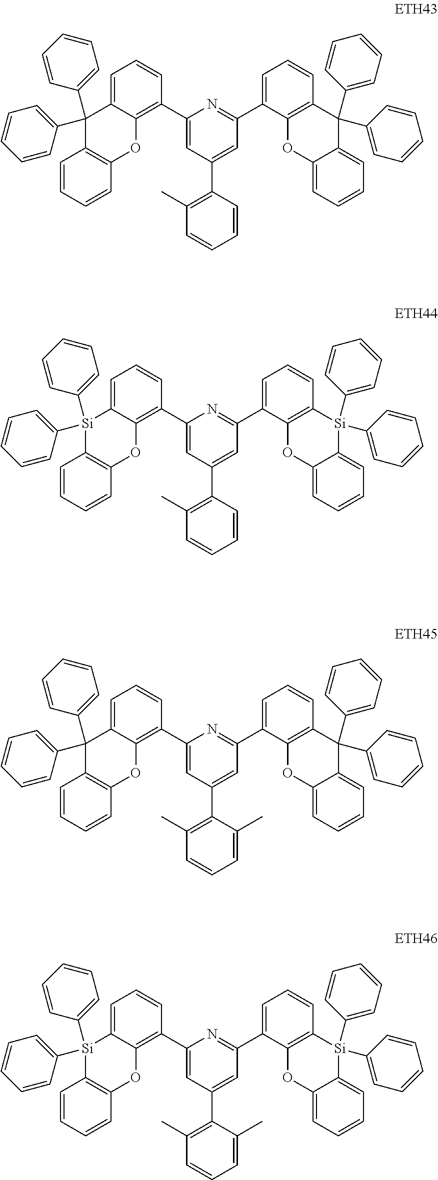 [SMILES: Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

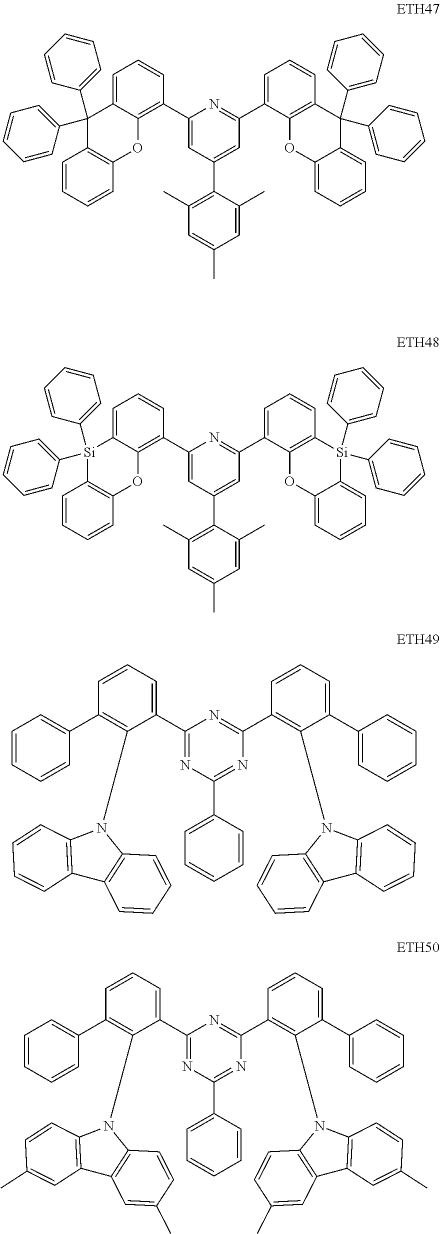

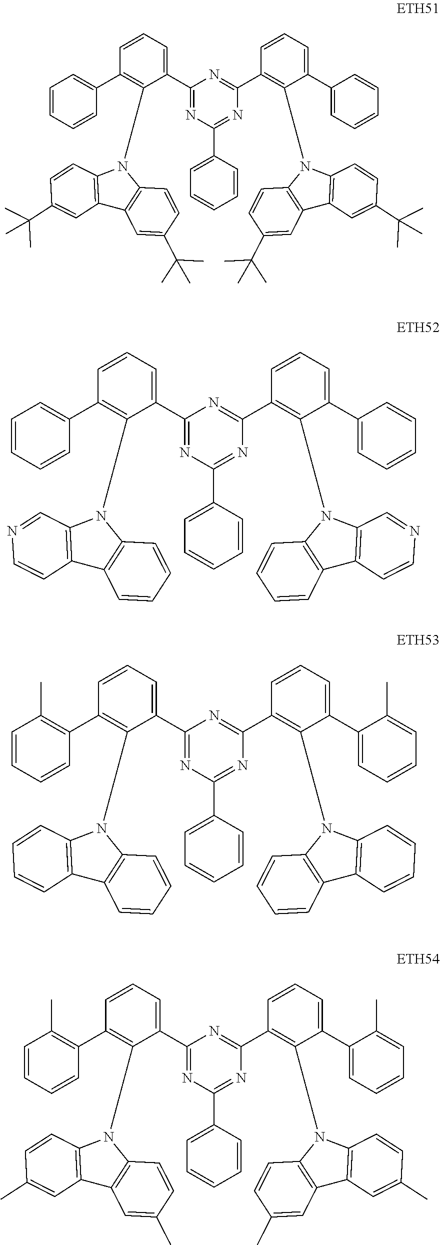

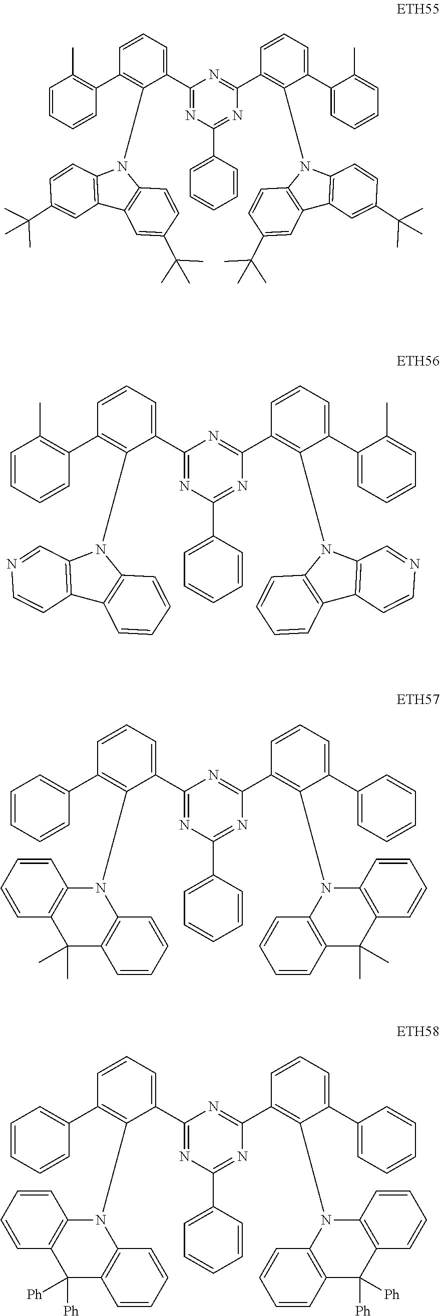

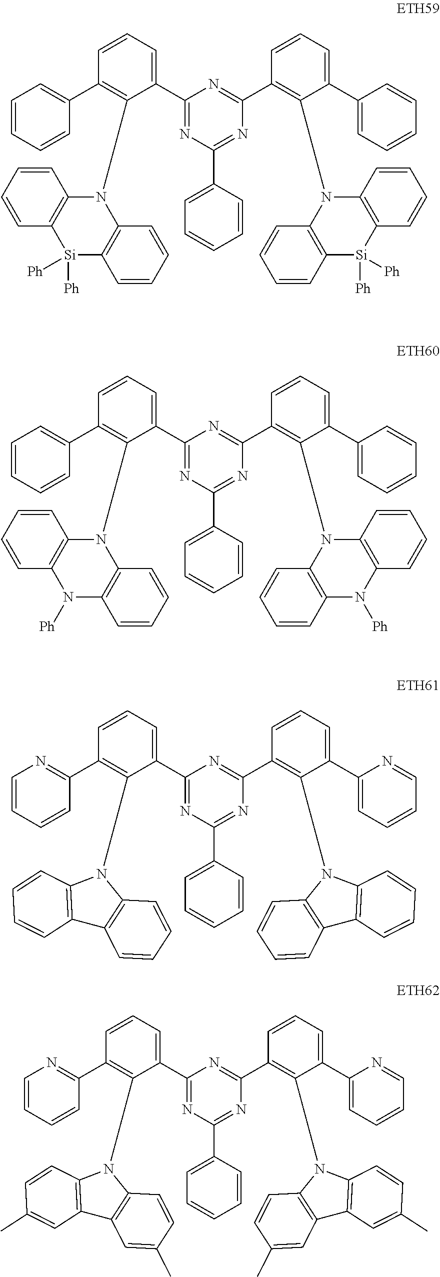

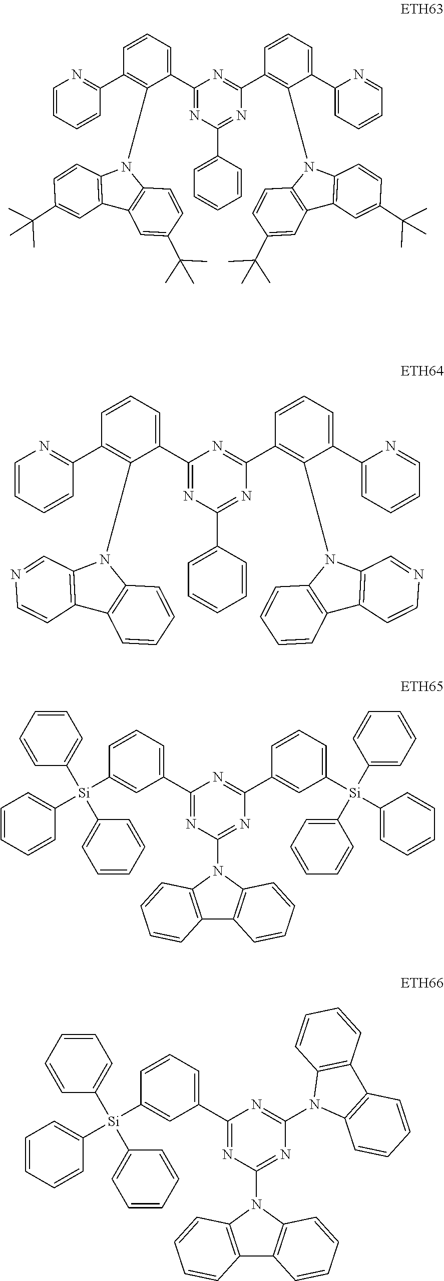 [SMILES: CC(C)(C)c1ccc2c(c1)c1cc(C(C)(C)C)ccc1n2CCc1c(-c2ccccn2)cccc1-c1nc(-c2ccccc2)nc(-c2cccc(-c3ccccn3)c2CCn2c3ccc(C(C)(C)C)cc3c3cc(C(C)(C)C)ccc32)n1 ; c1ccc(-c2nc(-c3cccc(-c4ccccn4)c3CCn3c4ccccc4c4ccncc43)nc(-c3cccc(-c4ccccn4)c3CCn3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

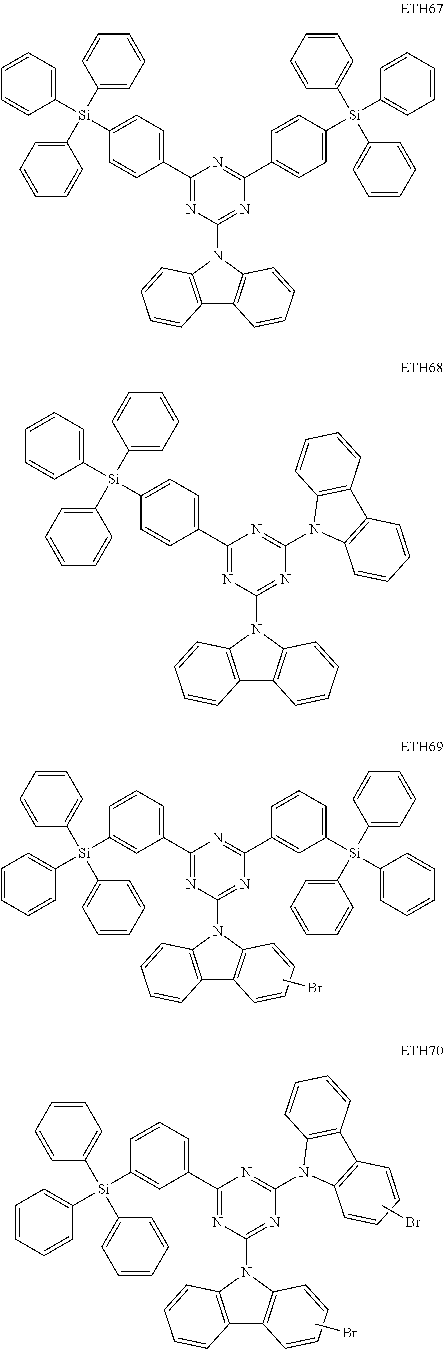

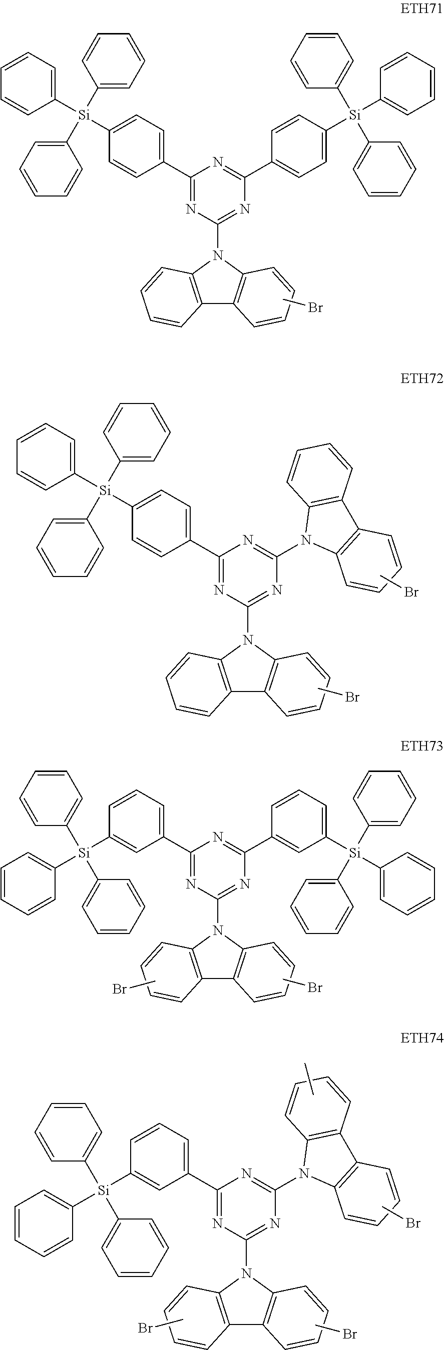

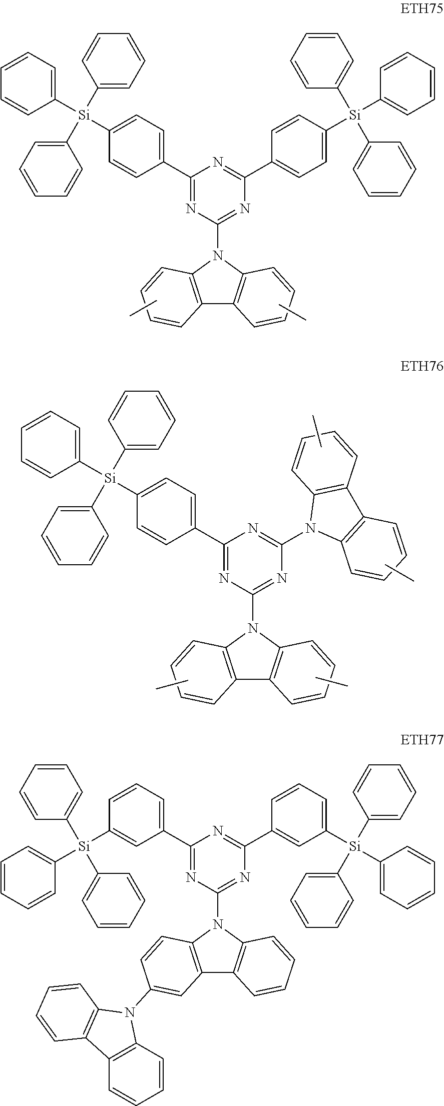

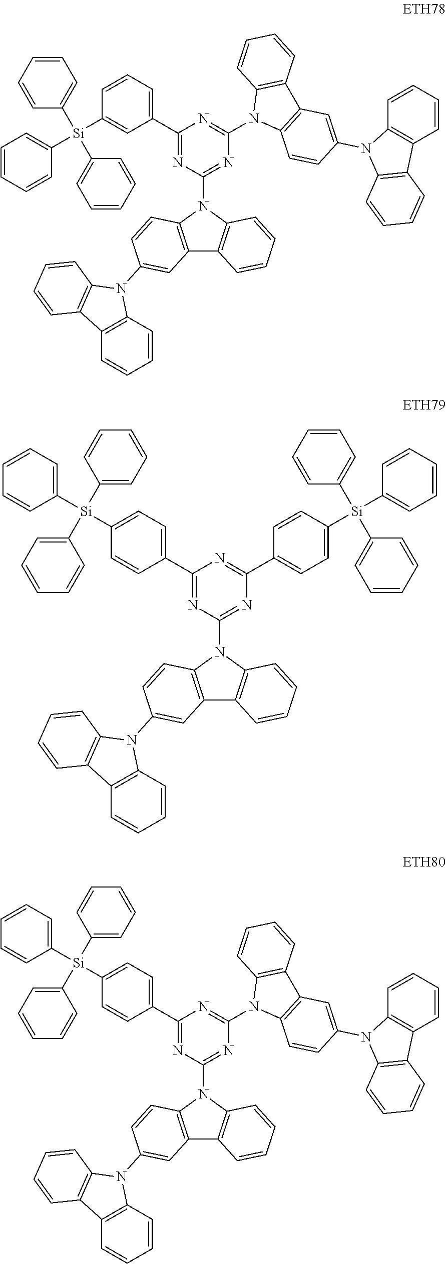 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

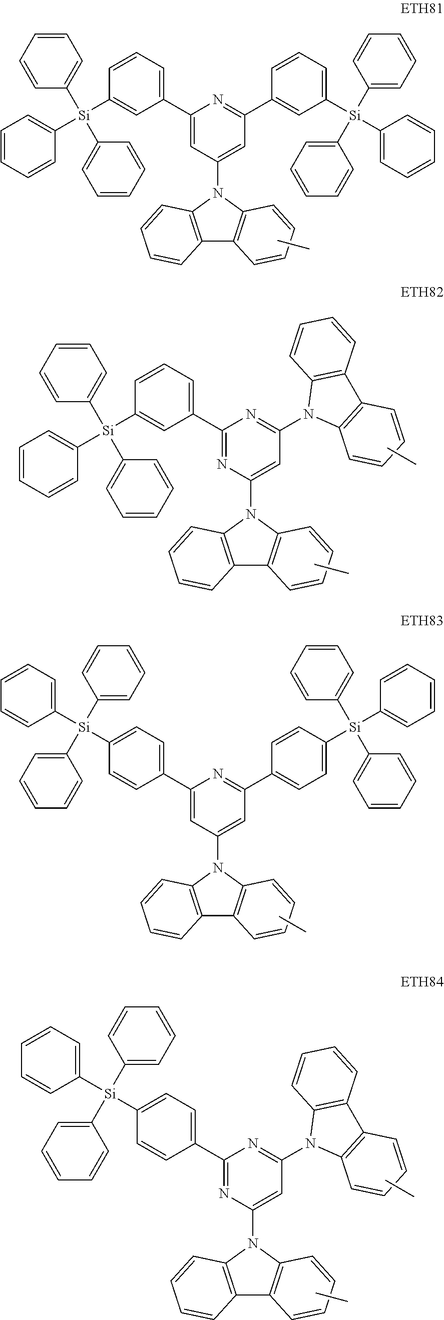

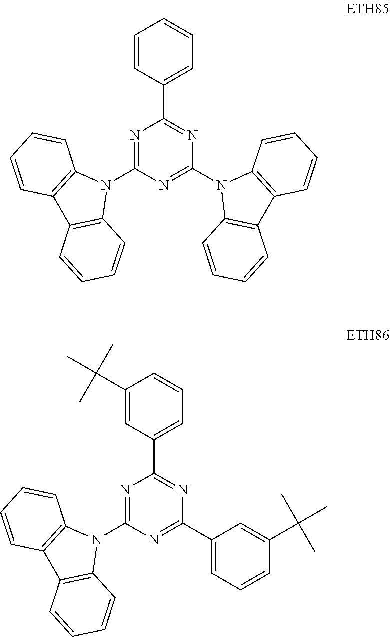 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In an embodiment, the fourth compound represented by Formula PS may be selected from Compound Group AD. In an embodiment, in the light emitting element ED, the fourth compound may include at least one compound selected from Compound Group AD.

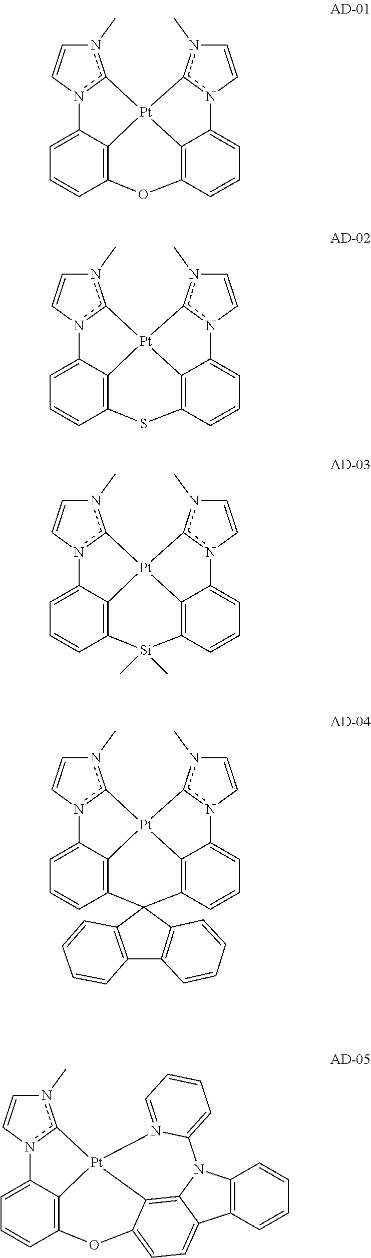

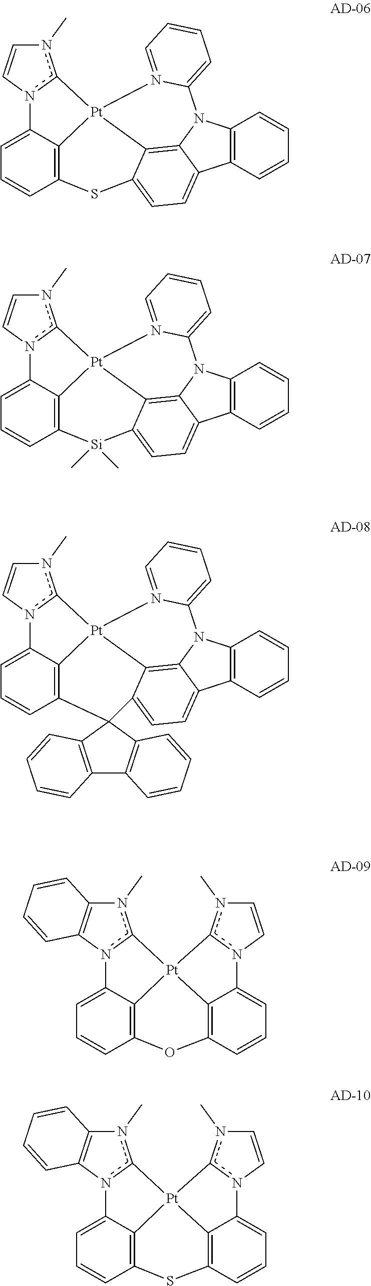

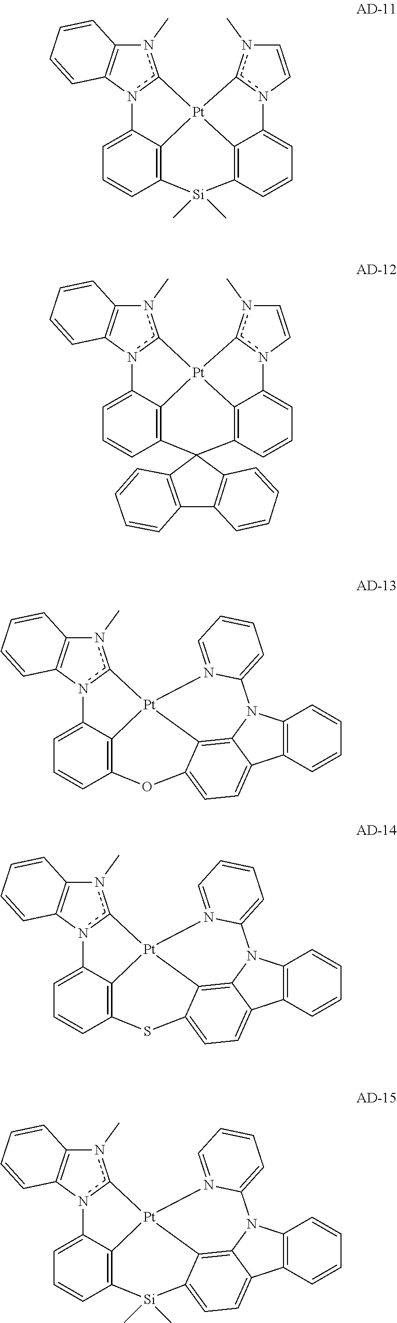

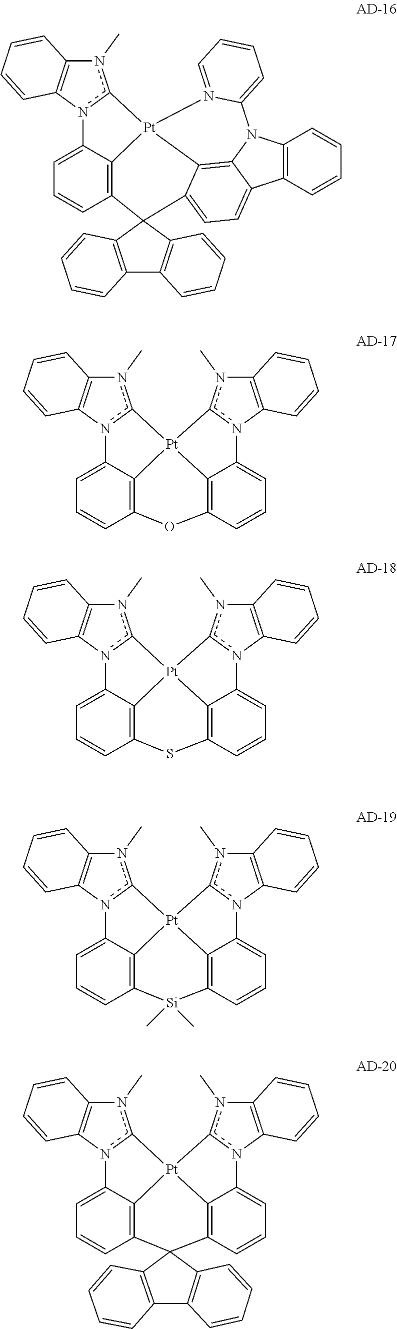

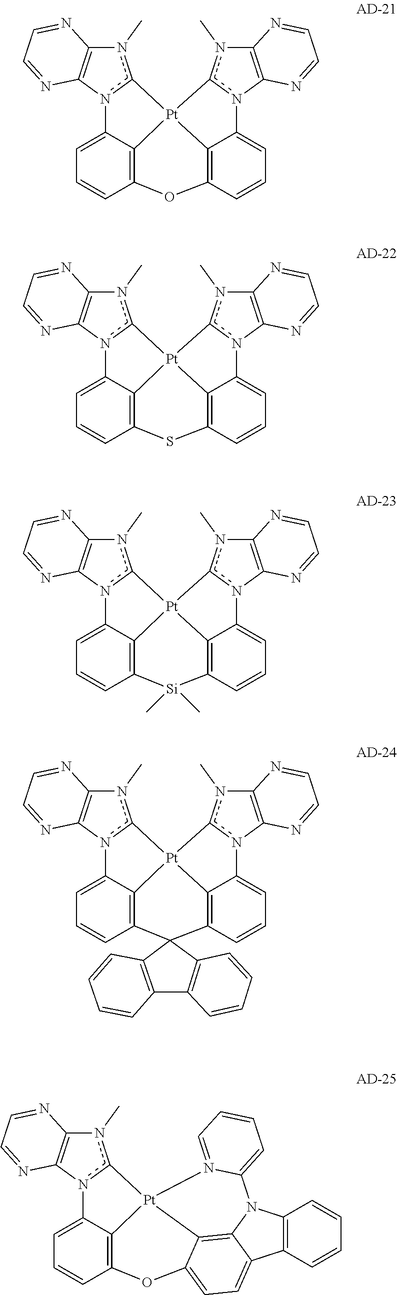

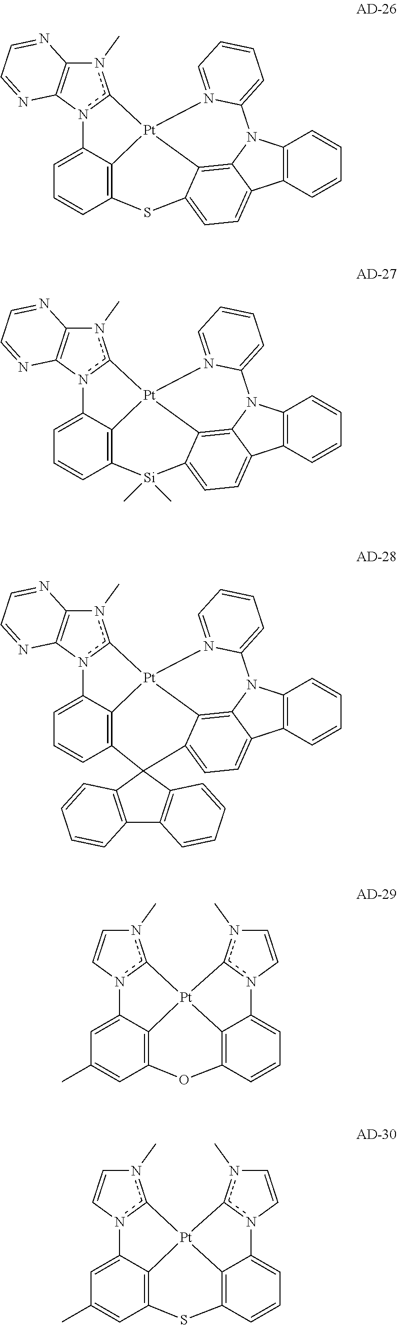

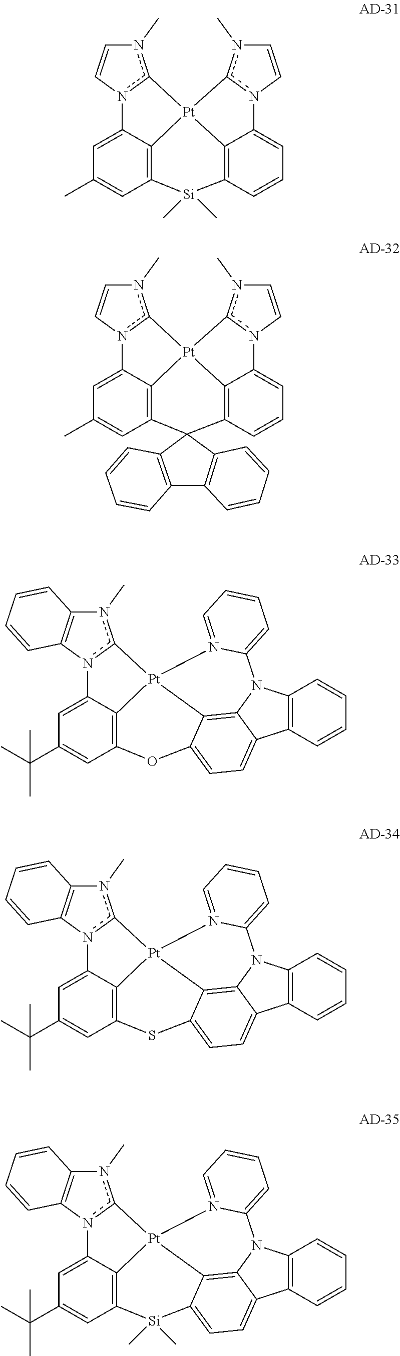

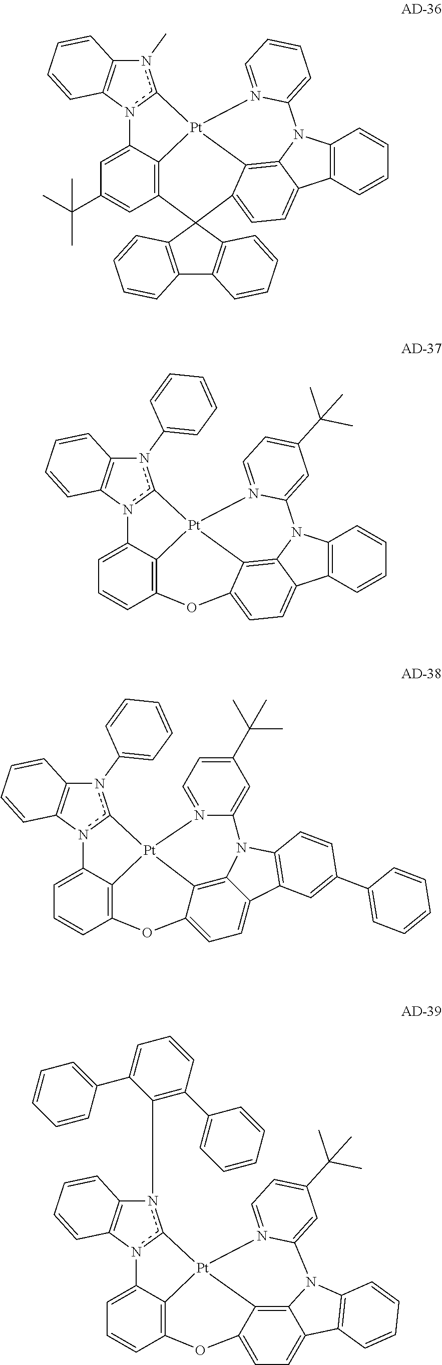

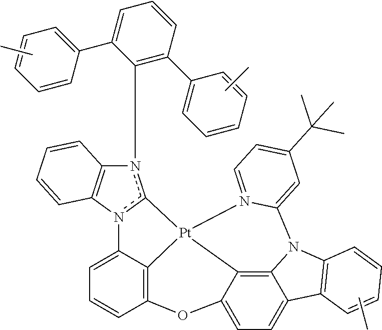

In an embodiment, the light emitting element ED may include multiple emission layers. The emission layers may be provided as a stack, so that a light emitting element ED including multiple emission layers may emit white light. The light emitting element ED including multiple emission layers may be a light emitting element ED having a tandem structure. If the light emitting element ED includes multiple emission layers, at least one emission layer EML may include the first compound, the second compound, the third compound, and the fourth compound as described above.

In the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIG. 3 to FIG. 6, the emission layer EML may further include a host and a dopant of the related art, in addition to the above-described host and dopant.

In an embodiment, the emission layer EML may include a compound represented by Formula E-1. The compound represented by Formula E-1 may be used as a fluorescence host material.

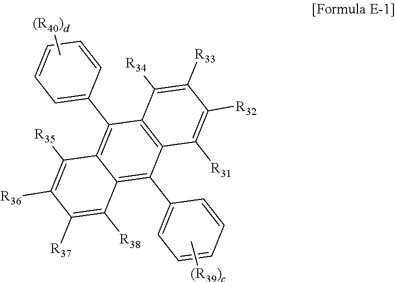

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19.

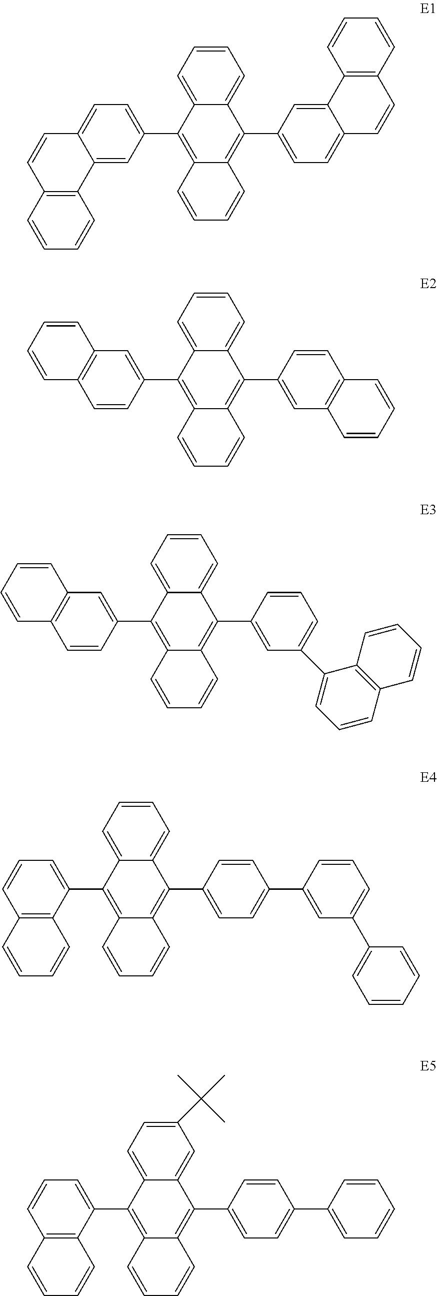

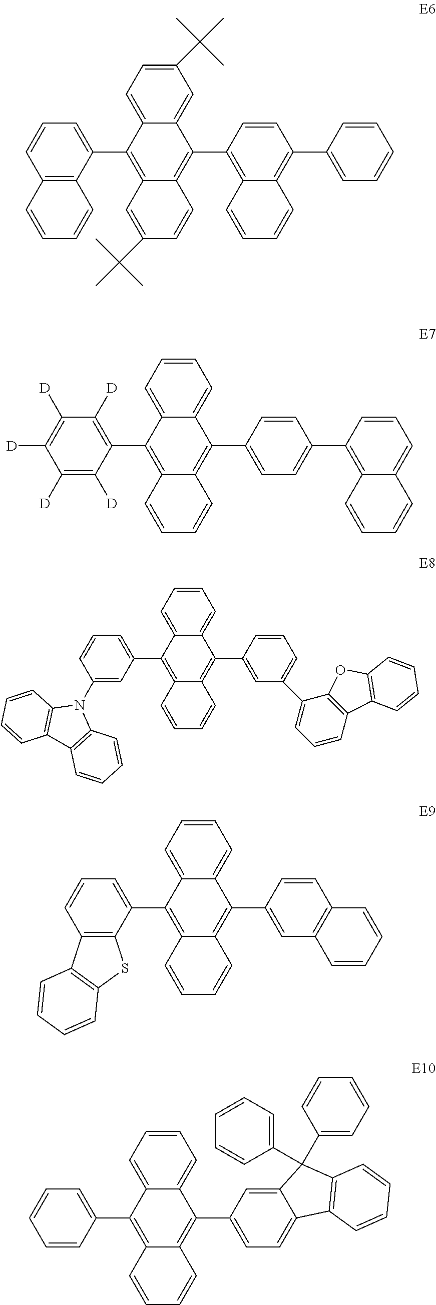

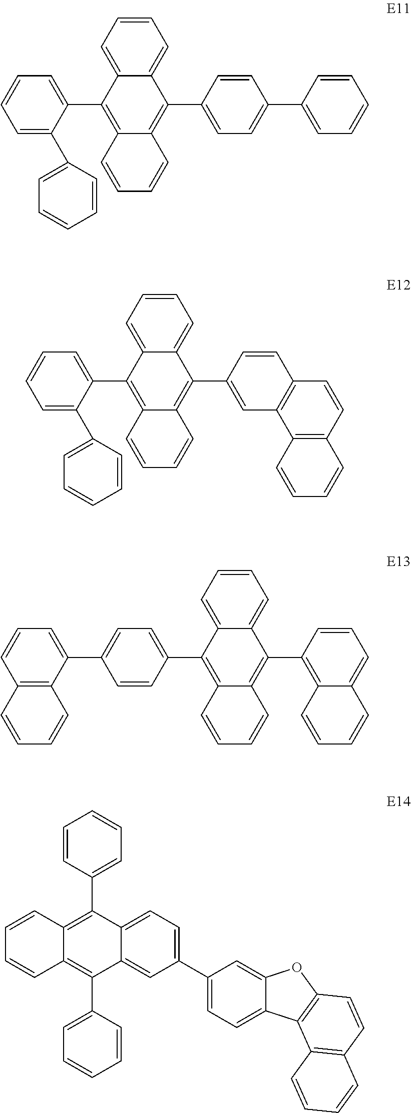

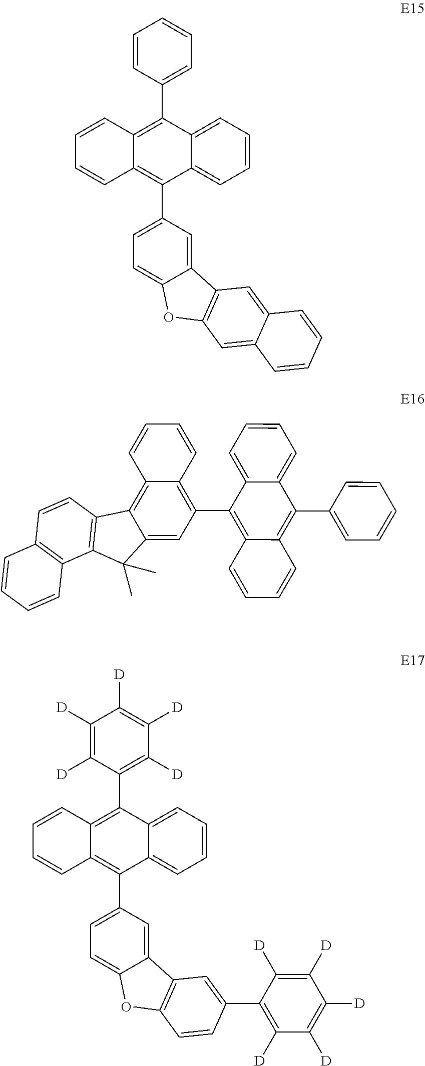

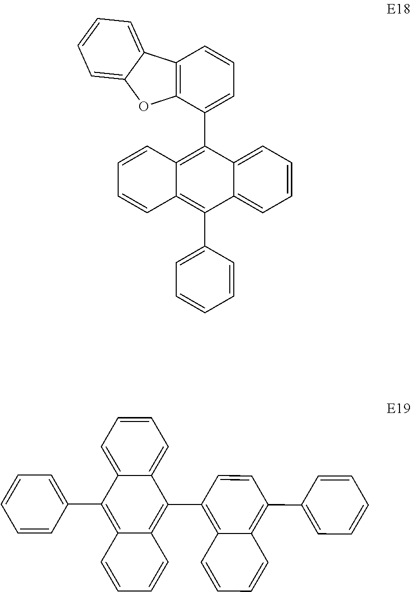

In an embodiment, the emission layer EML may include a compound represented by Formula E-2a or Formula E-2b. The compound represented by Formula E-2a or Formula E-2b may be used as a phosphorescence host material.

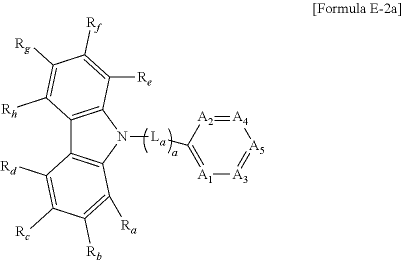

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

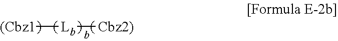

In Formula E-2b, Cbz1 and Cbz2 may each independently be an unsubstituted carbazole group, or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple L_{b} groups may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any compound selected from Compound Group E-2. However, the compounds shown in Compound Group E-2 are only examples, and the compound represented by Formula E-2a or Formula E-2b is not limited to Compound Group E-2.

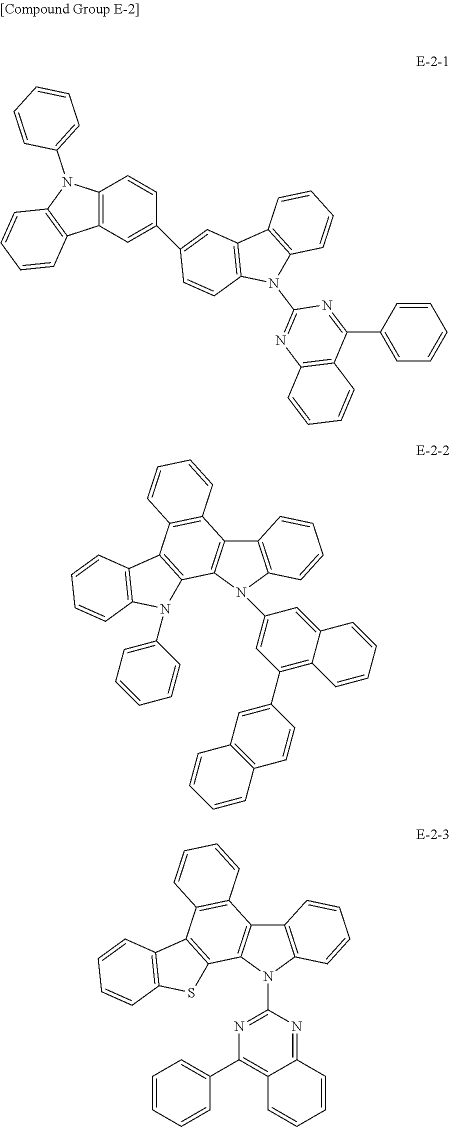

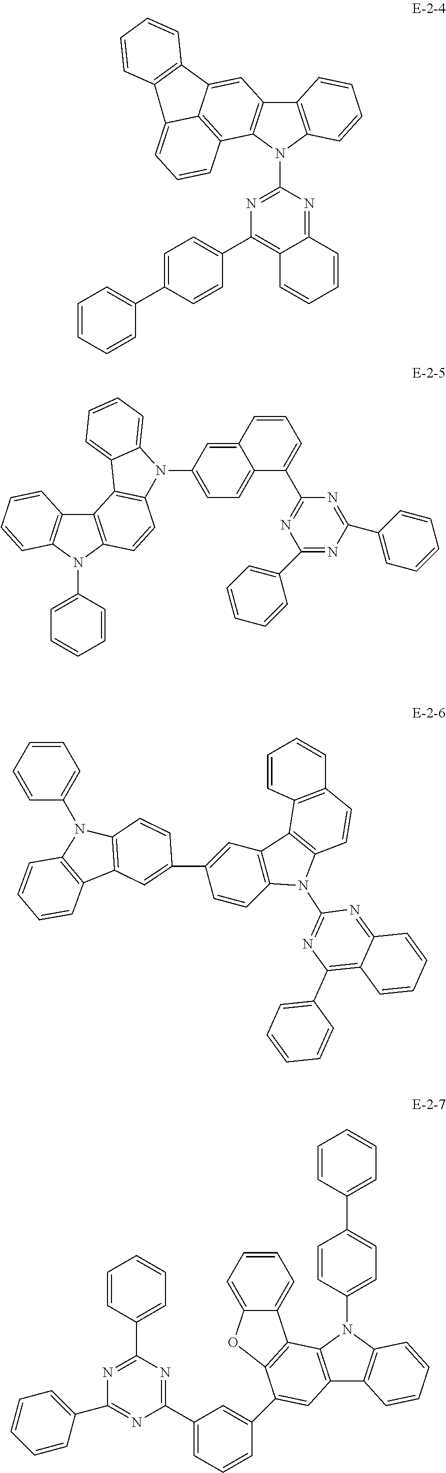

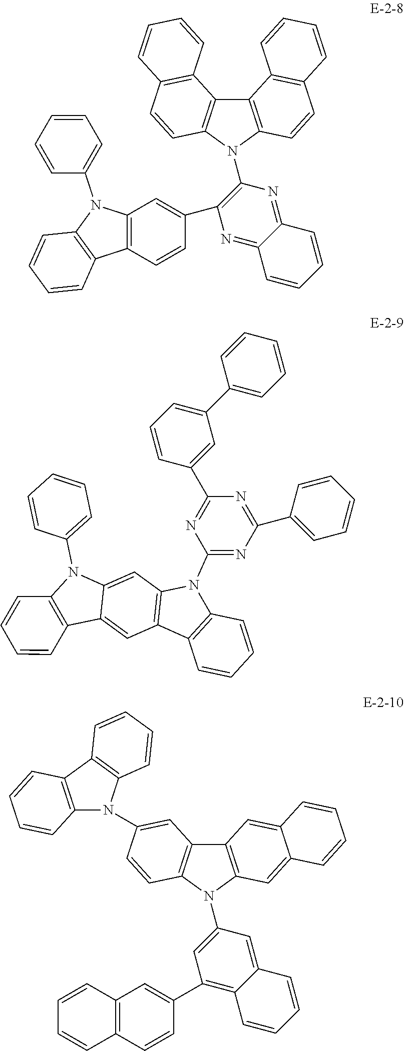 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3cc(-n4c5ccc(-n6c7ccccc7c7ccccc76)cc5c5cc6ccccc6cc54)cc4ccccc34)ccc2c1]

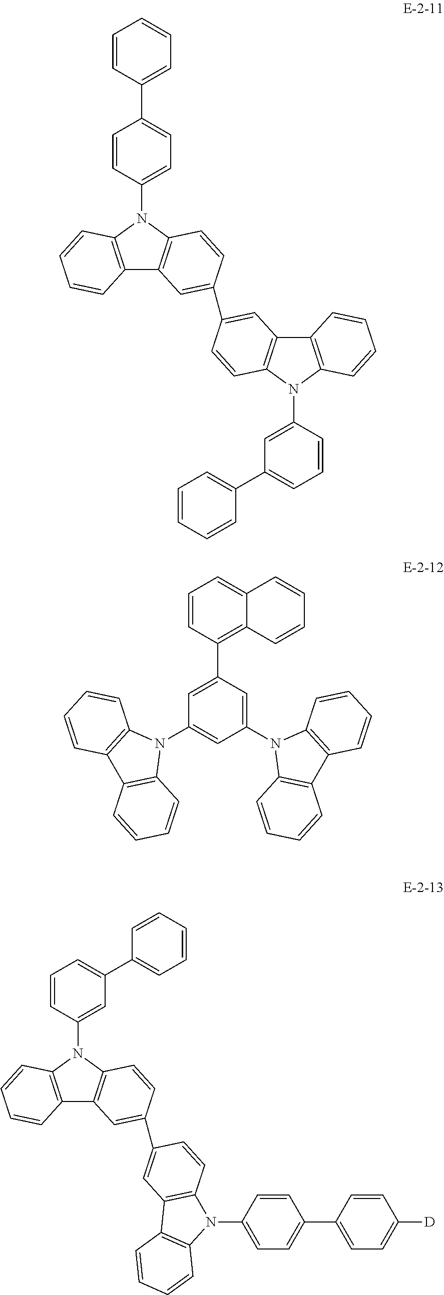

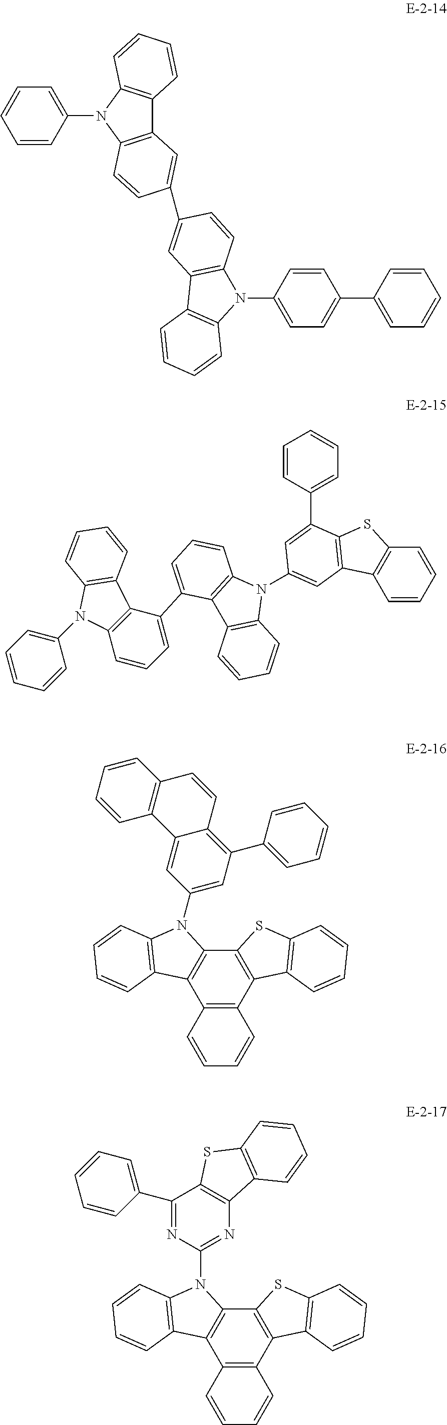 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2cc(-n3c4ccccc4c4c5ccccc5c5c6ccccc6sc5c43)cc3c2ccc2ccccc23)cc1 ; c1ccc(-c2nc(-n3c4ccccc4c4c5ccccc5c5c6ccccc6sc5c43)nc3c2sc2ccccc23)cc1]

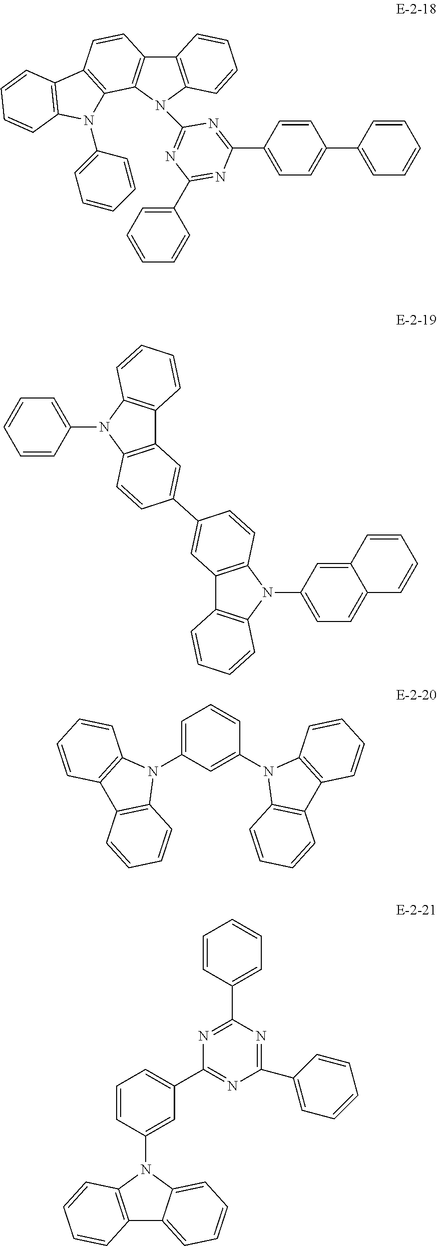

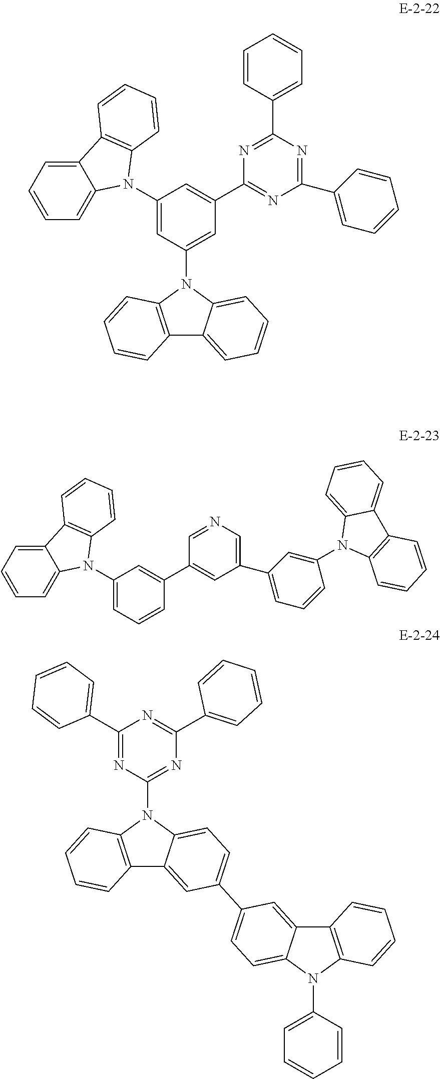 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include as a host material, at least one of bis (4-(9H-carbazol-9-yl) phenyl) diphenylsilane (BCPDS). (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the emission layer EML may include a compound represented by Formula M-a. The compound represented by Formula M-a may be used as a phosphorescence dopant material.

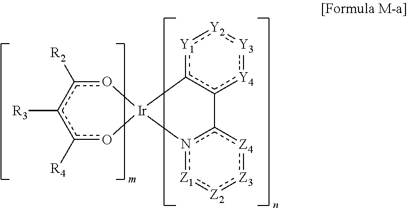

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring. In Formula M-a, m may be 0 or 1, and n may be 2 or 3. In Formula M-a, if m is 0, n may be 3, and if m is 1, n may be 2.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25.

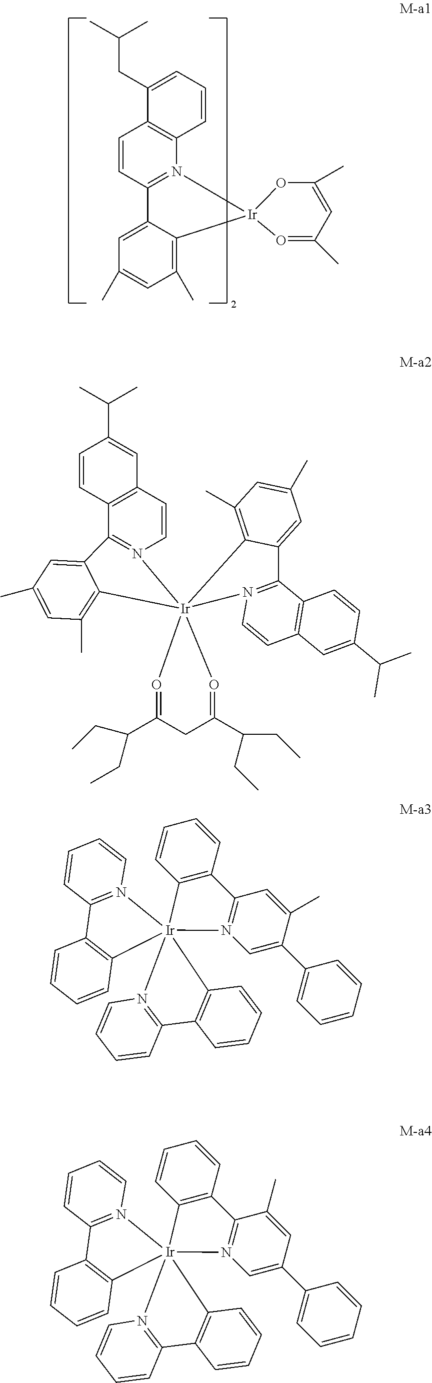

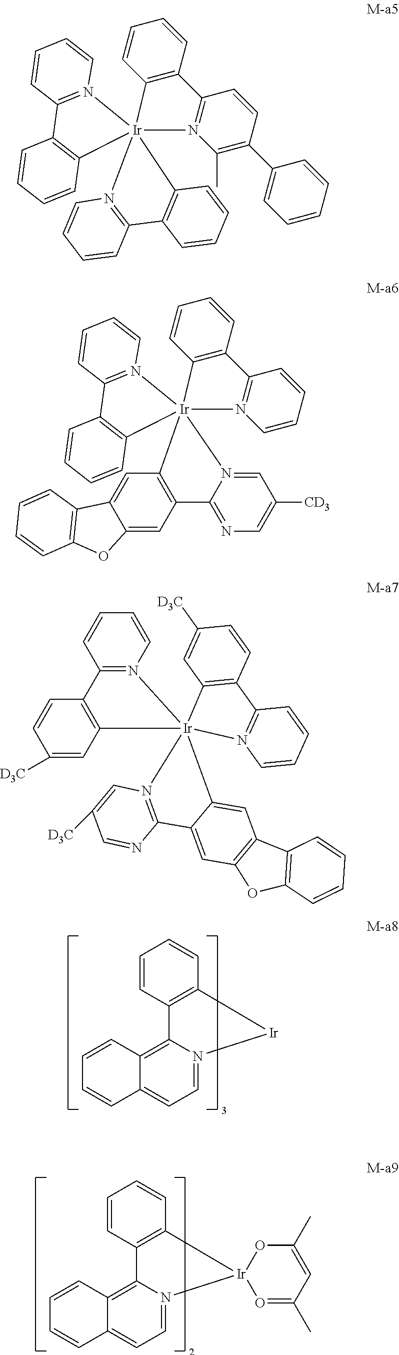

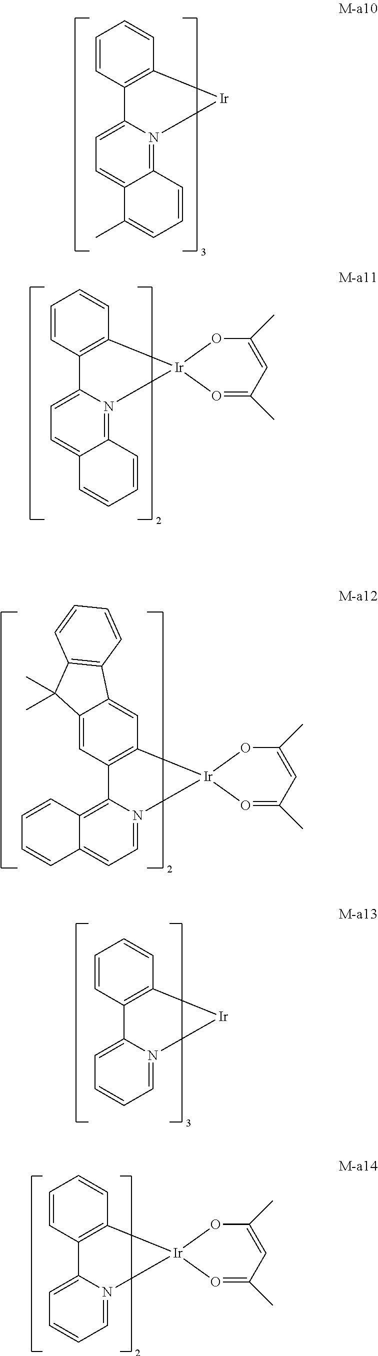

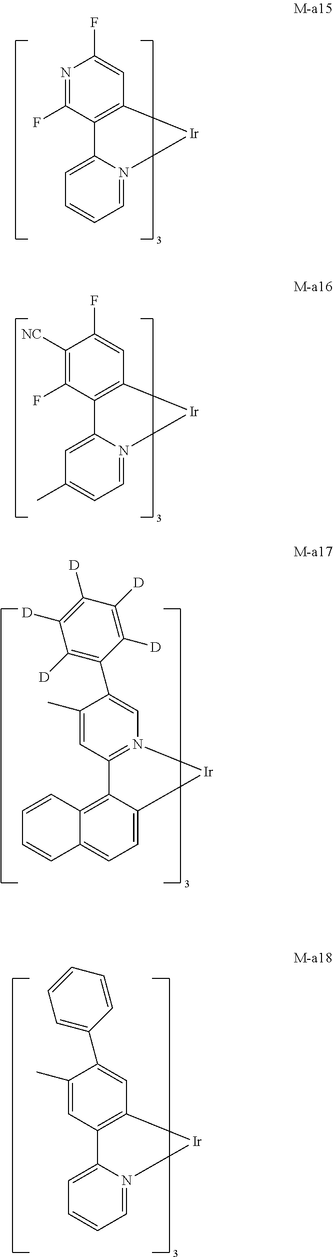

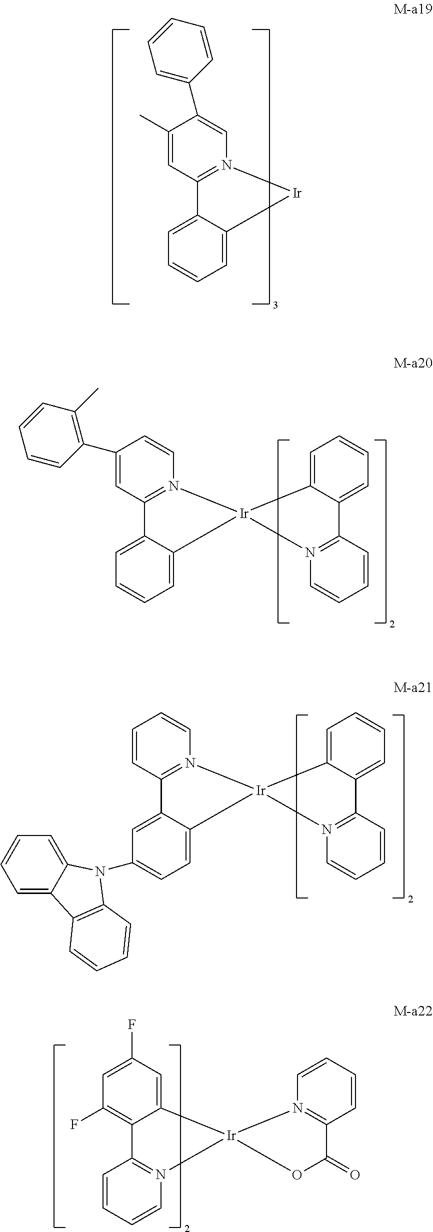

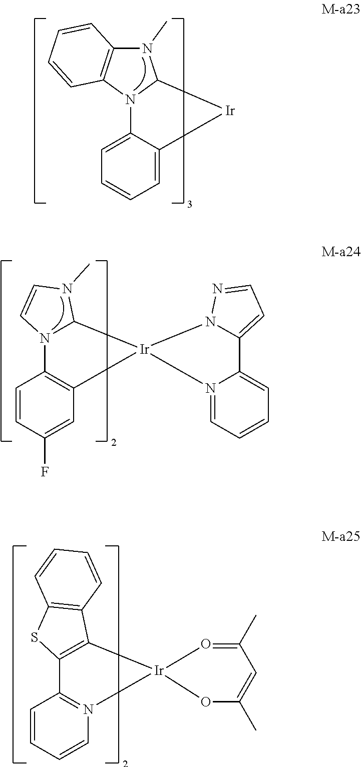

In an embodiment, the emission layer EML may include a compound represented by one of Formula F-a to Formula F-c. The compound represented by one of Formula F-a to Formula F-c may be used as a fluorescence dopant material.

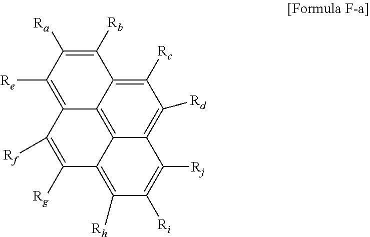

In Formula F-a, two of Rₐ to Rⱼ may each independently be substituted with a group represented by *—NAr₁Ar₂. The remainder of Rₐ to Rⱼ which are not substituted with the group represented by *-NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *-NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may be a heteroaryl group including O or S as a ring-forming atom.

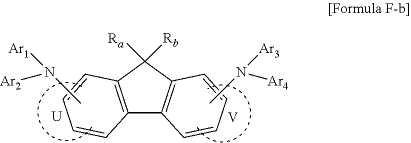

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the portion designated by U or V, and if the number of U or V is 0, a fused ring may not be present at the portion designated by U or V. If the number of U is 0 and the number of V is 1, or if the number of U is 1 and the number of V is 0, a fused ring having the fluorene core of Formula F-b may be a cyclic compound with four rings. If the number of U and V is each 0, a fused ring having the fluorene core of Formula F-b may be a cyclic compound with three rings. If the number of U and V is each 1, a fused ring having the fluorene core of Formula F-b may be a cyclic compound with five rings.

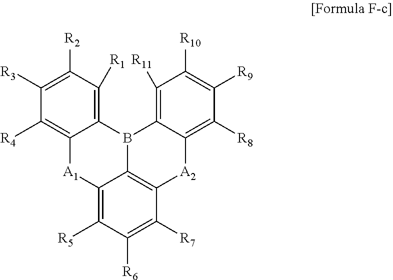

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or combined with an adjacent group to form a ring.

In Formula F-c, A₁ and A₂ may each independently be bonded to a substituent of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include, as a dopant material of related art, a styryl derivative (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (for example, 2,5,8,11-tetra-t-butylperylene (TBP)), pyrene or a derivative thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescence dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (FIr6), or platinum octaethyl porphyrin (PtOEP) may be used as a phosphorescence dopant. However, embodiments are not limited thereto.

In an embodiment, the emission layer EML may include a quantum dot. In the specification, the quantum dot may be a crystal of a semiconductor compound. The quantum dot may emit light of various emission wavelengths according to a size of the crystal. The quantum dot may emit light of various emission wavelengths by adjusting an elemental ratio of a quantum dot compound.

The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof; or any combination thereof.

Examples of a Group III-VI compound may include: a binary compound such as In₂S₃, and In₂Se₃; a ternary compound such as InGaS₃, and InGaSe₃; or any combination thereof.

Examples of a Group 1-III-VI compound may include: a ternary compound selected from the group consisting of AgInS, AgInS₂, CuInS, CuInS₂, AgGaS₂, CuGaS₂, CuGaO₂, AgGaO₂, AgAlO₂, and mixtures thereof; a quaternary compound such as AgInGaS₂, and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; or any combination thereof. In an embodiment, a Group III-V compound may further include a Group II metal. For example, InZnP, etc. may be selected as a Group III-II-V compound.

Examples of a Group IV-VI compound may include: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; a quaternary compound selected from the group consisting of SnPbSSe, SnPbSeTe, SnPbSTe, and mixtures thereof; or any combination thereof.

Examples of a Group IV element may include Si, Ge, and a mixture thereof. Examples of a Group IV compound may include a binary compound selected from the group consisting of SiC, SiGe, and mixtures thereof.

Each element included in the polynary compound such as a binary compound, a ternary compound, or a quaternary compound, may be present in a particle at a uniform concentration distribution or at a non-uniform concentration distribution. For example, a formula may indicate the elements included in a compound, but an elemental ratio in the compound may vary. For example, AgInGaS₂ may mean AgInₓGa₁₋ₓS₂ (where x is a real number between 0 and 1).

In an embodiment, a quantum dot may have a single structure, in which the concentration of each element included in a corresponding quantum dot is at a uniform concentration distribution, or a quantum dot may have a core-shell structure in which a quantum dot surrounds another quantum dot. For example, a material included in the core and a material included in the shell may be different from each other.

The shell of the quantum dot may serve as a protection layer that prevents chemical deformation of the core to maintain semiconductor properties and/or may serve as a charging layer that imparts the quantum dot with electrophoretic properties. The shell may be a single layer or a multilayer. An interface between the core and the shell may have a concentration gradient in which the concentration of an element that is present in the shell decreases toward the core.

Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a ternary compound such as MgAl₂O₄, CoFe₂O₄, NiFe₂O₄, and CoMn₂O₄; or any combination thereof.

Examples of a semiconductor compound may include a Group III-VI semiconductor compound, a Group II-VI semiconductor compound, a Group III-V semiconductor compound, a Group III-VI semiconductor compound, a Group 1-III-VI semiconductor compound, a Group IV-VI semiconductor compound, or a combination thereof, as described in the specification.

Examples of a semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

The quantum dot may have a full width at half maximum (FWHM) of an emission wavelength spectrum equal to or less than about 45 nm. For example, the quantum dot may have a full width at half maximum (FWHM) of emission wavelength spectrum equal to or less than about 40 nm. For example, the quantum dot may have a full width at half maximum (FWHM) of emission wavelength spectrum equal to or less than about 30 nm. Color purity or color reproducibility may be improved in any of the above ranges. Light that is emitted through a quantum dot may be emitted in all directions, so that viewing angle may be improved.

The shape of a quantum dot is not particularly limited and may be any shape used in the related art. For example, the quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

By controlling the size of a quantum dot or by controlling an elemental ratio in a quantum dot compound, the energy band gap may be controlled, and various wavelength bands of light may be obtained from a quantum dot emission layer. Accordingly, by using a quantum dot as described above (for example, using quantum dots having different sizes or having different elemental ratios in the quantum dot compound), a light emitting element that emits various wavelengths of light may be achieved. In an embodiment, a size of a quantum dot or an elemental ratio in a quantum dot compound may each independently be controlled to emit red light, green light, and/or blue light. For example, quantum dots may emit white light by combining light of various colors. A diameter of a quantum dot may be in a range of about 1 nm to about 10 nm.

The quantum dot may be synthesized by a chemical bath deposition, a metal organic chemical vapor deposition, a molecular beam epitaxy, or a similar process therewith.

The chemical bath deposition is a method of mixing an organic solvent and a precursor material and growing a quantum dot particle crystal. While growing the crystal, the organic solvent may serve as a dispersant that is coordinated on a surface of the quantum dot crystal and may control the growth of the crystal. Accordingly, chemical bath deposition may be more advantageous when compared to a vapor deposition method such as metal organic chemical vapor deposition (MOCVD) and molecular beam epitaxy (MBE), and the growth of the quantum dot particle may be controlled through a low-cost process.

In the light emitting elements ED according to an embodiment as shown in each of FIG. 3 to FIG. 6, the electron transport region ETR may be provided on the emission layer EML. The electron transport region ETR may include at least one of an electron blocking layer HBL, an electron transport layer ETL, and an electron injection layer EIL. However, embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or a single layer structure formed of an electron injection material and an electron transport material. In other embodiments, the electron transport region ETR may have a single layer structure formed of different materials, or may have a structure in which an electron transport layer ETL/electron injection layer EIL, a hole blocking layer HBL/electron transport layer ETL/electron injection layer EIL, or the like are stacked in its respective stated order from the emission layer EML, but embodiments are not limited thereto. A thickness of the electron transport region ETR may be in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-1.

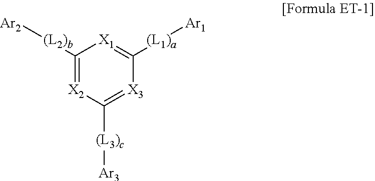

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-1, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butyiphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and a mixture thereof, but embodiments are not limited thereto.

In an embodiment, the electron transport region ETR may include at least one compound selected from Compounds ET1 to ET36:

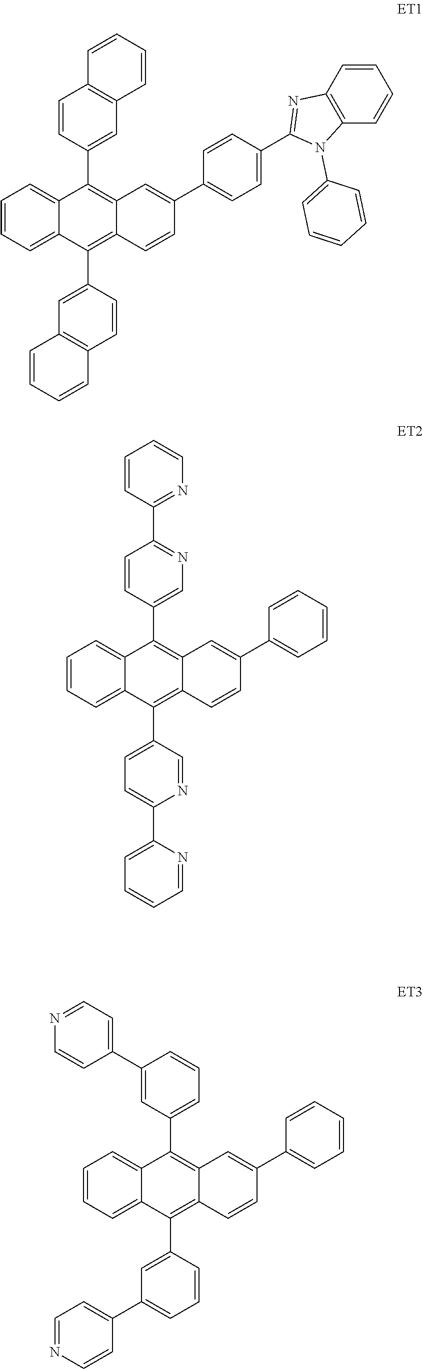 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

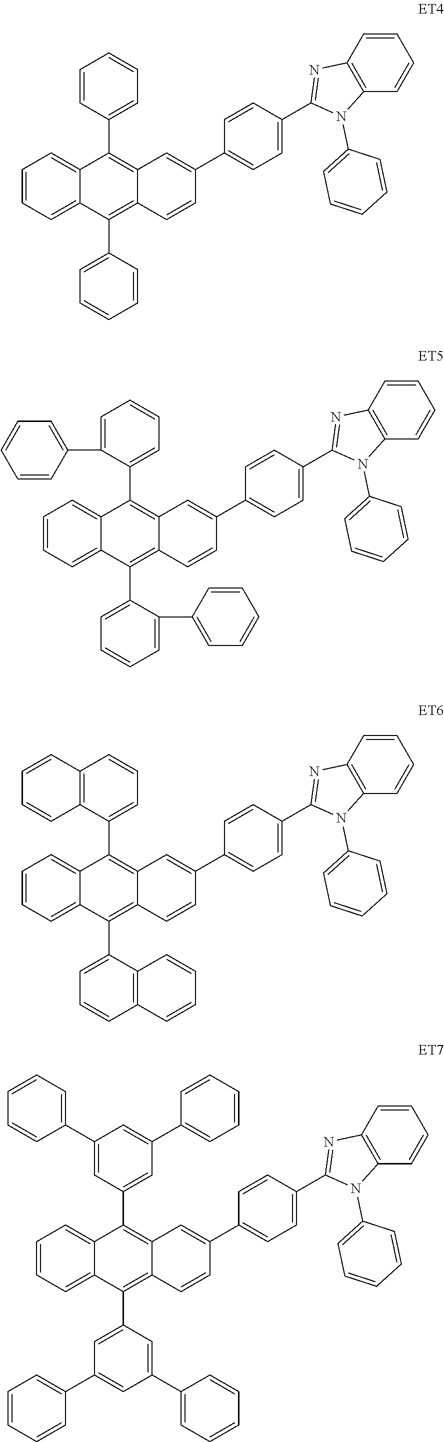 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

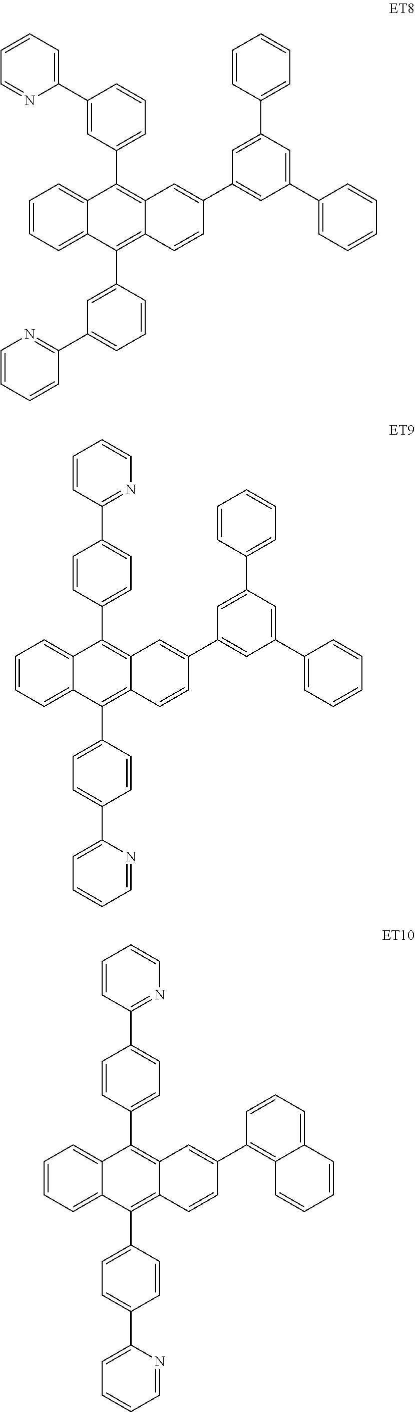 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

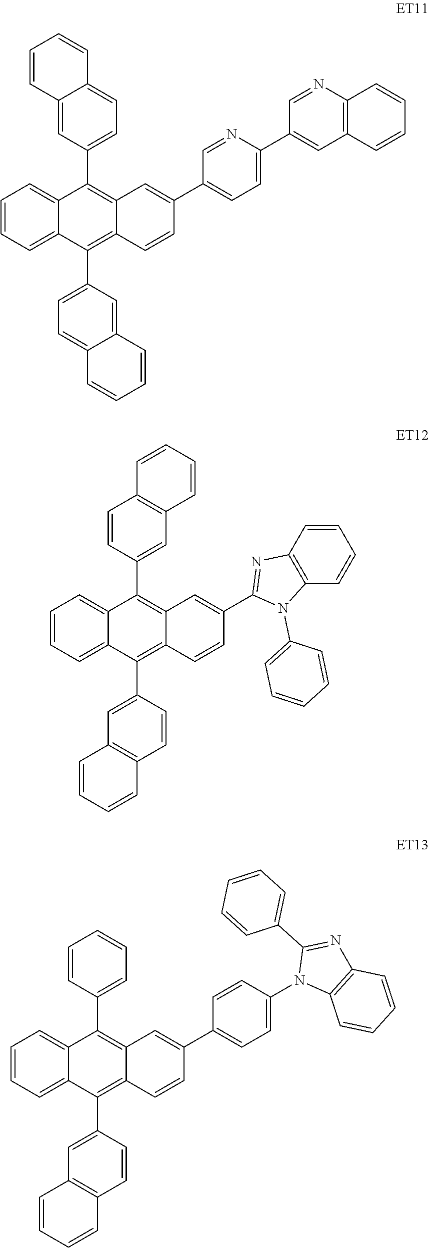 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

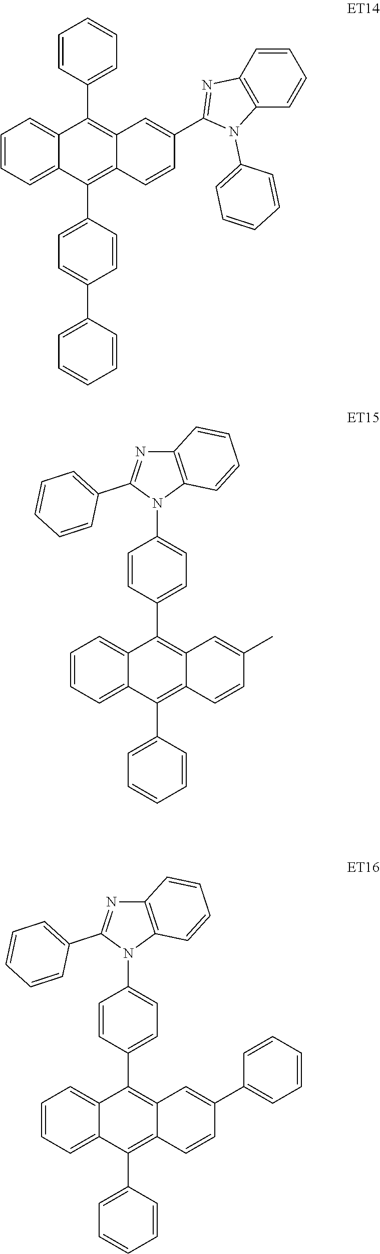 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

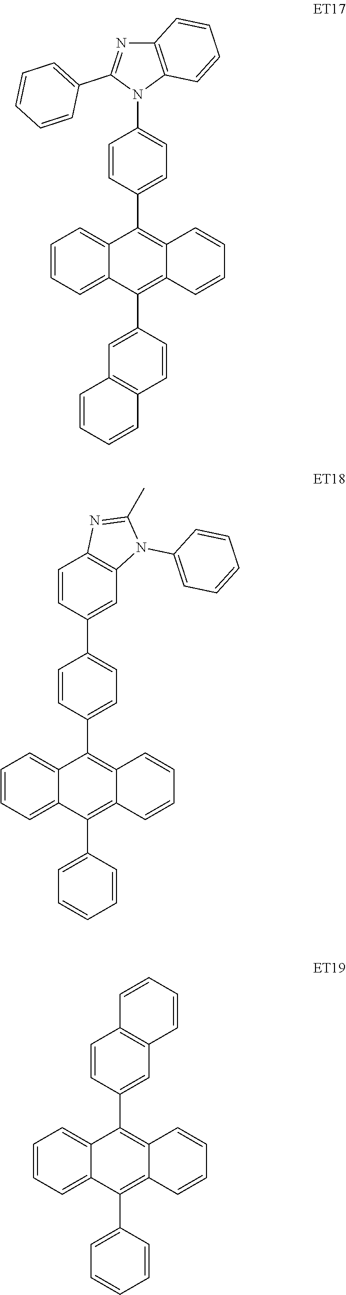

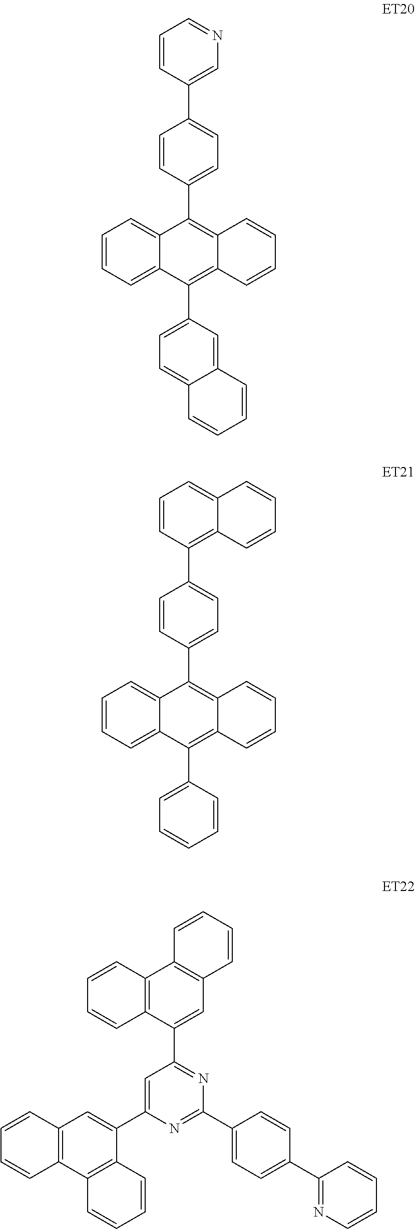

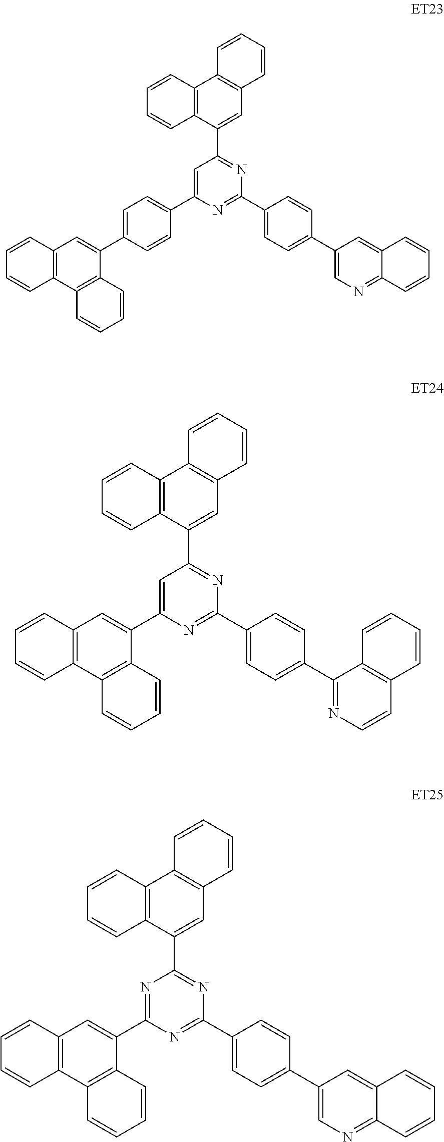 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

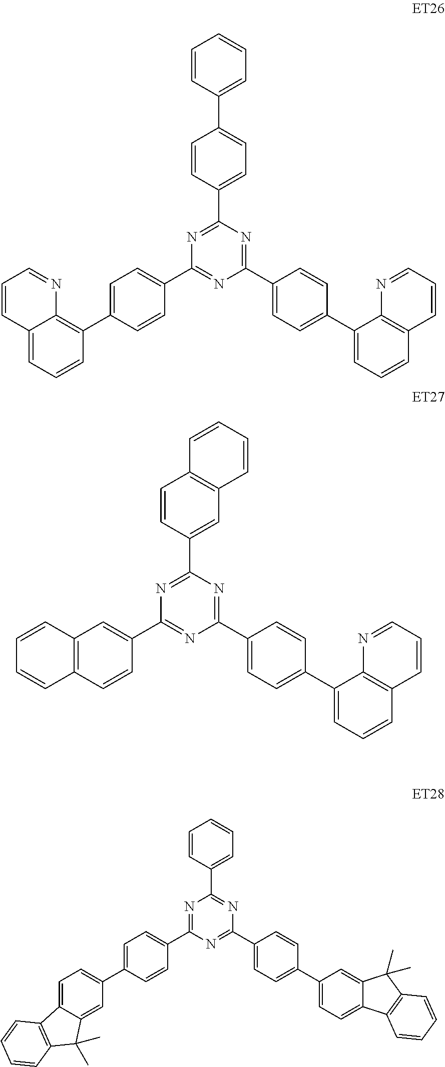 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

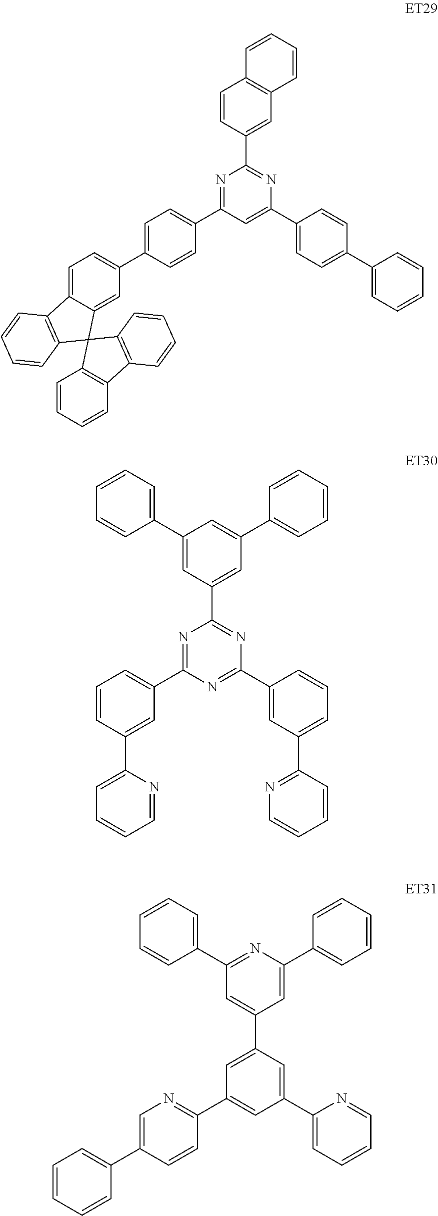 [SMILES: c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

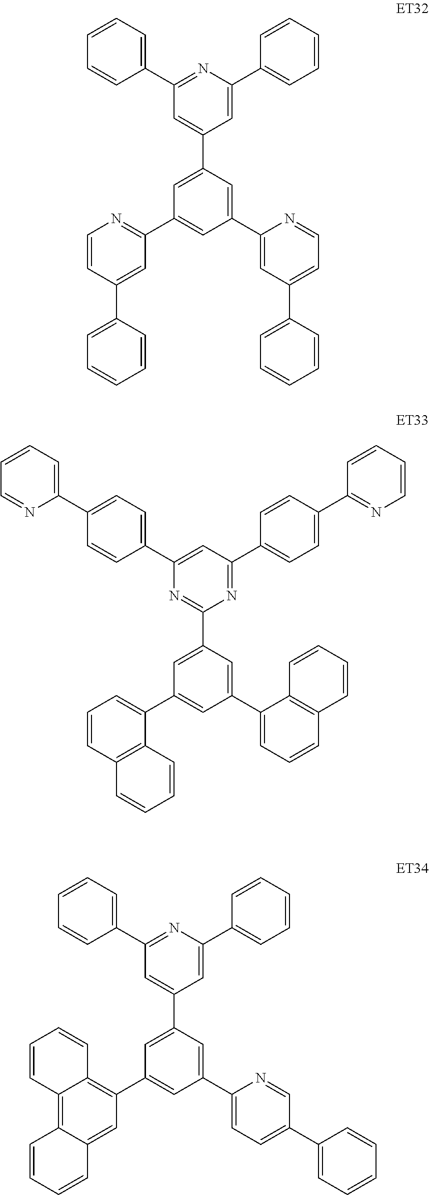 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

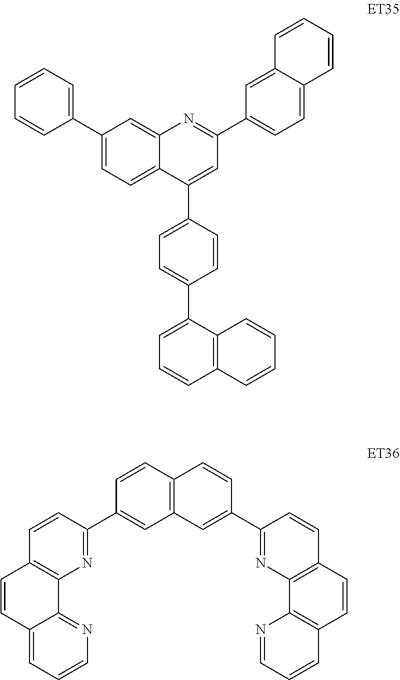 [SMILES: c1ccc(-c2ccc3c(-c4ccc(-c5cccc6ccccc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR also may be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, and a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without substantial increase of a driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without inducing substantial increase of a driving voltage.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, a compound thereof, a mixture thereof, or an oxide thereof.

The second electrode EL2 may be a transmissive electrode, a transflective electrode, or a reflective electrode. If the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgAg). In an embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. In an embodiment, the capping layer CPL may include at least one of Compounds P1 to P5, but embodiments are not limited thereto.

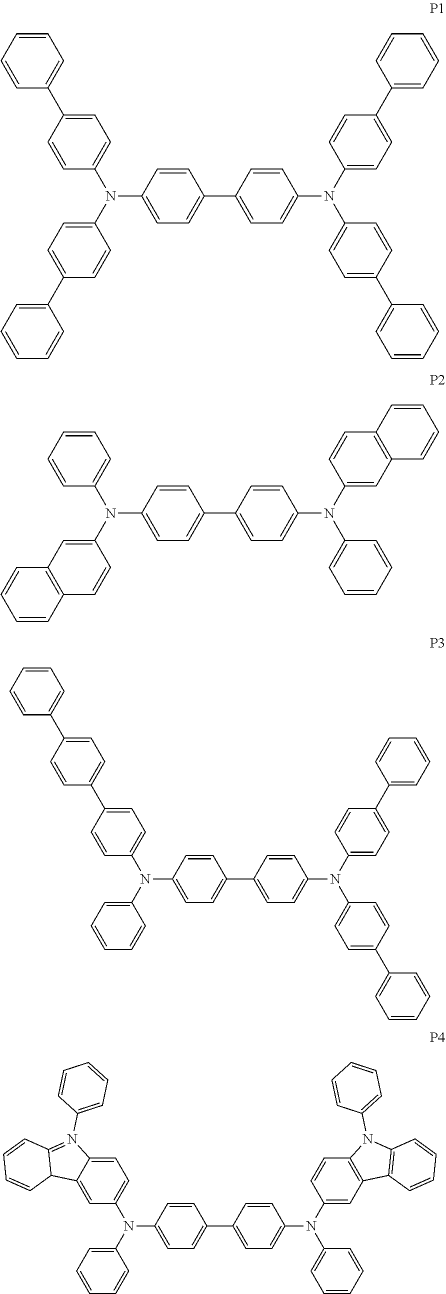

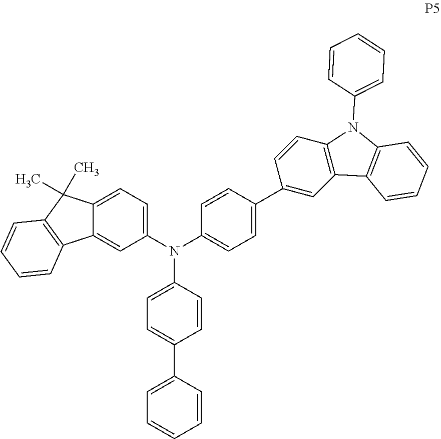 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

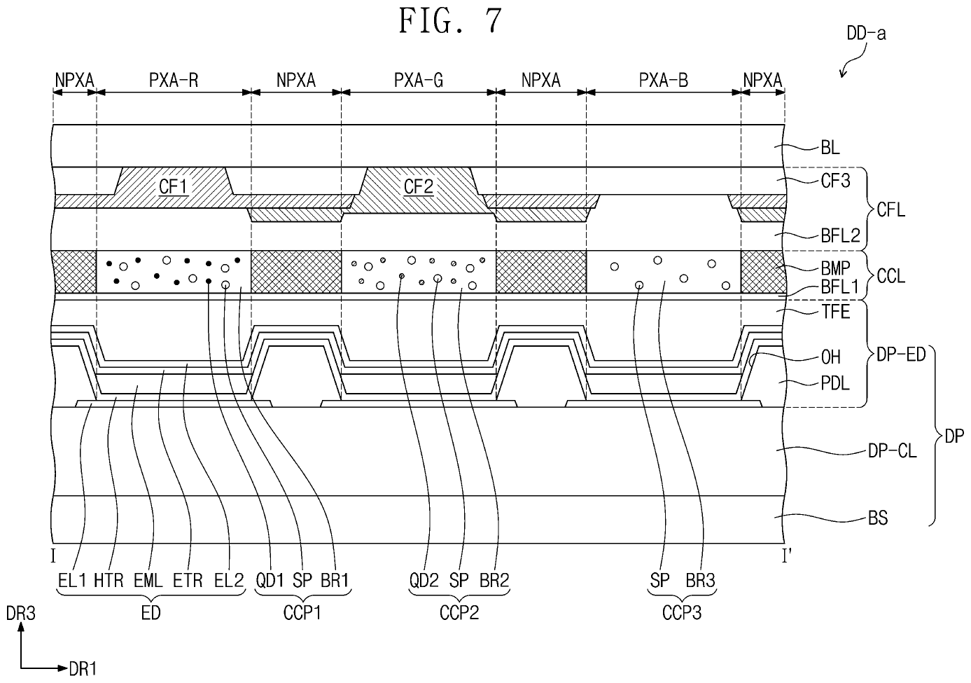

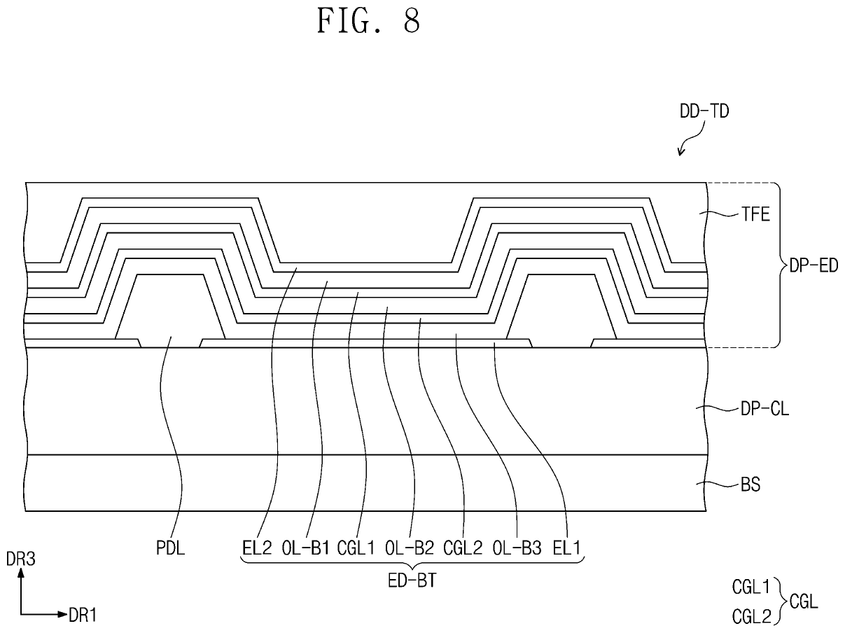

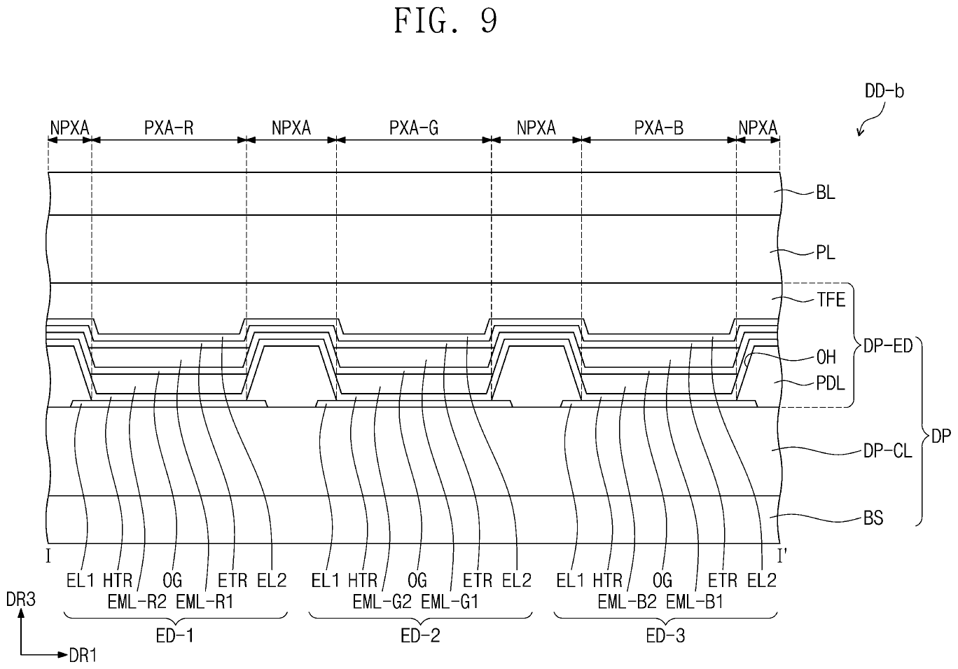

FIG. 7 and FIG. 8 are each a schematic cross-sectional view of a display device according to embodiments. In the descriptions of the display devices according to embodiments as shown in FIG. 7 and FIG. 8, the features which have been described above with respect to FIG. 1 to FIG. 6 will not be explained again, and the differing features will be described.

Referring to FIG. 7, a display device DD-a according to an embodiment may include a display panel DP including a display element layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIG. 3 to FIG. 6 as described above.

The emission layer EML of the light emitting element ED included in the display device DD-a according to an embodiment may include the above-described polycyclic compound according to an embodiment.

Referring to FIG. 7, the emission layer EML may be disposed in an opening OH defined in a pixel definition layer PDL. For example, the emission layer EML, which is separated by the pixel defining layer PDL and correspondingly provided to each of the light luminous areas PXA-R, PXA-G, and PXA-B, may emit light in a same wavelength region. In the display device DD-a, the emission layer EML may emit blue light. Although not shown in the drawings, in an embodiment, the emission layer EML may be provided as a common layer for each of the luminous areas PXA-R, PXA-G, and PXA-B.

The light controlling layer CCL may be disposed on the display panel DP. The light controlling layer CCL may include a light converter. The light converter may be a quantum dot or a phosphor. The light converter may transform the wavelength of a provided light and emit the resulting light. For example, the light controlling layer CCL may be a layer including a quantum dot or a layer including a phosphor.

The light controlling layer CCL may include multiple light controlling parts CCP1, CCP2, and CCP3. The light controlling parts CCP1, CCP2, and CCP3 may be spaced apart from each other.

Referring to FIG. 7, a partition pattern BMP may be disposed between the light controlling parts CCP1, CCP2, and CCP3, which are spaced apart from each other, but embodiments are not limited thereto. In FIG. 7, it is shown that the partition pattern BMP does not overlap the light controlling parts CCP1, CCP2, and CCP3, but the edges of the light controlling parts CCP1, CCP2, and CCP3 may overlap at least a portion of the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits first color light.

In an embodiment, the first light controlling part CCP1 may provide red light, which is the second color light, and the second light controlling part CCP2 may provide green light, which is the third color light. The third color controlling part CCP3 may transmit and provide blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but may include the scatterer SP.

The scatterer SP may be an inorganic particle. For example, the scatterer SP may include at least one of TiO₂, ZnO, Al₂O₃, SiO₂, and hollow silica. The scatterer SP may include at least one of TiO₂, ZnO, Al₂O₃, SiO₂, and hollow silica, or the scatterer SP may be a mixture of two or more materials selected from TiO₂, ZnO, Al₂O₃, SiO₂, and hollow silica.

The first light controlling part CCP1, the second light controlling part CCP2, and the third light controlling part CCP3 may include base resins BR1, BR2, and BR3, in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2, and BR3 are mediums in which the quantum dots QD1 and QD2 and the scatterer SP are dispersed, and may be composed of various resin compositions which may be generally referred to as a binder. For example, the base resins BR1, BR2, and BR3 may be acrylic resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light controlling layer CCL may include a barrier layer BFL1. The barrier layer BFL1 may prevent the penetration of moisture and/or oxygen (hereinafter, will be referred to as “moisture/oxygen”). The barrier layer BFL1 may be disposed on the light controlling parts CCP1, CCP2, and CCP3 to block the light controlling parts CCP1, CCP2, and CCP3 from exposure to moisture/oxygen. The barrier layer BFL1 may cover the light controlling parts CCP1, CCP2, and CCP3. A barrier layer BFL2 may be provided between the light controlling parts CCP1, CCP2, and CCP3 and a color filter layer CFL.

The barrier layers BFL1 and BFL2 may each independently include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. The barrier layers BFL1 and BFL2 may each independently further include an organic layer. The barrier layers BFL1 and BFL2 may each be formed of a single layer or of multiple layers.

In the display device DD-a, the color filter layer CFL may be disposed on the light controlling layer CCL. In an embodiment, the color filter layer CFL may be disposed directly on the light controlling layer CCL. For example, the barrier layer BFL2 may be omitted.

The color filter layer CFL may include a light blocking part (not shown) and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be provided in one body, without distinction. The first to third filters CF1, CF2, and CF3 may be disposed to respectively correspond to a red luminous area PXA-R, a green luminous area PXA-G, and a blue luminous area PXA-B.

The light blocking part (not shown) may be a black matrix. The light blocking part (not shown) may include an organic light blocking material or an inorganic light blocking material, each including a black pigment or black dye. The light blocking part (not shown) may separate the boundaries between adjacent filters CF1, CF2, and CF3. In an embodiment, the light blocking part (not shown) may be formed as a blue filter.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

FIG. 8 is a schematic cross-sectional view of a portion of the display device according to an embodiment. In a display device DD-TD according to an embodiment, the light emitting element ED-BT may include light emitting structures OL-B1, OL-B2, and OL-B3.

The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), a hole transport region HTR and an electron transport region ETR disposed with the emission layer EML (FIG. 7) therebetween.

For example, the light emitting element ED-BT included in the display device DD-TD may be a light emitting element having a tandem structure and including multiple emission layers.

In an embodiment shown in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength regions that are different from each other. For example, the light emitting element ED-BT that includes the light emitting structures OL-B1, OL-B2, and OL-B3, which emit light having wavelength ranges that are different from each other, may emit white light.

Charge generating layers CGL1 and CGL2 may be disposed between neighboring light emitting structures among the light emitting structures OL-B1, OL-B2, and OL-B3. Charge generating layers CGL1 and CGL2 may each independently include a p-type charge generating layer and/or an n-type charge generating layer.

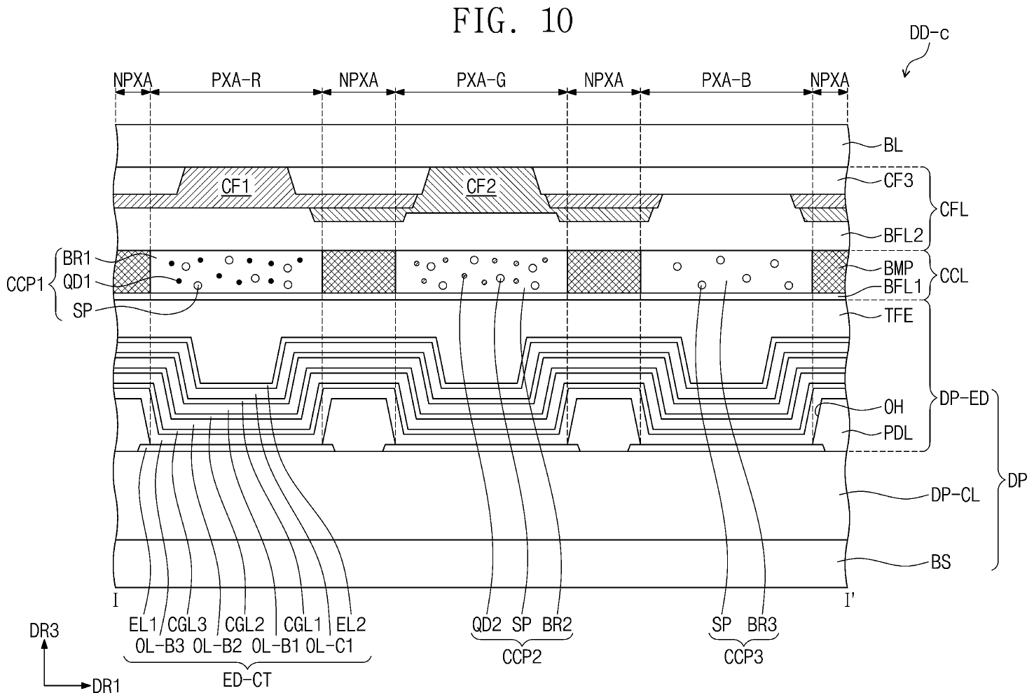

Referring to FIG. 9, a display device DD-b according to an embodiment may include light emitting elements ED-1, ED-2, and ED-3, in which two emission layers are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned in the openings OH defined in the pixel definition layer PDL.

The first red emission layer EML-R1, the first green emission layer EML-G1, and the first blue emission layer EML-B1 may be each disposed between the electron transport region ETR and the emission auxiliary part OG. The second red emission layer EML-R2, the second green emission layer EML-G2, and the second blue emission layer EML-B2 may be each disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display element layer DP-ED. The optical auxiliary layer PL may include a polarization layer. The optical auxiliary layer PL may be disposed on a display panel DP and may control light that is reflected at the display panel DP from an external light. Although not shown in the drawings, in an embodiment, the optical auxiliary layer PL may be omitted from the display device DD-b.

At least one emission layer included in the display device DD-b shown in FIG. 9 may include the polycyclic compound according to an embodiment. For example, in an embodiment, at least one of the first blue emission layer EML-B1 and the second blue emission layer EML-B2 may include the polycyclic compound according to an embodiment.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelengths from each other.

Charge generating layers CGL1, CGL2, and CGL3 may each be disposed between adjacent light emitting structures among the first to fourth light emitting structures OL-B1, OL-B2, OL-B3, and OL-C1. Charge generating layers CGL1, CGL2, and CGL3 may each independently include a p-type charge generating layer and/or an n-type charge generating layer.

In the display device DD-c, at least one of the light emitting structures OL-B1, OL-B2, OL-B3, and OL-C1 may each independently include the polycyclic compound according to an embodiment. For example, in an embodiment, at least one of the first to third light emitting structures OL-B1, OL-B2, OL-B3 may include the polycyclic compound.

The light emitting element ED according to an embodiment may include the polycyclic compound according to an embodiment in at least one functional layer disposed between the first electrode EL1 and the second electrode EL2, thereby exhibiting excellent emission efficiency and improved life characteristics. For example, the polycyclic compound according to an embodiment may be included in the emission layer EML of the light emitting element ED according to an embodiment, and the light emitting element according to an embodiment may show high efficiency and long-life characteristics simultaneously.

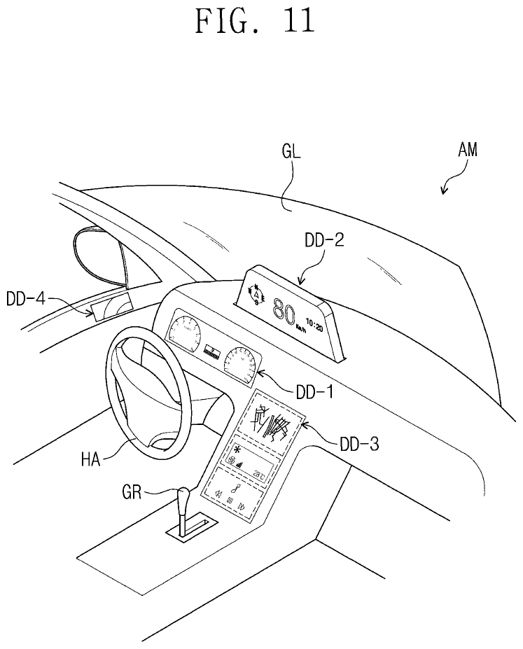

FIG. 11 is a schematic diagram of an interior of a vehicle AM including a display device according to an embodiment. In FIG. 11, a portion of a vehicle AM is shown as an example of an electronic device including a display device. However, this is only an example, and the electronic device may be various transport means, such as bicycles, motorcycles, trains, ships, and airplanes.

Referring to FIG. 11, a vehicle AM may include first to fourth display devices DD-1, DD-2, DD-3, and DD-4. At least one of the first to fourth display devices DD-1, DD-2, DD-3, and DD-4 may have a structure according to one of the display devices DD, DD-a, DD-TD, DD-b, and DD-c, as explained with reference to FIG. 1, FIG. 2, and FIG. 7 to FIG. 10.

In an embodiment, at least one of the first to fourth display devices DD-1, DD-2, DD-3, and DD-4 may each independently include a light emitting element ED according to an embodiment, as described with reference to FIG. 3 to FIG. 6. The first to fourth display devices DD-1, DD-2, DD-3, and DD-4 may each independently include multiple light emitting elements ED (see FIG. 3 to FIG. 6). The light emitting elements ED may each include a first electrode EL1, a hole transport region HTL, an emission layer EML, an electron transport region ETR, and a second electrode EL2 (see FIG. 3 to FIG. 6). The emission layer EML (see FIG. 3 to FIG. 6) may include the polycyclic compound according to an embodiment, thereby showing improved quality of images.

Referring to FIG. 11, the vehicle AM may include a steering wheel HA and a gearshift GR for the operation of the vehicle AM. The vehicle AM may include a front window GL that is disposed so as to face a driver.

A first display device DD-1 may be disposed in a first region that overlaps the steering wheel HA. For example, the first display device DD-1 may be a digital cluster that displays the first information of the vehicle AM. The first information may include a first scale that indicates a driving speed of the vehicle AM, a second scale that indicates an engine speed (for example, revolutions per minute (RPM)), and images showing a fuel level. The first scale and the second scale may each be represented by digital images.

A second display device DD-2 may be disposed in a second region facing a driver's seat and overlapping the front window GL. The driver's seat may be a seat where the steering wheel HA is disposed. For example, the second display device DD-2 may be a head up display (HUD) that shows the second information of the vehicle AM. The second display device DD-2 may be transparent. The second information may include digital numbers showing the driving speed of the vehicle AM, and may include further information, such as the current time, etc.

A third display device DD-3 may be disposed in a third region that is adjacent to the gearshift GR. For example, the third display device DD-3 may be a center information display (CID) for a vehicle, which shows third information and may be disposed between a driver's seat and a passenger seat. The passenger seat may be a seat that is spaced apart from the driver's seat, with the gearshift GR disposed therebetween. The third information may include information on road conditions (for example, navigation information), on music or radio that is playing, on a dynamic or still image that is displayed, on a temperature in the vehicle AM, or the like.

A fourth display device DD-4 may be disposed in a fourth region separated from the steering wheel HA and the gearshift GR and adjacent to a side of the vehicle AM. For example, the fourth display device DD-4 may be a digital side-view mirror that displays fourth information. The fourth information may display an external image of the vehicle AM that is taken by a camera module disposed outside the vehicle AM.

The first to fourth information as described above are only presented as examples, and the first to fourth display devices DD-1, DD-2, DD-3, and DD-4 may further display information about the interior and exterior of the vehicle. The first to fourth information may include information that are different from each other. However, embodiments are not limited thereto, and a portion of the first to fourth information may include a same information.

Hereinafter, a polycyclic compound according to an embodiment and a light emitting element according to an embodiment will be explained with reference to the Examples and the Comparative Examples. The Examples described below are only provided as illustrations to assist in understanding the disclosure, and the scope thereof is not limited thereto.

### EXAMPLES

### 1. Synthesis of Polycyclic Compounds

A synthesis method of the polycyclic compound according to an embodiment will be explained by illustrating the synthesis methods of Compounds 5, 7, 15, 29, 33, 42, 62, 69, 76, and 77. The synthesis methods of the polycyclic compounds explained hereinafter are provided only as examples, and the synthesis methods of the polycyclic compound according to embodiments are not limited to the Examples below.

### (1) Synthesis of Compound 62

Example Compound 62 according to an embodiment may be synthesized, for example, by Reactions 1 to 8.

### 1) Synthesis of Intermediate Compound 62-B

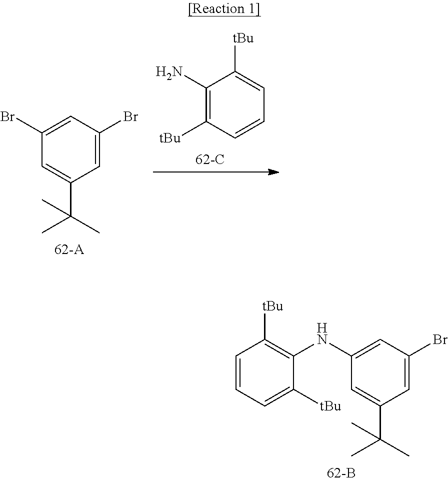 [SMILES: CC(C)(C)c1cc(Br)cc(Br)c1 ; CC(C)(C)c1cccc(C(C)(C)C)c1N ; CC(C)(C)c1cc(Br)cc(Nc2c(C(C)(C)C)cccc2C(C)(C)C)c1]

Compound 62-A (25.0 g, 85.6 mmol), Compound 62-C (17.6 g, 85.6 mmol), Pd(OAc)₂ (1.35 g, 6.0 mmol), DPPF (6.64 g, 12.0 mmol), tBuONa (24.7 g, 256.8 mmol), and xylene (428 ml) were stirred under an Ar atmosphere at about 60° C. for about 5 hours, and the resultant was purified by silica gel column chromatography and washed with hexane to obtain a white solid (30.0 g, yield 84%). FAB-MS analysis confirmed the compound obtained as Intermediate Compound 62-B with a molecular weight of 474.

### 2) Synthesis of Intermediate Compound 62-D

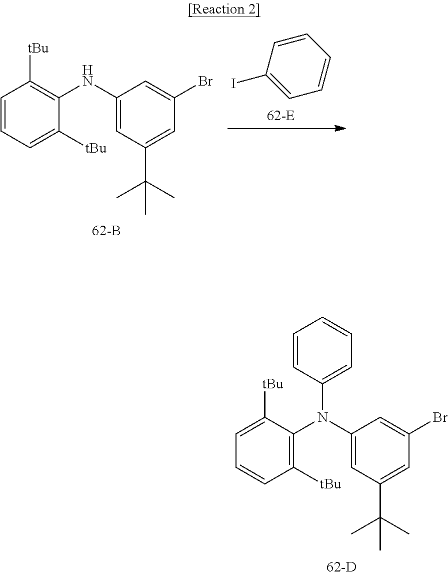

Compound 62-B (30.0 g, 72.0 mmol), Compound 62-E (220 g, 1.08 mmol), K₂CO₃ (59.7 g, 0.43 mmol), and CuI (13.7 g, 72.0 mmol) were stirred under an Ar atmosphere at about 180° C. for about 11 hours, and the resultant was purified by silica gel column chromatography and washed with ethanol to re-precipitate and to obtain a white solid (24.6 g, yield 69%). FAB-MS analysis confirmed the compound obtained as Intermediate Compound 62-D with a molecular weight of 492.

### 3) Synthesis of Intermediate Compound 62-F

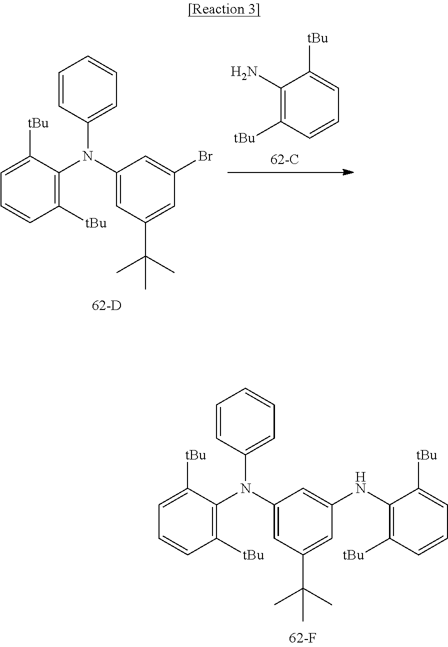 [SMILES: CC(C)(C)c1cc(Br)cc(N(c2ccccc2)c2c(C(C)(C)C)cccc2C(C)(C)C)c1 ; CC(C)(C)c1cccc(C(C)(C)C)c1N ; CC(C)(C)c1cc(Nc2c(C(C)(C)C)cccc2C(C)(C)C)cc(N(c2ccccc2)c2c(C(C)(C)C)cccc2C(C)(C)C)c1]

Compound 62-D (24.6 g, 49.9 mmol), Compound 62-C(10.8 g, 52.4 mmol), Pd(dba)₂ (1.15 g, 2.0 mmol), [(t-Bu)₃PH]BF₄ (0.87 g, 3.0 mmol), tBuONa (9.60 g, 99.9 mmol), and xylene (250 ml) were stirred under an Ar atmosphere at about 60° C. for about 1 hour, and the resultant was purified by silica gel column chromatography and washed with ethanol to re-precipitate and to obtain a white solid (29.9 g, yield 97%). FAB-MS analysis confirmed the compound obtained as Intermediate Compound 62-F with a molecular weight of 616.

### 4) Synthesis of Intermediate Compound 62-H

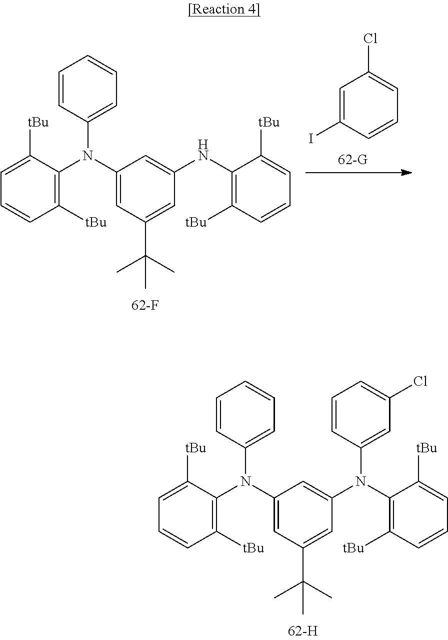

The reaction was performed by the same reaction conditions and the same order as Reaction 2, and a white solid (26.4 g, yield 65%) was obtained. FAB-MS analysis confirmed the compound obtained as Intermediate Compound 62-H with a molecular weight of 727.

### 5) Synthesis of Intermediate Compound 62-I

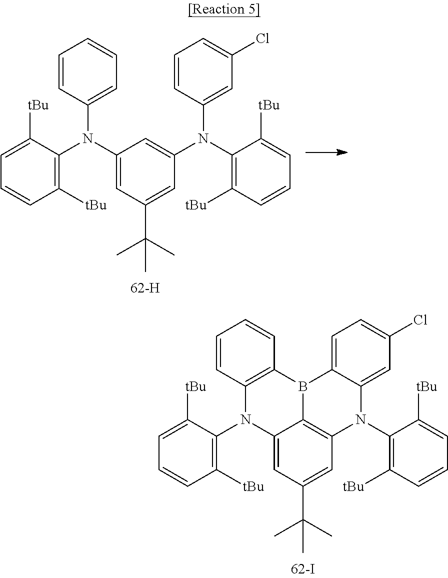 [SMILES: CC(C)(C)c1cc(N(c2ccccc2)c2c(C(C)(C)C)cccc2C(C)(C)C)cc(N(c2cccc(Cl)c2)c2c(C(C)(C)C)cccc2C(C)(C)C)c1 ; CC(C)(C)c1cc2c3c(c1)N(c1c(C(C)(C)C)cccc1C(C)(C)C)c1cc(Cl)ccc1B3c1ccccc1N2c1c(C(C)(C)C)cccc1C(C)(C)C]

Compound 62-H (26.4 g, 36.3 mmol), BI₃ (28.5 g, 72.6 mmol), and o-dichlorobenzene (121 ml) were stirred under an Ar atmosphere at about 145° C. for about 7 hours, and the temperature was reduced to room temperature. N,N-diisopropylethylamine (63.4 ml, 362 mmol) was added thereto, followed by stirring for about 30 minutes. The material thus obtained was purified by silica gel column chromatography, and a yellow solid (15.0 g, yield 56%) was obtained. FAB-MS analysis confirmed the compound obtained as Intermediate Compound 62-I with a molecular weight of 735.

### 6) Synthesis of Intermediate Compound 62-K

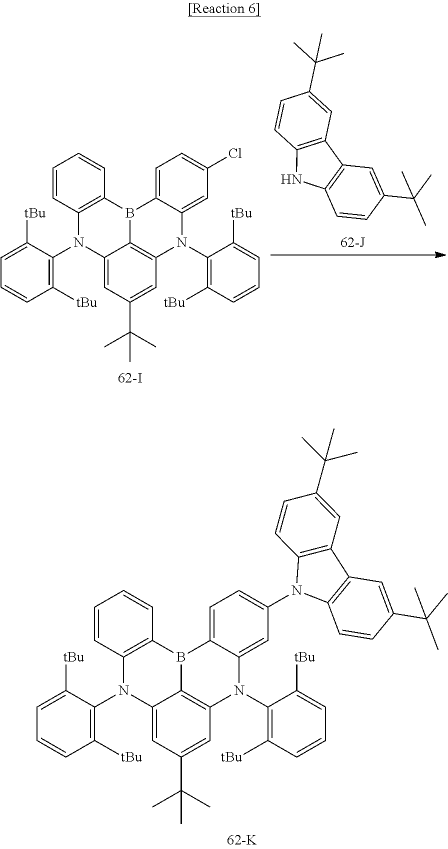 [SMILES: CC(C)(C)c1cc2c3c(c1)N(c1c(C(C)(C)C)cccc1C(C)(C)C)c1cc(Cl)ccc1B3c1ccccc1N2c1c(C(C)(C)C)cccc1C(C)(C)C ; CC(C)(C)c1ccc2[nH]c3ccc(C(C)(C)C)cc3c2c1 ; CC(C)(C)c1cc2c3c(c1)N(c1c(C(C)(C)C)cccc1C(C)(C)C)c1cc(-n4c5ccc(C(C)(C)C)cc5c5cc(C(C)(C)C)ccc54)ccc1B3c1ccccc1N2c1c(C(C)(C)C)cccc1C(C)(C)C]

Compound 62-I (15.0 g, 20.4 mmol), Compound 62-J (6.27 g, 22.4 mmol), Pd(dba)₂ (0.94 g, 1.63 mmol), [(t-Bu)₃PH]BF₄ (0.95 g, 3.26 mmol), tBuONa (2.75 g, 28.6 mmol), and xylene (102 ml) were stirred under an Ar atmosphere at about 110° C. for about 5 hours, and the resultant was purified by silica gel column chromatography and recrystallized using toluene/ethanol to obtain a yellow solid (12.9 g, yield 65%). FAB-MS analysis confirmed the compound obtained as Intermediate Compound 62-K with a molecular weight of 978.

### 7) Synthesis of Intermediate Compound 62-M

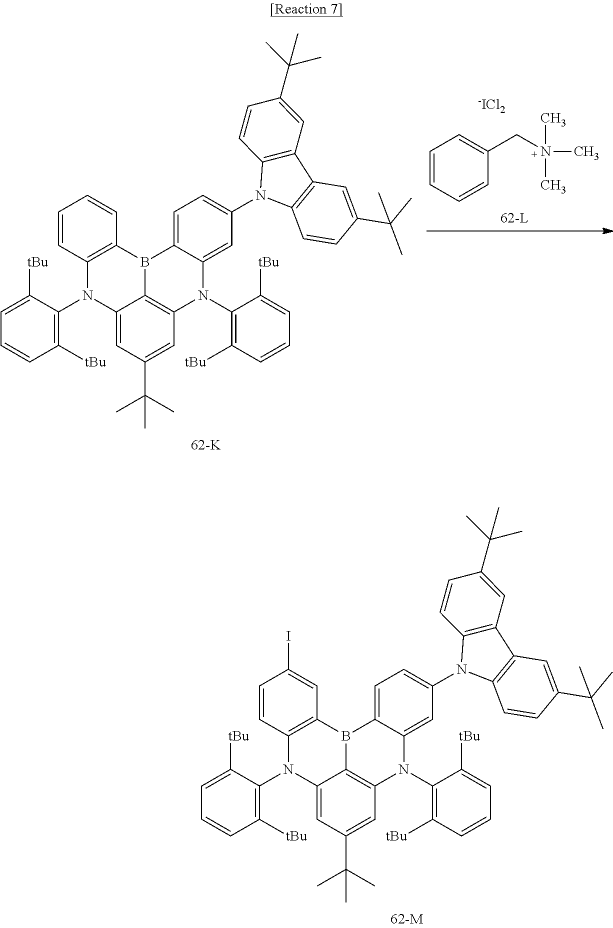

Compound 62-K (12.9 g, 13.2 mmol), Compound 62-L (4.59 g, 13.2 mmol), CaCO₃ (1.72 g, 17.1 mmol), MeOH (53 ml), and CH₂Cl₂ (132 ml) were stirred under an Ar atmosphere at room temperature for three days, and the resultant was purified by silica gel column chromatography and recrystallized using toluene/ethanol to obtain a yellow solid (10.2 g, yield 70%). FAB-MS analysis confirmed the compound obtained as Intermediate Compound 62-M with a molecular weight of 1104.

### 8) Synthesis of Example Compound 62

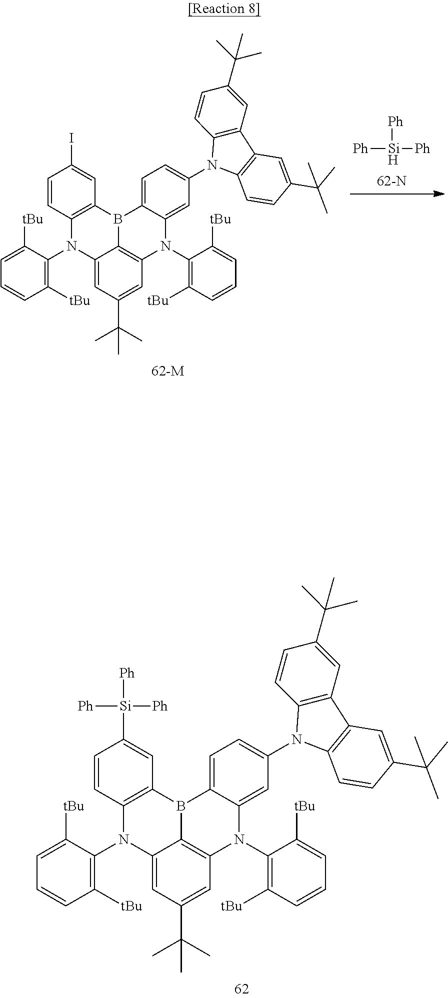

Compound 62-M (10.0 g, 9.06 mmol), Compound 62-N(2.78 g, 9.96 mmol), Pd(tBu₃P)₂ (0.05 g, 0.09 mmol), K₂PO₄ (5.77 g, 27.2 mmol), NMP (46 ml), and THF (23 ml) were stirred under an Ar atmosphere at room temperature for about 24 hours, and the resultant was purified by silica gel column chromatography and recrystallized using toluene/ethanol to obtain a yellow solid (7.53 g, yield 67%). FAB-MS analysis confirmed the compound obtained as Example Compound 62 with a molecular weight of 1236.

### (2) Synthesis of Example Compound 42

Example Compound 42 according to an embodiment may be synthesized, for example, by Reactions 9 to 13.

### 1) Synthesis of Intermediate Compound 42-C

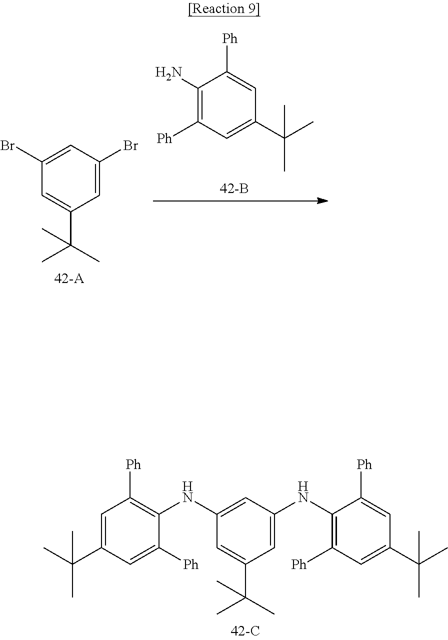

Compound 42-A (25.0 g, 85.6 mmol), Compound 42-B (54.2 g, 180 mmol), Pd(OAc)₂ (1.97 g, 3.42 mmol), [(t-Bu)₃PH]BF₄ (1.99 g, 6.85 mmol), tBuONa (24.7 g, 257 mmol), and xylene (428 ml) were stirred under an Ar atmosphere at about 60° C. for about 1 hour, and the resultant was purified by silica gel column chromatography and re-precipitated using ethanol to obtain a white solid (41.7 g, yield 95%). FAB-MS analysis confirmed the compound obtained as Intermediate Compound 42-C with a molecular weight of 733.

### 2) Synthesis of Intermediate Compound 42-D

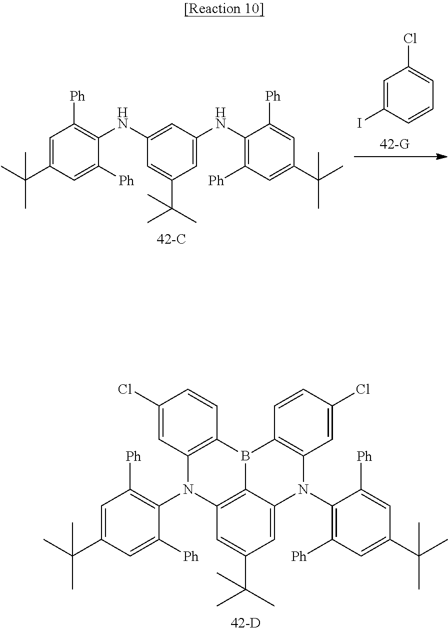

Compound 42-C(40.0 g, 54.6 mmol), Compound 42-G (130 g, 546 mmol), K₂CO₃ (75.4 g, 546 mmol), and CuI (21.8 g, 115 mmol) were stirred under an Ar atmosphere at about 180° C. for about 12 hours, and the resultant was purified by silica gel column chromatography and re-precipitated using ethanol to obtain a white solid (24.6 g, yield 69%). FAB-MS analysis confirmed the compound obtained as Intermediate Compound 42-D with a molecular weight of 954.

### 3) Synthesis of Intermediate Compound 42-E

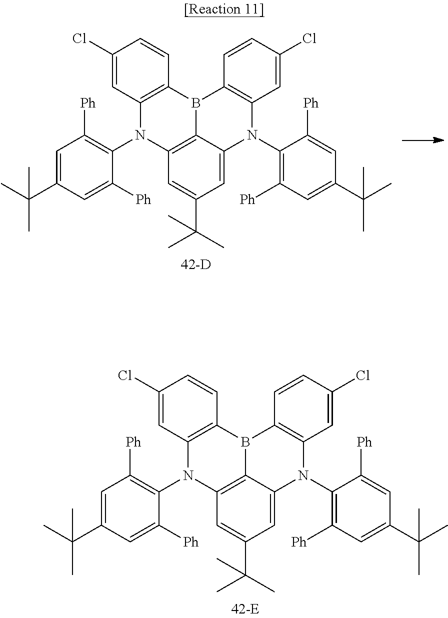

The reaction was performed by the same reaction conditions and the same order as Reaction 5, and a yellow solid (10.4 g, yield 42%) was obtained. FAB-MS analysis confirmed the compound obtained as Intermediate Compound 42-E with a molecular weight of 961.

### 4) Synthesis of Intermediate Compound 42-F

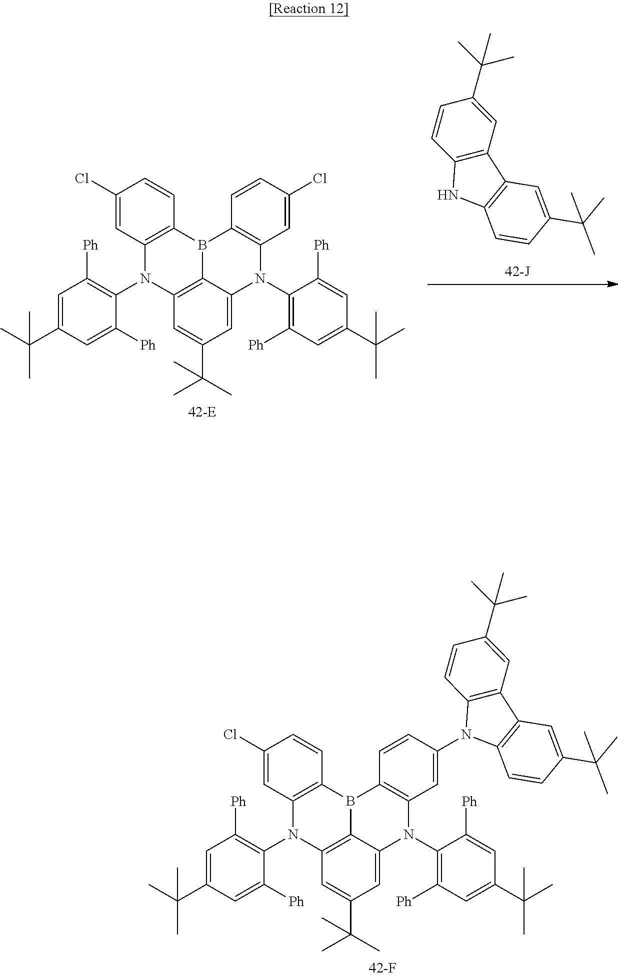

The reaction was performed by the same reaction conditions and the same order as Reaction 6, and a yellow solid (6.14 g, yield 49%) was obtained. FAB-MS analysis confirmed the compound obtained as Intermediate Compound 42-F with a molecular weight of 1204.

### 5) Synthesis of Example Compound 42

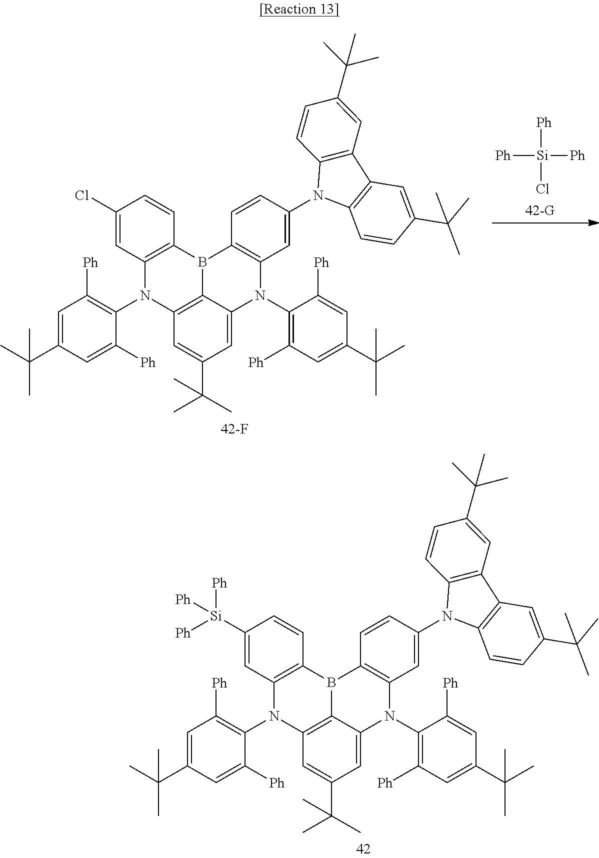

Compound 42-F (6.00 g, 4.98 mmol) was dissolved in THF, and t-BuLi (6.23 ml, 1.6 M n-hexane solution) was added thereto drop by drop at about −78° C., followed by stirring at about −78° C. for about 0.5 hours. A solution of Compound 42-G (1.47 g, 4.98 mmol) dissolved in THF was added thereto drop by drop at about −78° C., and after the dropwise addition, the temperature was naturally elevated to room temperature, followed by reacting overnight. The resultant was purified by silica gel column chromatography to obtain a yellow solid (2.06 g, yield 29%). FAB-MS analysis confirmed the compound obtained as Example Compound 42 with a molecular weight of 1428.

### (3) Synthesis of Example Compound 69

Example Compound 69 according to an embodiment may be synthesized, for example, by Reactions 14 to 18.

### 1) Synthesis of Intermediate Compound 69-C

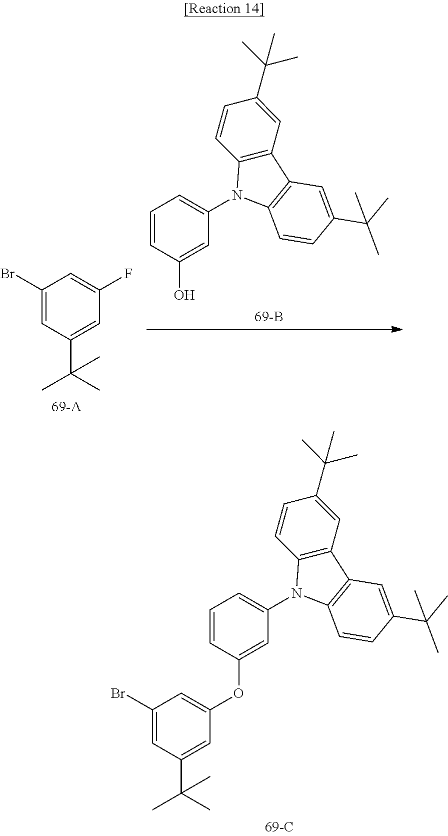

Compound 69-A (12.4 g, 53.8 mmol), Compound 69-B (20.0 g, 53.8 mmol), K₂CO₃ (14.9 g, 107 mmol), and DMF (538 ml) were stirred under an Ar atmosphere at about 110° C. for about 8 hours, and the resultant was purified by silica gel column chromatography to obtain a white solid (22.6 g, yield 72%). FAB-MS analysis confirmed the compound obtained as Intermediate Compound 69-C with a molecular weight of 582.

### 2) Synthesis of Intermediate Compound 69-E

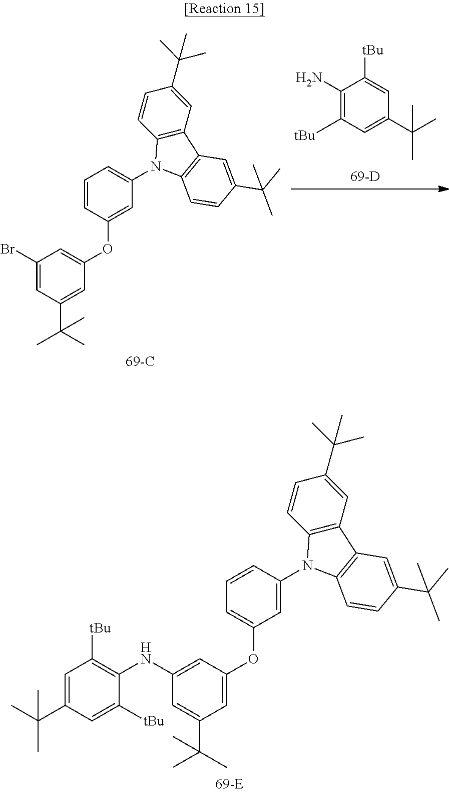

The reaction was performed by the same reaction conditions and the same order as Reaction 3, and a white solid (24.5 g, yield 83%) was obtained. FAB-MS analysis confirmed the compound obtained as Intermediate Compound 69-E with a molecular weight of 763.

### 3) Synthesis of Intermediate Compound 69-G

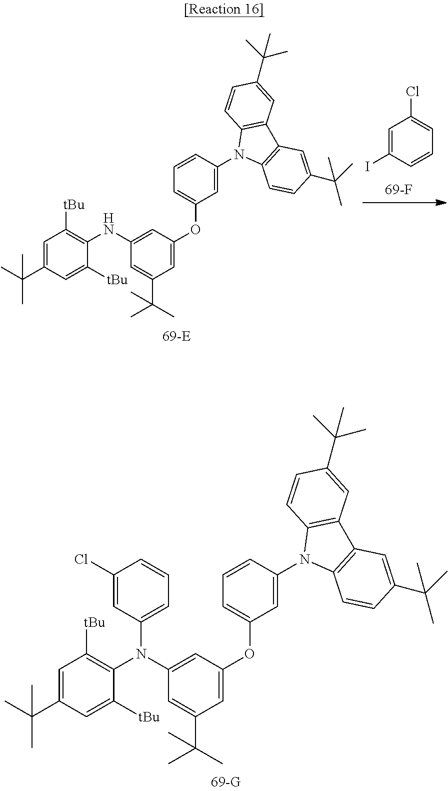

The reaction was performed by the same reaction conditions and the same order as Reaction 2, and a white solid (18.8 g, yield 67%) was obtained. FAB-MS analysis confirmed the compound obtained as Intermediate Compound 69-G with a molecular weight of 873.

### 4) Synthesis of Intermediate Compound 69-H

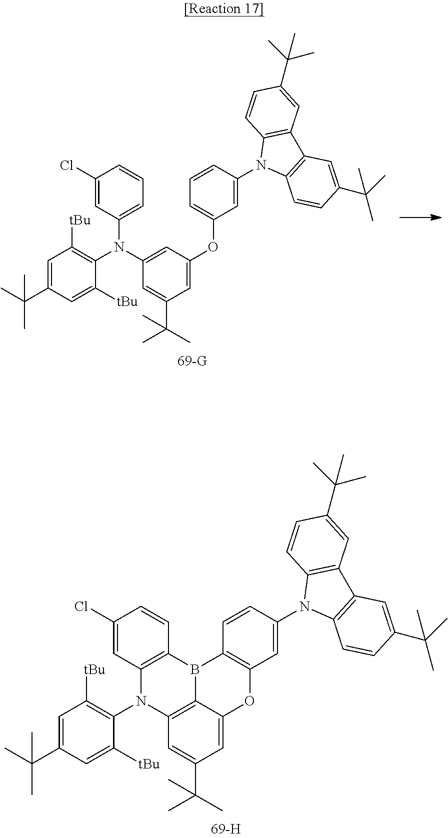

The reaction was performed by the same reaction conditions and the same order as Reaction 5, and a yellow solid (4.36 g, yield 23%) was obtained. FAB-MS analysis confirmed the compound obtained as Intermediate Compound 69-H with a molecular weight of 881.

### 5) Synthesis of Example Compound 69

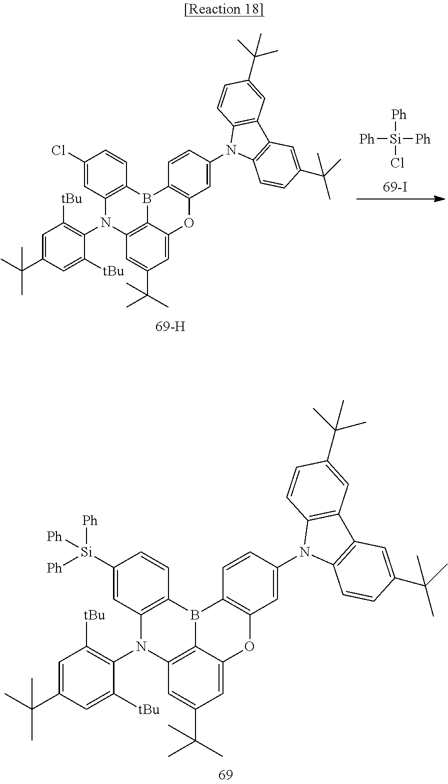

The reaction was performed by the same reaction conditions and the same order as Reaction 13, and a yellow solid (1.76 g, yield 35%) was obtained. FAB-MS analysis confirmed the compound obtained as Example Compound 69 with a molecular weight of 1105.

### (4) Synthesis of Example Compound 5

Example Compound 5 was synthesized by the same order and conditions as the above-described method of Example Compound 62, except for Reaction 19 and Reaction 20.

### 1) Synthesis of Intermediate Compound 5-B

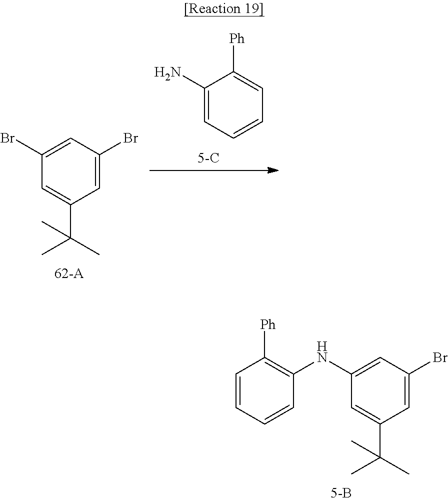 [SMILES: CC(C)(C)c1cc(Br)cc(Br)c1 ; Nc1ccccc1-c1ccccc1 ; CC(C)(C)c1cc(Br)cc(Nc2ccccc2-c2ccccc2)c1]

Intermediate Compound 5-B was synthesized by the same reaction conditions as [Reaction 1] of Example Compound 62, except for using Compound 5-C instead of Compound 62-C.

### 2) Synthesis of Intermediate Compound 5-F

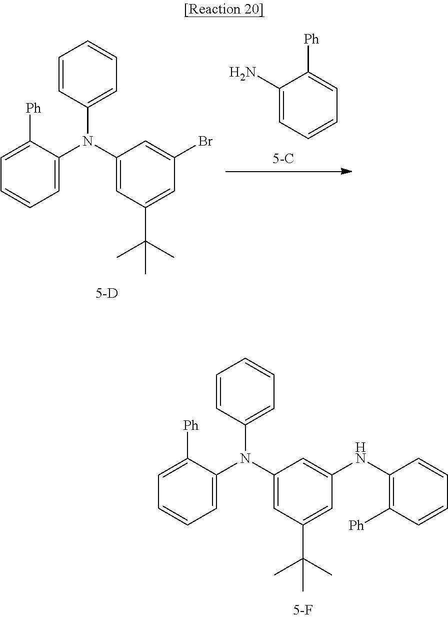 [SMILES: CC(C)(C)c1cc(Br)cc(N(c2ccccc2)c2ccccc2-c2ccccc2)c1 ; Nc1ccccc1-c1ccccc1 ; CC(C)(C)c1cc(Nc2ccccc2-c2ccccc2)cc(N(c2ccccc2)c2ccccc2-c2ccccc2)c1]

Intermediate Compound 5-F was synthesized by the same reaction conditions as [Reaction 3] of Example Compound 62, except for using Compounds 5-C and 5-D instead of Compounds 62-C and 62-D, respectively.

### (5) Synthesis of Example Compound 7

Example Compound 7 was synthesized by the same order and conditions as the above-described method of Example Compound 62, except for Reaction 21 to Reaction 23.

### 1) Synthesis of Intermediate Compound 7-B

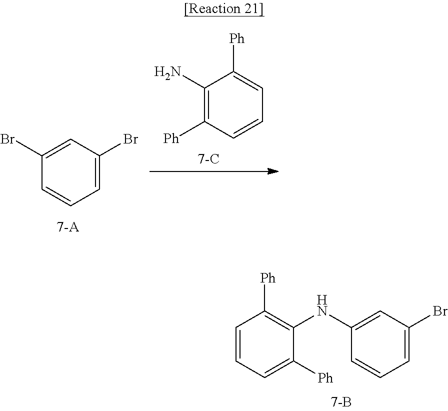 [SMILES: Nc1c(-c2ccccc2)cccc1-c1ccccc1 ; Brc1cccc(Br)c1 ; Brc1cccc(Nc2c(-c3ccccc3)cccc2-c2ccccc2)c1]

Intermediate Compound 7-B was synthesized by the same reaction conditions as [Reaction 1] of Example Compound 62, except for using Compounds 7-A and 7-C instead of Compounds 62-A and 62-C, respectively.

### 2) Synthesis of Intermediate Compound 7-F

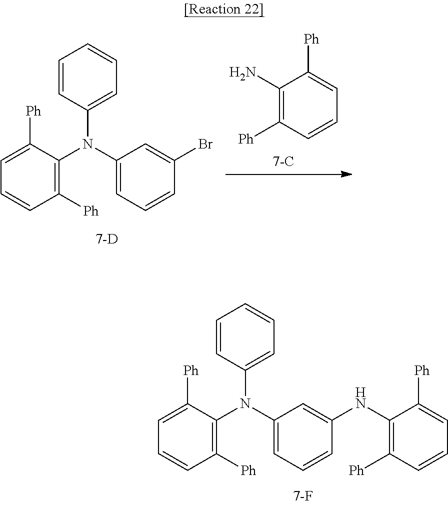 [SMILES: Brc1cccc(N(c2ccccc2)c2c(-c3ccccc3)cccc2-c2ccccc2)c1 ; Nc1c(-c2ccccc2)cccc1-c1ccccc1 ; c1ccc(-c2cccc(-c3ccccc3)c2Nc2cccc(N(c3ccccc3)c3c(-c4ccccc4)cccc3-c3ccccc3)c2)cc1]

Intermediate Compound 7-F was synthesized by the same reaction conditions as [Reaction 3] of Example Compound 62, except for using Compounds 7-C and 7-D instead of Compounds 62-C and 62-D, respectively.

### 3) Synthesis of Intermediate Compound 7-K

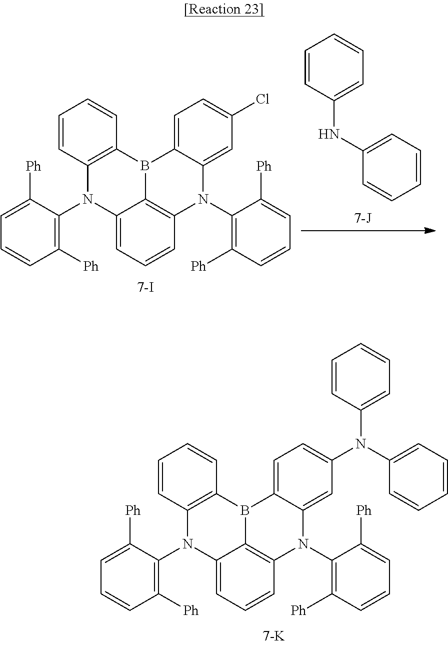 [SMILES: Clc1ccc2c(c1)N(c1c(-c3ccccc3)cccc1-c1ccccc1)c1cccc3c1B2c1ccccc1N3c1c(-c2ccccc2)cccc1-c1ccccc1 ; c1ccc(Nc2ccccc2)cc1 ; c1ccc(-c2cccc(-c3ccccc3)c2N2c3ccccc3B3c4ccc(N(c5ccccc5)c5ccccc5)cc4N(c4c(-c5ccccc5)cccc4-c4ccccc4)c4cccc2c43)cc1]

Intermediate Compound 7-K was synthesized by the same reaction conditions as [Reaction 6] of Example Compound 62, except for using Compounds 7-I and 7-J instead of Compounds 62-I and 62-J, respectively.

### (6) Synthesis of Example Compound 15

Example Compound 15 was synthesized by the same order and conditions as the above-described method of Example Compound 62, except for Reaction 24 and Reaction 25.

### 1) Synthesis of Intermediate Compound 15-B

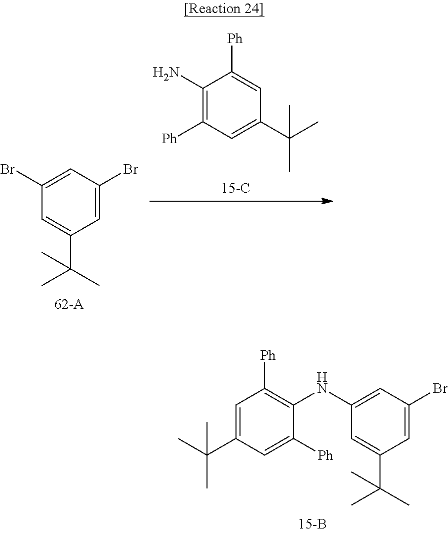 [SMILES: CC(C)(C)c1cc(Br)cc(Br)c1 ; CC(C)(C)c1cc(-c2ccccc2)c(N)c(-c2ccccc2)c1 ; CC(C)(C)c1cc(Br)cc(Nc2c(-c3ccccc3)cc(C(C)(C)C)cc2-c2ccccc2)c1]

Intermediate Compound 15-B was synthesized by the same reaction conditions as [Reaction 1] of Example Compound 62, except for using Compound 15-C instead of Compound 62-C.

### 2) Synthesis of Intermediate Compound 15-F

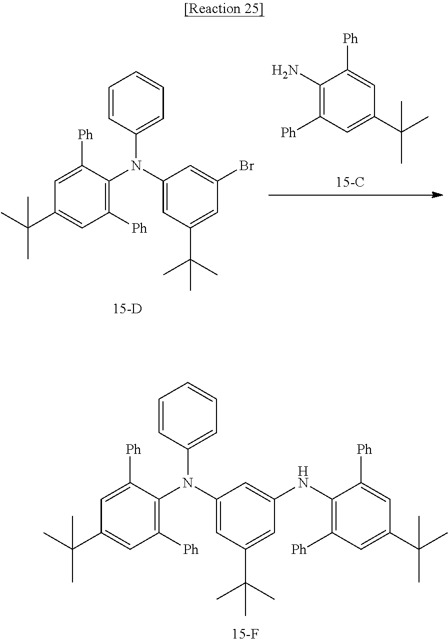 [SMILES: CC(C)(C)c1cc(Br)cc(N(c2ccccc2)c2c(-c3ccccc3)cc(C(C)(C)C)cc2-c2ccccc2)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(N(c2ccccc2)c2c(-c3ccccc3)cc(C(C)(C)C)cc2-c2ccccc2)c1]

Intermediate Compound 15-F was synthesized by the same reaction conditions as [Reaction 3] of Example Compound 62, except for using Compounds 15-C and 15-D instead of Compounds 62-C and 62-D, respectively.

### (7) Synthesis of Example Compound 29

Example Compound 29 was synthesized by the same order and conditions as the above-described method of Example Compound 15, except for Reaction 26.

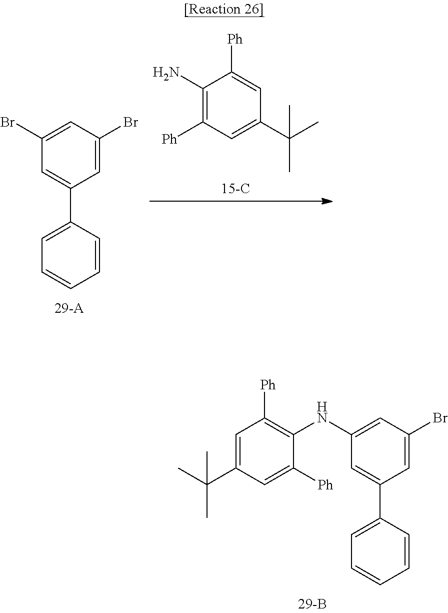 [SMILES: Brc1cc(Br)cc(-c2ccccc2)c1 ; CC(C)(C)c1cc(-c2ccccc2)c(N)c(-c2ccccc2)c1 ; CC(C)(C)c1cc(-c2ccccc2)c(Nc2cc(Br)cc(-c3ccccc3)c2)c(-c2ccccc2)c1]

Intermediate Compound 29-B was synthesized by the same reaction conditions as [Reaction 24] of Example Compound 15, except for using Compound 29-A instead of Compound 62-A.

### (8) Synthesis of Example Compound 33

Example Compound 33 was synthesized by the same order and conditions as the above-described method of Example Compound 15, except for Reaction 27.

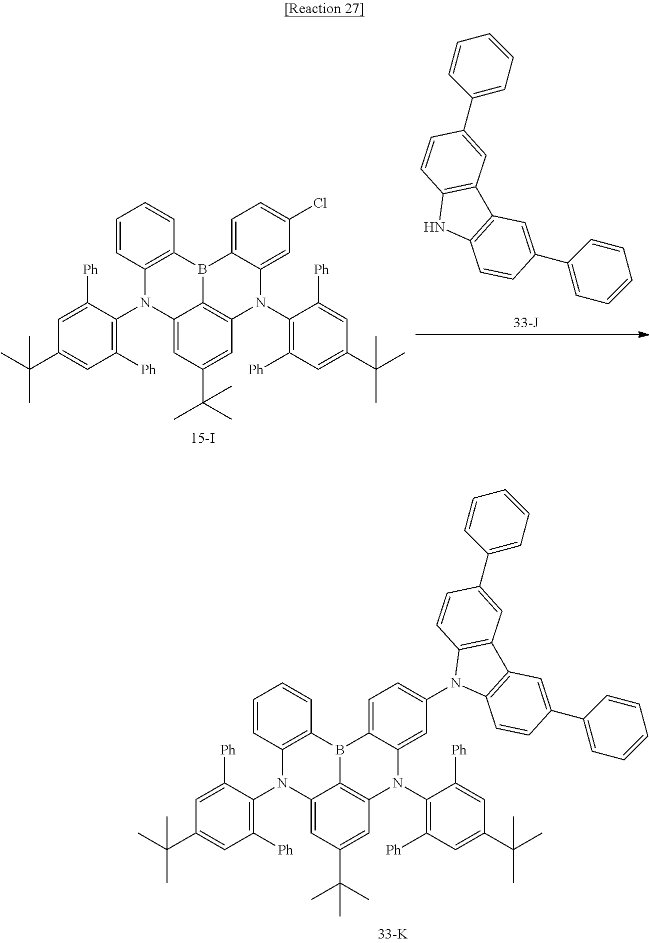

Intermediate Compound 33-K was synthesized by the same reaction conditions as [Reaction 27] of Example Compound 15, except for using Compound 33-J instead of Compound 62-J.

### (9) Synthesis of Example Compound 76

Example Compound 76 was synthesized by the same order and conditions as the above-described method of Example Compound 29, except for Reaction 28.

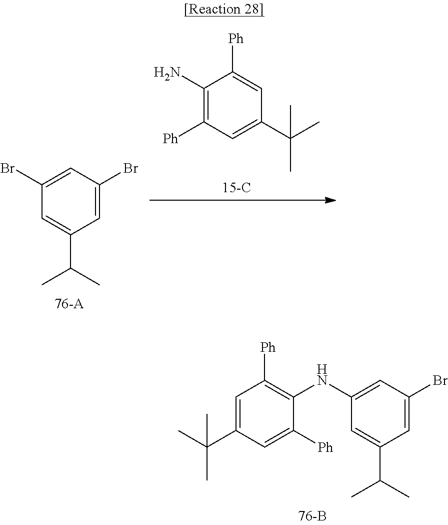 [SMILES: CC(C)c1cc(Br)cc(Br)c1 ; CC(C)(C)c1cc(-c2ccccc2)c(N)c(-c2ccccc2)c1 ; CC(C)c1cc(Br)cc(Nc2c(-c3ccccc3)cc(C(C)(C)C)cc2-c2ccccc2)c1]

Intermediate Compound 76-B was synthesized by the same reaction conditions as [Reaction 26] of Example Compound 29, except for using Compound 76-A instead of Compound 29-A.

### (10) Synthesis of Example Compound 77

Example Compound 77 was synthesized by the same order and conditions as the above-described method of Example Compound 62, except for Reaction 29 and Reaction 30.

### 1) Synthesis of Intermediate Compound 77-B

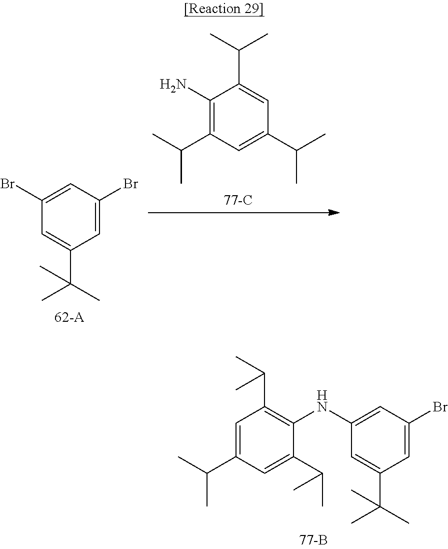 [SMILES: CC(C)(C)c1cc(Br)cc(Br)c1 ; CC(C)c1cc(C(C)C)c(N)c(C(C)C)c1 ; CC(C)c1cc(C(C)C)c(Nc2cc(Br)cc(C(C)(C)C)c2)c(C(C)C)c1]

Intermediate Compound 77-B was synthesized by the same reaction conditions as [Reaction 1] of Example Compound 62, except for using Compound 77-C instead of Compound 62-C.

### 2) Synthesis of Intermediate Compound 77-F

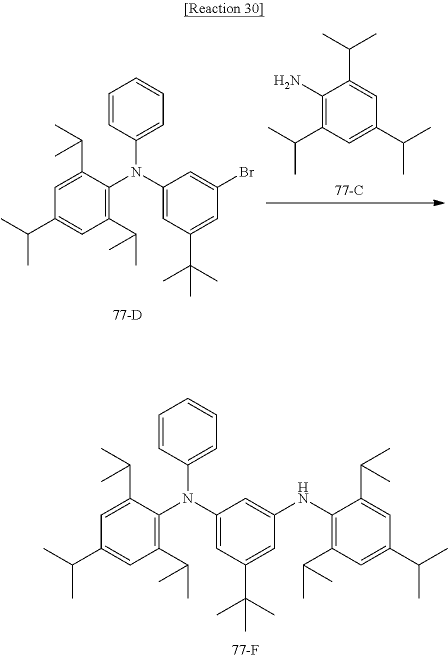 [SMILES: CC(C)c1cc(C(C)C)c(N(c2ccccc2)c2cc(Br)cc(C(C)(C)C)c2)c(C(C)C)c1 ; CC(C)c1cc(C(C)C)c(N)c(C(C)C)c1 ; CC(C)c1cc(C(C)C)c(Nc2cc(N(c3ccccc3)c3c(C(C)C)cc(C(C)C)cc3C(C)C)cc(C(C)(C)C)c2)c(C(C)C)c1]

Intermediate Compound 77-F was synthesized by the same reaction conditions as [Reaction 3] of Example Compound 62, except for using Compounds 77-C and 77-D instead of Compounds 62-C and 62-D, respectively.

### 2. Manufacture and Evaluation of Light Emitting Element Including Polycyclic Compound

### (1) Manufacture of Light Emitting Element

Light emitting elements including the Example Compounds or the Comparative Example Compounds in an emission layer were manufactured by a method described below. The light emitting elements of Examples 1 to 10 were manufactured using Example Compounds 5, 7, 15, 29, 33, 42, 62, 69, 76, and 77, respectively, as the dopant materials of an emission layer. Comparative Examples 1 to 9 respectively corresponded to light emitting elements using Comparative Compounds C1 to C9 as the dopant materials of an emission layer. Example Compounds and Comparative Compounds applicable in an emission layer are as follows.

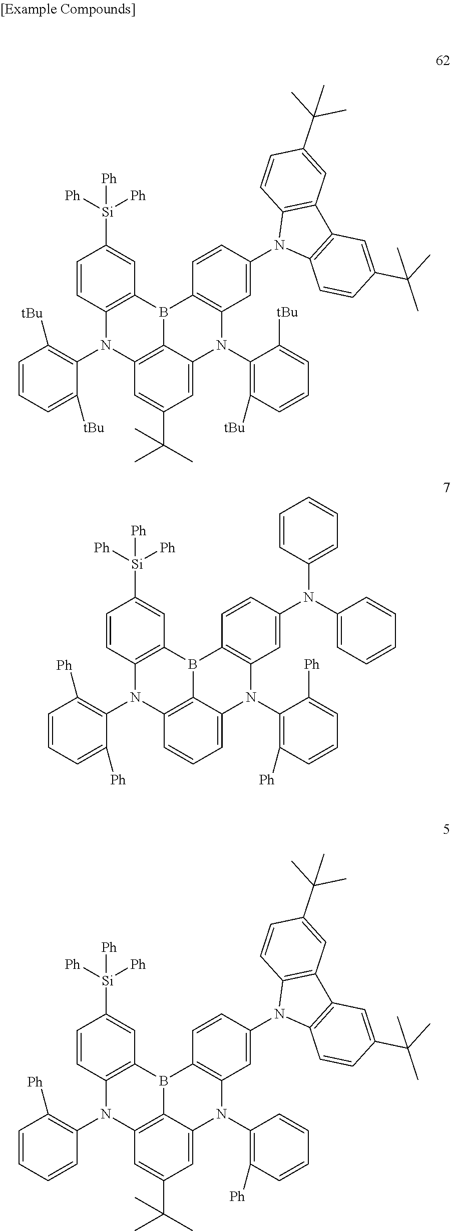 [SMILES: CC(C)(C)c1cc2c3c(c1)N(c1c(C(C)(C)C)cccc1C(C)(C)C)c1cc(-n4c5ccc(C(C)(C)C)cc5c5cc(C(C)(C)C)ccc54)ccc1B3c1cc([Si](c3ccccc3)(c3ccccc3)c3ccccc3)ccc1N2c1c(C(C)(C)C)cccc1C(C)(C)C ; c1ccc(-c2cccc(-c3ccccc3)c2N2c3ccc([Si](c4ccccc4)(c4ccccc4)c4ccccc4)cc3B3c4ccc(N(c5ccccc5)c5ccccc5)cc4N(c4c(-c5ccccc5)cccc4-c4ccccc4)c4cccc2c43)cc1 ; CC(C)(C)c1cc2c3c(c1)N(c1ccccc1-c1ccccc1)c1cc(-n4c5ccc(C(C)(C)C)cc5c5cc(C(C)(C)C)ccc54)ccc1B3c1cc([Si](c3ccccc3)(c3ccccc3)c3ccccc3)ccc1N2c1ccccc1-c1ccccc1]

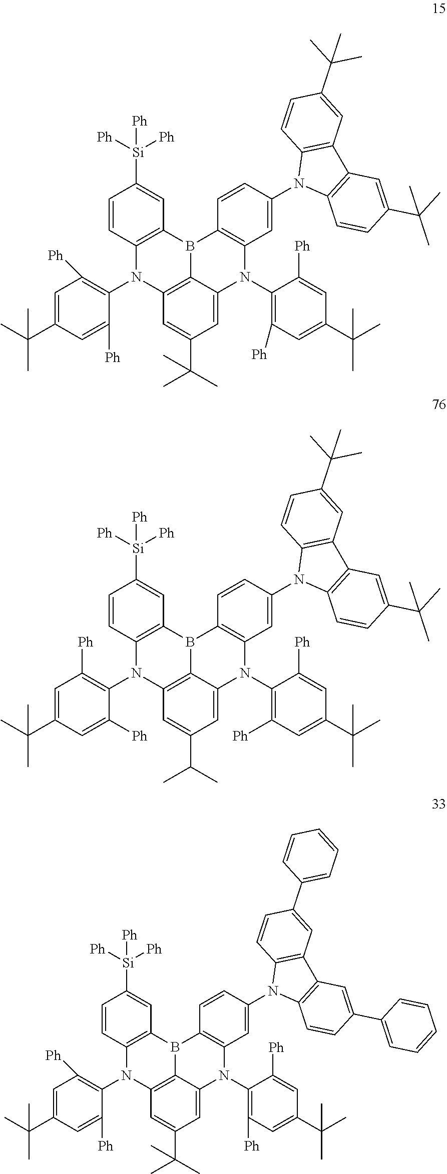

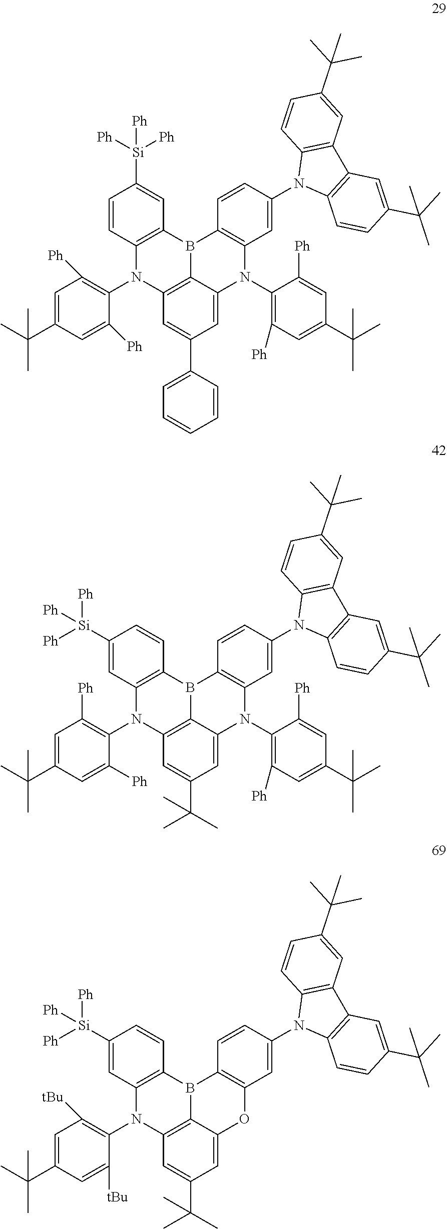

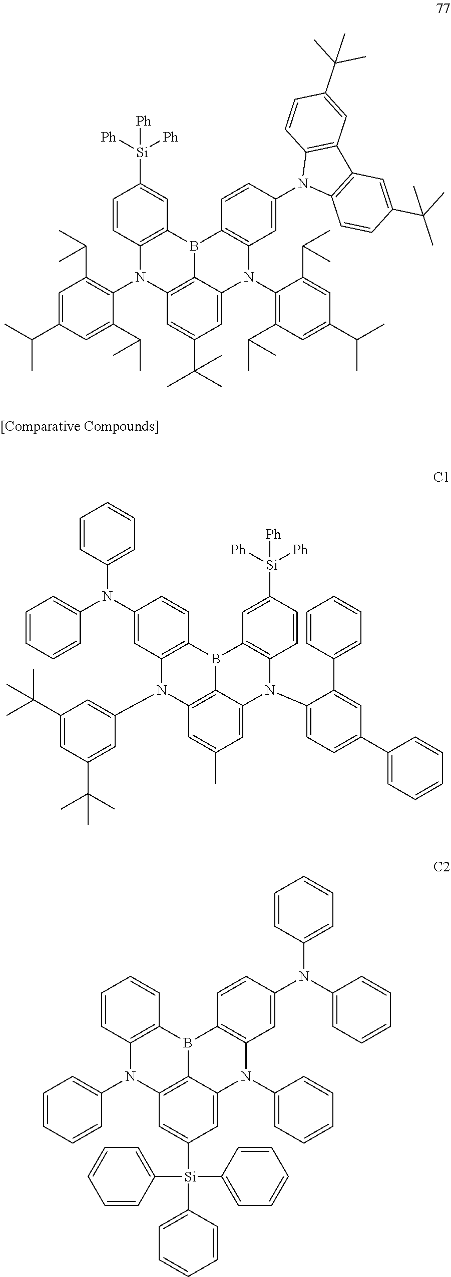

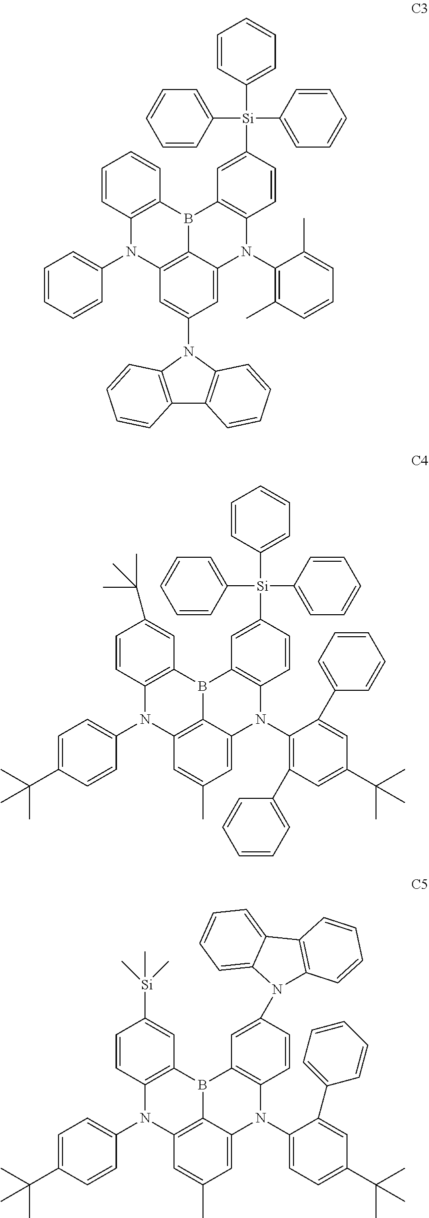

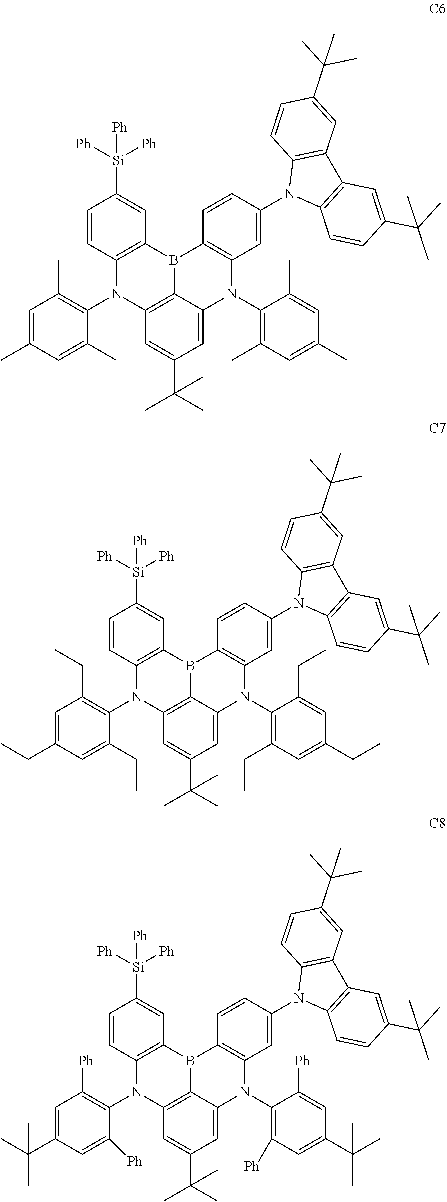

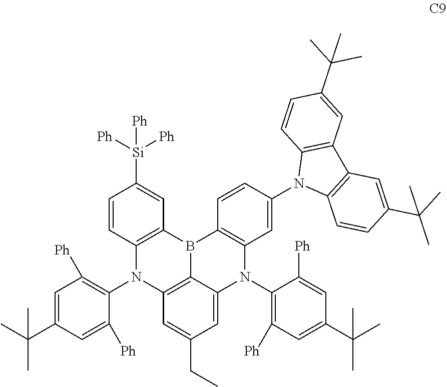 [SMILES: CCc1cc2c3c(c1)N(c1c(-c4ccccc4)cc(C(C)(C)C)cc1-c1ccccc1)c1cc(-n4c5ccc(C(C)(C)C)cc5c5cc(C(C)(C)C)ccc54)ccc1B3c1cc([Si](c3ccccc3)(c3ccccc3)c3ccccc3)ccc1N2c1c(-c2ccccc2)cc(C(C)(C)C)cc1-c1ccccc1]

A first electrode with a thickness of about 150 nm was formed of ITO. On the first electrode, a hole injection layer with a thickness of about 10 nm was formed of dipyrazino[2,3-f:2′,3′-h]quinoxaline-2,3,6,7,10,11-hexacarbonitrile (HAT-CN). On the hole injection layer, a hole transport layer with a thickness of about 80 nm was formed of N,N′-bis(naphthalen-1-yl)-N,N′-bis(phenyl)-2,2′-dimethylbenzidine (α-NPD). On the hole transport layer, an emission auxiliary layer with a thickness of about 5 nm was of using 1,3-bis(carbazol-9-yl)benzene (mCP). On the emission auxiliary layer, 3,3′-di(9H-carbazol-9-yl)-1,1′-biphenyl (mCBP) and the Example Compound were co-deposited at a mass ratio of about 99:1 to form an emission layer with a thickness of about 20 nm. For the manufacture of an element of the Comparative Example, the Comparative Compound was applied instead of the Example Compound. On the emission layer, a hole blocking layer with a thickness of about 10 nm was formed of bis[2-(diphenylphosphino)phenyl]ether oxide (DPEPO). An electron transport layer with a thickness of about 30 nm was formed of 2,2′,2″-(1,3,5-benzinetriyl)-tris(1-phenyl-1-H-benzimidazole) (TPBi). On the electron transport layer, an electron injection layer with a thickness of about 0.5 nm was formed of LiF. On the electron injection layer, a second electrode with a thickness of about 100 nm was formed of Al. All layers were formed by a vacuum deposition method.

The compounds of the functional layers used for the manufacture of the light emitting elements of the Examples and Comparative Examples are shown below. The materials are materials of the related art, and commercially available products were used after sublimation purification for the manufacture of the elements.

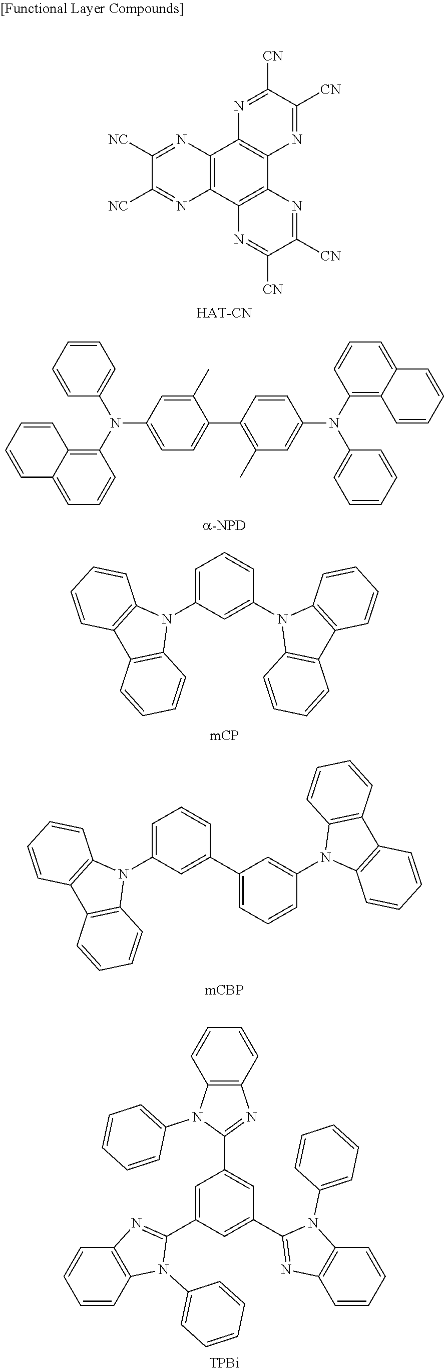

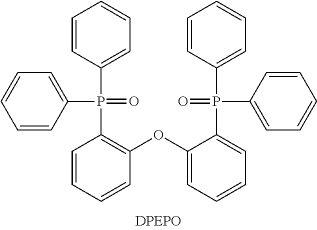 [SMILES: O=P(c1ccccc1)(c1ccccc1)c1ccccc1Oc1ccccc1P(=O)(c1ccccc1)c1ccccc1]

Measurement was performed using a Hamamatsu C9920-11 light distribution characteristics measurement system. λₘₐₓ is the maximum emission wavelength of emission spectrum. EQEₘₐₓ is external quantum efficiency at about 1000 cd/m². The lifetime (LT₅₀) of a light emitting element is time from an initial value to luminance deterioration to about 50% when continuously driven at a current density of about 10 mA/cm², and represents relative lifetime based on Comparative Example 1.

Table 1 shows the properties of the light emitting elements of Examples 1 to 10 and Comparative Examples 1 to 9. The light emitting elements of Examples 1 to 10 and Comparative Examples 1 to 9 were manufactured according to the above-described method for manufacturing an element.

TABLE 1

| | | λₘₐₓ | EQEₘₐₓ | |
|---|---|---|---|---|
| | Emission layer dopant | (nm) | (%) | LT50 |
| Example 1 | Example Compound 62 | 461 | 15.2 | 1.6 |
| Example 2 | Example Compound 7 | 458 | 14.6 | 1.7 |
| Example 3 | Example Compound 5 | 459 | 14.8 | 1.8 |
| Example 4 | Example Compound 15 | 457 | 15.3 | 2.1 |
| Example 5 | Example Compound 76 | 456 | 15.4 | 1.8 |
| Example 6 | Example Compound 33 | 459 | 15.0 | 2.0 |
| Example 7 | Example Compound 29 | 462 | 15.9 | 2.0 |
| Example 8 | Example Compound 42 | 468 | 16.2 | 1.9 |
| Example 9 | Example Compound 69 | 461 | 14.9 | 1.7 |
| Example 10 | Example Compound 77 | 460 | 15.4 | 1.5 |
| Comparative | Comparative Compound C1 | 459 | 14.2 | 1.0 |
| Example 1 | | | | |
| Comparative | Comparative Compound C2 | 454 | 12.8 | 0.7 |
| Example 2 | | | | |
| Comparative | Comparative Compound C3 | 455 | 11.5 | 0.8 |
| Example 3 | | | | |
| Comparative | Comparative Compound C4 | 456 | 11.9 | 1.2 |
| Example 4 | | | | |
| Comparative | Comparative Compound C5 | 465 | 12.5 | 0.9 |
| Example 5 | | | | |
| Comparative | Comparative Compound C6 | 458 | 14.2 | 0.7 |
| Example 6 | | | | |
| Comparative | Comparative Compound C7 | 458 | 14.0 | 0.8 |
| Example 7 | | | | |
| Comparative | Comparative Compound C8 | 454 | 14.1 | 1.3 |
| Example 8 | | | | |
| Comparative | Comparative Compound C9 | 455 | 14.5 | 1.4 |
| Example 9 | | | | |

Referring to Table 1, the light emitting elements of Examples 1 to 10, applying the polycyclic compound, showed high emission efficiency and long-life characteristics when compared to Comparative Examples 1 to 9.

The compounds of Examples 1 to 10 include a core structure of three benzene rings fused via a boron atom, a nitrogen atom, and a heteroatom. The heteroatom is a nitrogen atom, or an oxygen atom. Example Compounds 5, 7, 15, 29, 33, 42, 62, 69, 76, and 77 include a silyl group, and further include an amine group or a carbazole group. A phenyl group is bonded to the nitrogen atom of the core structure, and a bulky substituent is bonded to the phenyl group at an ortho position to the nitrogen atom. For example, the phenyl group bonded to the nitrogen atom of the core structure has a structure in which an alkyl group of 3 to 30 carbon atoms, or an aryl group of 6 to 30 ring-forming carbon atoms is substituted at an ortho position to the nitrogen atom. A hydrogen atom, an alkyl group of 3 to 30 carbon atoms, or an aryl group of 6 to 30 ring-forming carbon atoms is bonded to the benzene ring connected with the nitrogen atom and the heteroatom of the core structure, at a para position to a boron atom. Example Compounds 5, 7, 15, 29, 33, 42, 62, 69, 76, and 77 have the above-described structure, and when applied to the emission layer of a light emitting element, the properties of the light emitting element, for example, emission efficiency and lifetime were improved.

Comparative Compound C1 applied to the light emitting element of Comparative Example 1 includes a silyl group and an amine group. However, a substituent combined with a benzene ring connected with two nitrogen atoms of a core structure is an alkyl group of 1 carbon atom (a methyl group), and emission efficiency and lifetime were evaluated as low when compared to a light emitting element in which the Example Compound was applied.

Comparative Compounds C2 and C3, applied in the light emitting elements of Comparative Examples 2 and 3 include a silyl group, and an amine group or a carbazole group. However, in Comparative Compound C2, the bonding position of the silyl group is different from the position of the Example Compounds, and in Comparative Compound C3, the bonding position of the carbazole group is different from the position of the Example Compounds. Accordingly, emission efficiency and lifetime were evaluated as low when compared to a light emitting element in which the Example Compound was applied.

Comparative Compound C4 applied in the light emitting element of Comparative Example 4 includes a silyl group, but is a compound not including an amine group or a carbazole group. Accordingly, emission efficiency and lifetime were evaluated as low when compared to a light emitting element in which the Example Compound was applied.

Comparative Compound C5 applied in the light emitting element of Comparative Example 5 includes a silyl group and a carbazole group. However, the bonding position of the carbazole group is the meta position to a boron atom, and emission efficiency and lifetime were evaluated as low when compared to a light emitting element in which the Example Compound was applied.

Comparative Compounds C6 and C7, applied in the light emitting elements of Comparative Examples 6 and 7 include a silyl group and a carbazole group. However, an alkyl group of 1 or 2 carbon atoms (a methyl group or an ethyl group) is combined at the ortho position to a phenyl group which is combined with a nitrogen atom, and it is thought that different from the Example Compounds, effects of shielding a core structure through the introduction of a bulky substituent, could not be achieved.

Comparative Compounds C8 and C9, applied in the light emitting elements of Comparative Examples 8 and 9 include a silyl group and a carbazole group. However, substituents combined with benzene rings connected with two nitrogen atoms of core structures are alkyl groups of 1 and 2 carbon atoms (a methyl group and an ethyl group), respectively, and emission efficiency and lifetime were evaluated low when compared to a light emitting element in which the Example Compound was applied.

The light emitting element according to an embodiment may show element properties of high emission efficiency and long lifetime.

The polycyclic compound according to an embodiment is included in the emission layer of a light emitting element and may contribute to the improvement of the emission efficiency and the lifetime of the light emitting element.

The display device according to an embodiment may show excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode facing the first electrode; and
at least one functional layer disposed between the first electrode and the second electrode, wherein
the at least one functional layer comprises a first compound represented by Formula 1: 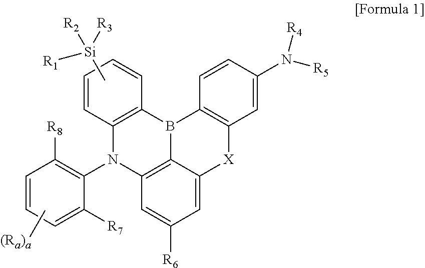
wherein in Formula 1,
X is N(Ar), O, or S,
Ar is a substituted or unsubstituted aryl group of 6 to 30 ring-forming carbon atoms,
R₁ to R₅ are each independently a substituted or unsubstituted alkyl group of 1 to 30 carbon atoms, a substituted or unsubstituted aryl group of 6 to 30 ring-forming carbon atoms, or combined with an adjacent group to form a ring,
R₆ and Rₐ are each independently a hydrogen atom, a substituted or unsubstituted alkyl group of 3 to 30 carbon atoms, or a substituted or unsubstituted aryl group of 6 to 30 ring-forming carbon atoms,
at least one of R₇ and R₈ is each independently a substituted or unsubstituted alkyl group of 3 to 30 carbon atoms or a substituted or unsubstituted aryl group of 6 to 30 ring-forming carbon atoms, and the remainder of R₇ and R₈ is a hydrogen atom,
a is an integer from 0 to 3, and
at least one hydrogen atom is optionally substituted with a deuterium atom.

2. The light emitting element of claim 1, wherein the first compound is represented by Formula 1-1a or Formula 1-1b: 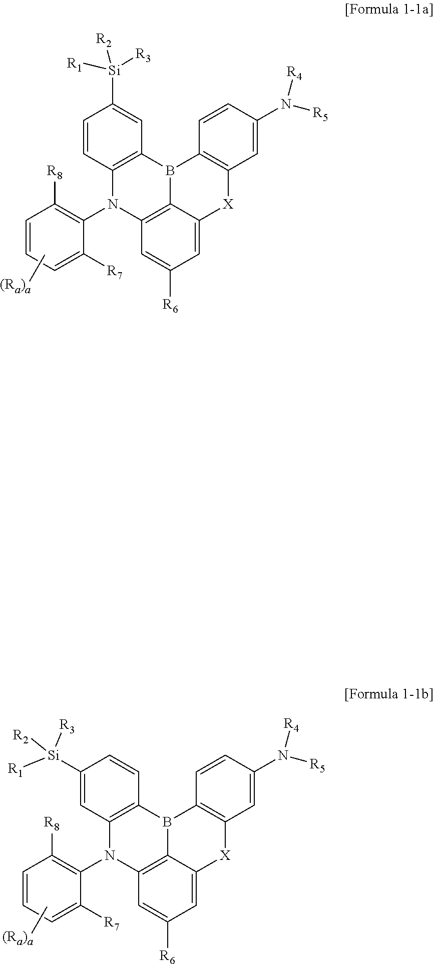
wherein in Formula 1-1a and Formula 1-1b,
X, R₁ to R₈, Rₐ, and a are each as defined in Formula 1.

3. The light emitting element of claim 1, wherein the first compound is represented by Formula 1-2a or Formula 1-2b: 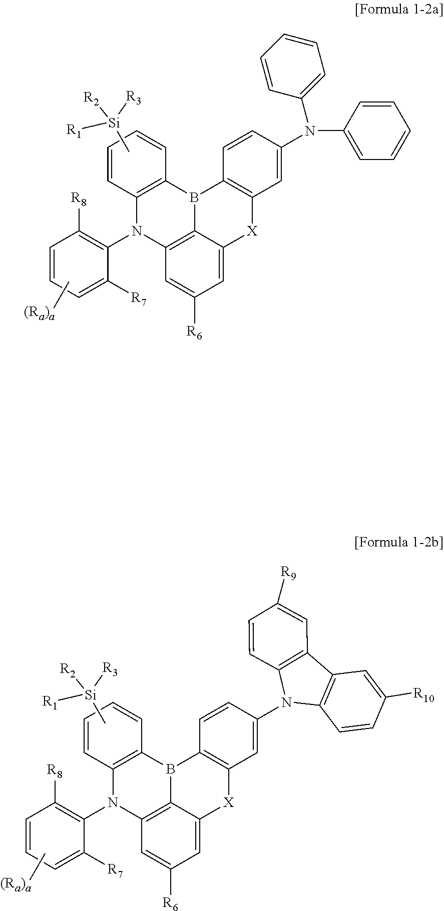
wherein in Formula 1-2a and Formula 1-2b,
R₉ and R₁₀ are each independently a hydrogen atom, a substituted or unsubstituted alkyl group of 3 to 30 carbon atoms, or a substituted or unsubstituted aryl group of 6 to 30 ring-forming carbon atoms, and
X, R₁ to R₃, R₆ to R₈, Rₐ, and a are each as defined in Formula 1.

4. The light emitting element of claim 1, wherein the first compound is represented by one of Formula 1-3a to Formula 1-3c: 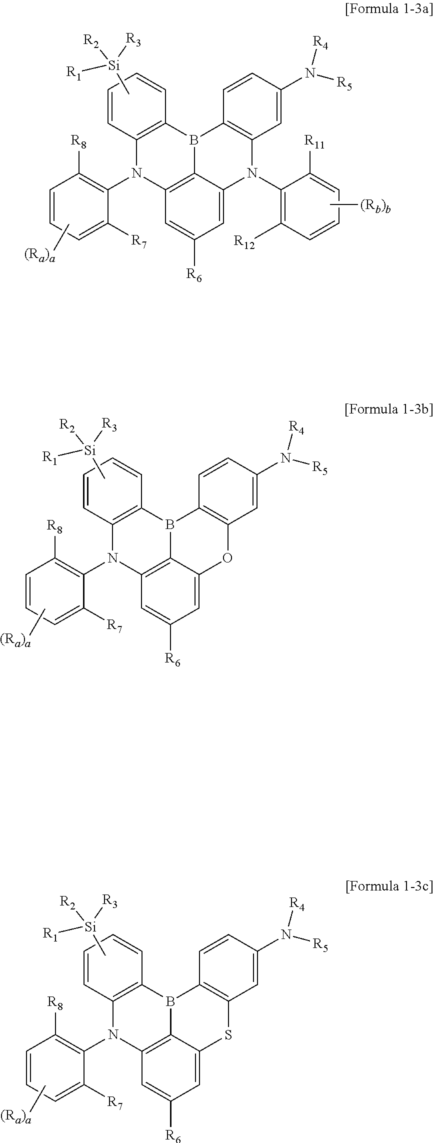
wherein in Formula 1-3a to Formula 1-3c,
at least one of R₁₁ and R₁₂ is each independently a substituted or unsubstituted alkyl group of 3 to 30 carbon atoms or a substituted or unsubstituted aryl group of 6 to 30 ring-forming carbon atoms, and the remainder of R₁₁ and R₁₂ is a hydrogen atom,
R_{b} is a hydrogen atom, a substituted or unsubstituted alkyl group of 3 to 30 carbon atoms, or a substituted or unsubstituted aryl group of 6 to 30 ring-forming carbon atoms,
b is an integer from 0 to 3, and
R₁ to R₈, Rₐ, and a are each as defined in Formula 1.

5. The light emitting element of claim 1, wherein the first compound is represented by one of Formula 1-4a to Formula 1-4c: 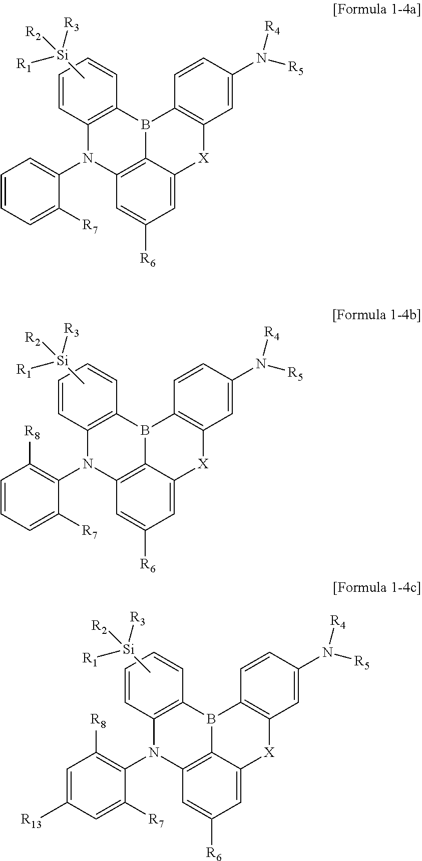
wherein in Formula 1-4a to Formula 1-4c,
R₇, R₈, and R₁₃ are each independently an unsubstituted i-propyl group, an unsubstituted t-butyl group, or a substituted or unsubstituted phenyl group, and
X and R₁ to R₆ are each as defined in Formula 1.

6. The light emitting element of claim 1, wherein the first compound is represented by one of Formula 1-5a to Formula 1-5e: 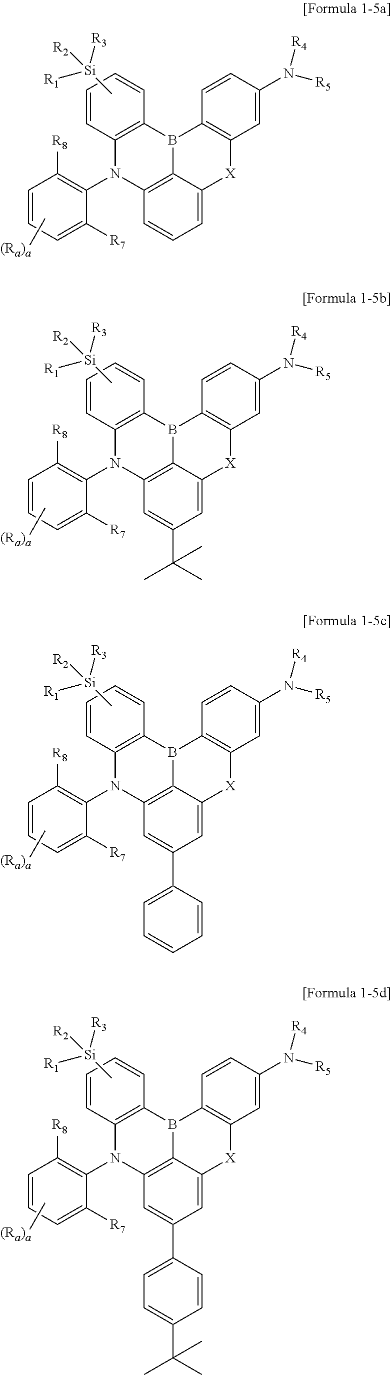 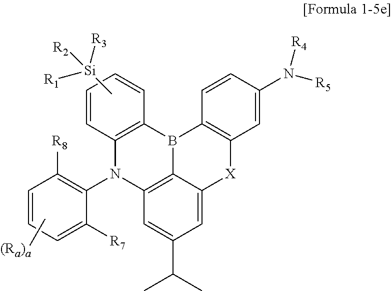
wherein in Formula 1-5a to Formula 1-5e,
X, R₁ to R₅, R₇, R₈, Rₐ, and a are each as defined in Formula 1.

7. The light emitting element of claim 1, wherein R₁ to R₃ are each independently an unsubstituted methyl group or an unsubstituted phenyl group.

8. The light emitting element of claim 1, wherein the first compound comprises at least one compound selected from Compound Group 1: 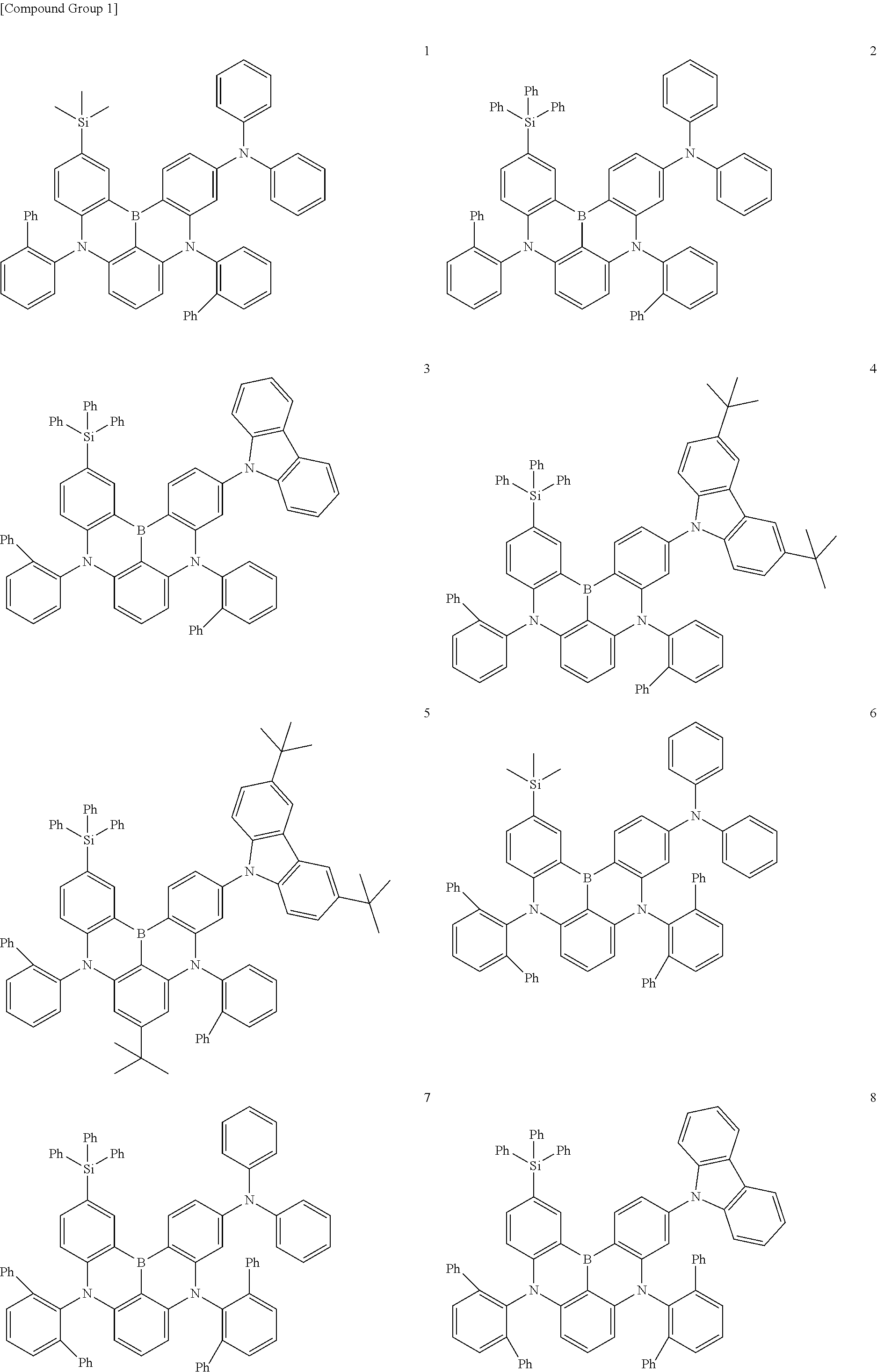 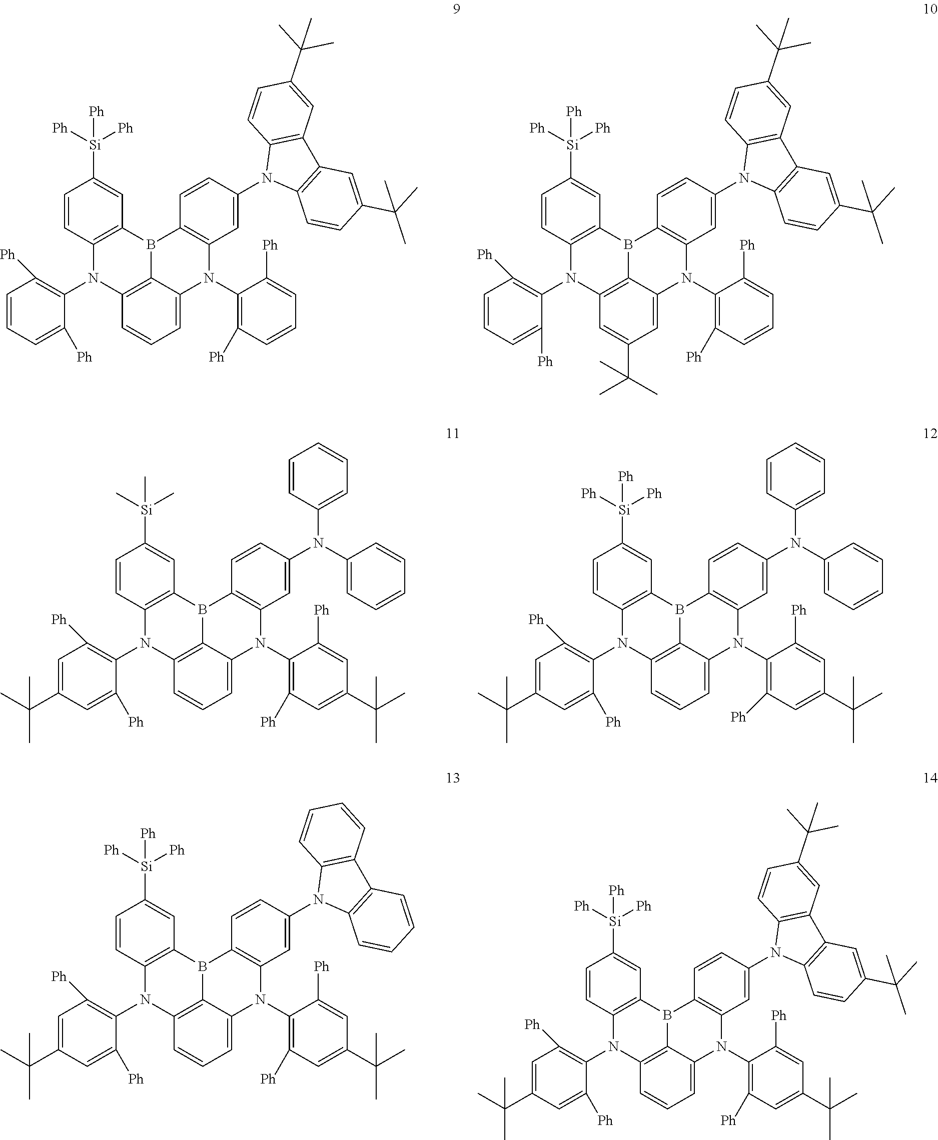 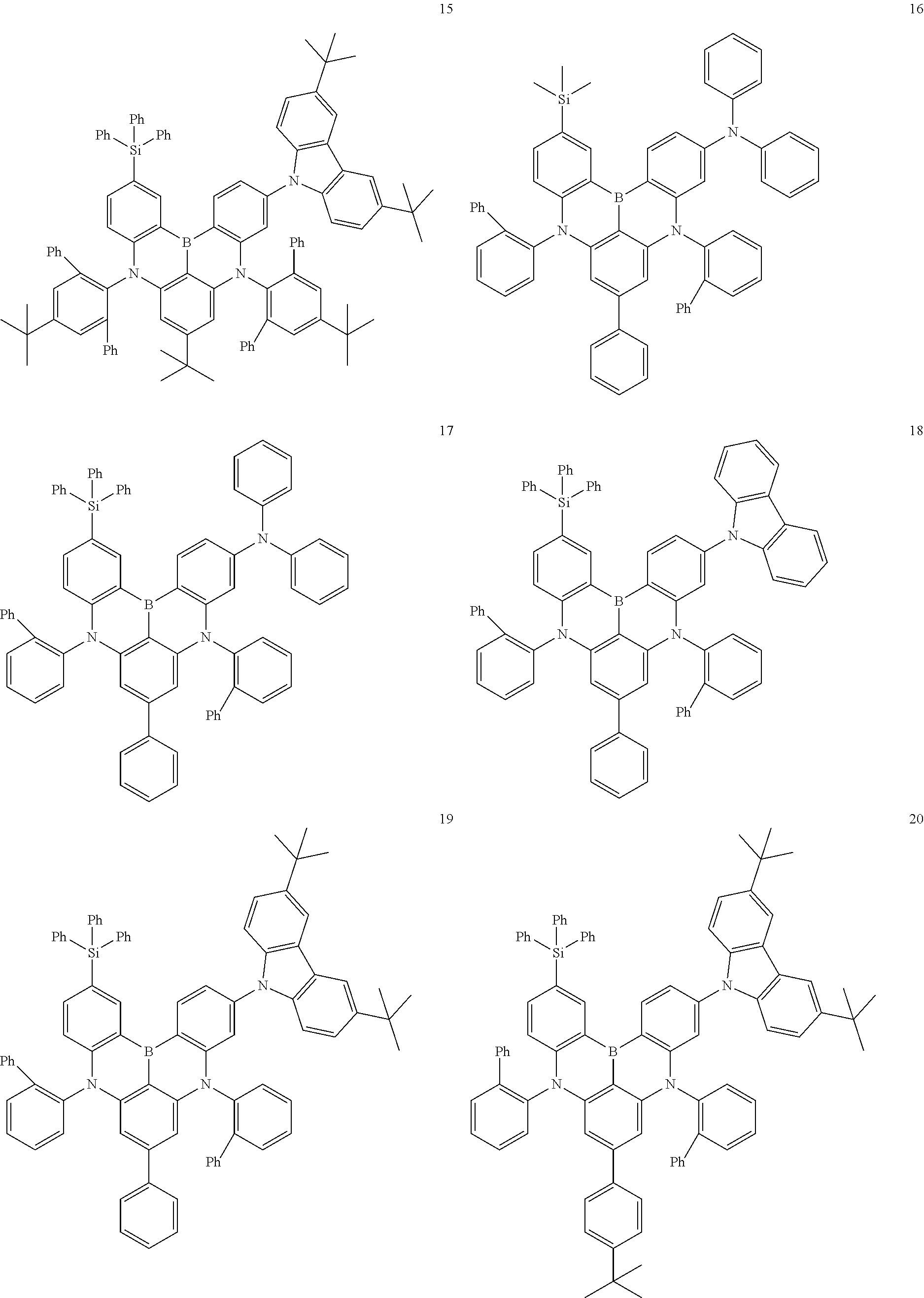 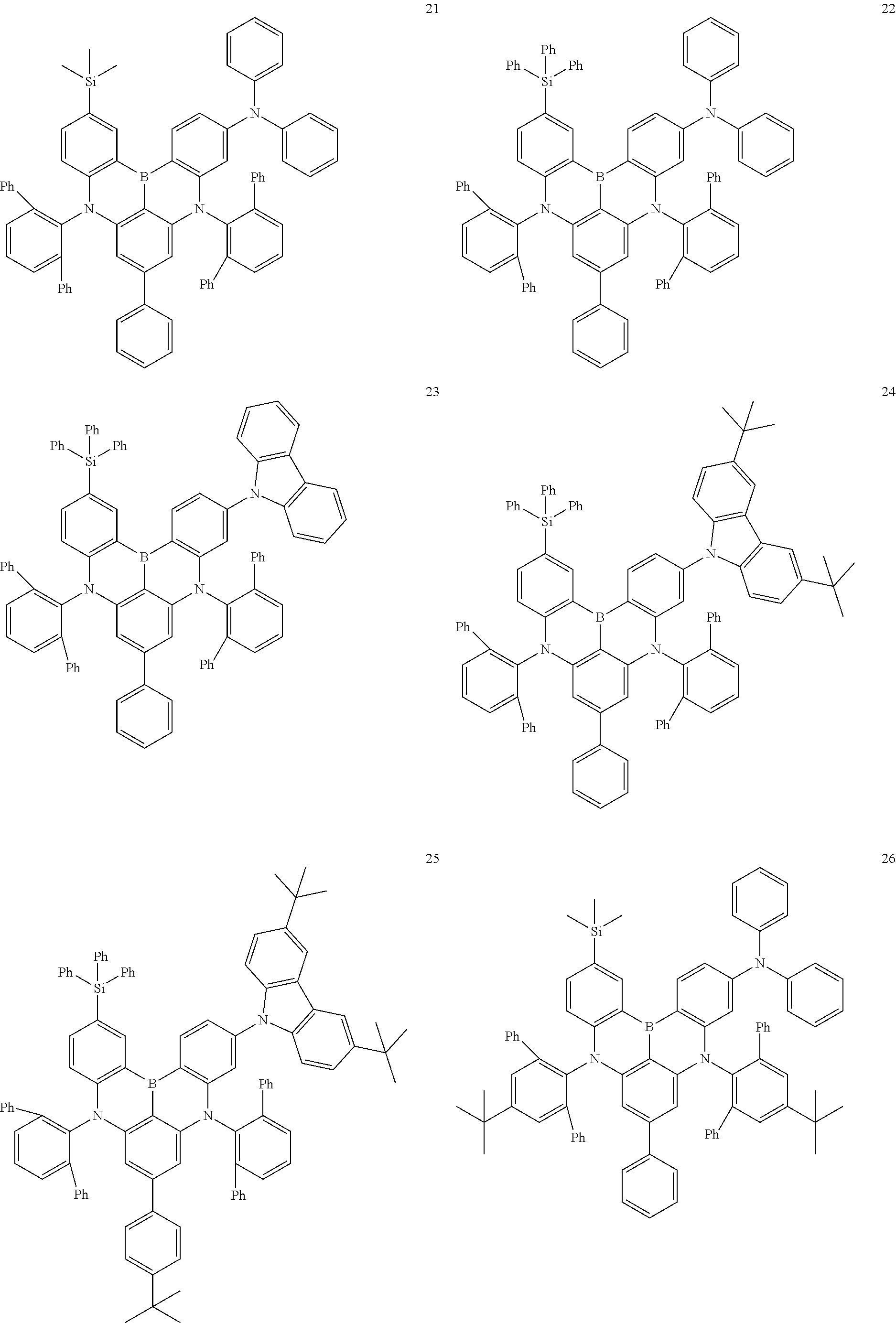 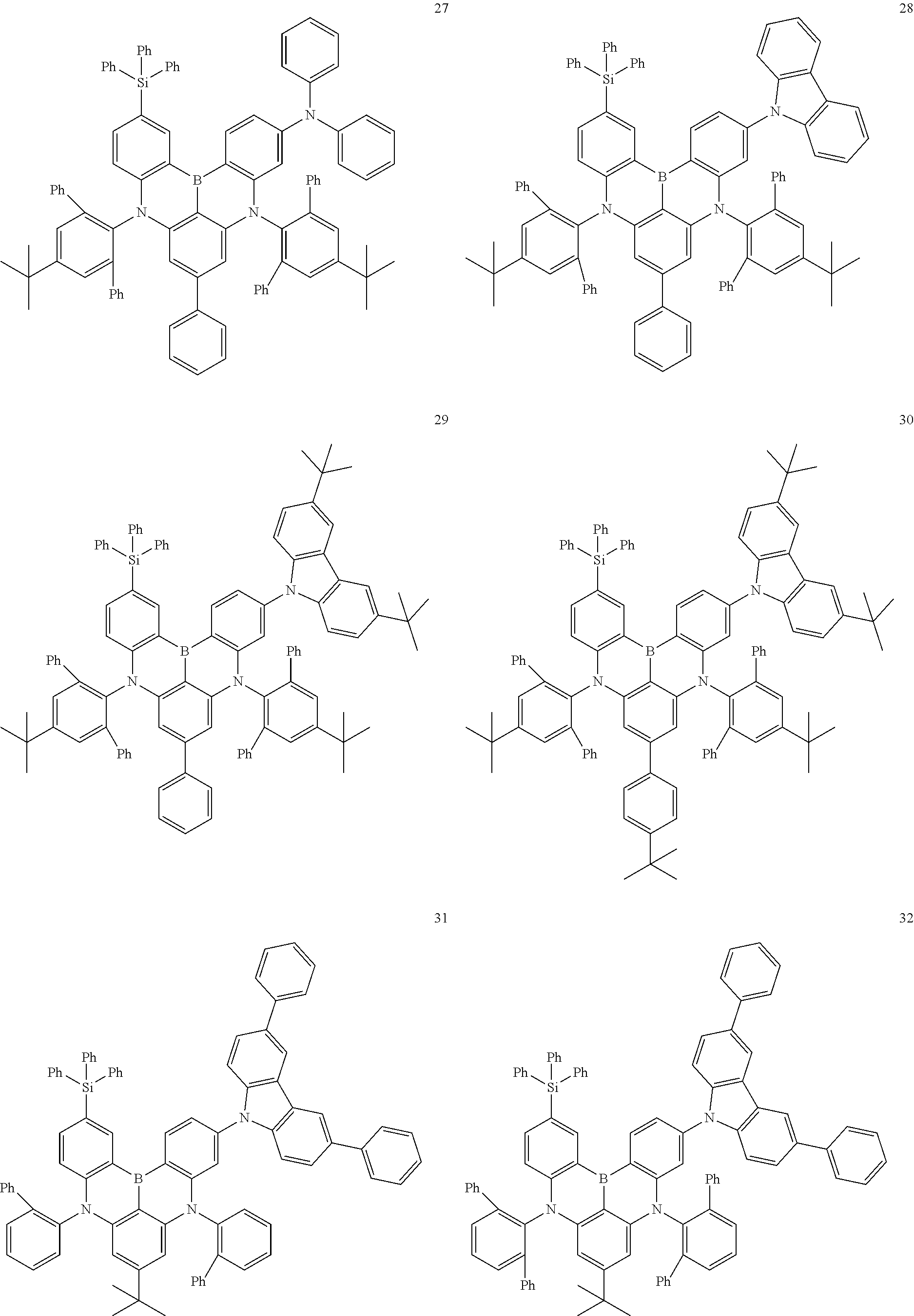 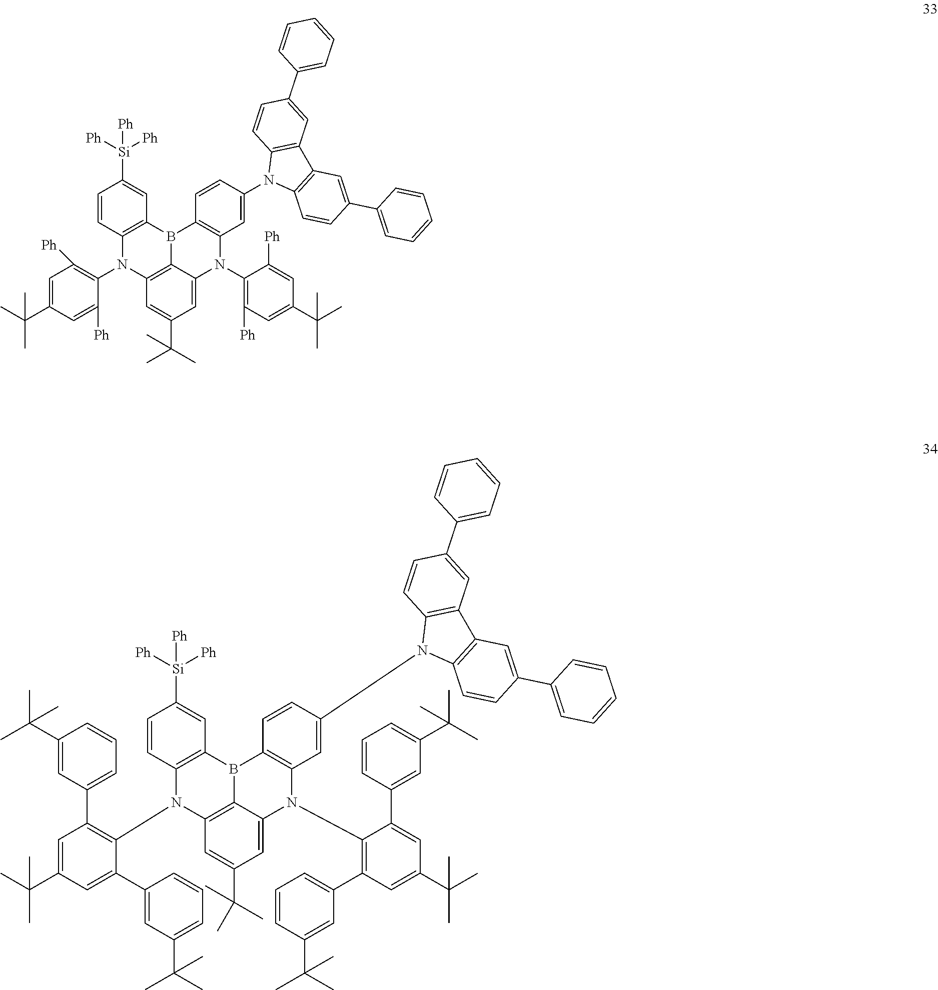 [SMILES: CC(C)(C)c1cc(-c2ccccc2)c(N2c3ccc([Si](c4ccccc4)(c4ccccc4)c4ccccc4)cc3B3c4ccc(-n5c6ccc(-c7ccccc7)cc6c6cc(-c7ccccc7)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cccc(-c2cc(C(C)(C)C)cc(-c3cccc(C(C)(C)C)c3)c2N2c3ccc([Si](c4ccccc4)(c4ccccc4)c4ccccc4)cc3B3c4ccc(-n5c6ccc(-c7ccccc7)cc6c6cc(-c7ccccc7)ccc65)cc4N(c4c(-c5cccc(C(C)(C)C)c5)cc(C(C)(C)C)cc4-c4cccc(C(C)(C)C)c4)c4cc(C(C)(C)C)cc2c43)c1] 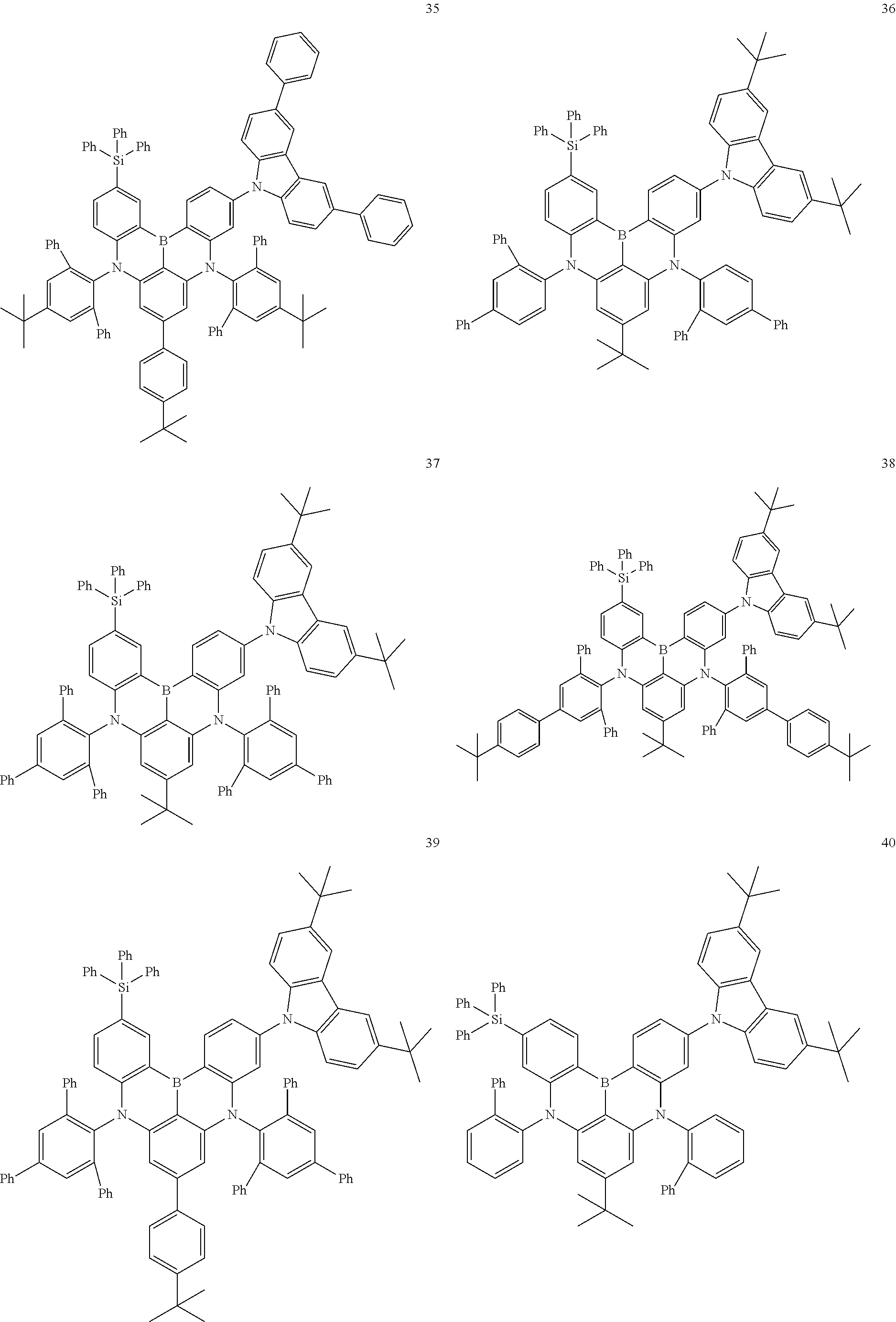 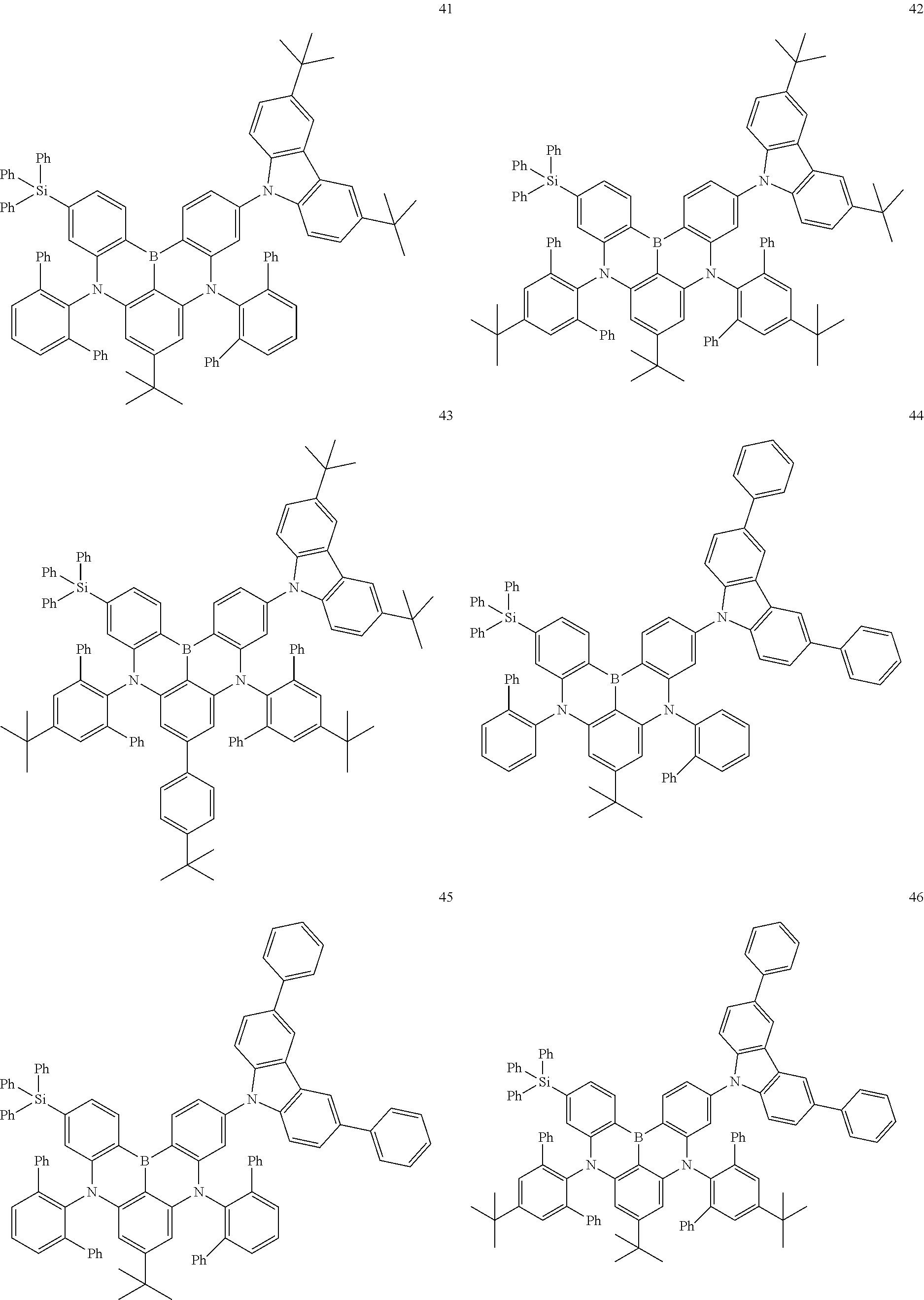 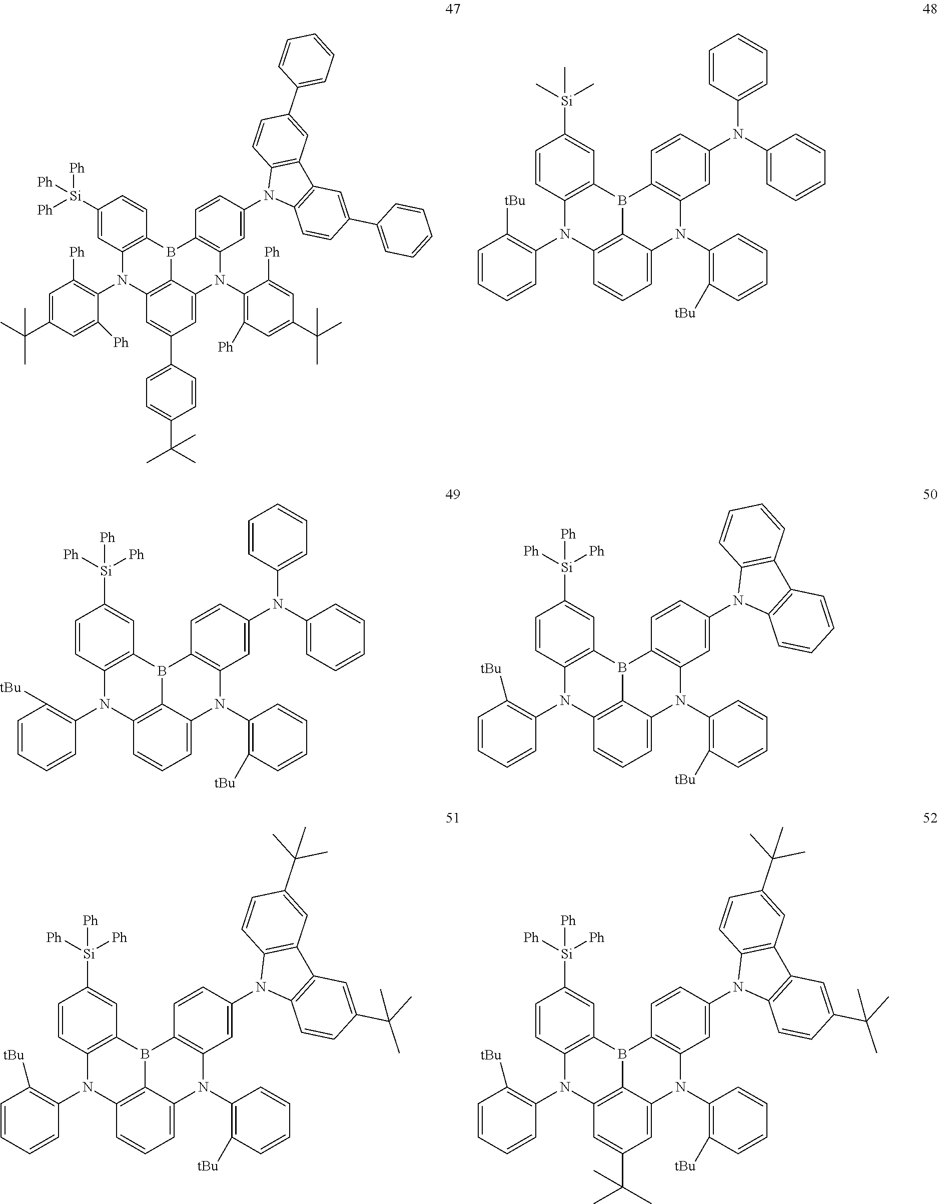 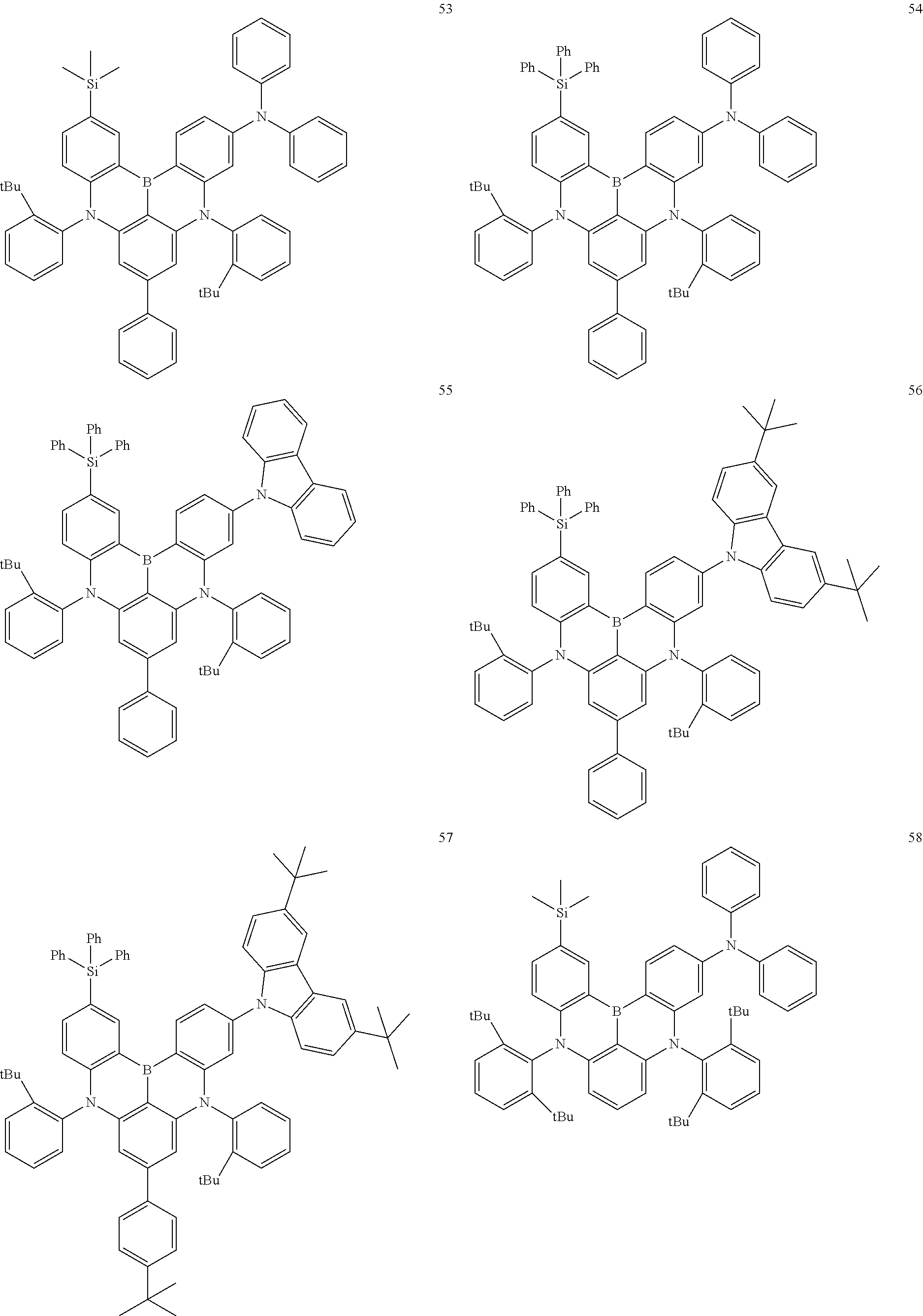 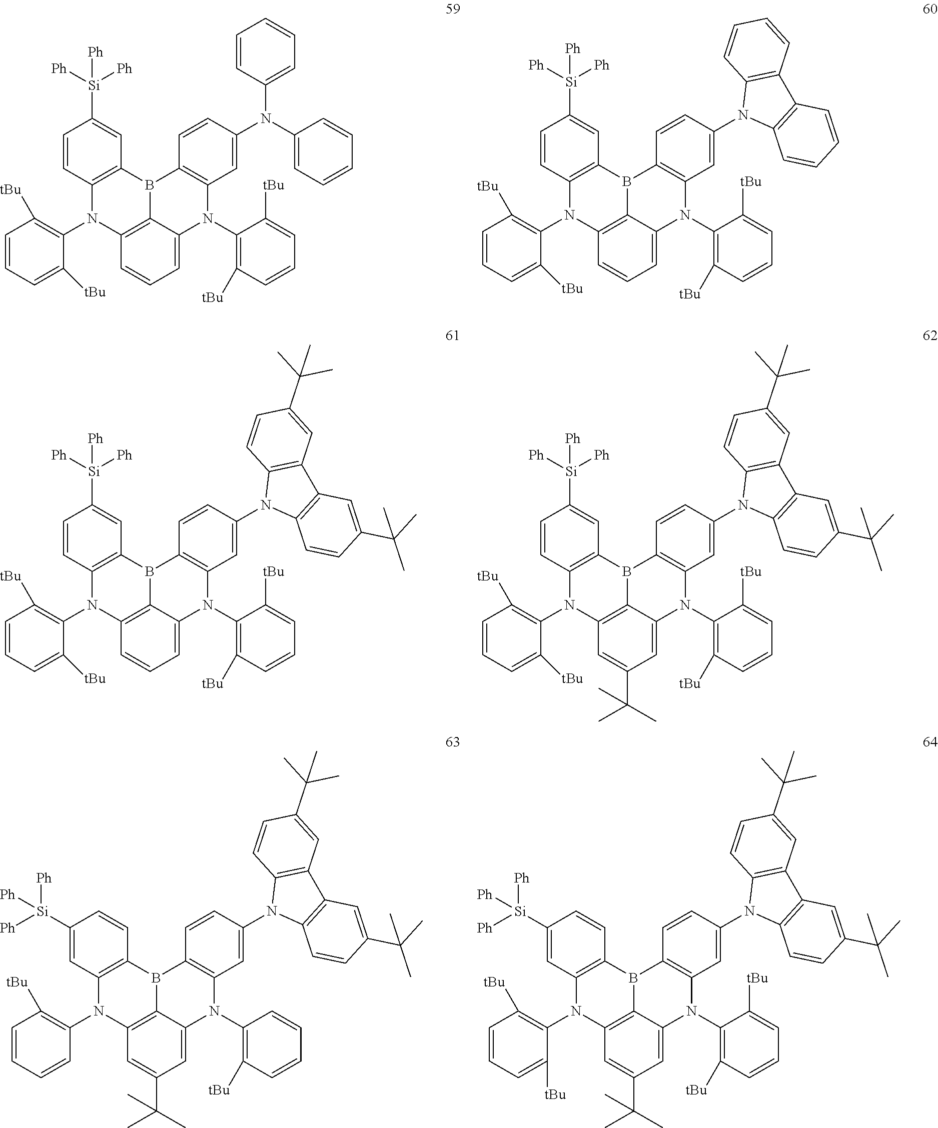 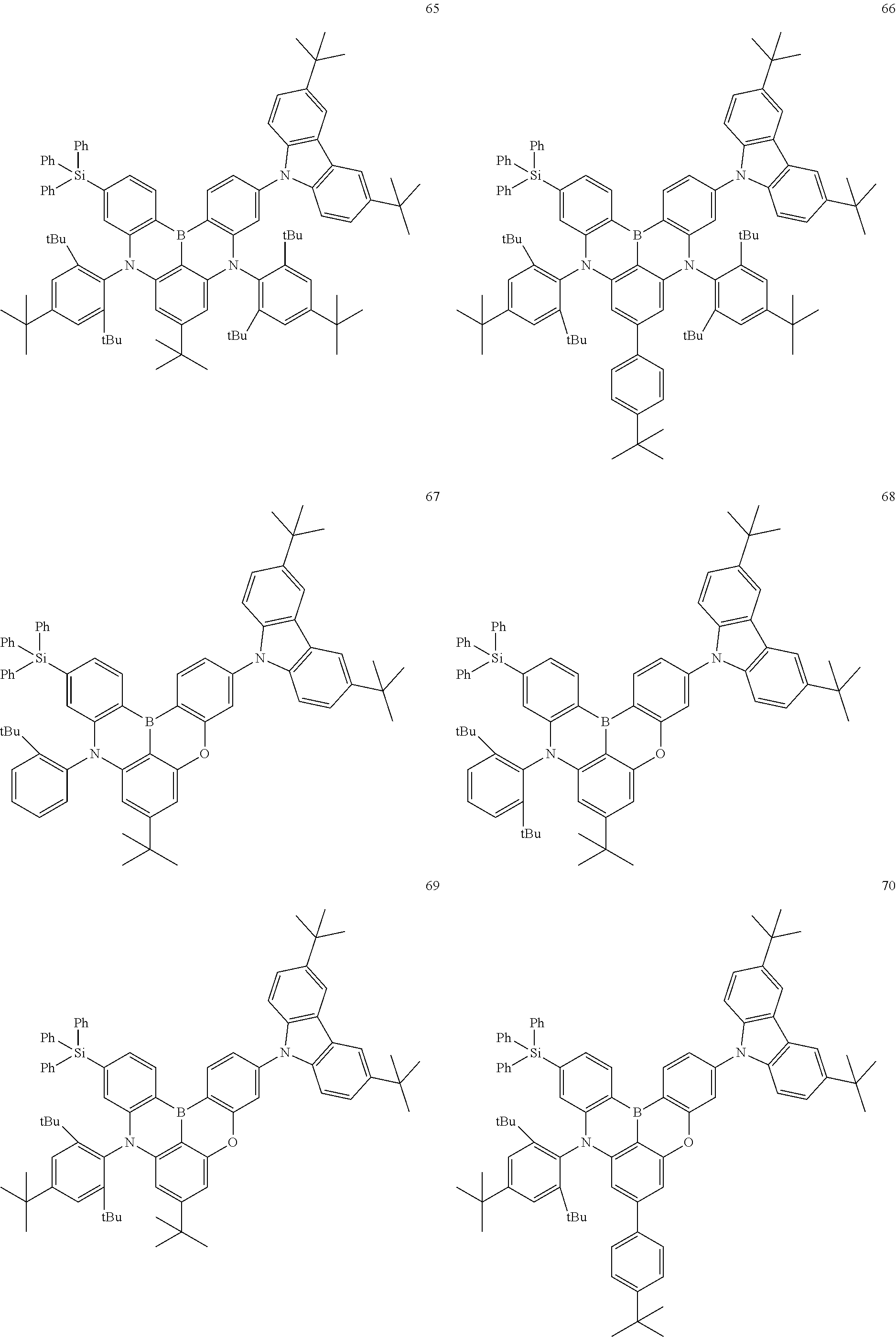 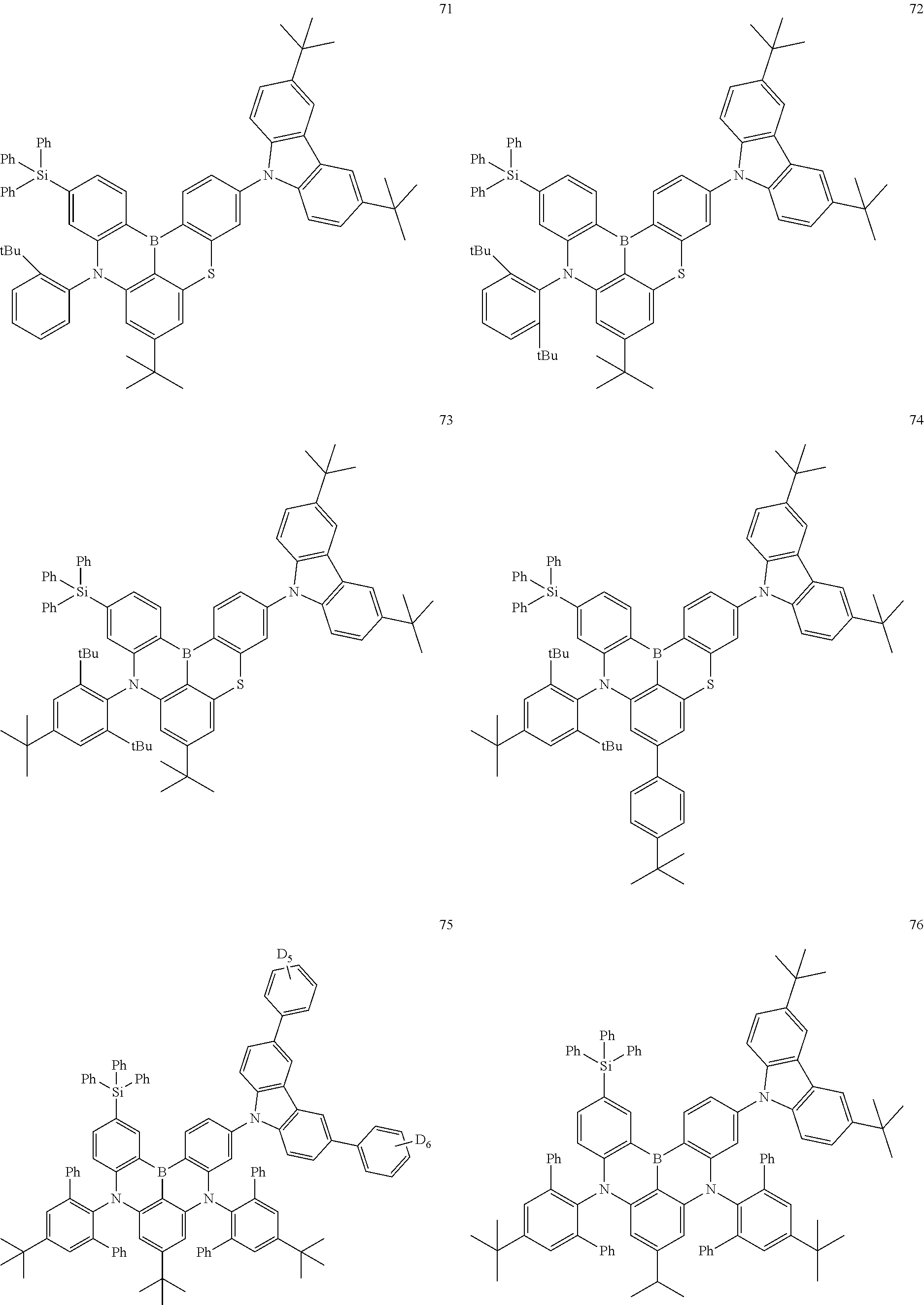 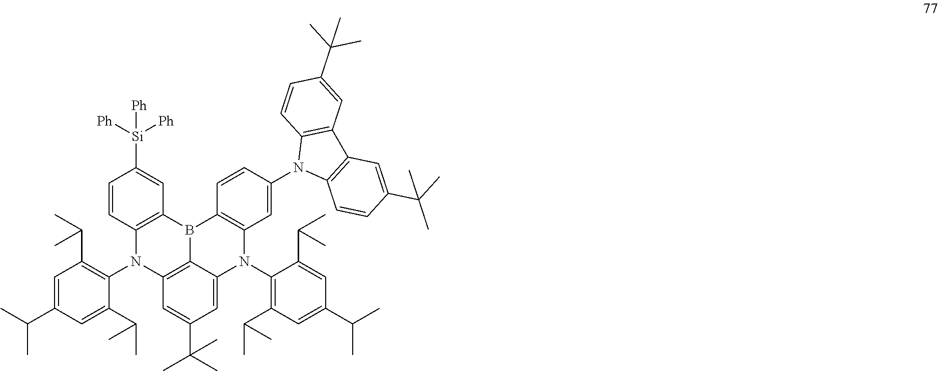 [SMILES: CC(C)c1cc(C(C)C)c(N2c3ccc([Si](c4ccccc4)(c4ccccc4)c4ccccc4)cc3B3c4ccc(-n5c6ccc(C(C)(C)C)cc6c6cc(C(C)(C)C)ccc65)cc4N(c4c(C(C)C)cc(C(C)C)cc4C(C)C)c4cc(C(C)(C)C)cc2c43)c(C(C)C)c1]
wherein in Compound Group 1,
D is a deuterium atom, and
Ph is an unsubstituted phenyl group.

9. The light emitting element of claim 1, wherein the at least one functional layer further comprises at least one of a second compound represented by Formula HT and a third compound represented by Formula ET: 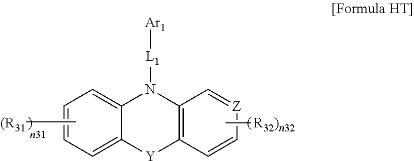
wherein in Formula HT,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms or a substituted or unsubstituted heteroaryl group of 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring,
n31 is an integer from 0 to 4, and
n32 is an integer from 0 to 3; 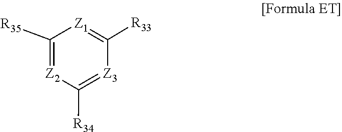
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring.

10. The light emitting element of claim 9, wherein the at least one functional layer comprises the first compound, the second compound, and the third compound.

11. The light emitting element of claim 9, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound and the third compound.

12. The light emitting element of claim 11, wherein the emission layer emits delayed fluorescence.

13. The light emitting element of claim 11, wherein the emission layer emits blue light.

14. The light emitting element of claim 1, wherein the at least one functional layer further comprises a fourth compound represented by Formula PS: 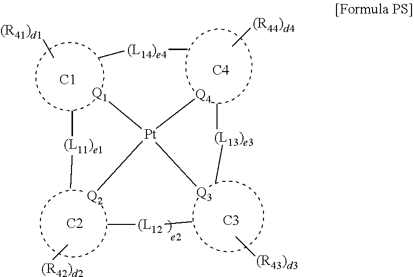
wherein in Formula PS,
Q₁ to Q₄t are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₄ are each independently a direct linkage, 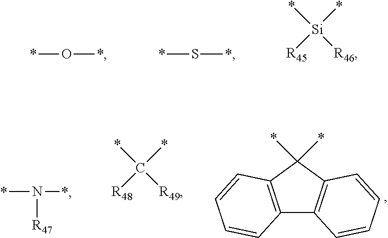
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, wherein in L₁₁ to L₁₄, ----* represents a bond to one of C1 to C4,
e1 to e4 are each independently 0 or 1,
R₄₁ to R₄₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring, and
d1 to d4 are each independently an integer from 0 to 4.

15. The light emitting element of claim 14, wherein the at least one functional layer comprises the first compound, the second compound, the third compound, and the fourth compound.

16. A polycyclic compound represented by Formula 1: 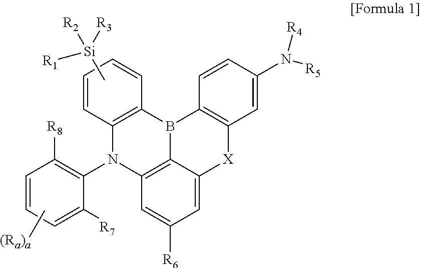
wherein in Formula 1,
X is N(Ar), O, or S,
Ar is a substituted or unsubstituted aryl group of 6 to 30 ring-forming carbon atoms,
R₁ to R₅ are each independently a substituted or unsubstituted alkyl group of 1 to 30 carbon atoms, a substituted or unsubstituted aryl group of 6 to 30 ring-forming carbon atoms, or combined with an adjacent group to form a ring,
R₆ and Rₐ are each independently a hydrogen atom, a substituted or unsubstituted alkyl group of 3 to 30 carbon atoms, or a substituted or unsubstituted aryl group of 6 to 30 ring-forming carbon atoms,
at least one of R₇ and R₈ is a substituted or unsubstituted alkyl group of 3 to 30 carbon atoms or a substituted or unsubstituted aryl group of 6 to 30 ring-forming carbon atoms, and the remainder of R₇ and R₈ is a hydrogen atom,
a is an integer from 0 to 3, and
at least one hydrogen atom is optionally substituted with a deuterium atom.

17. The polycyclic compound of claim 16, wherein the polycyclic compound represented by Formula 1 is represented by Formula 1-1a or Formula 1-1b: 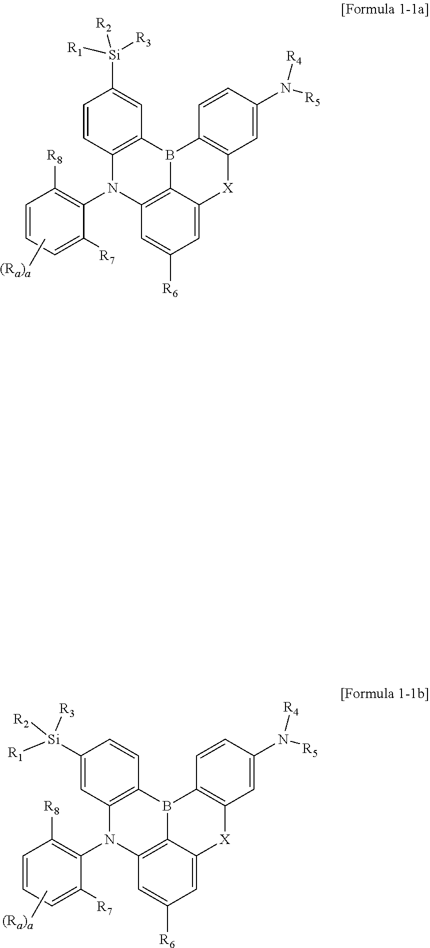
wherein in Formula 1-1a and Formula 1-1b,
X, R₁ to R₈, Rₐ, and a are each as defined in Formula 1.

18. The polycyclic compound of claim 16, wherein the polycyclic compound represented by Formula 1 is represented by Formula 1-2a or Formula 1-2b: 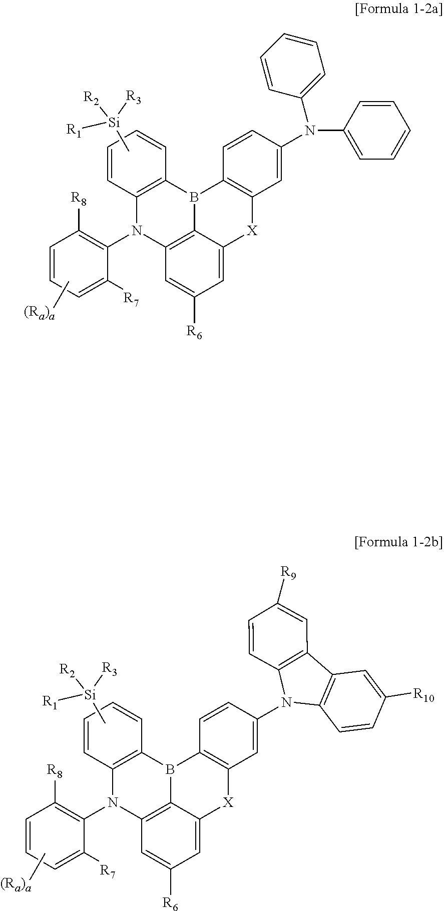
wherein in Formula 1-2a and Formula 1-2b,
R₉ and R₁₀ are each independently a hydrogen atom, a substituted or unsubstituted alkyl group of 3 to 30 carbon atoms, or a substituted or unsubstituted aryl group of 6 to 30 ring-forming carbon atoms, and
X, R₁ to R₃, R₆ to R₈, Rₐ, and a are each as defined in Formula 1.

19. The polycyclic compound of claim 16, wherein the polycyclic compound represented by Formula 1 is represented by one of Formula 1-3a to Formula 1-3c: 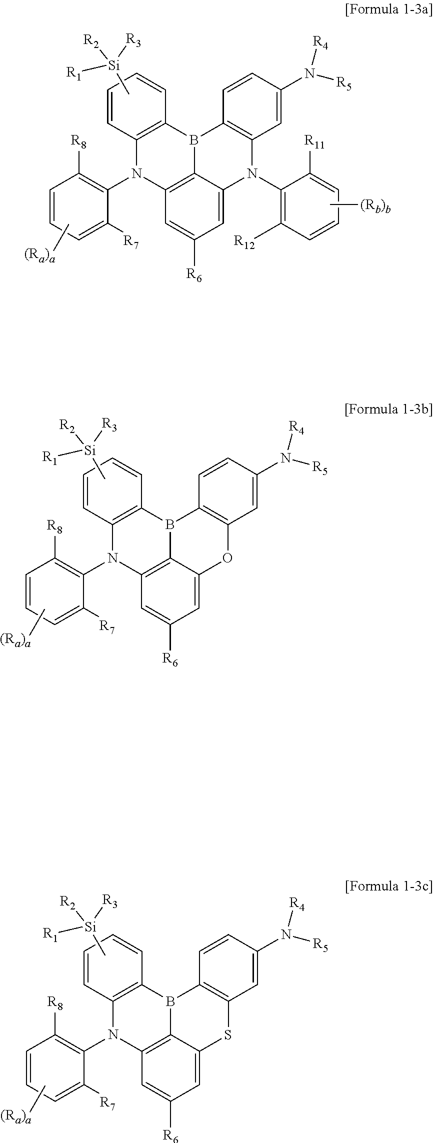
wherein in Formula 1-3a to Formula 1-3c,
at least one of R₁₁ and R₁₂ is a substituted or unsubstituted alkyl group of 3 to 30 carbon atoms or a substituted or unsubstituted aryl group of 6 to 30 ring-forming carbon atoms, and the remainder of R₁₁ and R₁₂ is a hydrogen atom,
R_{b} is a hydrogen atom, a substituted or unsubstituted alkyl group of 3 to 30 carbon atoms, or a substituted or unsubstituted aryl group of 6 to 30 ring-forming carbon atoms,
b is an integer from 0 to 3, and
R₁ to R₈, Rₐ, and a are each as defined in Formula 1.

20. The polycyclic compound of claim 16, wherein the polycyclic compound represented by Formula 1 is represented by one of Formula 1-4a to Formula 1-4c: 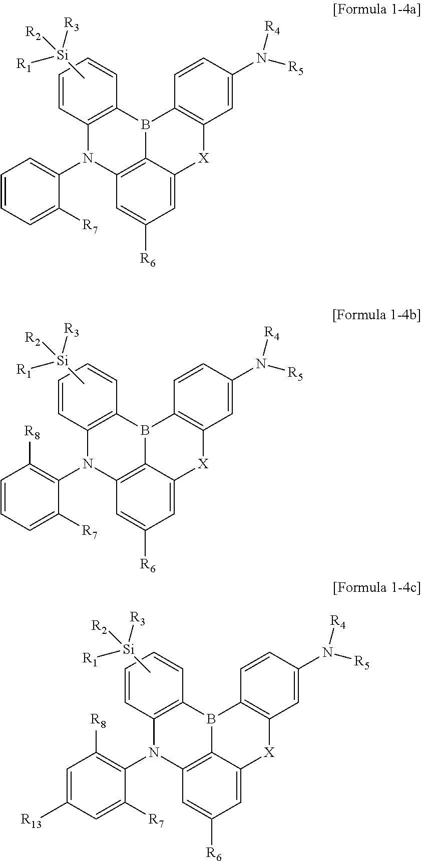
wherein in Formula 1-4a to Formula 1-4c,
R₇, R₈, and R₁₃ are each independently an unsubstituted i-propyl group, an unsubstituted t-butyl group, or a substituted or unsubstituted phenyl group, and
X and R₁ to R₆ are each as defined in Formula 1.

21. The polycyclic compound of claim 16, wherein the polycyclic compound represented by Formula 1 is represented by one of Formula 1-5a to Formula 1-5e: 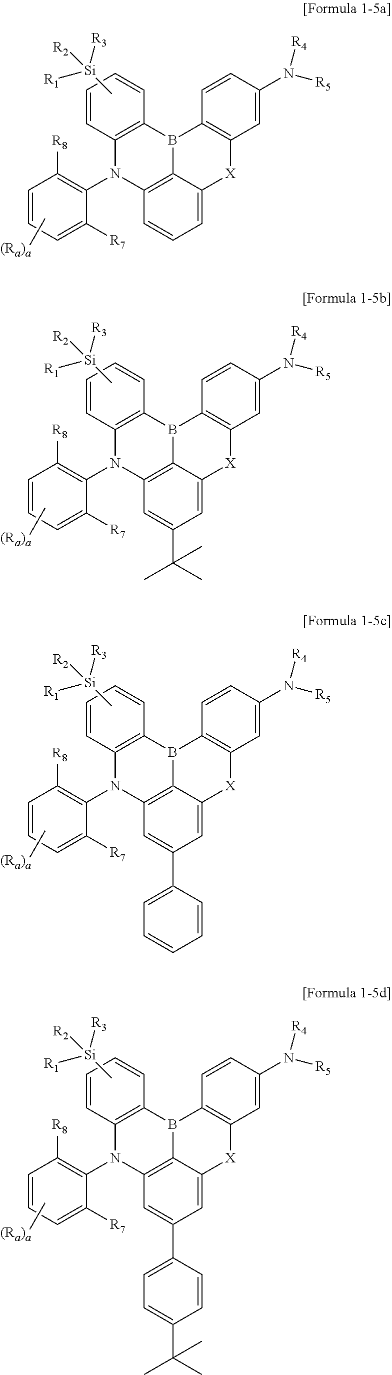 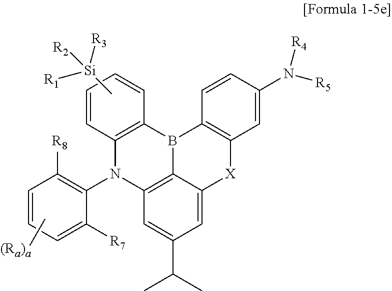
wherein in Formula 1-5a to Formula 1-5e,
X, R₁ to R₅, R₇, R₈, Rₐ, and a are each as defined in Formula 1.

22. The polycyclic compound of claim 16, wherein R₁ to R₃ are each independently an unsubstituted methyl group or an unsubstituted phenyl group.

23. The polycyclic compound of claim 16, wherein the polycyclic compound represented by Formula 1 is selected from Compound Group 1: 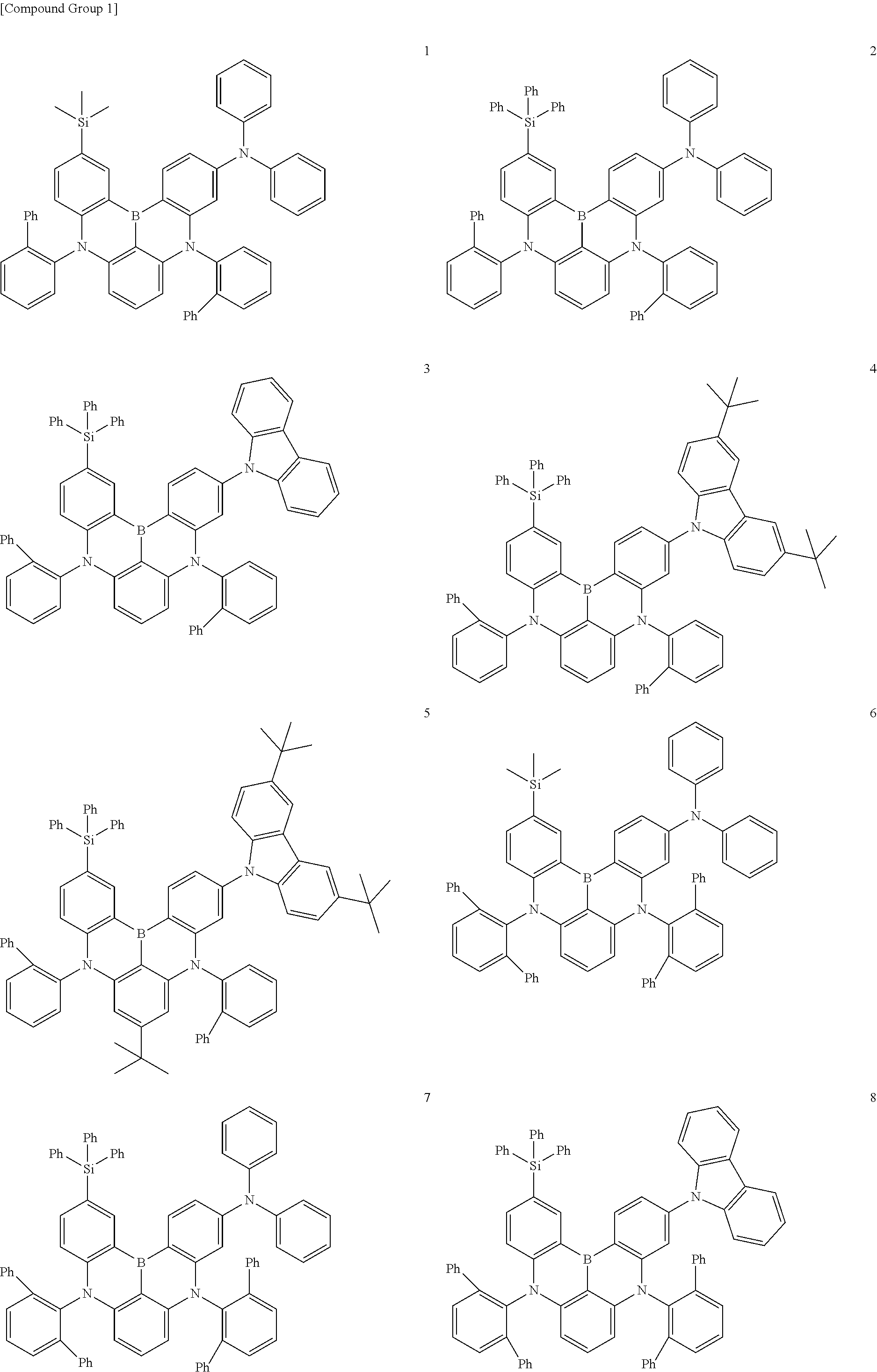 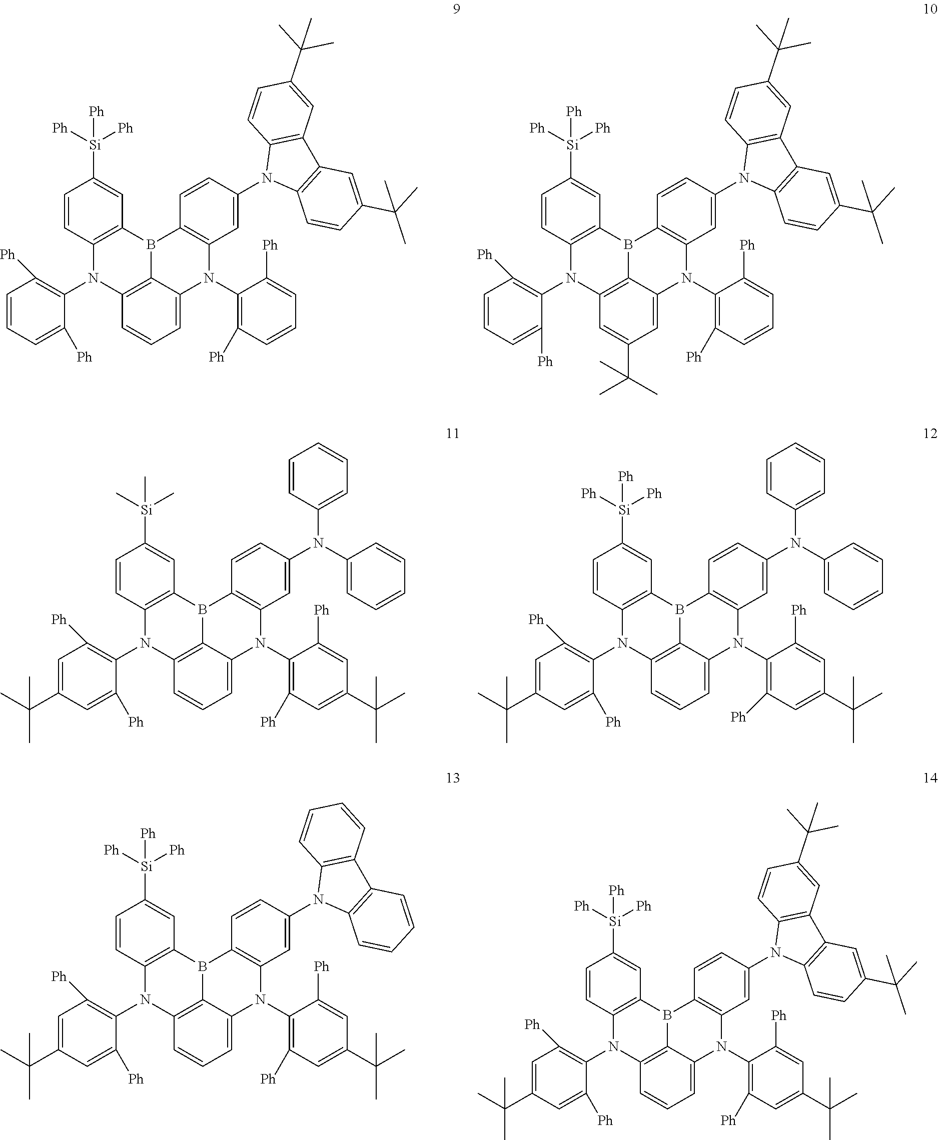 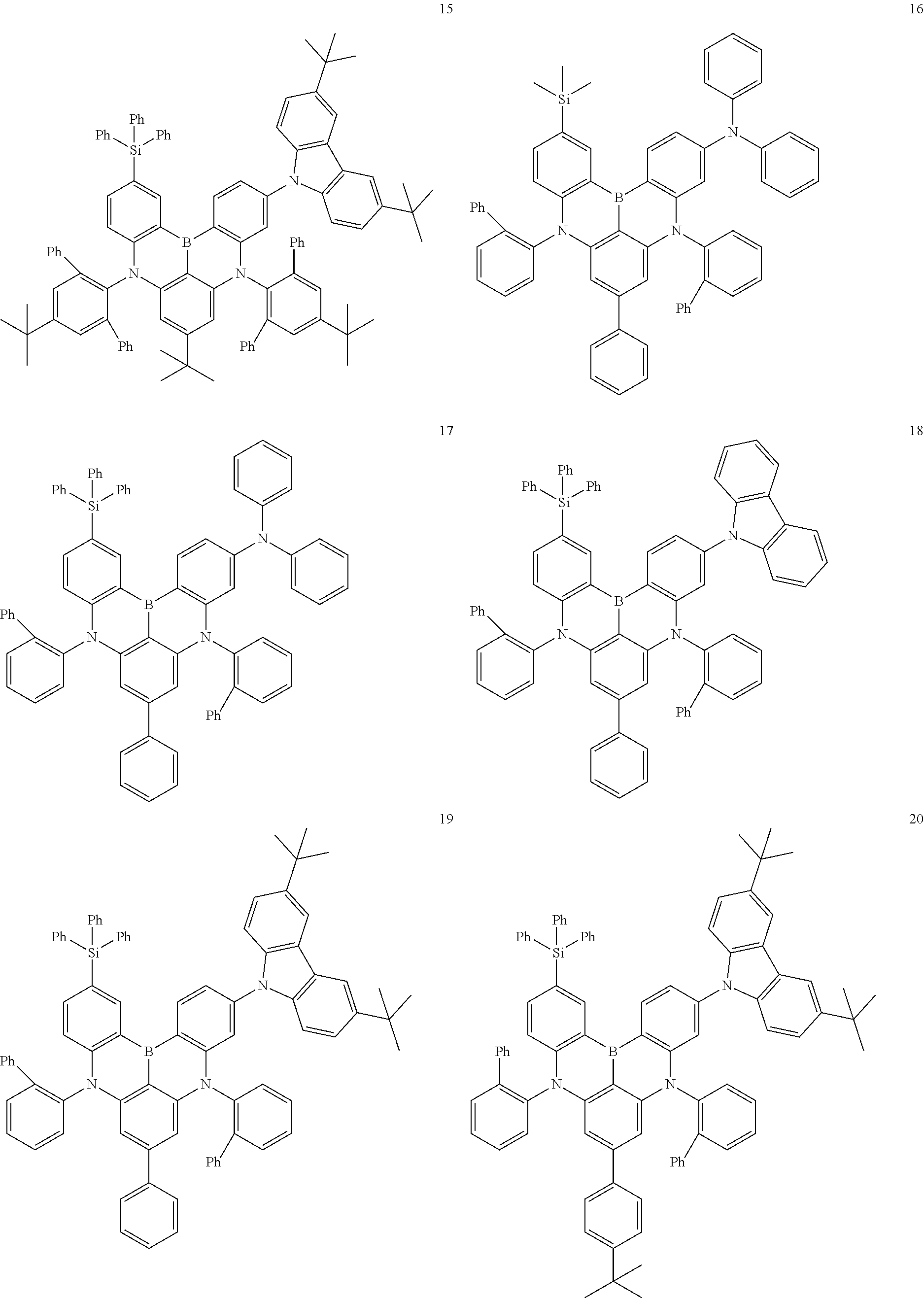 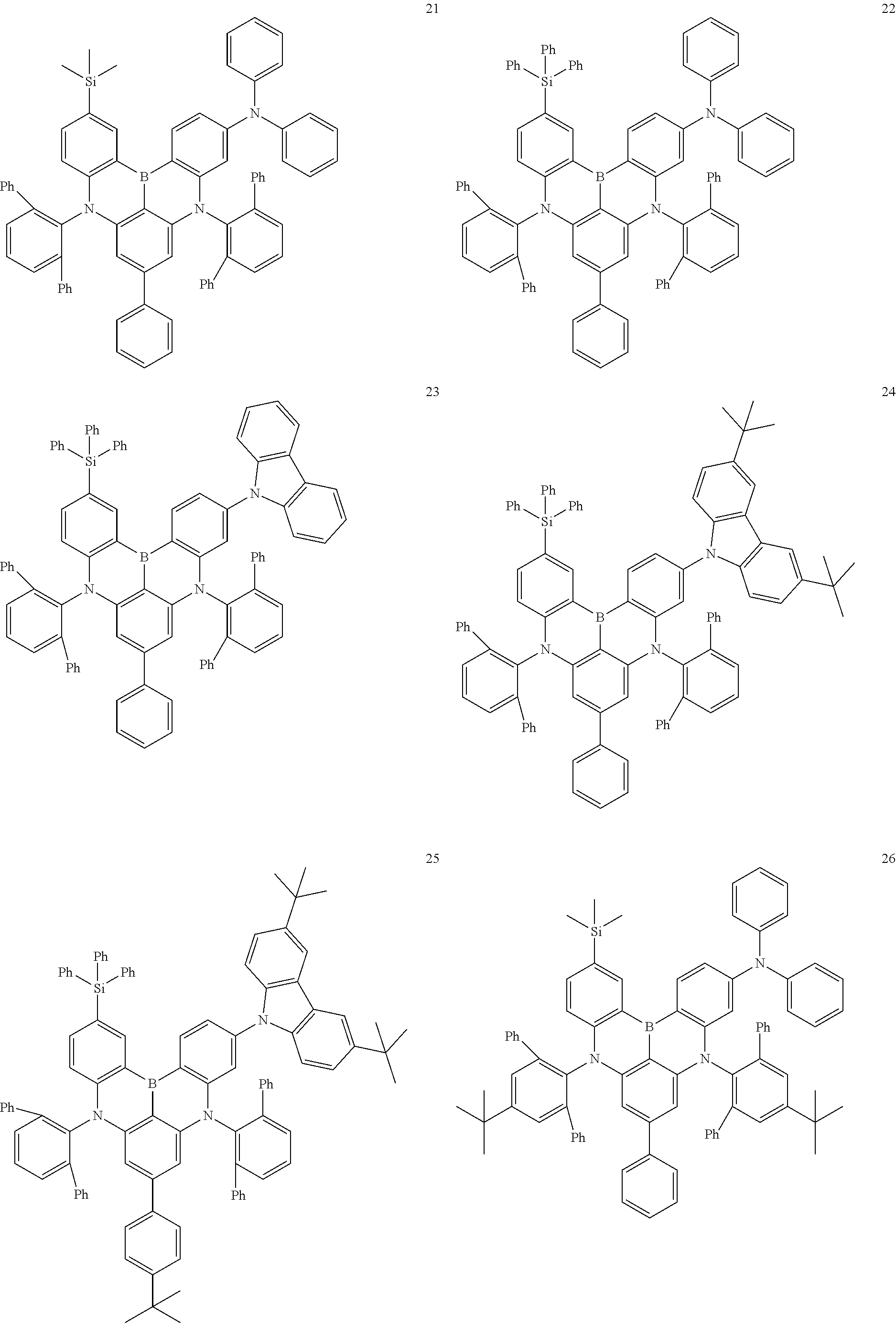 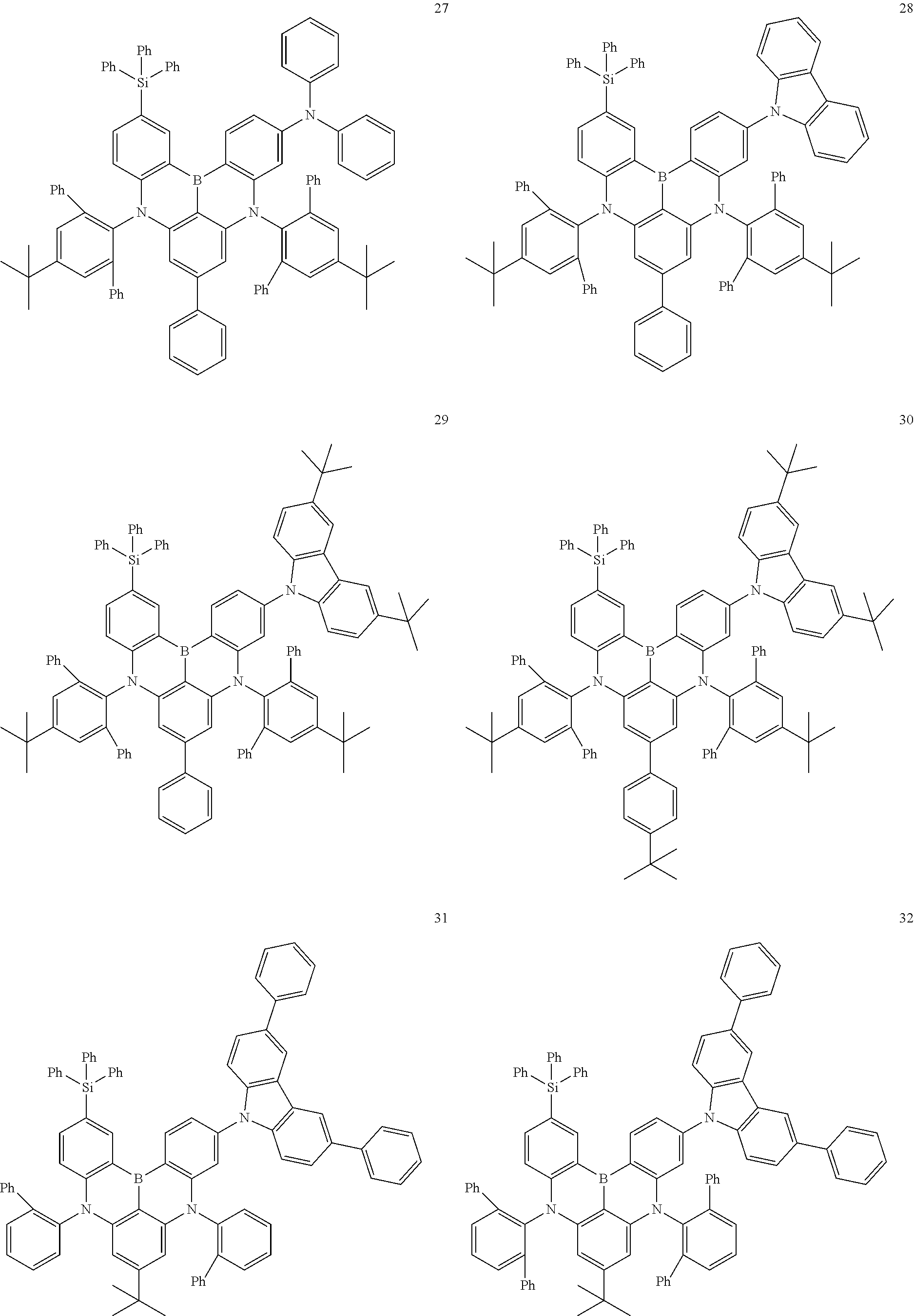 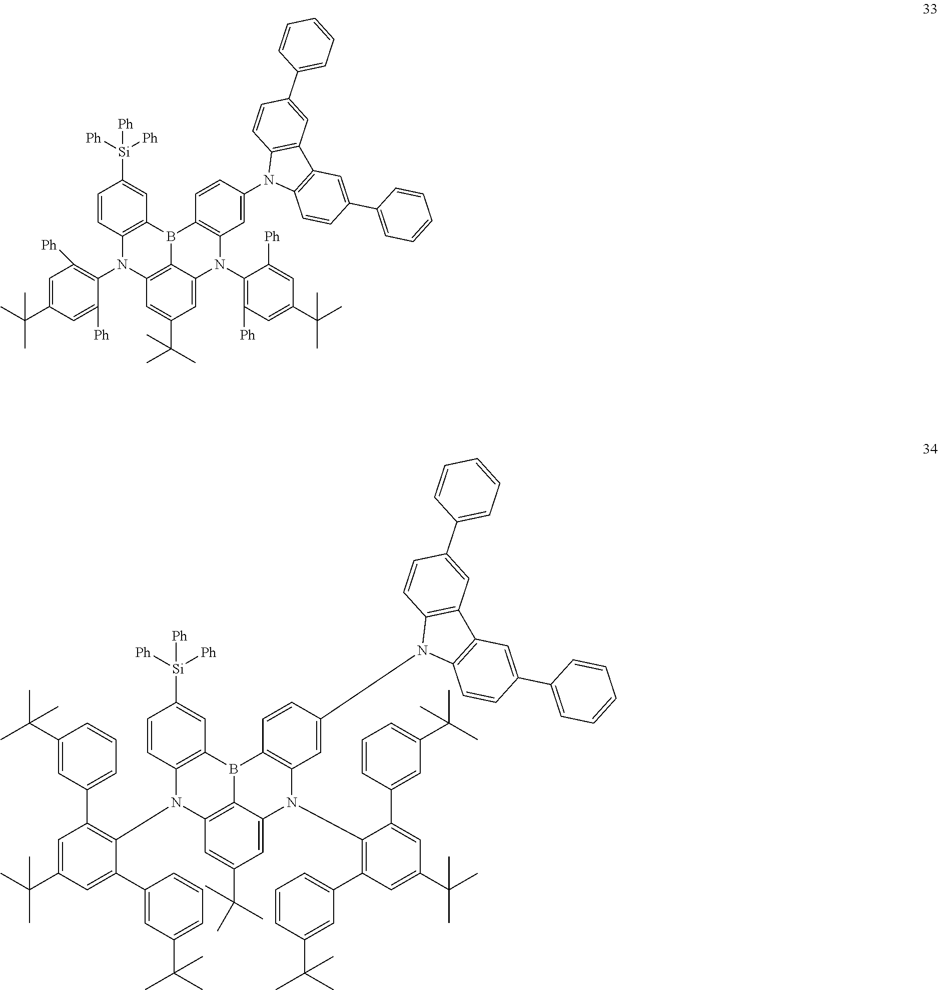 [SMILES: CC(C)(C)c1cc(-c2ccccc2)c(N2c3ccc([Si](c4ccccc4)(c4ccccc4)c4ccccc4)cc3B3c4ccc(-n5c6ccc(-c7ccccc7)cc6c6cc(-c7ccccc7)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cccc(-c2cc(C(C)(C)C)cc(-c3cccc(C(C)(C)C)c3)c2N2c3ccc([Si](c4ccccc4)(c4ccccc4)c4ccccc4)cc3B3c4ccc(-n5c6ccc(-c7ccccc7)cc6c6cc(-c7ccccc7)ccc65)cc4N(c4c(-c5cccc(C(C)(C)C)c5)cc(C(C)(C)C)cc4-c4cccc(C(C)(C)C)c4)c4cc(C(C)(C)C)cc2c43)c1] 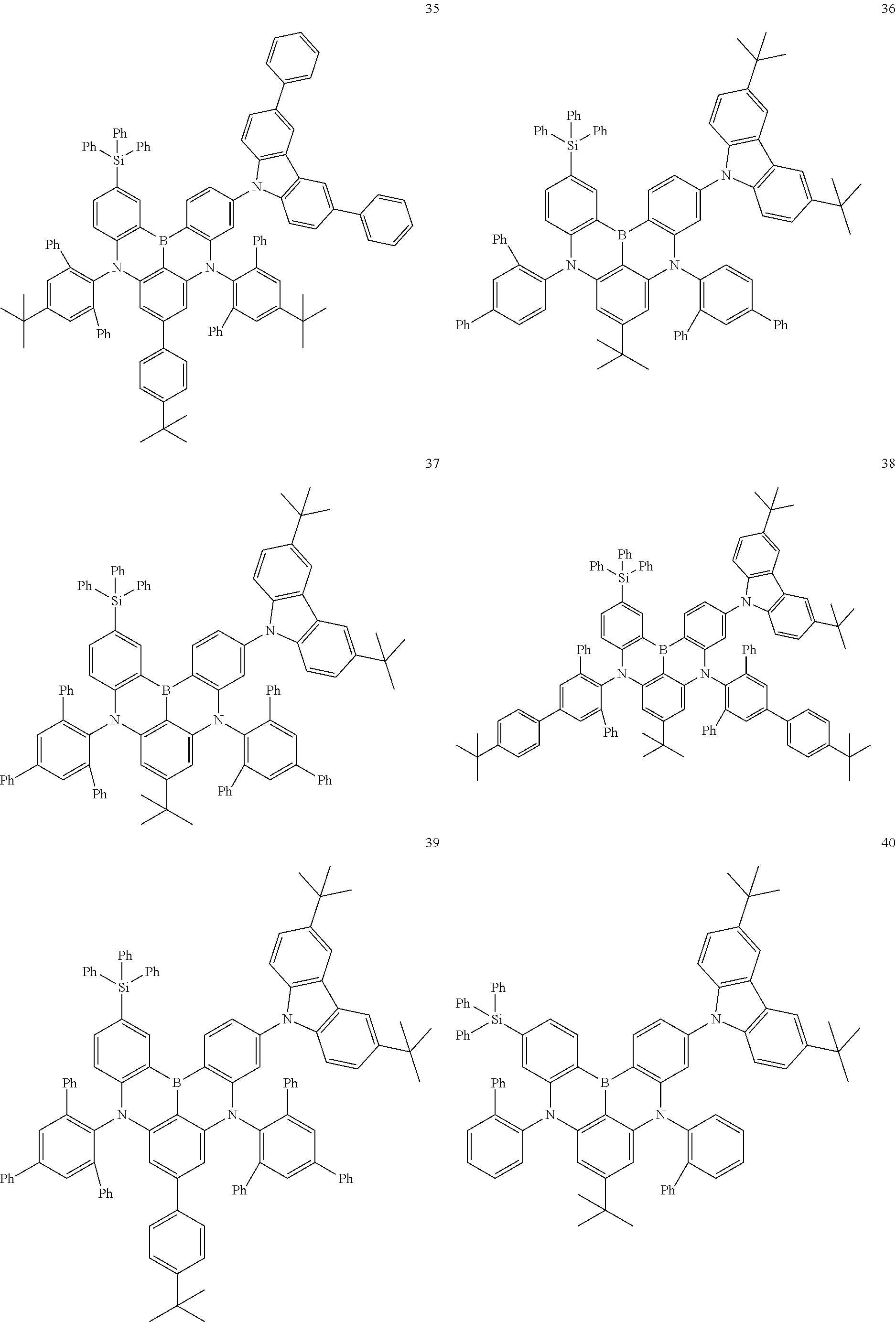 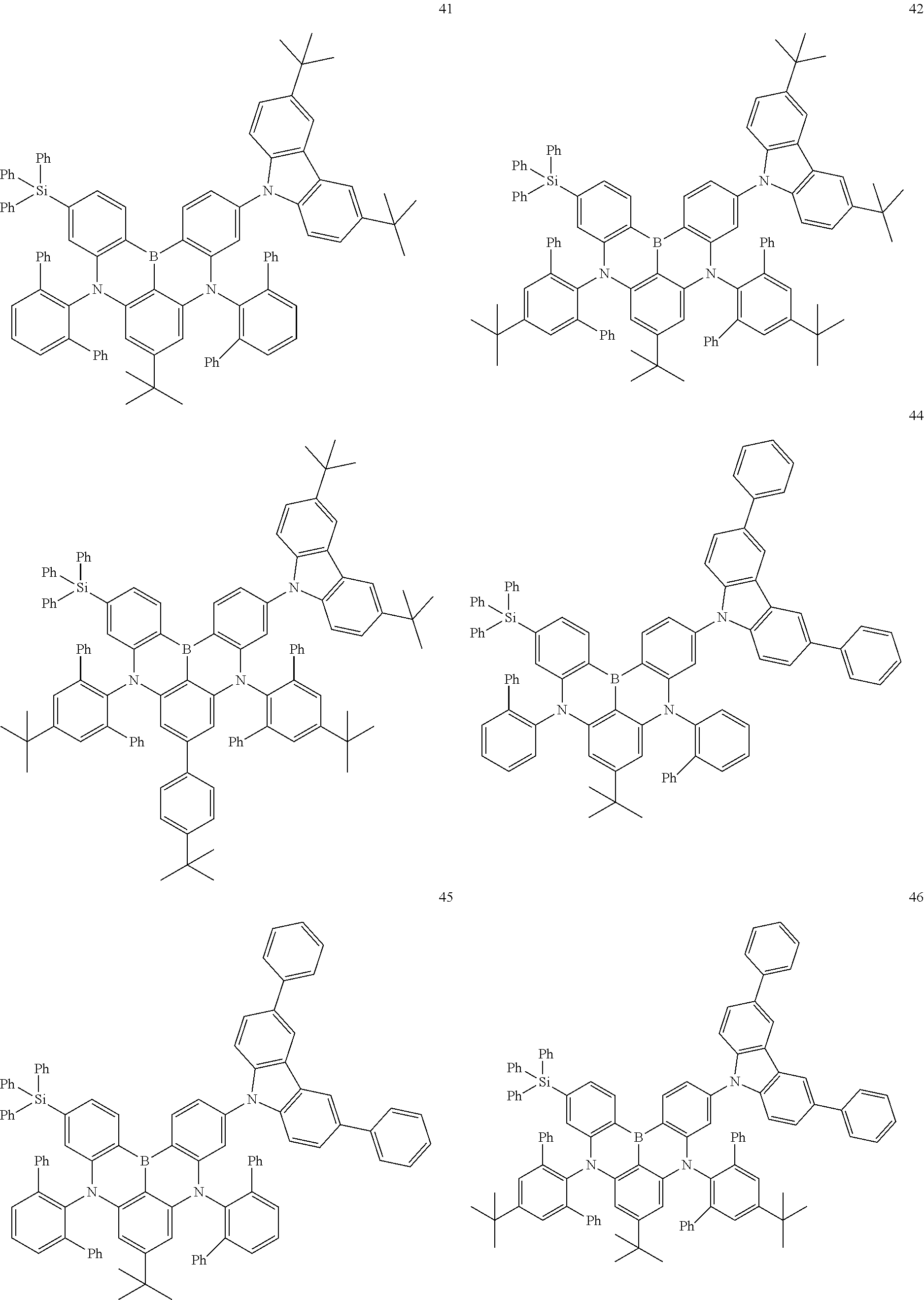 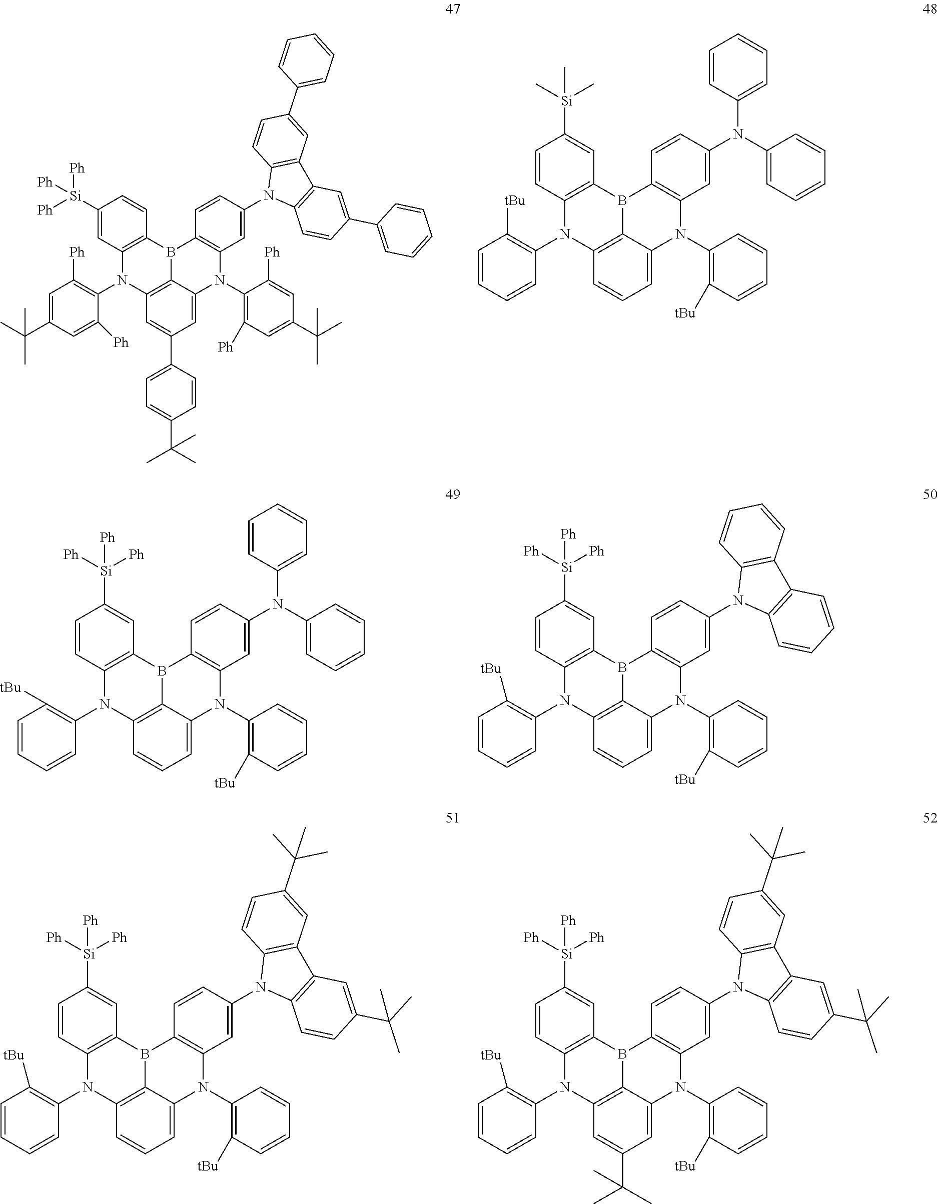 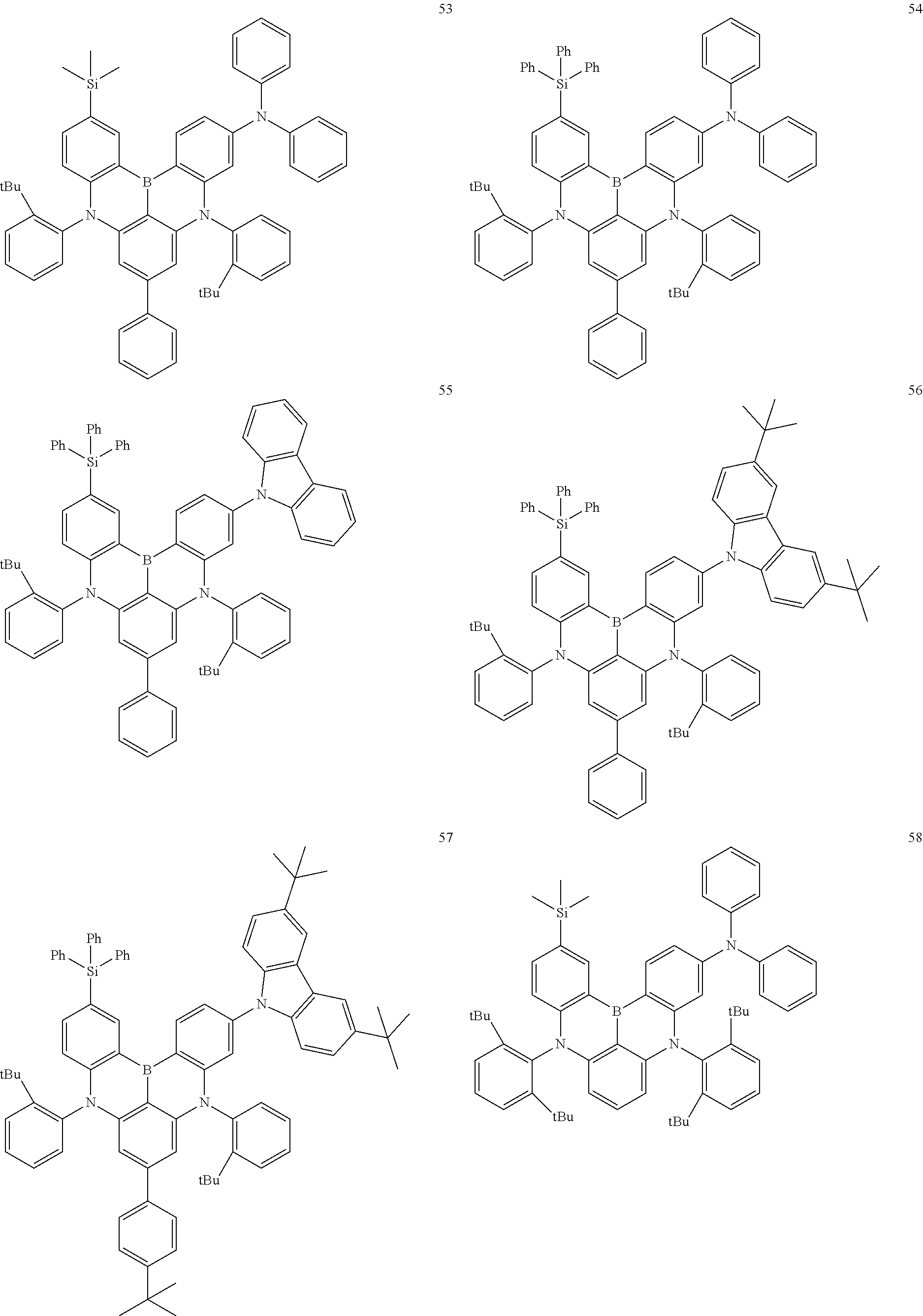 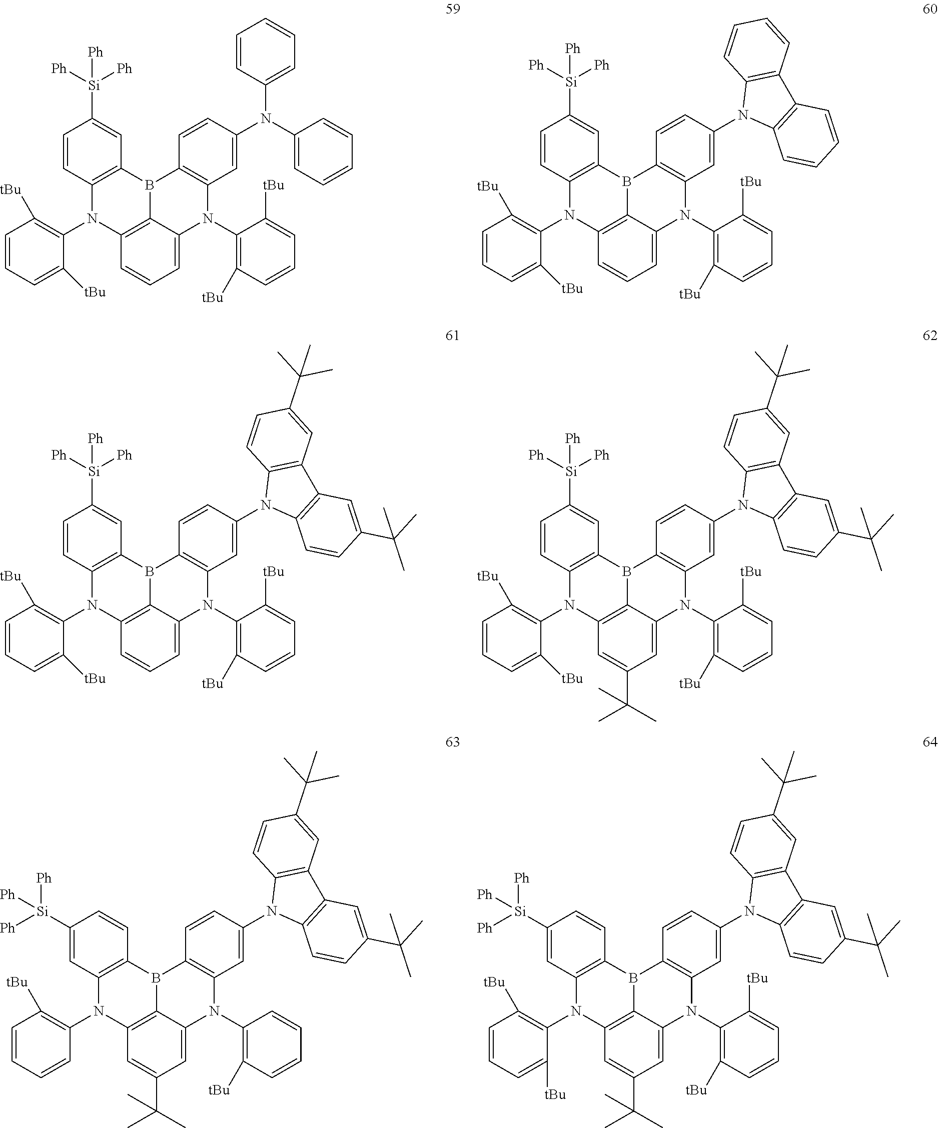 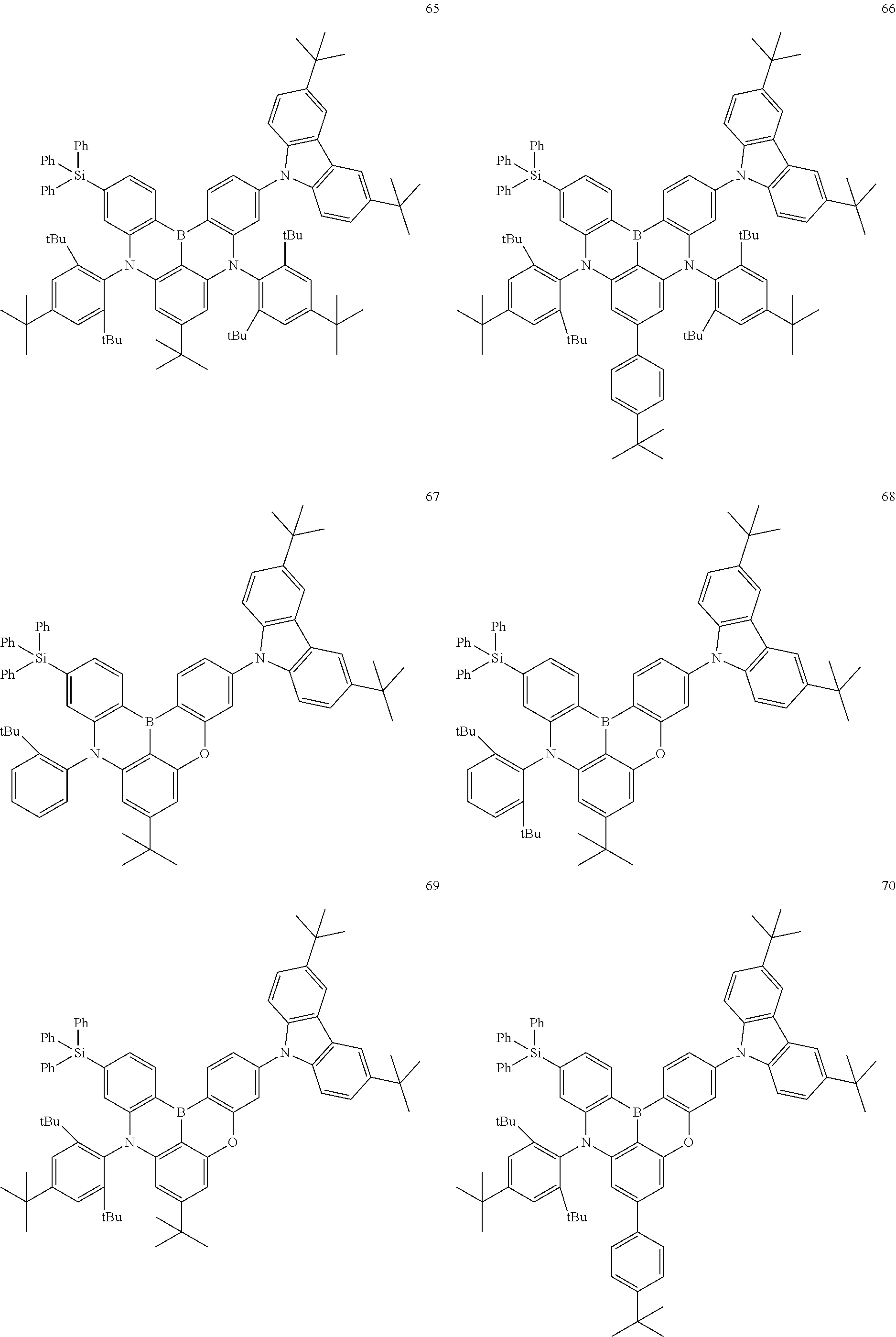 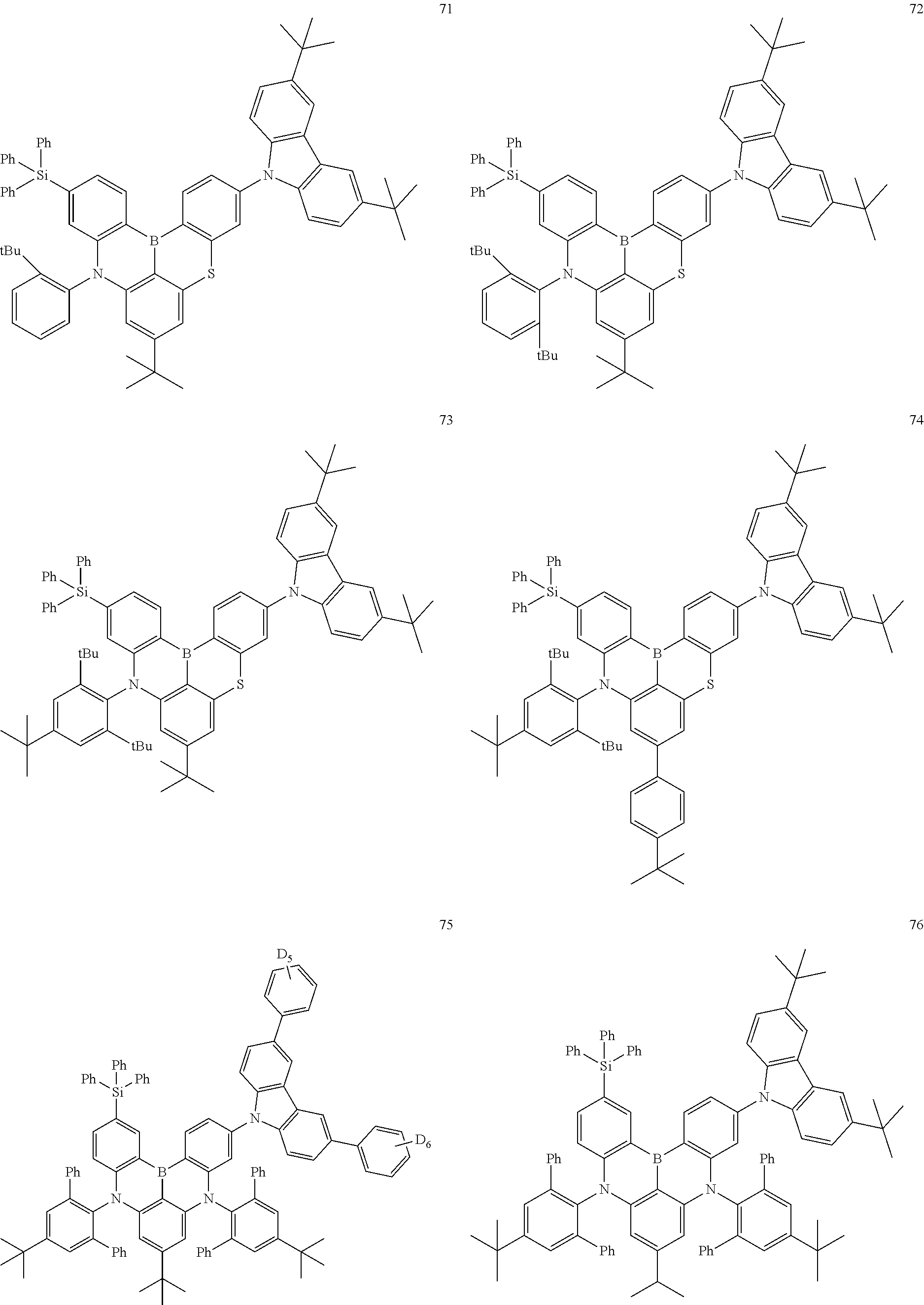 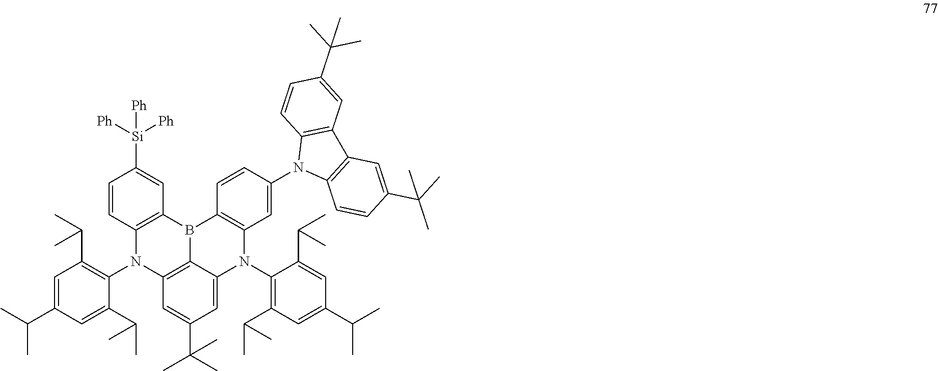 [SMILES: CC(C)c1cc(C(C)C)c(N2c3ccc([Si](c4ccccc4)(c4ccccc4)c4ccccc4)cc3B3c4ccc(-n5c6ccc(C(C)(C)C)cc6c6cc(C(C)(C)C)ccc65)cc4N(c4c(C(C)C)cc(C(C)C)cc4C(C)C)c4cc(C(C)(C)C)cc2c43)c(C(C)C)c1]
wherein in Compound Group 1,
D is a deuterium atom, and
Ph is an unsubstituted phenyl group.

24. A display device comprising:
a base layer;
a circuit layer disposed on the base layer; and
a display element layer disposed on the circuit layer and comprising a light emitting element, wherein
the light emitting element comprises:
a first electrode,
a second electrode facing the first electrode, and
at least one functional layer disposed between the first electrode and the second electrode, and
the functional layer comprises:
a first compound represented by Formula 1; and
at least one of a second compound represented by Formula HT and a third compound represented by Formula ET: 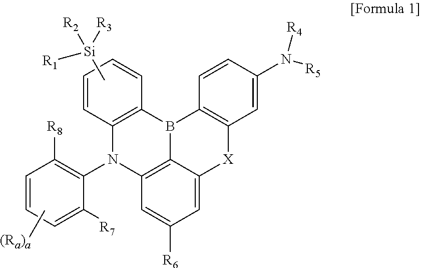
wherein in Formula 1,
X is N(Ar), O, or S,
Ar is a substituted or unsubstituted aryl group of 6 to 30 ring-forming carbon atoms,
R₁ to R₅ are each independently a substituted or unsubstituted alkyl group of 1 to 30 carbon atoms, a substituted or unsubstituted aryl group of 6 to 30 ring-forming carbon atoms, or combined with an adjacent group to form a ring,
R₆ and Rₐ are each independently a hydrogen atom, a substituted or unsubstituted alkyl group of 3 to 30 carbon atoms, or a substituted or unsubstituted aryl group of 6 to 30 ring-forming carbon atoms,
at least one of R₇ and R₈ is a substituted or unsubstituted alkyl group of 3 to 30 carbon atoms or a substituted or unsubstituted aryl group of 6 to 30 ring-forming carbon atoms, and the remainder of R₇ and R₈ is a hydrogen atom,
a is an integer from 0 to 3, and
at least one hydrogen atom is optionally substituted with a deuterium atom; 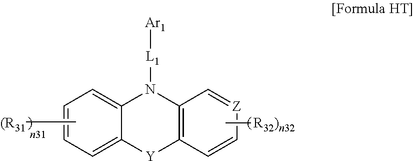
wherein in Formula HT,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms or a substituted or unsubstituted heteroaryl group of 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring,
n31 is an integer from 0 to 4, and
n32 is an integer from 0 to 3; 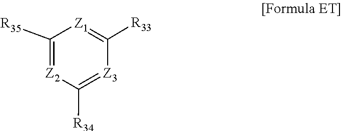
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, a substituted or unsubstituted heteroaryl group of 2 to 60 ring-forming carbon atoms, or combined with an adjacent group to form a ring.

25. The display device of claim 24, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound and the third compound.

26. The display device of claim 24, wherein
the light emitting element comprises a first light emitting element emitting red light, a second light emitting element emitting green light, and a third light emitting element emitting blue light, and
the third light emitting element comprises the first compound.

27. The display device of claim 24, wherein the light emitting element emits blue light.

28. The display device of claim 24, further comprising:
a light controlling layer disposed on the display element layer and comprising a quantum dot.
